(19) United States
(12) Patent Application Publication
(10) Pub. No.: US 2026/0136753 A1
(43) Pub. Date: May 14, 2026

(54) ELECTRONIC APPARATUS, LIGHT EMITTING-ELEMENT, AND POLYCYCLIC COMPOUND FOR THE SAME

(71) Applicant: Samsung Display Co., Ltd., Yongin-si (KR)

(72) Inventors: Hirokazu KUWABARA, Yokohama-shi (JP); Keigo HOSHI, Yokohama-shi (JP); Yoshiro SUGITA, Yokohama-shi (JP)

(21) Appl. No.: 19/380,546

(22) Filed: Nov. 5, 2025

(30) Foreign Application Priority Data
Nov. 12, 2024 (JP) 2024-197105

(51) Int. Cl. H10K 50/12; C09K 11/06; H10K 59/35; H10K 85/30; H10K 85/40; H10K 85/60; H10K 101/00

(52) U.S. Cl. CPC H10K 50/121; C09K 11/06; H10K 59/35; H10K 85/342; H10K 85/346; H10K 85/40; H10K 85/623; H10K 85/626; H10K 85/633; H10K 85/636; H10K 85/654; H10K 85/6572; H10K 85/6574; H10K 85/6576; H10K 85/658; C09K 2211/10; H10K 2101/90

(57) ABSTRACT

A polycyclic compound, a light-emitting element including the polycyclic compound, and an electronic apparatus including the light-emitting element are disclosed. The light-emitting element may include a first electrode, a second electrode being opposite to (e.g., facing) the first electrode, and an emission layer disposed or provided between the first electrode and the second electrode and including a polycyclic compound represented by Formula 1.

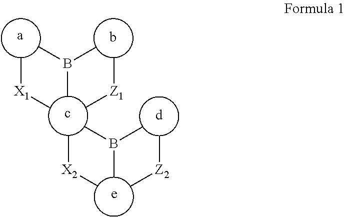

### CROSS-REFERENCE TO RELATED APPLICATION

The present application claims priority to and the benefit of Japanese Patent Application No. 2024-197105, filed on Nov. 12, 2024, the entire disclosure of which is incorporated herein by reference.

### BACKGROUND

### 1. Field

One or more embodiments of the present disclosure relate to an electronic apparatus, a light-emitting element, and a polycyclic compound utilized for the light-emitting element.

### 2. Description of the Related Art

Development of organic electroluminescence display devices as an image display device has been conducted. The organic electroluminescence display devices include, namely, a self-luminous display device which achieves display by recombining, in an emission layer, holes and electrons respectively injected from a first electrode and a second electrode to cause a light-emitting material including an organic compound in the emission layer to emit light.

For application of a light-emitting element to a display device, it is desirable to improve or enhance high luminous efficiency and long lifespan and develop materials for a light-emitting element, which may stably or suitably accomplish the requirements. For example, development for thermally activated delayed fluorescence (TADF) material that utilizes a delayed fluorescence phenomenon is underway.

### SUMMARY

One or more aspects of embodiments of the present disclosure are directed toward an electronic apparatus having excellent or suitable display quality by including a light-emitting element having improved or enhanced luminous efficiency and lifespan.

One or more aspects of embodiments of the present disclosure are also directed toward a light-emitting element having improved or enhanced luminous efficiency and lifespan.

One or more aspects of embodiments of the present disclosure are also directed toward a polycyclic compound having improved or enhanced material lifespan.

Additional aspects of embodiments will be set forth in part in the description which follows and, in part, will be apparent from the description or may be learned by practice of the presented embodiments of the disclosure.

One or more embodiments of the present disclosure provide an electronic apparatus including a display panel including a plurality of light-emitting elements, and at least one selected from among the plurality of light-emitting elements includes a first electrode, a second electrode being opposite to (e.g., facing) the first electrode, and an emission layer disposed or provided between the first electrode and the second electrode and including a polycyclic compound represented by Formula 1.

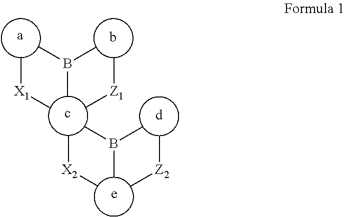

In Formula 1, ring a, ring b, ring c, ring d, and ring e may each independently be a substituted or unsubstituted aromatic hydrocarbon ring having 6 to 30 ring-forming carbon atoms, or a substituted or unsubstituted heterocycle which includes a hetero atom other than a boron atom as a ring-forming atom and has 2 to 30 ring-forming carbon atoms, or may be bonded to an adjacent group to form a ring. In Formula 1, X₁, X₂, Z₁, and Z₂ may each independently be O, S, NRₐ, or NR_{b}, and at least one of X₁, X₂, Z₁, or Z₂ may be NR_{b}, Rₐ may be a substituted or unsubstituted aryl group having 6 to 30 ring-forming carbon atoms, or may be bonded to an adjacent group to form a ring, and R_{b} may be represented by Formula 2.

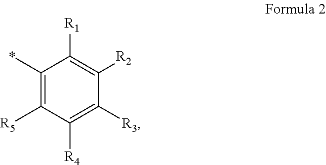

In Formula 2, R₁ to R₅ may each independently be a hydrogen atom, a deuterium atom, a halogen atom, a cyano group, a nitro group, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring, or may be represented by Formula 3, [symbol] may be a portion connected to Formula 1, and at least two selected from among R₁ to R₅ may be represented by Formula 3:

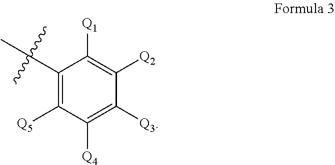

In Formula 3, Q₁ to Q₅ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and may be

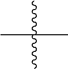

a portion connected to Formula 2.

In one or more embodiments, the electronic apparatus may include a display device including the display panel and displaying a video, and the display device may include a first emission region, a second emission region, and a third emission region, each emitting light in a different wavelength region from each other and distinguished from each other on a plane (e.g., in plan view), and the first emission region, the second emission region, and the third emission region may each be a region from which light generated in each of the plurality of light-emitting elements is emitted.

In one or more embodiments, the plurality of light-emitting elements may each include a first light-emitting element arranged to correspond to the first emission region, a second light-emitting element arranged to correspond to the second emission region, and a third light-emitting element arranged to correspond to the third emission region.

In one or more embodiments, the display device may include a plurality of display surfaces each having a different main or predominant display direction of a video from each other.

In one or more embodiments, the electronic apparatus may include a plurality of display devices which are independently controlled and each displays a video, and at least one selected from among the plurality of display devices may include the display panel.

In one or more embodiments, the electronic apparatus may further include at least one selected from among a processor, a memory, and a power module.

In one or more embodiments, the electronic apparatus may include the display panel and may be a television, a monitor, an outdoor billboard, a personal computer, a laptop computer, a personal digital assistant, a vehicular apparatus, a game console, a smartphone, a tablet terminal, a smart watch, or a camera.

In one or more embodiments of the present disclosure, a light-emitting element may include a first electrode, a second electrode being opposite to (e.g., facing) the first electrode, and an emission layer disposed or provided between the first electrode and the second electrode and including a first compound represented by Formula 1.

In one or more embodiments, Formula 2 may be represented by Formula 2-1.

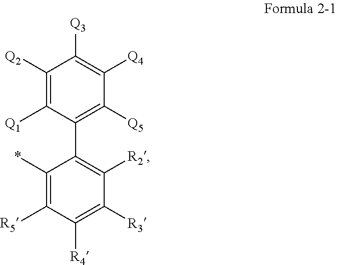

In Formula 2-1, one or two selected from among R₂′, R₃′, R₄′, and R₅′ may be represented by Formula 3, and the rest may each independently be a hydrogen atom, a deuterium atom, or a substituted or unsubstituted alkyl group having 1 to 20 carbon atoms. In Formula 2-1, Q₁ to Q₅ may be the same as defined in Formula 3.

In one or more embodiments, at least one selected from among X₁, X₂, and Z₂ may be NR_{b}, and Z₁ and the rest among X₁, X₂, and Z₂ that are not NR_{b} may each independently be O, S, or NRₐ.

In one or more embodiments, the first compound represented by Formula 1 may be represented by Formula 4.

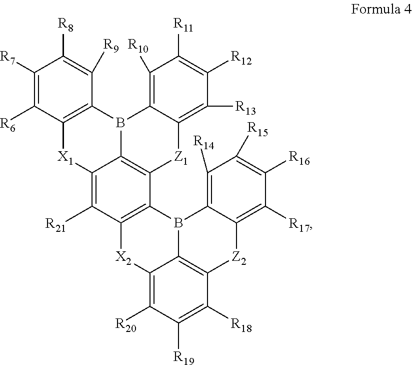

In Formula 4, R₆ to R₂₁ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula 4, X₁, X₂, Z₁, and Z₂ may be the same as defined in Formula 1.

In one or more embodiments, the first compound represented by Formula 4 may be represented by any one selected from among Formula 5-1 to Formula 5-3:

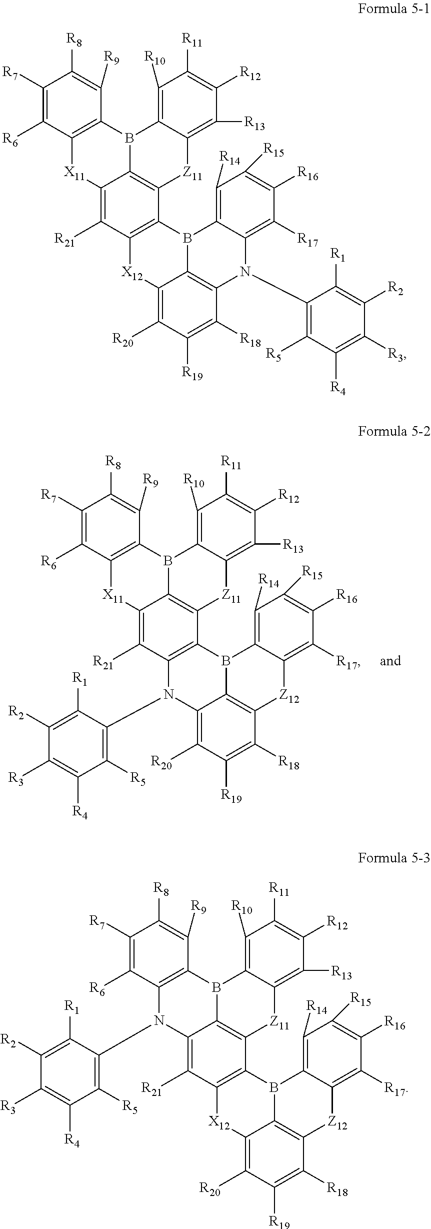

In Formula 5-1 to Formula 5-3, X₁₁, X₁₂, and Z₁₂ may each independently be O, S, NRₐ, or NR_{b}, Z₁₁ may be O, S, or NRₐ, Rₐ and R_{b} may be the same as defined in Formula 1, R₁ to R₅ may be the same as defined in Formula 2, and R₆ to R₂₁ may be the same as defined in Formula 4.

In one or more embodiments, the first compound represented by Formula 4 may be represented by any one selected from among Formula 6-1 to Formula 6-6.

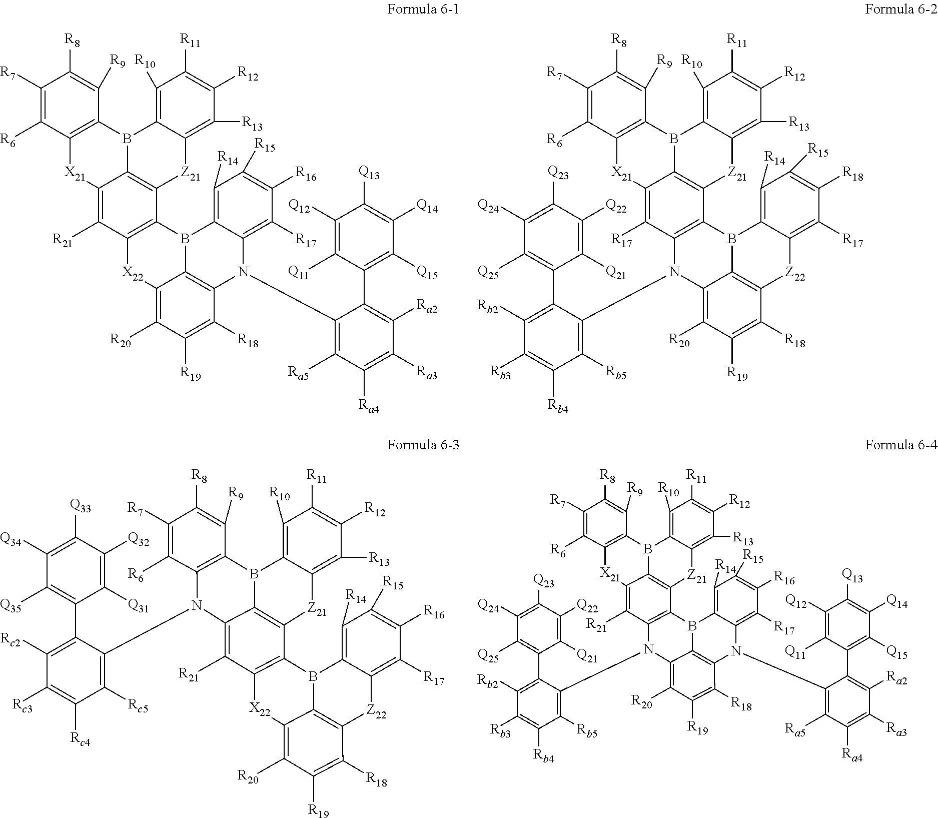

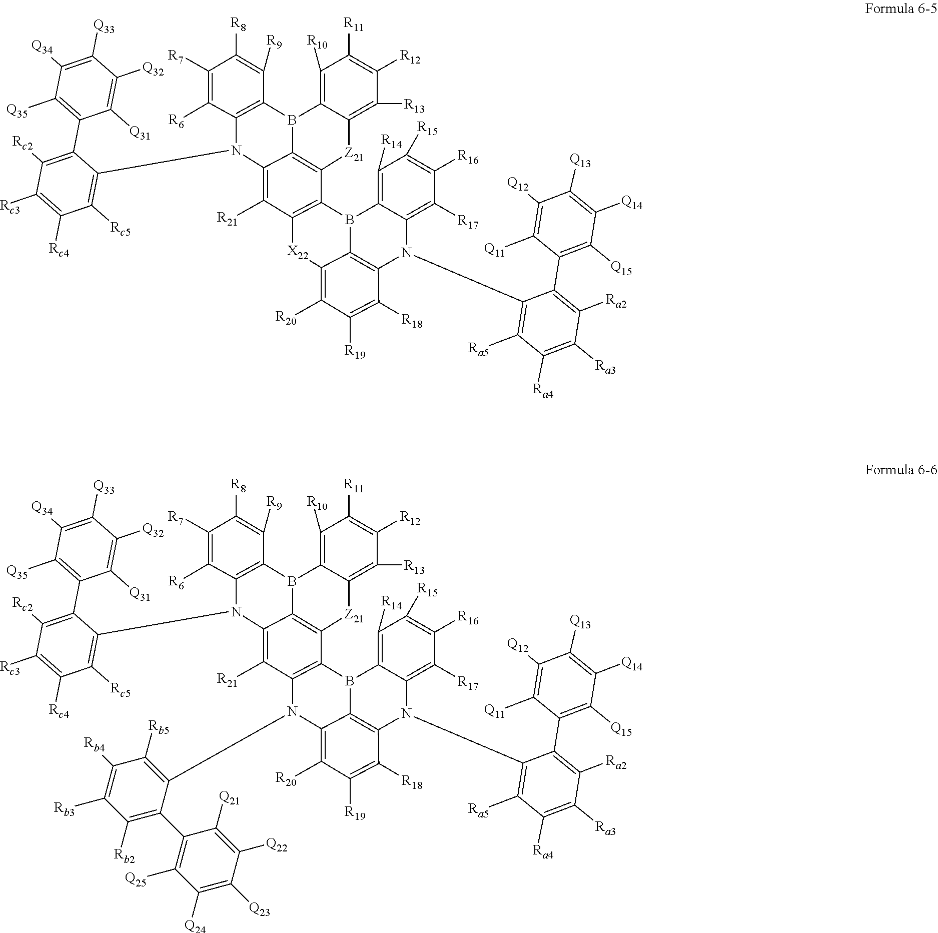

In Formula 6-1 to Formula 6-6, X₂₁, X₂₂, Z₂₁, and Z₂₂ may each independently be O, S, or NRₐ, at least one selected from among Rₐ₂ to Rₐ₅, at least one selected from among R_{b2} to R_{b5}, and at least one selected from among R_{c2} to R_{c5} may each independently be represented by Formula 3, the rest among Rₐ₂ to Rₐ₅, R_{b2} to R_{b5}, and R_{c2} to R_{c5} that are not represented by Formula 3 may each independently be a hydrogen atom, a deuterium atom, a substituted or unsubstituted alkyl group having 1 to 20 carbon atoms, or a substituted or unsubstituted aryl group having 6 to 30 ring-forming carbon atoms. In Formula 6-1 to Formula 6-6, Q₁₁ to Q₁₅, Q₂₁ to Q₂₅, and Q₃₁ to Q₃₅ may each independently be a hydrogen atom, a deuterium atom, a substituted or unsubstituted t-butyl group, a substituted or unsubstituted phenyl group, or may be bonded to an adjacent group to form a ring, Rₐ may be the same as defined in Formula 1, and R₆ to R₂₁ may be the same as defined in Formula 4.

In one or more embodiments, R₆ to R₂₁ may each independently be a hydrogen atom, a deuterium atom, a cyano group, a substituted or unsubstituted diphenylamine group, a substituted or unsubstituted propyl group, a substituted or unsubstituted t-butyl group, a substituted or unsubstituted phenyl group, a substituted or unsubstituted terphenyl group, a substituted or unsubstituted carbazole group, or a substituted or unsubstituted dibenzofuran group.

In one or more embodiments, at least one selected from among hydrogen atoms in the first compound represented by Formula 1 may be substituted with a deuterium atom.

In one or more embodiments, the emission layer may emit blue light.

In one or more embodiments, the emission layer may further include at least one selected from among a second compound represented by Formula HT-1, a third compound represented by Formula ET-1, and a fourth compound represented by Formula D-1.

In one or more embodiments, the first compound may be represented by any one selected from among the compounds in Compound Group 1.

In one or more embodiments of the present disclosure, a polycyclic compound may be represented by Formula 1.

In one or more embodiments of the present disclosure, a display device may include a base layer, a circuit layer disposed or provided on the base layer, and a display element layer disposed or provided on the circuit layer and including a light-emitting element, and the light-emitting element may include a first electrode, a second electrode being opposite to (e.g., facing) the first electrode, and an emission layer disposed or provided between the first electrode and the second electrode and including a polycyclic compound represented by Formula 1.

In one or more embodiments, the light-emitting element may emit blue light.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure and, together with the description, serve to explain principles of embodiments of the subject matter of the present disclosure. In the drawings:

FIG. 1 is a block diagram of an electronic apparatus according to one or more embodiments;

FIG. 2 is schematic views of electronic apparatuses according to one or more embodiments;

FIG. 3 is a plan view illustrating a display device according to one or more embodiments;

FIG. 4 is a cross-sectional view illustrating a portion taken along the line I-I′ in FIG. 1;

FIG. 5 is a cross-sectional view schematically illustrating a light-emitting element according to one or more embodiments;

FIG. 6 is a cross-sectional view schematically illustrating a light-emitting element according to one or more embodiments;

FIG. 7 is a cross-sectional view schematically illustrating a light-emitting element according to one or more embodiments;

FIG. 8 is a cross-sectional view schematically illustrating a light-emitting element according to one or more embodiments;

FIG. 9 is a cross-sectional view schematically illustrating a light-emitting element according to one or more embodiments;

FIG. 10 is a cross-sectional view illustrating a display device according to one or more embodiments;

FIG. 11 is a cross-sectional view illustrating a display device according to one or more embodiments;

FIG. 12 is a cross-sectional view illustrating a display device according to one or more embodiments;

FIG. 13 is a cross-sectional view illustrating a display device according to one or more embodiments;

FIG. 14 is a perspective view of an electronic apparatus according to one or more embodiments;

FIG. 15 is a perspective view of an electronic apparatus according to one or more embodiments; and

FIG. 16 is a view illustrating an interior of a vehicle in which a display device according to one or more embodiments is disposed or provided.

### DETAILED DESCRIPTION

The subject matter of the present disclosure may be modified in one or more suitable manners and have one or more suitable forms, and thus example embodiments will be illustrated in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

If (e.g., when) explaining each of drawings, like reference numbers are used for referring to like elements.

In the accompanying drawings, the dimensions of each structure may be exaggeratingly illustrated for clarity of the present disclosure.

The utilization of “may,” if (e.g., when) describing embodiments of the present disclosure, refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend the present disclosure, including the appended claims, to expressly recite any sub-range subsumed within the ranges expressly recited herein.

It will be understood that, although the terms “first,” “second,” and/or the like may be used herein to describe one or more suitable components, these components should not be limited by these terms. These terms are only used to distinguish one component from another. For example, a first component may be termed a second component, and, similarly, a second component may be termed a first component, without departing from the scope of one or more embodiments of the present disclosure.

As used herein, the singular forms, “a,” “an,” and “the” are intended to include the plural forms as well, unless the context clearly indicates otherwise.

In the present application, it will be understood that the terms “include,” “have,” “including,” “having,” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the present application, if (e.g., when) a layer, a film, a region, or a plate is referred to as being “on,” “above,” or “in an upper portion of” another layer, film, region, or plate, it may be not only “directly on” or “directly above” the layer, film, region, or plate, but intervening layers, films, regions, or plates may also be present therebetween. In contrast, if (e.g., when) a layer, a film, a region, or a plate is referred to as being “directly on” or “directly above” another layer, film, region, or plate, there are no intervening layers, films, regions, or plates present therebetween.

If (e.g., when) a layer, a film, a region, or a plate is referred to as being “below” or “in a lower portion of” another layer, film, region, or plate, it may be not only directly under the layer, film, region, or plate, but intervening layers, films, regions, or plates may also be present therebetween.

It will be understood that if (e.g., when) a part is referred to as being “on” another part, it may be disposed or provided above the other part or disposed or provided under the other part as well.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

In the specification, the term “substituted or unsubstituted” may refer to being substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the substituents exemplified herein may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In one or more embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the specification, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the present disclosure are not limited thereto.

In the specification, an alkenyl group may refer to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl group, a styrenyl group, a styryl vinyl group, and/or the like, but embodiments of the present disclosure are not limited thereto.

In the specification, an alkynyl group may refer to a hydrocarbon group including at least one carbon-carbon triple bond in the middle or terminal of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the specification, the hydrocarbon ring group may refer to any suitable functional group or substituent derived from an aliphatic hydrocarbon ring. The hydrocarbon ring group may be a saturated hydrocarbon ring group having 5 to 20 ring-forming carbon atoms.

In the specification, an aryl group may refer to any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the specification, the fluorenyl group may be substituted, and two substituents may be bonded to each other to form a spiro structure. Examples of the substituted fluorenyl group may be as follows. However, embodiments of the present disclosure are not limited thereto.

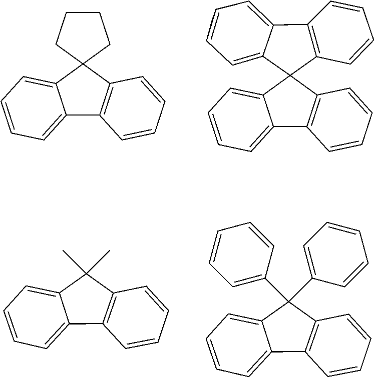

The heterocyclic group herein may refer to any suitable functional group or substituent derived from a ring containing at least one of B, O, N, P, Si, or S as a heteroatom. The heterocyclic group may include an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group and may include a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the specification, the heteroaryl group may contain at least one of B, O, N, P, Si, or S as a heteroatom. If (e.g., when) the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the specification, the description of the aryl group herein may be applied to an arylene group except that the arylene group is a divalent group. The description of the heteroaryl group herein may be applied to a heteroarylene group except that the heteroarylene group is a divalent group.

In the specification, the silyl group may include an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the specification, the number of carbon atoms in the carbonyl group is not specifically limited, but may be 1 to 40, 1 to 30, or 1 to 20. For example, the carbonyl group may have the following structures, but embodiments of the present disclosure are not limited thereto.

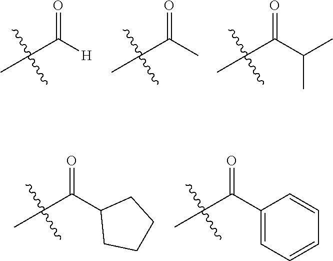

In the specification, the number of carbon atoms in the sulfinyl group and the sulfonyl group is not limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain, or a ring chain. The number of carbon atoms in the alkoxy group is not specifically limited, but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and/or the like, but embodiments of the present disclosure are not limited thereto.

The boron group herein may refer to that a boron atom is bonded to the alkyl group or the aryl group as defined herein. The boron group may include an alkyl boron group and an aryl boron group. Examples of the boron group may include a dimethylboron group, a diphenylboron group, a phenylboron group, and/or the like, but embodiments of the present disclosure are not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto.

In the specification, the alkyl group among an alkylthio group, an alkylsulfoxy group, an alkylaryl group, an alkylamino group, an alkyl boron group, an alkyl silyl group, and an alkyl amine group may be the same as the examples of the alkyl group as described herein.

In the specification, the aryl group among an aryloxy group, an arylthio group, an arylsulfoxy group, an arylamino group, an arylboron group, an arylsilyl group, an arylamine group may be the same as the examples of the aryl group as described herein.

In the specification, a direct linkage may refer to a single bond (e.g., a single covalent bond).

In the specification,

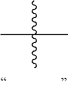

and “ [symbol] ” refer to a position to be connected.

Hereinafter, one or more embodiments of the present disclosure will be described in more detail with reference to the accompanying drawings.

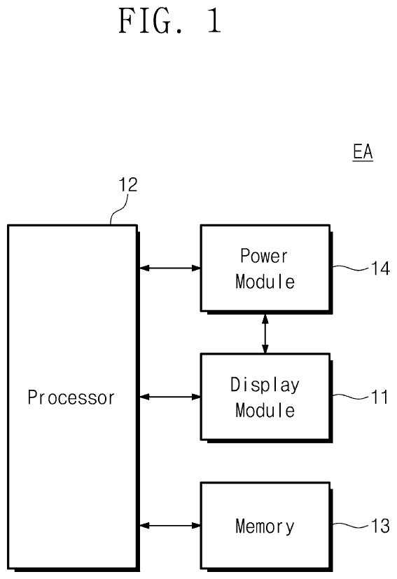

FIG. 1 is a block diagram of an electronic apparatus according to one or more embodiments. Referring to FIG. 1, the electronic apparatus EA according to one or more embodiments may include a display module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

In the memory 15, data information needed or desired for an operation of the processor 12 or the display module 11 may be stored. If (e.g., when) the processor 12 executes an application stored in the memory 15, a video data signal and/or input control signal may be transmitted to the display module 11, and the display module 11 may process the provided signal to output a video information through a display screen. The display module 11 may include a display panel displaying a video.

The power module 14 may include a power supply module, such as a power adapter and/or battery device, and a power conversion module that generates power needed or desired for operations of the electronic apparatus EA by converting the supplied power by the power supply module.

At least one selected from among the components of the electronic apparatus EA as described in one or more embodiments may be included in a display panel according to one or more embodiments and a display device according to one or more embodiments including the display panel, which will be described here in more detail. In one or more embodiments, one or more suitable individual modules functionally included in one module may be included in the display device, and one or more other modules may be provided separately from the display device. For example, the display device may include a display module 11, a processor 12, a memory 13, and a power module 14 and may be provided in other device form that is not a display device in the electronic apparatus EA.

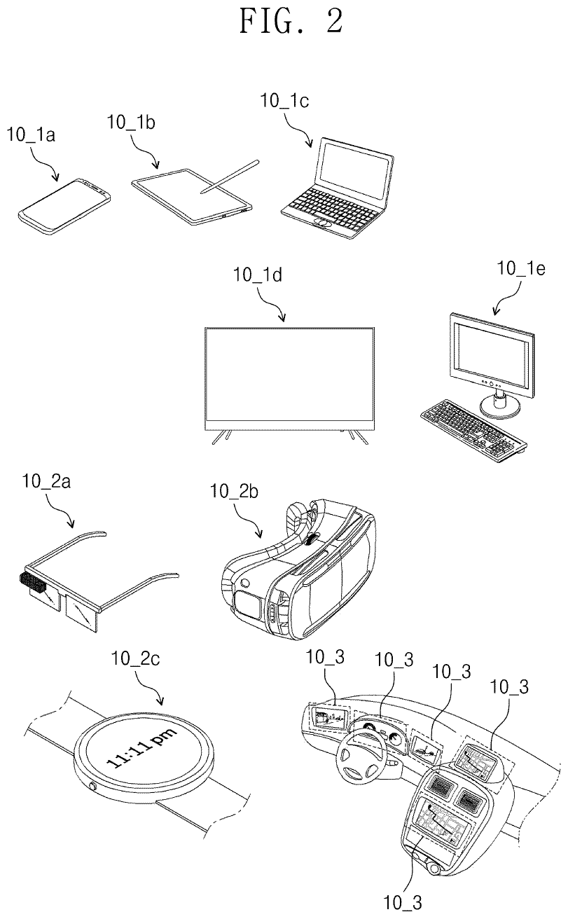

FIG. 2 is schematic views of electronic apparatuses according to one or more embodiments.

Referring to FIG. 2, one or more suitable electronic apparatuses including the display device according to one or more embodiments may include not only an electronic apparatus to display an image, such as a smart phone 10_1a, a tablet PC 10_1b, a laptop computer 10_1c, a TV 10_1d, a desktop monitor 10_1e, and/or the like but also an wearable electronic apparatus, such as smart glasses 10_2a, a head-mounted display 10_2b, a smart watch 10_2c, an electronic apparatus 10_3 for vehicles including a display device, such as a center information display (CID) on a vehicle's instrument cluster, center fascia, or dashboard, and a room mirror display.

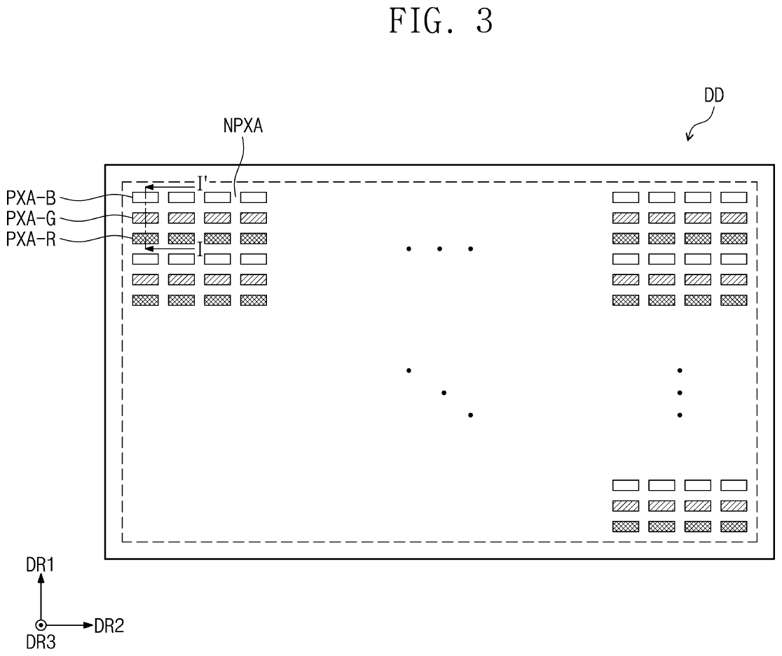

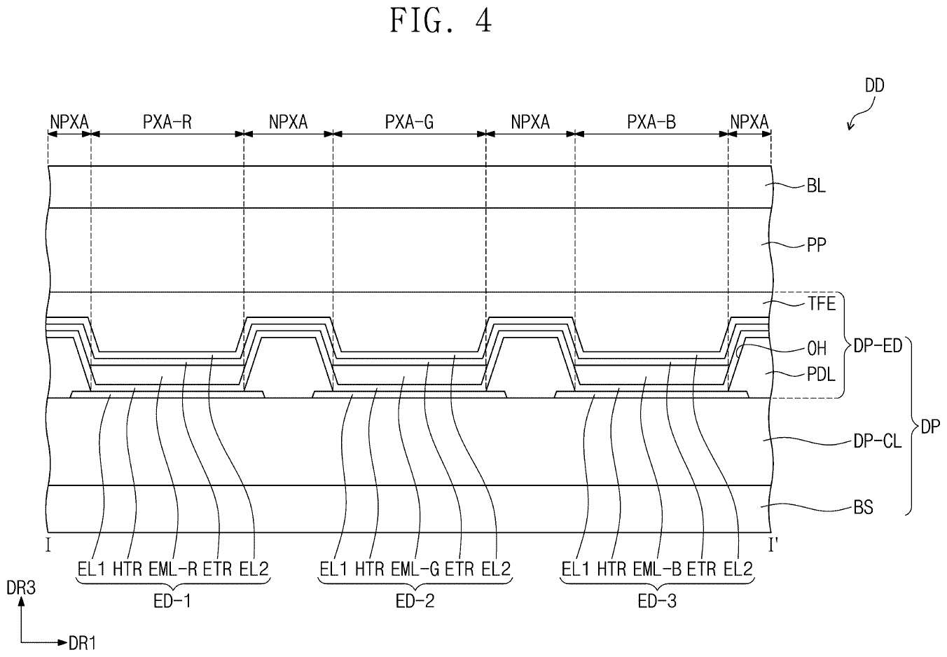

FIG. 3 is a plan view illustrating one or more embodiments of a display device DD. FIG. 4 is a cross-sectional view of the display device DD of one or more embodiments. FIG. 4 is a cross-sectional view illustrating a part taken along the line I-I′ of FIG. 3.

The display device DD may include a display panel DP and an optical layer PP disposed or provided on the display panel DP. The display panel DP may include light-emitting elements ED-1, ED-2, and ED-3. The display device DD may include a plurality of light-emitting elements ED-1, ED-2, and ED-3. The optical layer PP may be disposed or provided on the display panel DP to control reflected light in the display panel DP due to external light. The optical layer PP may include, for example, a polarization layer and/or a color filter layer. In one or more embodiments, the optical layer PP may be omitted from the display device DD of one or more embodiments.

A base substrate BL may be disposed or provided on the optical layer PP. The base substrate BL may be a member which provides a base surface on which the optical layer PP disposed or provided. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be disposed or provided between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light-emitting elements ED-1, ED-2, and ED-3 disposed or provided between portions of the pixel defining film PDL, and an encapsulation layer TFE disposed or provided on the light-emitting elements ED-1, ED-2, and ED-3.

The base layer BS may be a member which provides a base surface on which the display device layer DP-ED is disposed or provided. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be disposed or provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor to drive the light-emitting elements ED-1, ED-2, and ED-3 of the display device layer DP-ED.

Each of the light-emitting elements ED-1, ED-2, and ED-3 may have a structure of each light-emitting element ED of one or more embodiments according to FIGS. 3 to 6, which will be described herein in more detail. Each of the light-emitting elements ED-1, ED-2, and ED-3 may include a first electrode EL1, a hole transport region HTR, emission layers EML-R, EML-G, and EML-B, an electron transport region ETR, and a second electrode EL2.

FIG. 4 illustrates one or more embodiments in which the emission layers EML-R, EML-G, and EML-B of the light-emitting elements ED-1, ED-2, and ED-3 are disposed or provided in openings OH defined in the pixel defining film PDL, and the hole transport region HTR, the electron transport region ETR, and the second electrode EL2 are provided as a common layer in the entire light-emitting elements ED-1, ED-2, and ED-3. However, embodiments of the present disclosure are not limited thereto, and the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light-emitting element ED-1, ED-2, and ED-3 in one or more embodiments may be provided by being patterned in an inkjet printing method.

The encapsulation layer TFE may cover the light-emitting elements ED-1, ED-2 and ED-3. The encapsulation layer TFE may seal the display device layer DP-ED. The encapsulation layer TFE may be a thin film encapsulation layer. The encapsulation layer TFE may be formed or provided by laminating one layer or a plurality of layers. The encapsulation layer TFE may include at least one insulation (e.g., electrical insulation) layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film may protect the display device layer DP-ED from moisture/oxygen, and the encapsulation-organic film may protect the display device layer DP-ED from foreign substances, such as dust particles. The encapsulation-inorganic film may include silicon nitride, silicon oxynitride, silicon oxide, titanium oxide, aluminum oxide, and/or the like, but embodiments of the present disclosure are not limited thereto. The encapsulation-organic film may include an acrylic-based compound, an epoxy-based compound, and/or the like. The encapsulation-organic film may include a photopolymerizable organic material, but embodiments of the present disclosure are not limited thereto.

The encapsulation layer TFE may be disposed or provided on the second electrode EL2 and may be disposed or provided to fill the opening OH.

Referring to FIGS. 3 and 4, the display device DD may include a non-light emitting region NPXA and light emitting regions PXA-R, PXA-G, and PXA-B. The light emitting regions PXA-R, PXA-G, and PXA-B may be regions in which light generated by the respective light-emitting elements ED-1, ED-2, and ED-3 is emitted. The light emitting regions PXA-R, PXA-G, and PXA-B may be spaced and/or apart (e.g., spaced apart or separated) from each other on a plane (e.g., in plan view).

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide light-emitting elements ED-1, ED-2, and ED-3. The emission layers EML-R, EML-G, and EML-B of the light-emitting elements ED-1, ED-2, and ED-3 may be disposed or provided in openings OH defined in the pixel defining film PDL and separated from each other.

The light emitting regions PXA-R, PXA-G, and PXA-B may be divided into a plurality of groups according to the color of light generated from the light-emitting elements ED-1, ED-2, and ED-3. In the display device DD of one or more embodiments as illustrated in FIGS. 3 and 4, three light emitting regions PXA-R, PXA-G, and PXA-B, which emit red light, green light, and blue light, respectively, are illustrated as examples. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light-emitting elements ED-1, ED-2 and ED-3 may emit light beams having wavelengths different from each other. For example, in one or more embodiments, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may correspond to the first light-emitting element ED-1, the second light-emitting element ED-2, and the third light-emitting element ED-3, respectively.

However, embodiments of the present disclosure are not limited thereto, and the first to third light-emitting elements ED-1, ED-2, and ED-3 may emit light beams in substantially the same wavelength range or at least one light-emitting element may emit a light beam in a wavelength range different from the others. For example, the first to third light-emitting elements ED-1, ED-2, and ED-3 may all emit blue light.

The light emitting regions PXA-R, PXA-G, and PXA-B in the display device DD according to one or more embodiments may be arranged in a stripe form (e.g., a substantially stripe form). Referring to FIG. 3, the plurality of red light emitting regions PXA-R, the plurality of green light emitting regions PXA-G, and the plurality of blue light emitting regions PXA-B each may be arranged along a second directional axis DR2. In one or more embodiments, the red light emitting region PXA-R, the green light emitting region PXA-G, and the blue light emitting region PXA-B may be alternately arranged in this order along a first directional axis DR1.

FIGS. 3 and 4 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light.

In this case, the areas of the light emitting regions PXA-R, PXA-G, and PXA-B may refer to areas if (e.g., when) viewed on a plane (e.g., in plan view) defined by the first directional axis DR1 and the second directional axis DR2.

In one or more embodiments, an arrangement form of the light emitting regions PXA-R, PXA-G, and PXA-B is not limited to the configuration or arrangement as illustrated in FIG. 3, and the order in which the red light emitting region PXA-R, the green light emitting region PXA-G, and the blue light emitting region PXA-B are arranged may be provided in one or more suitable combinations according to the characteristics of display quality required or desired in the display device DD. For example, the arrangement form of the light emitting regions PXA-R, PXA-G, and PXA-B may be a pentile (PENTILE®) arrangement form (e.g., an RGBG matrix, an RGBG structure, or an RGBG matrix structure) or a diamond (DIAMOND PIXEL™) arrangement form. PENTILE® is a duly registered trademark of Samsung Display Co., Ltd., and DIAMON PIXEL™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than the area of the blue light emitting region PXA-B, but embodiments of the present disclosure are not limited thereto.

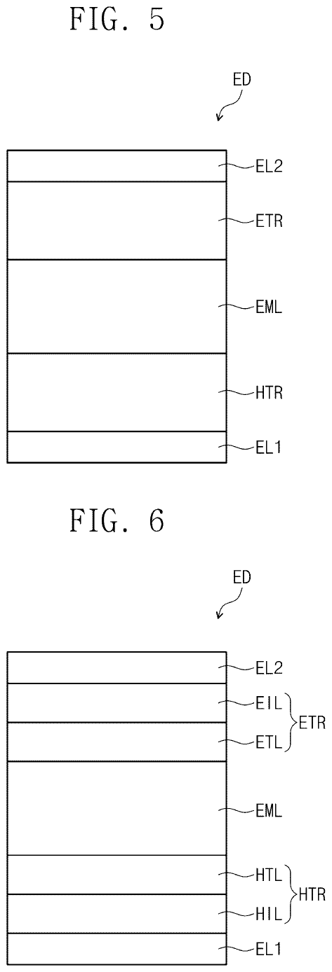

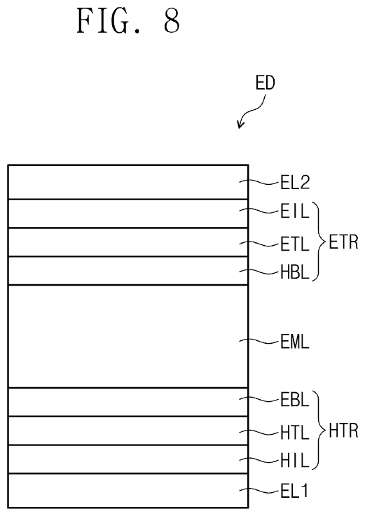

Hereinafter, FIG. 5 to FIG. 9 are cross-sectional views schematically illustrating light-emitting elements according to one or more embodiments. The light-emitting element ED according to one or more embodiments may include a first electrode EL1, a second electrode EL2 being opposite to (e.g., facing) the first electrode EL1, and an emission layer EML disposed or provided between the first electrode EL1 and the second electrode EL2. In one or more embodiments, the light-emitting element ED may include a hole transport region HTR or an electron transport region ETR between the first electrode EL1 and the emission layer EML and between the emission layer EML and the second electrode EL2. For example, the light-emitting element ED of one or more embodiments may include a first electrode EL1, a hole transport region HTR, an emission layer EML, an electron transport region ETR, and a second electrode EL2 stacked in order.

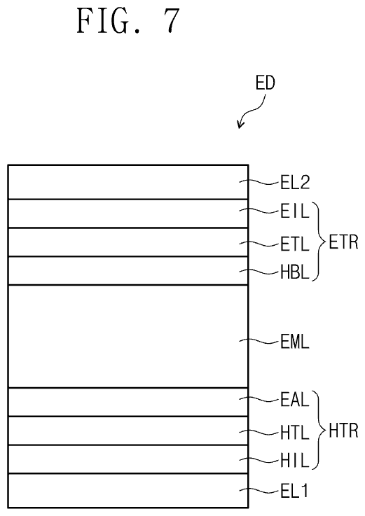

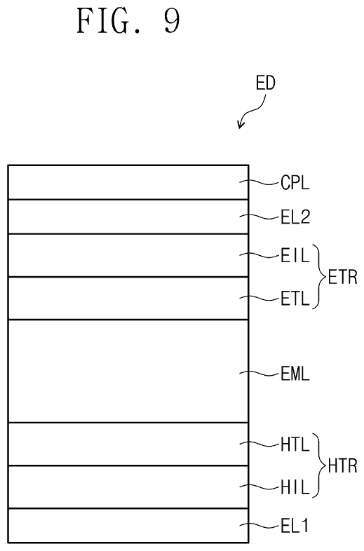

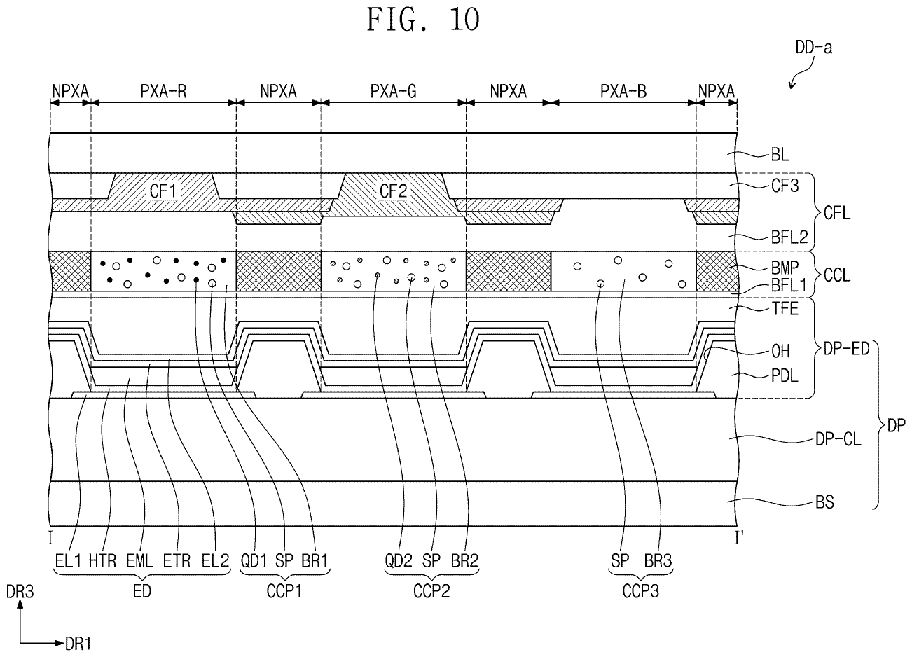

Compared with FIG. 5, FIG. 6 is a cross-sectional view of a light-emitting element ED of one or more embodiments, in which a hole transport region HTR includes a hole injection layer HIL and a hole transport layer HTL, and an electron transport region ETR includes an electron injection layer EIL and an electron transport layer ETL. In one or more embodiments, compared with FIG. 5, FIG. 7 is a cross-sectional view of a light-emitting element ED of one or more embodiments, in which a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. Compared to FIG. 6, FIG. 9 is a cross-sectional view of a light-emitting element ED according to one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 6 FIG. 9 is a cross-sectional view of a light-emitting element ED of one or more embodiments including a capping layer CPL disposed or provided on a second electrode EL2.

The first electrode EL1 may have conductivity (e.g., electrical conductivity). The first electrode EL1 may be formed or composed of a metal material, a metal alloy, or a conductive (e.g., electrically conductive) compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If (e.g., when) the first electrode EL1 is the transmissive electrode, the first electrode EL1 may include a transparent (e.g., substantially transparent) metal oxide, such as indium tin oxide (ITO), indium zinc oxide (IZO), zinc oxide (e.g., ZnOₓ, wherein 0<x≤2, e.g., ZnO), and/or indium tin zinc oxide (ITZO). If (e.g., when) the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In one or more embodiments, the first electrode EL1 may have a multilayer structure including a reflective film or a transflective film formed or composed of the materials as described in one or more embodiments, and a transparent (e.g., substantially transparent) conductive (e.g., electrically conductive) film formed or composed of ITO, IZO, ZnO, ITZO, and/or the like. For example, the first electrode EL1 may have a three-layer structure of ITO/Ag/ITO, but embodiments of the present disclosure are not limited thereto. In one or more embodiments, embodiments of the present disclosure are not limited thereto, and the first electrode EL1 may include the metal materials as described in one or more embodiments, combinations of at least two metal materials of the metal materials as described in one or more embodiments, oxides of metal materials as described in one or more embodiments, and/or the like. The thickness of the first electrode EL1 may be from about 700 Å to about 10,000 Å. For example, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer EAL, or an electron blocking layer EBL. The thickness of the hole transport region HTR may be, for example, from about 50 Å to about 15,000 Å.

The hole transport region HTR may have a single layer formed or composed of a single material, a single layer formed or composed of a plurality of different materials, or a multilayer structure including a plurality of layers formed or composed of a plurality of different materials.

For example, the hole transport region HTR may have a single layer structure of the hole injection layer HIL or the hole transport layer HTL, or may have a single layer structure formed or composed of a hole injection material and a hole transport material. In one or more embodiments, the hole transport region HTR may have a single layer structure formed or composed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed or provided utilizing one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

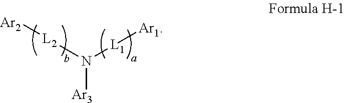

In Formula H-1, L₁ and L₂ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

The compound represented by Formula H-1 may be a monoamine compound. In one or more embodiments, the compound represented by Formula H-1 may be a diamine compound in which at least one selected from among Ar₁ to Ar₃ includes the amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds as listed in Compound Group H are examples, and the compounds represented by Formula H-1 are not limited to those represented by Compound Group H:

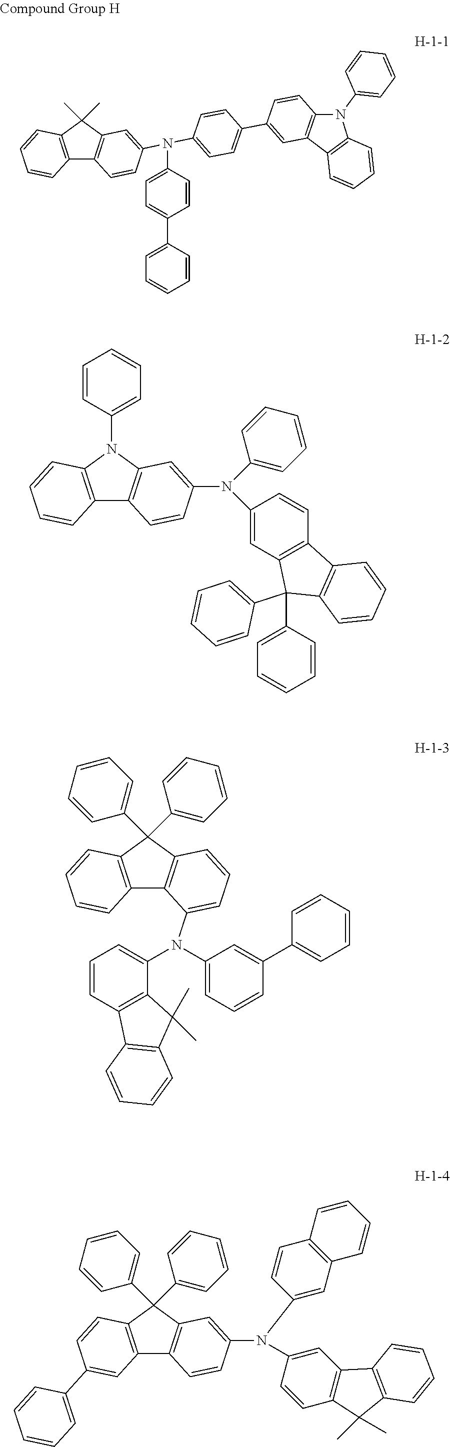 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

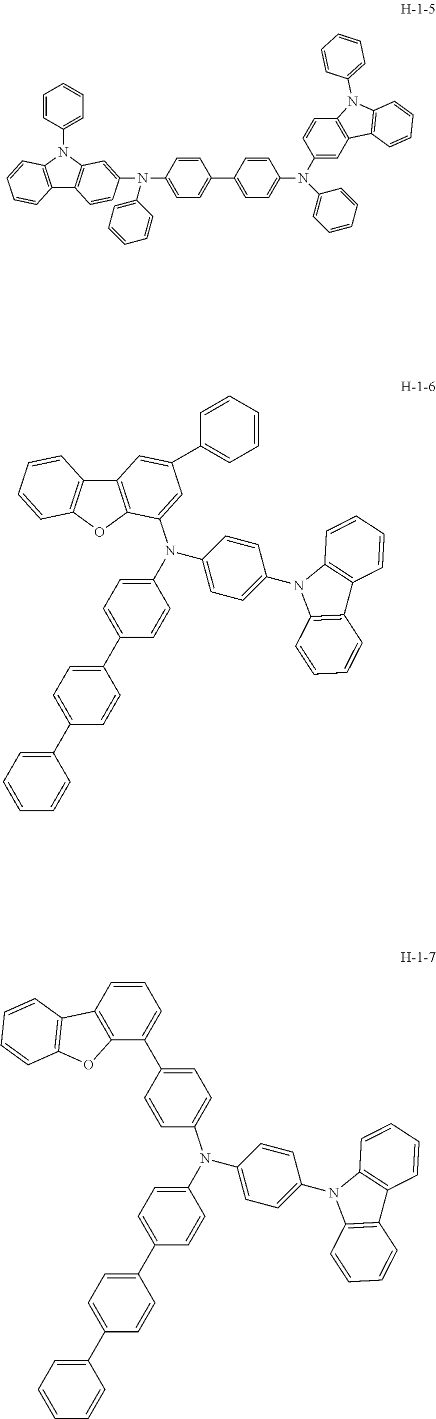 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

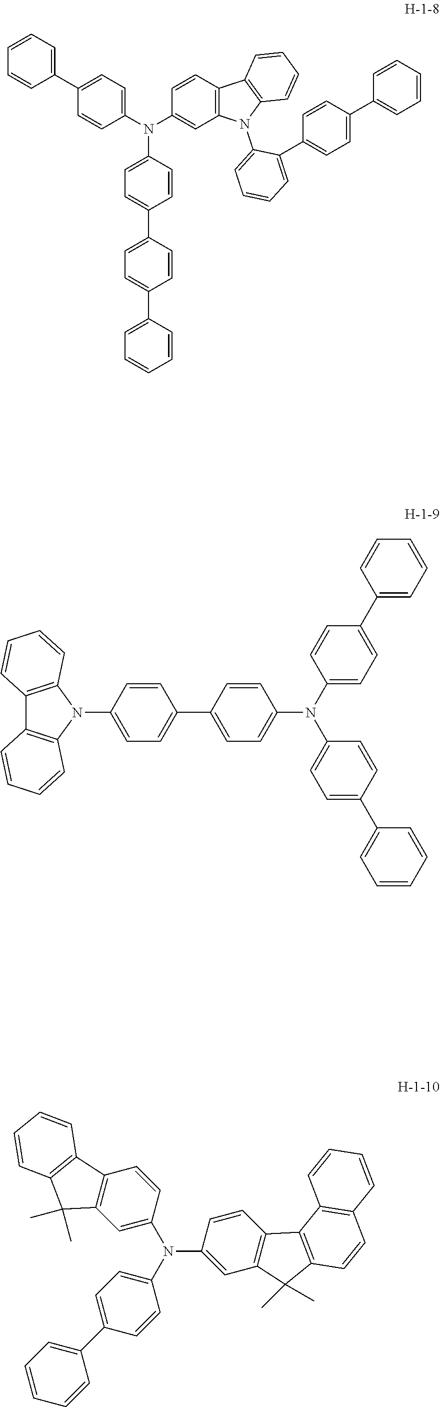 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

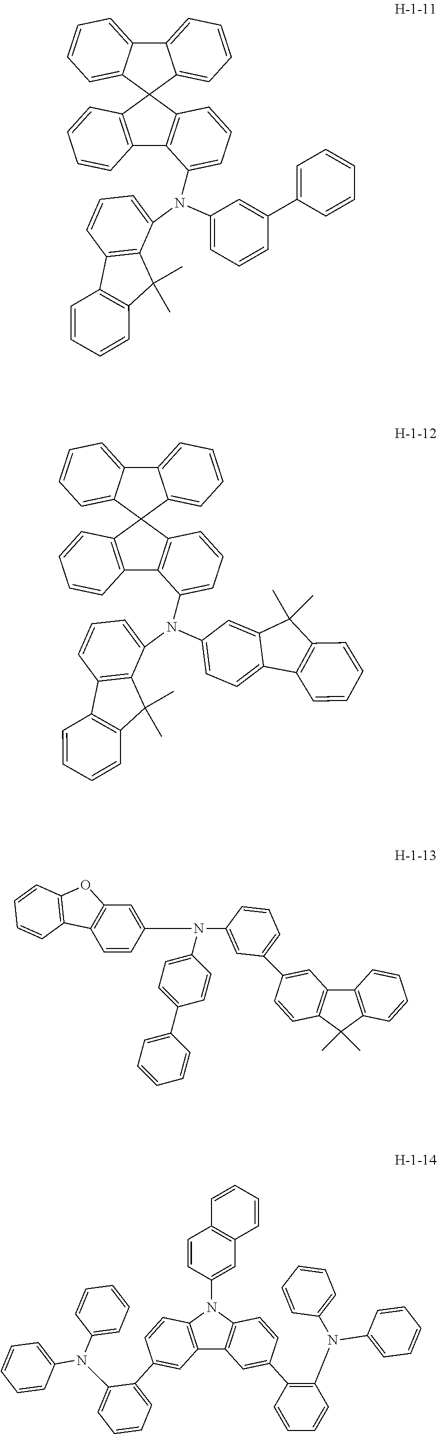 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(Cc4ccc5c(c4)oc4ccccc45)c4ccc(-c5ccccc5)cc4)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

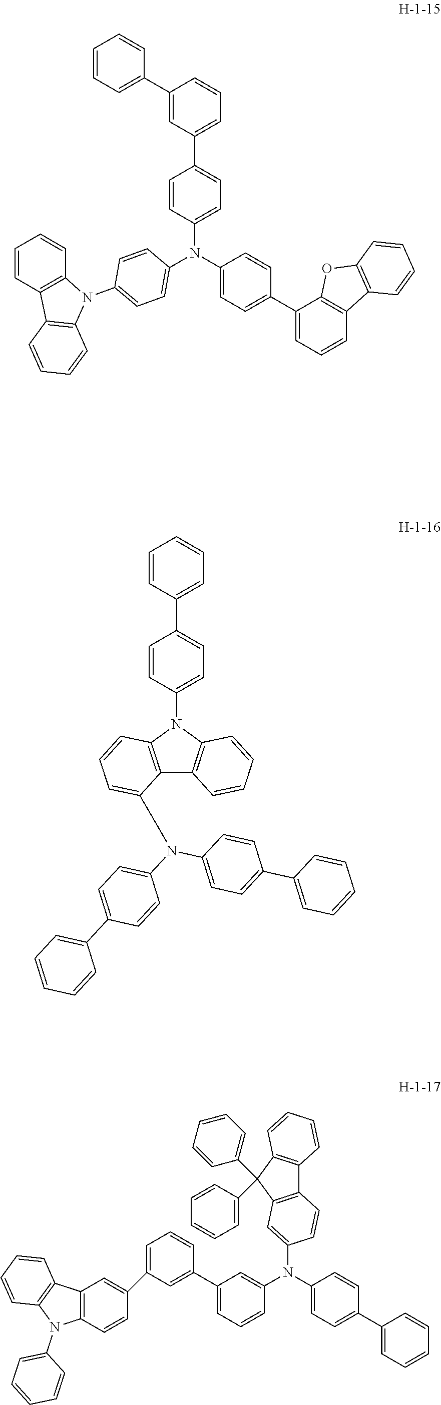 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

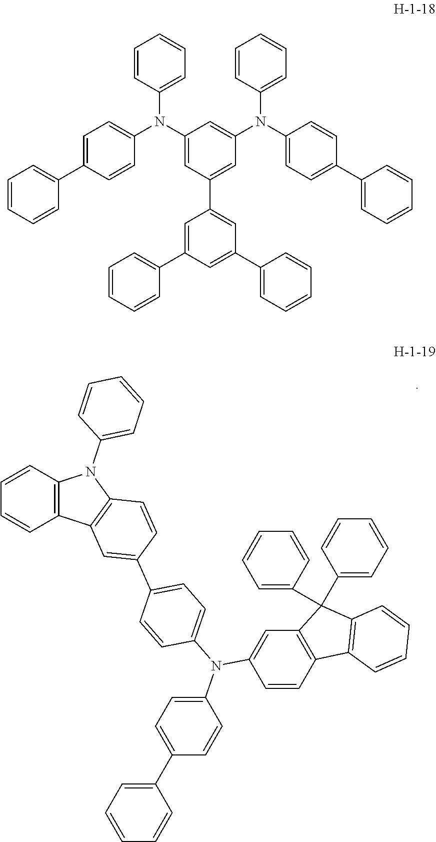 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound, such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), and/or the like.

The hole transport region HTR may include a carbazole-based derivative, such as N-phenyl carbazole and/or polyvinyl carbazole, a fluorene-based derivative, a triphenylamine-based derivative, such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the compounds of the hole transport region HTR as described in one or more embodiments in at least one of a hole injection layer HIL, a hole transport layer HTL, an emission auxiliary layer EAL, or an electron blocking layer EBL.

The thickness of the hole transport region HTR may be from about 100 Å to about 10,000 Å, for example, from about 100 Å to about 5,000 Å. If (e.g., when) the hole transport region HTR includes the hole injection layer HIL, the hole injection layer HIL may have, for example, a thickness of about 30 Å to about 1,000 Å. If (e.g., when) the hole transport region HTR includes the hole transport layer HTL, the hole transport layer HTL may have a thickness of about 250 Å to about 1,000 Å. For example, if (e.g., when) the hole transport region HTR includes the electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL and the electron blocking layer EBL satisfy the foregoing ranges, satisfactory or suitable hole transport properties may be achieved without a substantial increase in driving voltage.

The hole transport region HTR may further include a charge generating material to increase or enhance conductivity (e.g., electrical conductivity) in addition to the materials as described in one or more embodiments. The charge generating material may be dispersed uniformly (e.g., substantially uniformly) or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound, such as CuI and/or RbI, a quinone derivative, such as tetracyanoquinodimethane (TCNQ) and/or 2,3,5,6-tetrafluoro-7,7′8,8-tetracyanoquinodimethane (F4-TCNQ), a metal oxide, such as tungsten oxide and/or molybdenum oxide, a cyano group-containing compound, such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described in one or more embodiments, the hole transport region HTR may further include at least one of the emission auxiliary layer EAL or the electron blocking layer EBL in addition to the hole injection layer HIL and the hole transport layer HTL. The emission auxiliary layer EAL may compensate for a resonance distance depending on a wavelength of light emitted from the emission layer EML and control a hole charge balance, and thus luminous efficiency may increase or enhance. In one or more embodiments, the emission auxiliary layer EAL may serve to prevent electrons from being injected to the hole transport region HTR (or reduce a degree to or occurrence of which electrons are injected to the hole transport region HTR). Materials that may be included in the hole transport region HTR may be included in the emission auxiliary layer EAL. The electron blocking layer EBL may be a layer that serves to prevent the electron injection from the electron transport region ETR to the hole transport region HTR.

In the light-emitting element ED according to one or more embodiments, the emission layer EML may include a polycyclic compound according to one or more embodiments. The emission layer EML may include the polycyclic compound according to one or more embodiments as a dopant. The polycyclic compound according to one or more embodiments may be a dopant material in the emission layer EML. In the present specification, the polycyclic compound according to one or more embodiments may be referred to as a first compound.

The polycyclic compound according to one or more embodiments may include, as a core structure, a fused ring with at least nine rings which includes four hetero atoms and two boron (B) atoms as ring-forming atoms. The polycyclic compound according to one or more embodiments may have a structure in which two fused rings each with 5 rings are connected by sharing one ring, wherein the fused ring each 5 rings includes two hetero atoms and one boron (B) atom as a ring-forming atom. For example, a first fused ring with 5 rings, represented by Formula a and a second fused ring with 5 rings, represented by Formula b1 may be connected by sharing a ring c with each other. Therefore, the polycyclic compound according to one or more embodiments may have a core structure of the fused ring with at least nine rings, in which a first fused ring represented by Formula a and a second fused ring represented by Formula b2 are bonded.

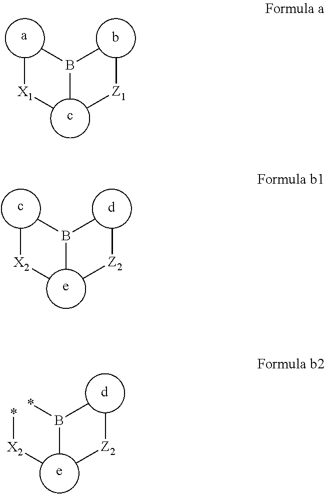

In Formula a, Formula b1, and Formula b2, ring a, ring b, ring c, ring d, and ring e may each independently be a substituted or unsubstituted aromatic hydrocarbon ring or a substituted or unsubstituted heterocycle. In one or more embodiments, each of the ring a, the ring b, the ring c, the ring d, and the ring e may be connected to an adjacent group to form a ring. In Formula a, Formula b1, and Formula b2, if (e.g., when) the ring a, the ring b, the ring c, the ring d, and the ring e are each a heterocycle, each of the ring a, the ring b, the ring c, the ring d, and the ring e may include no boron atom as a ring-forming atom. The polycyclic compound according to one or more embodiments may include two boron atoms in a core structure, and thus molecular planarity thereof may be appropriately or suitably alleviated. Therefore, in the light-emitting element ED including the polycyclic compound according to one or more embodiments, a concentration quenching phenomenon in that luminous efficiency decreases may be suppressed or reduced, and thus luminous efficiency and lifespan may be improved or enhanced.

In Formula a, Formula b1, and Formula b2, X₁, X₂, Z₁, and Z₂ may each independently be an oxygen (O) atom, a sulfur (S) atom, or a nitrogen (N) atom. If (e.g., when) each of X₁, X₂, Z₁, and Z₂ is a nitrogen (N) atom, another substituent may be connected to the nitrogen atom. In one or more embodiments, in Formula a, Formula b1, and Formula b2, more details to be described in Formula 1 herein may be similarly applied to the ring a, the ring b, the ring c, the ring d, the ring e.

In Formula b2, [symbol] may be a portion connected to the ring c of Formula a. For example, two [symbol] in Formula b2 may be respectively bonded to two ring-forming atoms which are continuously positioned among atoms which form the ring c.

The polycyclic compound according to one or more embodiments may include a nitrogen atom as a ring-forming atom, which is substituted with at least one first substituent in the core structure of the fused ring with nine rings. At least two first sub substituents may be connected to the first substituent. The first substituent and the first sub substituent may each be a substituted or unsubstituted phenyl group. The polycyclic compound according to one or more embodiments may exhibit a molecular form in which the core structure is protected because the first substituent is connected to at least one nitrogen atom forming the core structure and at least two first sub substituents are connected to the first substituent. In one or more embodiments, p-orbitals of boron (B) atoms forming the core structure of the fused ring with nine rings may be protected well or suitably by the first substituent and the first sub substituent and thus material stability may increase or enhance.

The light-emitting element ED according to one or more embodiments may include the polycyclic compound according to one or more embodiments. The polycyclic compound according to one or more embodiments may be represented by Formula 1.

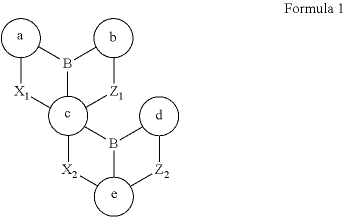

In Formula 1, ring a, ring b, ring c, ring d, and ring e may each independently be a substituted or unsubstituted aromatic hydrocarbon ring having 6 to 30 ring-forming carbon atoms or a substituted or unsubstituted heterocycle having 2 to 30 ring-forming carbon atoms. If (e.g., when) the ring a, the ring b, the ring c, the ring d, and the ring e are each a heterocycle, no boron atom may be included as a ring-forming atom. For example, the ring a, the ring b, the ring c, the ring d, and the ring e may each be a substituted or unsubstituted benzene ring (for example, a substituted or unsubstituted phenyl group), but embodiments of the present disclosure are not limited thereto. The ring a, the ring b, the ring c, the ring d, and the ring e, which are substituted or unsubstituted benzene rings, may each be connected to an adjacent group to form a ring.

In Formula 1, X₁, X₂, Z₁, and Z₂ may each independently be O, S, NRₐ, or NR_{b}. In one or more embodiments, at least one of X₁, X₂, Z₁, or Z₂ may be NR_{b}. The others other than NR_{b} among X₁, X₂, Z₁, and Z₂ may each independently be O, S, or NRₐ.

For example, X₁, X₂, and Z₂ may each independently be O, S, NRₐ, or NR_{b}. At least one of X₁, X₂, or Z₂ may be NR_{b}, and the others among X₁, X₂, or Z₂ that are not NR_{b} may be O, S, or NRₐ. Z₁ may be O, S, or NRₐ, but embodiments of the present disclosure are not limited thereto.

In one or more embodiments, Rₐ may be a substituted or unsubstituted aryl group having 6 to 30 ring-forming carbon atoms. For example, Rₐ may be a substituted or unsubstituted phenyl group, a substituted or unsubstituted biphenyl group, or a substituted or unsubstituted terphenyl group. If (e.g., when) Rₐ is substituted with a different substituent, Rₐ may be substituted with a deuterium atom, an alkyl group, an aryl group, and/or the like. In one or more embodiments, Rₐ may be connected to an adjacent group to form a ring. For example, Rₐ may be bonded to any adjacent one selected from among the ring a, the ring b, the ring c, the ring d, and the ring e to form a ring.

In one or more embodiments, R_{b} may correspond to the first substituent as described in one or more embodiments. R_{b} may be represented by Formula 2. In Formula 2, [symbol] may be a portion connected to Formula 1. [symbol] may e a portion connected to a nitrogen atom of NR_{b} among X₁, X₂, Z₁, and Z₂ in Formula 1.

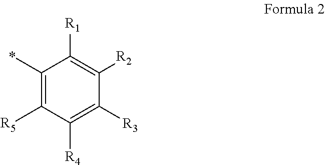

In Formula 2, R₁ to R₅ may each independently be a hydrogen atom, a deuterium atom, a halogen atom, a cyano group, a nitro group, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be represented by Formula 3. In one or more embodiments, R₁ to R₅ may be bonded to an adjacent group to form a ring. For example, any one selected from among R₁ to R₅ may be bonded to any adjacent one selected from among the ring a, the ring b, the ring c, the ring d, and the ring e to form a ring.

In one or more embodiments, at least two selected from among R₁ to R₅ may be represented by Formula 3. For example, two or three selected from among R₁ to R₅ may be represented by Formula 3. If (e.g., when) two selected from among R₁ to R₅ are represented by Formula 3, one selected from among R₁ and R₅, and R₃ may be represented by Formula 3, R₁ and R₄ may be represented by Formula 3, R₁ and R₅ may be represented by Formula 3, R₂ and R₅ may be represented by Formula 3, or R₂ and R₄ may be represented by Formula 3. If (e.g., when) three among R₁ to R₅ are represented by Formula 3, R₁, R₃, and R₅ may be represented by Formula 3, but embodiments of the present disclosure are not limited thereto.

In one or more embodiments, the rest among R₁ to R₅ that are not represented by Formula 3 may each independently be a hydrogen atom, a deuterium atom, a cyano group, a substituted or unsubstituted alkyl group having 1 to 20 carbon atoms, or a substituted or unsubstituted aryl group having 6 to 30 ring-forming carbon atoms. For example, the rest that are not represented by Formula 3 may each independently be a hydrogen atom, a deuterium atom, a cyano group, a substituted or unsubstituted propyl group, a substituted or unsubstituted t-butyl group, a substituted or unsubstituted phenyl group, or a substituted or unsubstituted biphenyl group. In one or more embodiments, the rest that are not represented by Formula 3 may each independently be bonded to an adjacent group to form a ring.

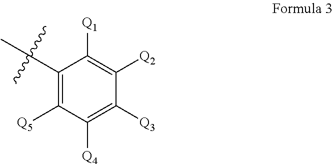

In Formula 3, Q₁ to Q₅ may each independently be a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Q₁ to Q₅ may each independently be a hydrogen atom, a deuterium atom, a substituted or unsubstituted t-butyl group, or a substituted or unsubstituted phenyl group. In one or more embodiments, Q₁ to Q₅ may each independently be bonded to an adjacent group to form a ring. For example, any one selected from among Q₁ to Q₅ may be bonded to any adjacent one selected from among the ring a, the ring b, the ring c, the ring d, and the ring e to form a ring.

In one or more embodiments, all Q₁ to Q₅ may be hydrogen atoms, but embodiments of the present disclosure are not limited thereto. In Formula 3,

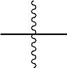

may be a portion connected to Formula 2.

In one or more embodiments, Formula 2 may be represented by Formula 2-1. Formula 2-1 is a structure in which Formula 3 is connected to R₁ of Formula 2 as an example. Formula 2-1 may correspond to a structure in which Formula 3 is connected to R₅ in Formula 2.

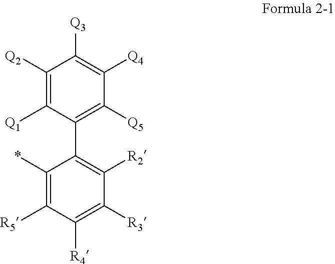

In Formula 2-1, one or two selected from among R₂′, R₃′, R₄′, and R₅′ may be represented by Formula 3. For example, R₃′, R₄′, or R₅′ may be represented by Formula 3. In one or more embodiments, R₃′ and R₅′ may be represented by Formula 3. In Formula 2-1, the rest among R₂′, R₃′, R₄′, and R₅′ that are not represented by Formula 3 may each independently be a hydrogen atom, a deuterium atom, a cyano group, a substituted or unsubstituted alkyl group having 1 to 20 carbon atoms, or a substituted or unsubstituted aryl group having 6 to 30 ring-forming carbon atoms.

In Formula 2-1, the more details as described in one or more embodiments with reference to Formula 3 may be similarly applied to Q₁ to Q₅. For example, all Q₁ to Q₅ may be hydrogen atoms, but embodiments of the present disclosure are not limited thereto.

In the polycyclic compound according to one or more embodiments as represented by Formula 1, at least one selected from among hydrogen atoms may be substituted with a deuterium atom. For example, in the polycyclic compound represented by Formula 1, in addition to a hydrogen atom in the ring a, the ring b, the ring c, the ring d, the ring e, X₁, X₂, Z₁, and Z₂, a hydrogen atom of each substituent which is substituted therefor may be substituted with a deuterium atom.

In one or more embodiments, the polycyclic compound represented by Formula 1 may be represented by Formula 4. The more details as described in one or more embodiments with reference to Formula 1 may be similarly applied to X₁, X₂, Z₁, and Z₂ in Formula 4.

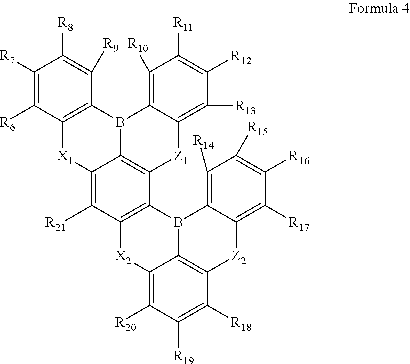

In Formula 4, R₆ to R₂₁ may each independently be a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, R₆ to R₂₁ may each independently be a hydrogen atom, a deuterium atom, a cyano group, a substituted or unsubstituted diphenylamine group, a substituted or unsubstituted propyl group, a substituted or unsubstituted t-butyl group, a substituted or unsubstituted phenyl group, a substituted or unsubstituted terphenyl group, a substituted or unsubstituted carbazole group, or a substituted or unsubstituted dibenzofuran group. In one or more embodiments, R₆ to R₂₁ may each independently be bonded to an adjacent group to form a ring. For example, R₆ may be bonded to adjacent Rₐ or R_{b} to form a ring, and R₁₃ may be bonded to adjacent Rₐ or R_{b} to form a ring.

In one or more embodiments, at least one selected from among R₆ to R₂₁ in Formula 4 may be represented by any one selected from among substituents in Substituent Group 1. However, embodiments of the present disclosure are not limited thereto.

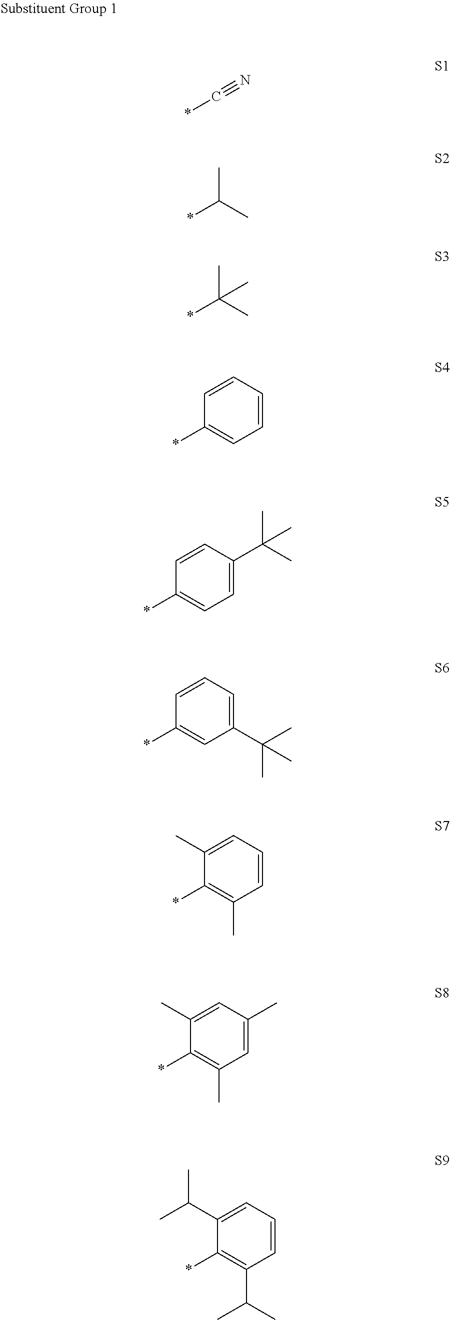

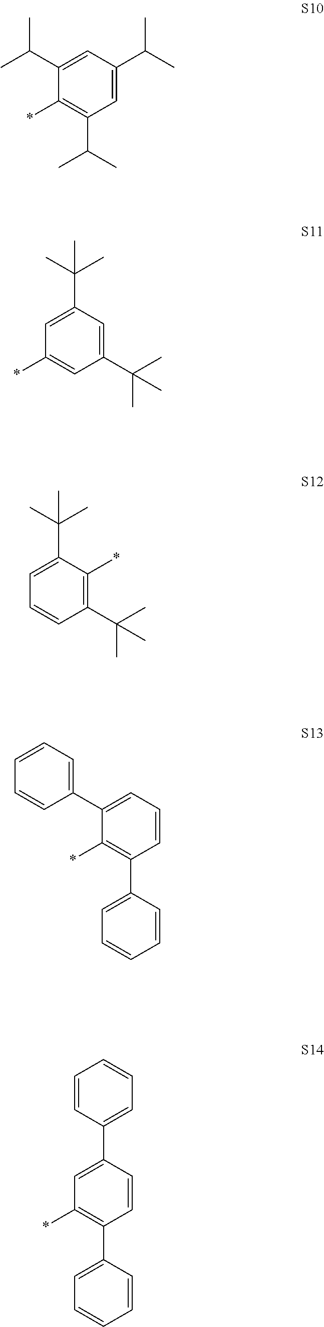 [SMILES: *c1c(C(C)C)cc(C(C)C)cc1C(C)C ; *c1cc(C(C)(C)C)cc(C(C)(C)C)c1 ; *c1c(C(C)(C)C)cccc1C(C)(C)C ; *c1c(-c2ccccc2)cccc1-c1ccccc1 ; *c1cc(-c2ccccc2)ccc1-c1ccccc1]

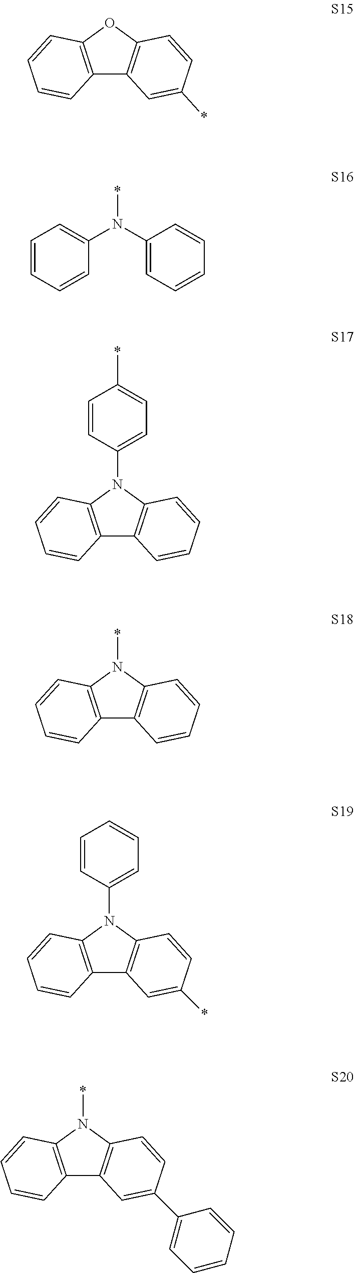 [SMILES: *c1ccc2oc3ccccc3c2c1 ; *N(c1ccccc1)c1ccccc1 ; *c1ccc(-n2c3ccccc3c3ccccc32)cc1 ; *n1c2ccccc2c2ccccc21 ; *c1ccc2c(c1)c1ccccc1n2-c1ccccc1 ; *n1c2ccccc2c2cc(-c3ccccc3)ccc21]

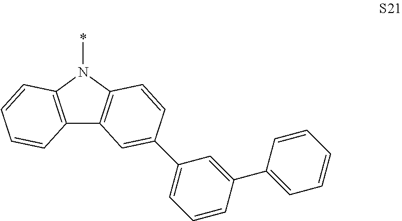 [SMILES: *n1c2ccccc2c2cc(-c3cccc(-c4ccccc4)c3)ccc21]

In one or more embodiments, the polycyclic compound represented by Formula 4 may be represented by any one selected from among Formula 5-1 to Formula 5-3. Formula 5-1 to Formula 5-3 may correspond to cases where corresponding positions to X₁, X₂, and Z₂ in the polycyclic compound represented by Formula 4 are NR_{b}, respectively, and R_{b} may be represented by Formula 2. In one or more embodiments, in the polycyclic compound represented by Formula 1, Formula 5-1 to Formula 5-3 respectively may correspond to cases where corresponding positions to ring a, ring b, ring c, ring d, and ring e are substituted or unsubstituted benzene rings, corresponding portions to X₁, X₂, and Z₂ are NR_{b}, and R_{b} is represented by Formula 2.

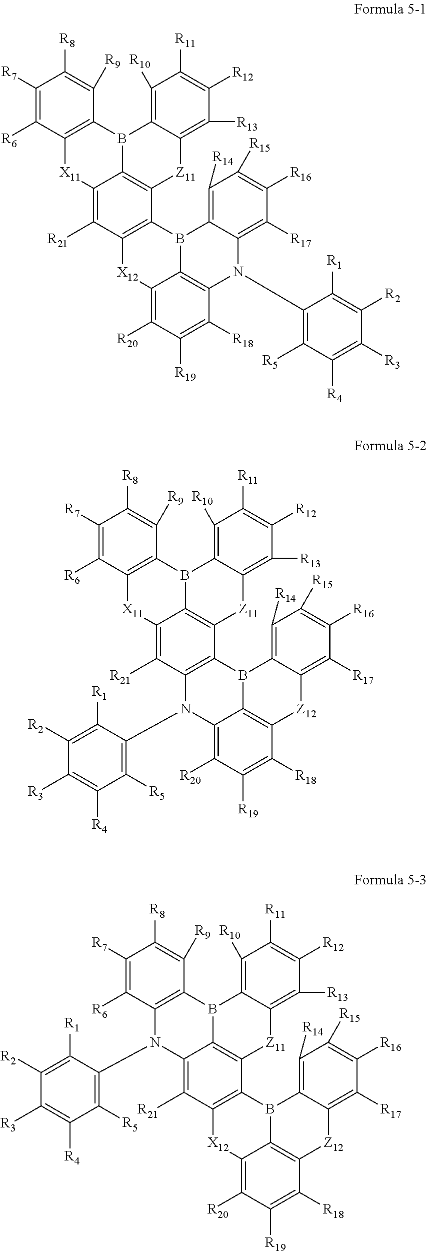

In Formula 5-1 to Formula 5-3, X₁₁, X₁₂, and Z₁₂ may each independently be O, S, NRₐ, or NR_{b}, and Z₁₁ may be O, S, or NRₐ. The more details as described in one or more embodiments with reference to Formula 1 may be similarly applied to Rₐ and R_{b}.

For example, X₁₁, X₁₂, and Z₁₁ in Formula 5-1 may each independently be O, S, or NRₐ. In one or more embodiments, X₁₁ may be NR_{b}, and X₁₂ and Z₁₁ may each independently be O, S, or NRₐ. In one or more embodiments, X₁₁ and X₁₂ may be each NR_{b}, and Z₁₁ may be O, S, or NRₐ. If (e.g., when) X₁₁ and X₁₂ are each NR_{b}, X₁₁ and X₁₂ may be the same as, or may be different from each other.

For example, X₁₁, Z₁₁, and Z₁₂ in Formula 5-2 may each independently be O, S, or NRₐ. In one or more embodiments, Z₁₂ may be NR_{b}, and X₁₁ and Z₁₁ may each independently be O, S, or NRₐ. In one or more embodiments, X₁₁ and Z₁₂ may be each NR_{b}, and Z₁₁ may be O, S, or NRₐ. If (e.g., when) X₁₁ and Z₁₂ are each NR_{b}, X₁₁ and Z₁₂ may be the same as, or may be different from each other.

For example, X₁₂, Z₁₁, and Z₁₂ in Formula 5-3 may each independently be O, S, or NRₐ. In one or more embodiments, Z₁₂ may be NR_{b}, and X₁₂ and Z₁₁ may each independently be O, S, or NRₐ. In one or more embodiments, X₁₂ and Z₁₂ may be each NR_{b}, and Z₁₁ may be O, S, or NRₐ. If (e.g., when) X₁₂ and Z₁₂ are each NR_{b}, X₁₂ and Z₁₂ may be the same as, or may be different from each other.

In Formula 5-1 to Formula 5-3, the more details as described in one or more embodiments with reference to Formula 2 as described in one or more embodiments may be similarly applied to R₁ to R₅, and the more details as described in one or more embodiments with reference to Formula 4 may be similarly applied to R₆ to R₂₁.

In one or more embodiments, the polycyclic compound represented by Formula 4 may be represented by any one selected from among Formula 6-1 to Formula 6-6. Each of Formula 6-1 to Formula 6-6 may correspond to a case where at least one corresponding position among X₁, X₂, and Z₂ in the polycyclic compound represented by Formula 4 is NR_{b}, and R_{b} is represented by Formula 2. In one or more embodiments, each of Formula 6-1 to Formula 6-6 may correspond to a case where corresponding positions to the ring a, the ring b, the ring c, the ring d, and the ring e are each a substituted or unsubstituted benzene ring, at least one corresponding position among X₁, X₂, or Z₂ is NR_{b}, and R_{b} is represented by Formula 2 in the polycyclic compound represented by Formula 1.

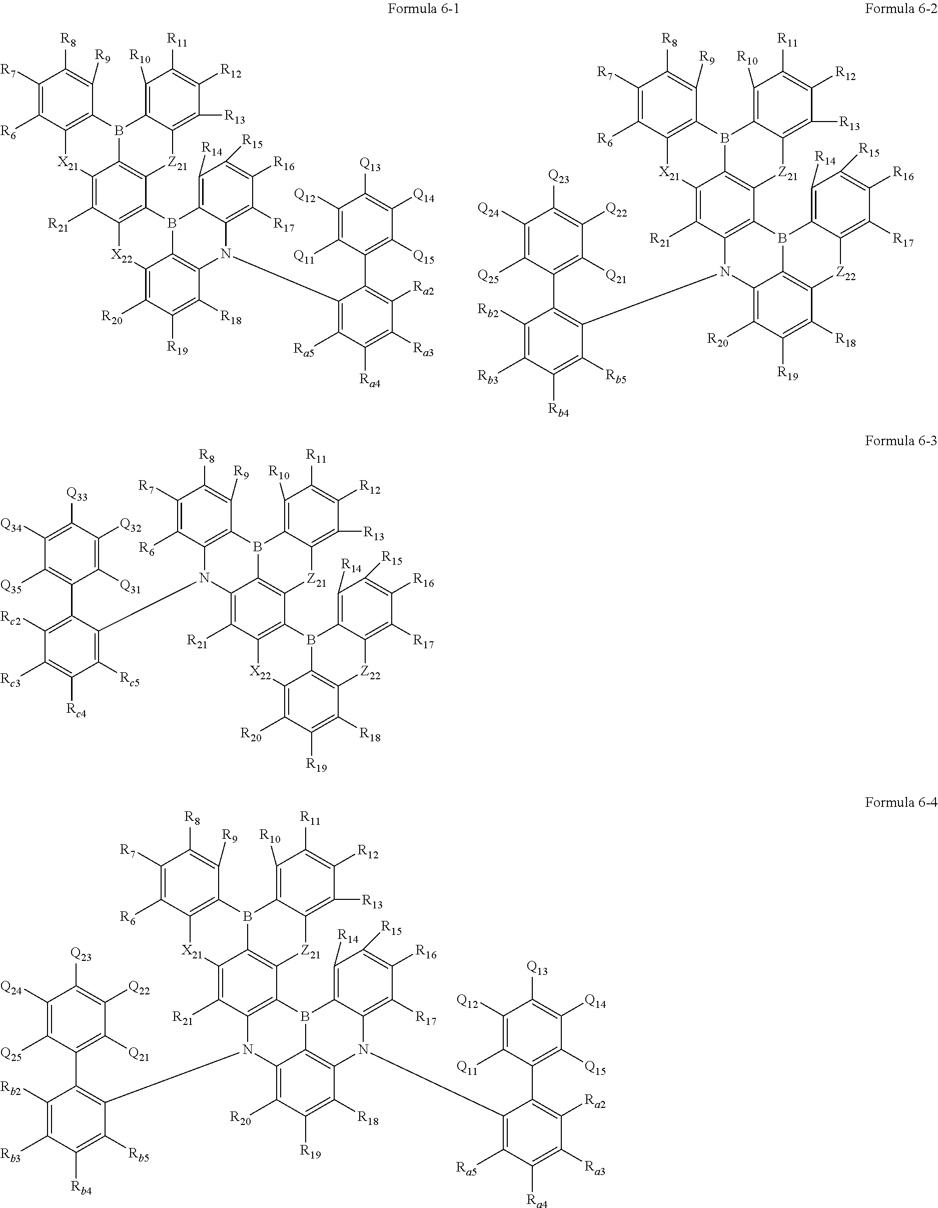

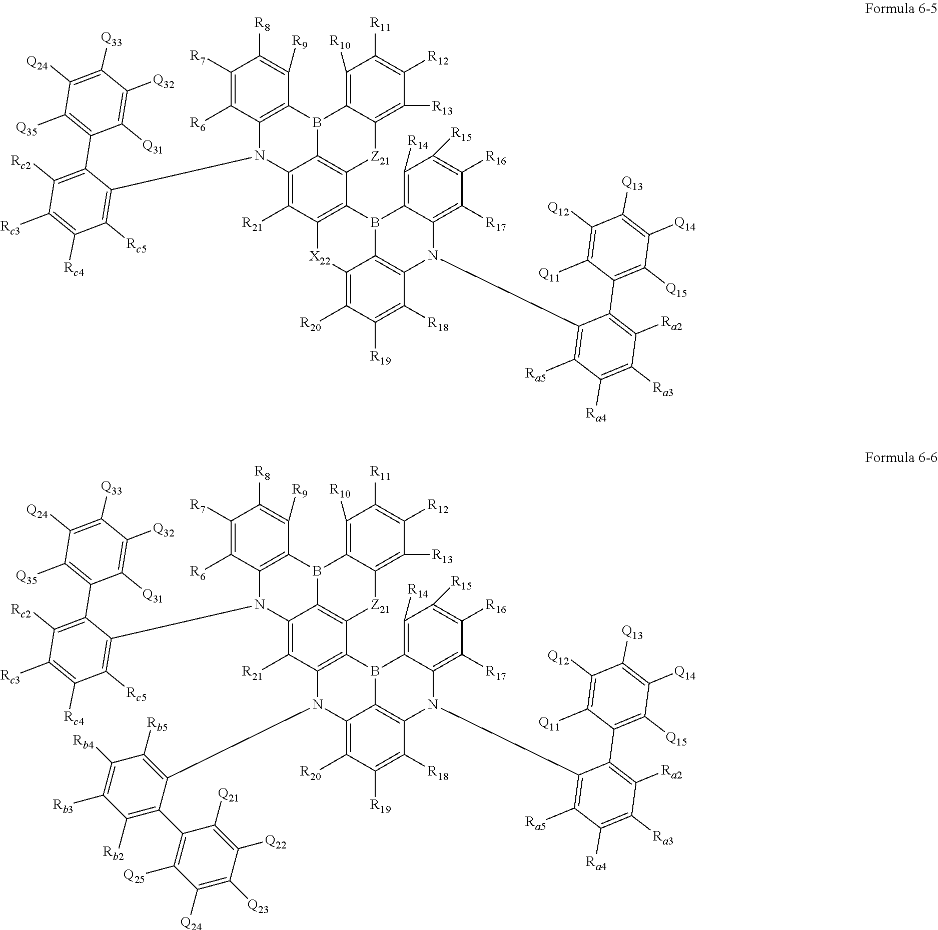

In Formula 6-1 to Formula 6-6, X₂₁, X₂₂, Z₂₁, and Z₂₂ may each independently be O, S, or NRₐ. The more details as described in one or more embodiments with reference to Formula 1 may be similarly applied to Rₐ.

In Formula 6-1 to Formula 6-6, at least one selected from among Rₐ₂ to Rₐ₅, at least one selected from among R_{b2} to R_{b5}, and at least one selected from among R_{c2} to Ros may each independently be represented by Formula 3. For example, one or two selected from among Rₐ₂ to R₅ₛ in Formula 6-1, Formula 6-4, Formula 6-5, and Formula 6-6 may be represented by Formula 3. In one or more embodiments, one or two selected from among R_{c2} to R_{c5} in Formula 6-3, Formula 6-5, and Formula 6-6 may be represented by Formula 3.

In Formula 6-1 to Formula 6-6, the rest among Rₐ₂ to Rₐ, R_{b2} to R_{b5}, and R_{c2} to R_{c5} that are not represented by Formula 3 as described in one or more embodiments may each independently be a hydrogen atom, a deuterium atom, a substituted or unsubstituted alkyl group having 1 to 20 carbon atoms, or a substituted or unsubstituted aryl group having 6 to 30 ring-forming carbon atoms. For example, the rest among Rₐ₂ to Rₐ₅, R_{b2} to R_{b5}, and R_{c2} to R_{c5} that are not represented by Formula 3 as described in one or more embodiments may each independently be a hydrogen atom, a deuterium atom, a substituted or unsubstituted t-butyl group, or a substituted or unsubstituted phenyl group.

In Formula 6-1 to Formula 6-6, Q₁₁ to Q₁₅, Q₂₁ to Q₂₅, and Q₃₁ to Q₃₅ may each independently be a hydrogen atom, a deuterium atom, a substituted or unsubstituted t-butyl group, or a substituted or unsubstituted phenyl group, but embodiments of the present disclosure are not limited thereto. Q₁₁ to Q₁₅, Q₂₁ to Q₂₅, and Q₃₁ to Q₃₅ may each independently be bonded to an adjacent group to form a ring.

In Formula 6-1 to Formula 6-6, the more details as described in one or more embodiments with reference to Formula 4 may be similarly applied to R₆ to R₂₁.

In one or more embodiments, the polycyclic compound represented by Formula 1 and/or the like may include a core of a fused ring with nine rings in which two fused rings with 5 rings, each including two hetero atoms and one boron (B) atom as a ring-forming atom, are connected by sharing one ring, and include at least one nitrogen atom in the core of the fused ring with nine rings, to which the first substituent is connected. Therefore, the polycyclic compound according to one or more embodiments may contribute to achieving high efficiency and long lifespan.

The polycyclic compound according to one or more embodiments may exhibit high absorbance and a narrow full width at half maximum characteristics by including the core of the fused ring with at least nine rings and may provide an effect of improvement or enhancement in both (e.g., simultaneously) luminous efficiency and lifespan because rapid reverse intersystem crossing (RISC) is feasible. In one or more embodiments, the polycyclic compound according to one or more embodiments may include at least one nitrogen atom by which the first substituent is connected to the core of the fused ring with nine rings, and at least two first sub substituents may be additionally bonded to the first substituent, and thus intermolecular interactions between the polycyclic compounds decrease due to a steric hindrance effect. Therefore, excellent or suitable material stability may be exhibited. For example, the polycyclic compound according to one or more embodiments may include at least one nitrogen atom, to which the first substituent and the first sub substituents are connected, wherein the first substituent and the first sub substituents may protect the fused ring with nine rings, and thus an intermolecular distance increases. Therefore, Dexter energy transfer may be reduced. Accordingly, an increase in concentration of triplet exciton in the polycyclic compound may be suppressed or reduced, and thus lifespan deterioration caused due to the increase in the triplet concentration may be suppressed or reduced. Therefore, if (e.g., when) the polycyclic compound according to one or more embodiments is applied to the emission layer EML, the luminous efficiency may not only be increased or enhanced, but also the element lifespan may be improved or enhanced.

The polycyclic compound according to one or more embodiments may include the fused ring core with at least nine rings, and thus high absorbance and a narrow full width at half maximum characteristics may be exhibited, and the light-emitting element ED may have improved or enhanced effects on both (e.g., simultaneously) light-emitting element and lifespan because the rapid reverse intersystem crossing (RISC) is feasible. In one or more embodiments, the polycyclic compound according to one or more embodiments may include at least one nitrogen atom to which the first substituent is connected in the core of the fused ring with nine rings, and at least two first sub substituents may be additionally bonded to the first substituent, and thus intermolecular interactions between the polycyclic compound decreases due to the steric hindrance effect. Therefore, excellent or suitable material stability may be exhibited. For example, the polycyclic compound according to one or more embodiments may include at least one nitrogen atom to which the first substituent and the first sub substituents are connected, which may sterically protect the core of the fused ring with nine rings. Therefore, intermolecular distance may increase, and thus Dexter energy transfer may decrease. Accordingly, an increase in concentration of triplet exciton in the polycyclic compound may be suppressed or reduced, and thus lifespan deterioration caused due to the increase in the concentration of triplet exciton may be suppressed or reduced. Therefore, if (e.g., when) the polycyclic compound according to one or more embodiments is applied in the emission layer EML, luminous efficiency may not only be increased or enhanced but lifespan may also be improved or enhanced.

The polycyclic compound according to one or more embodiments may be represented by any one selected from among the compounds present in Compound Group 1. The light-emitting element ED according to one or more embodiments may include at least one selected from among the compounds in Compound Group 1. The light-emitting element ED according to one or more embodiments may include at least one selected from among the compounds in Compound Group 1 in the emission layer EML.

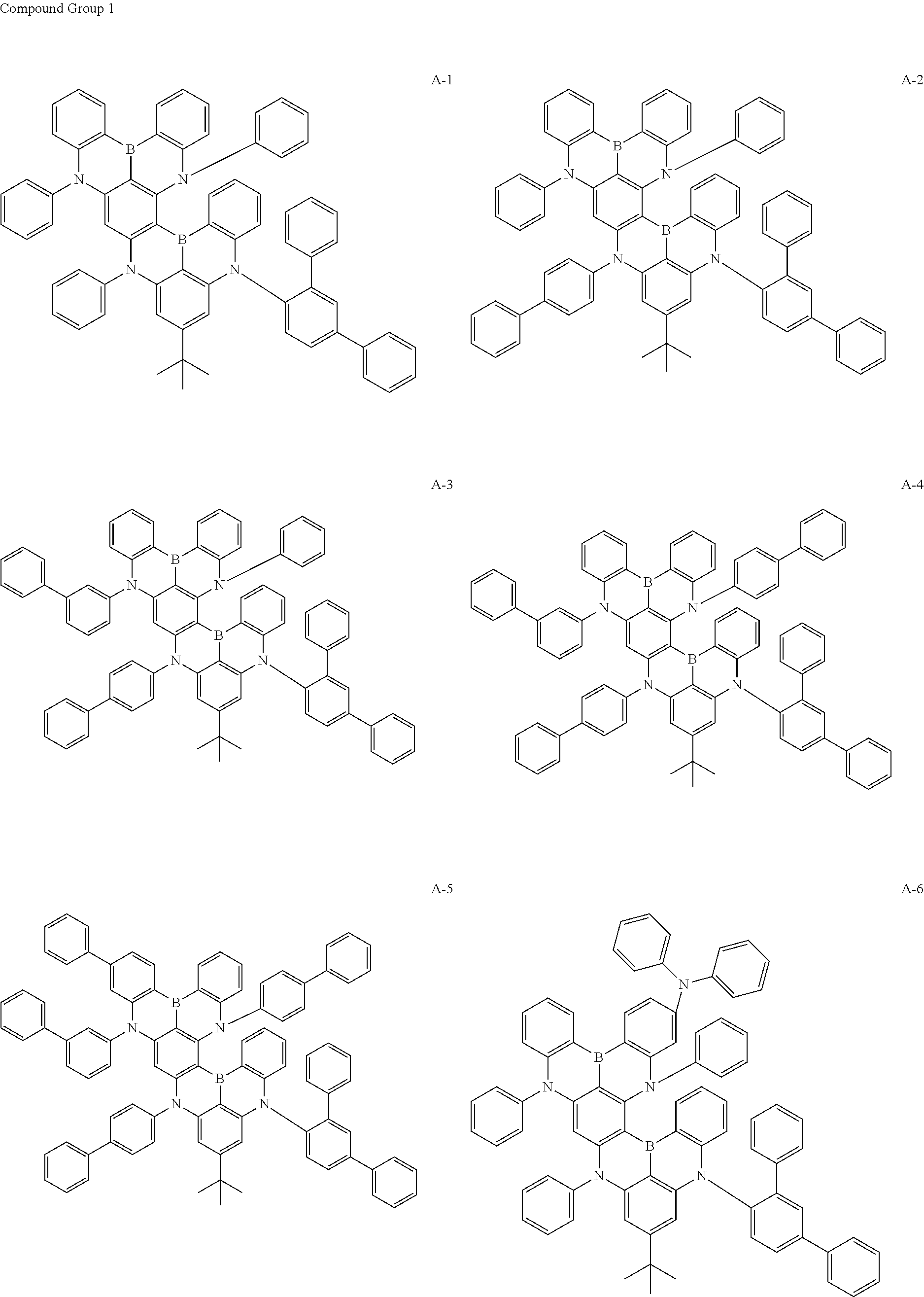

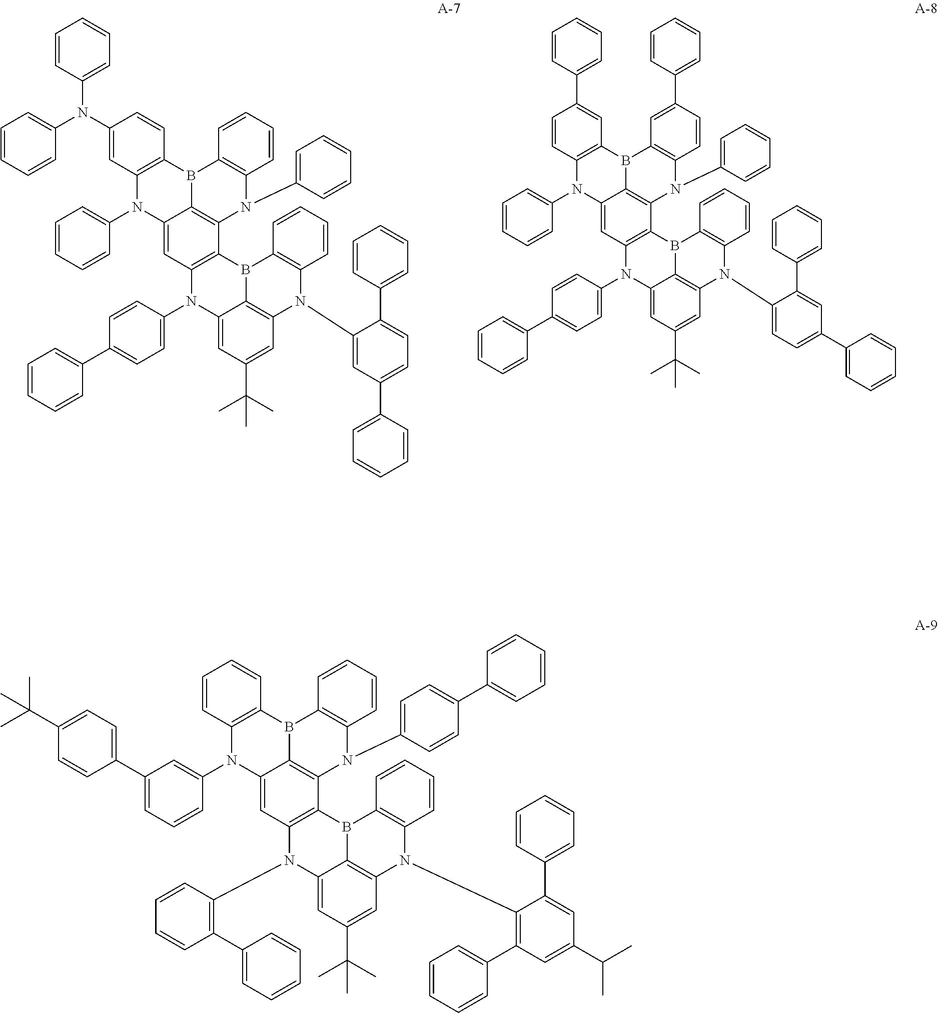 [SMILES: CC(C)(C)c1cc2c3c(c1)N(c1cc(-c4ccccc4)ccc1-c1ccccc1)c1ccccc1B3c1c(cc3c4c1N(c1ccccc1)c1ccccc1B4c1ccc(N(c4ccccc4)c4ccccc4)cc1N3c1ccccc1)N2c1ccc(-c2ccccc2)cc1 ; CC(C)(C)c1cc2c3c(c1)N(c1ccc(-c4ccccc4)cc1-c1ccccc1)c1ccccc1B3c1c(cc3c4c1N(c1ccccc1)c1ccc(-c5ccccc5)cc1B4c1cc(-c4ccccc4)ccc1N3c1ccccc1)N2c1ccc(-c2ccccc2)cc1 ; CC(C)c1cc(-c2ccccc2)c(N2c3ccccc3B3c4c(cc(C(C)(C)C)cc42)N(c2ccccc2-c2ccccc2)c2cc4c5c(c23)N(c2ccc(-c3ccccc3)cc2)c2ccccc2B5c2ccccc2N4c2cccc(-c3ccc(C(C)(C)C)cc3)c2)c(-c2ccccc2)c1]

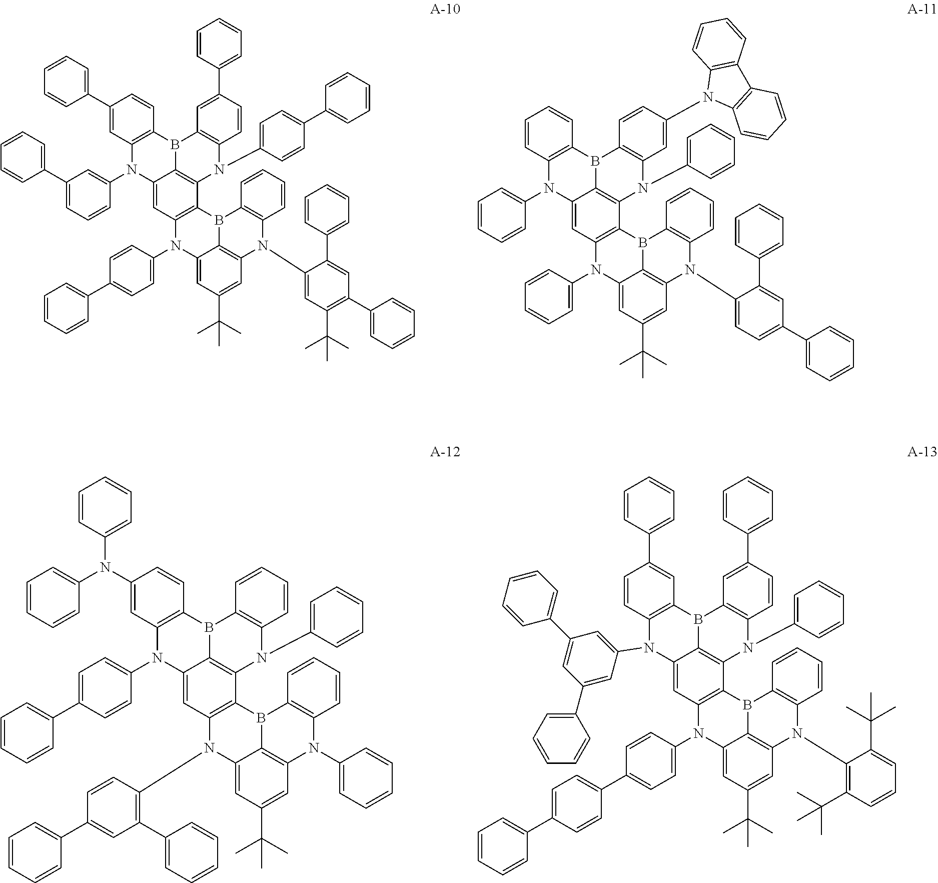

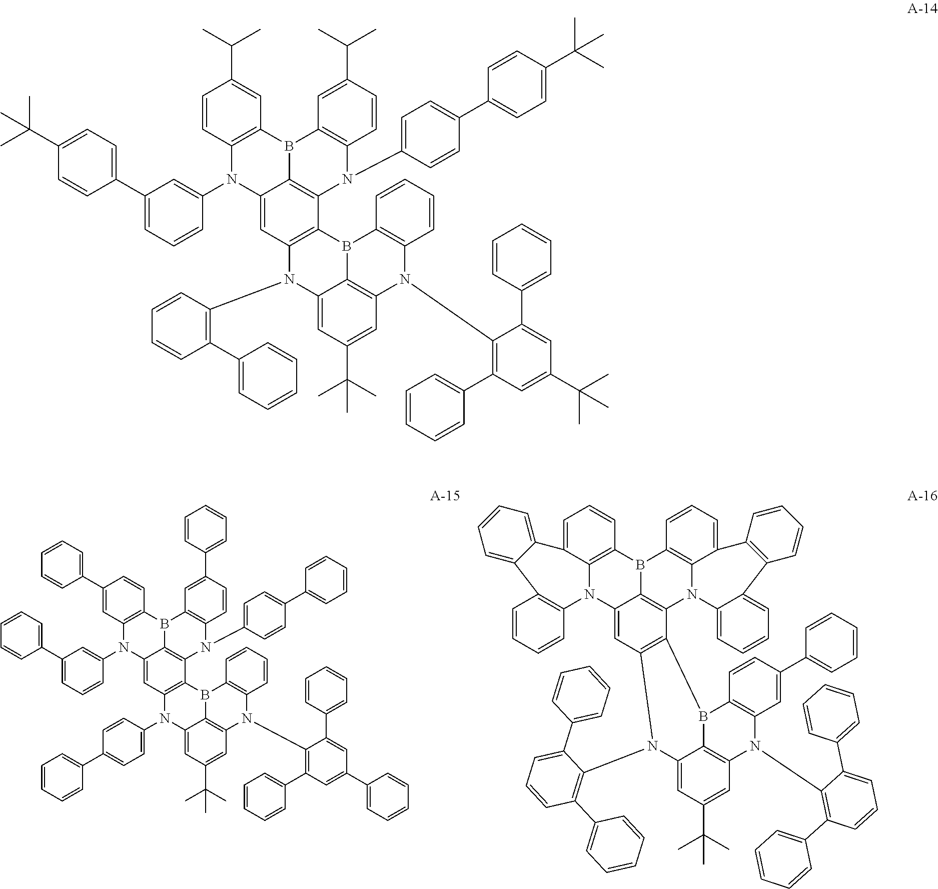

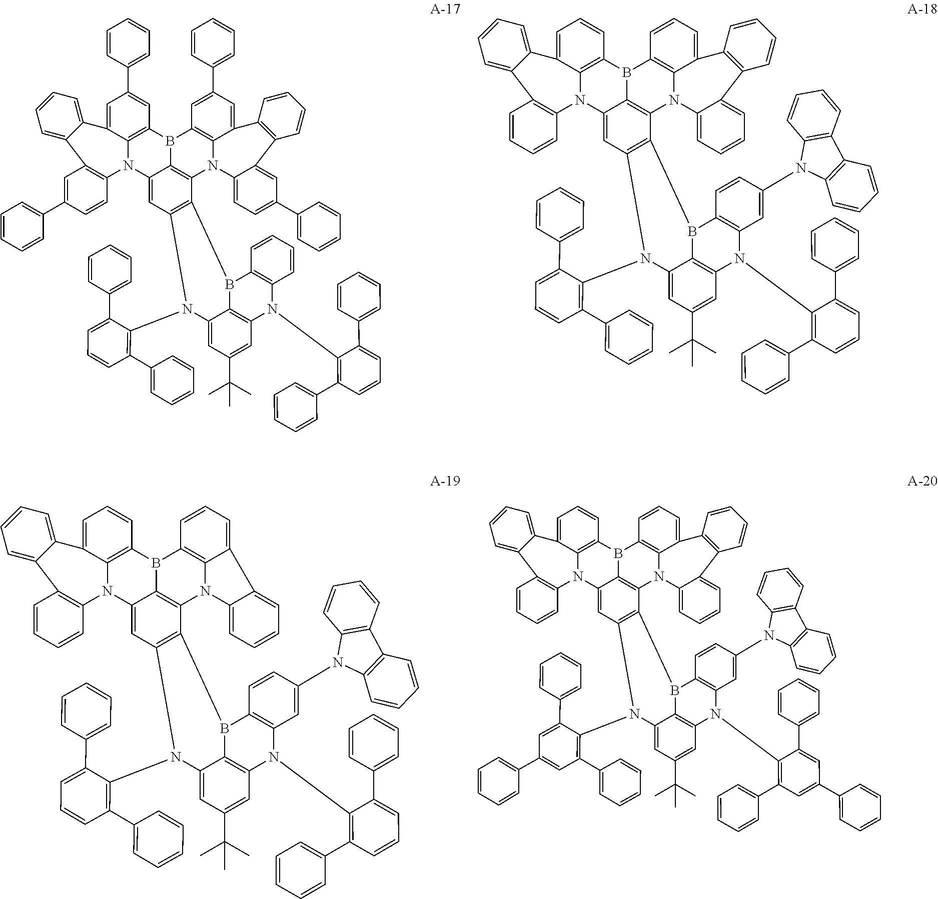

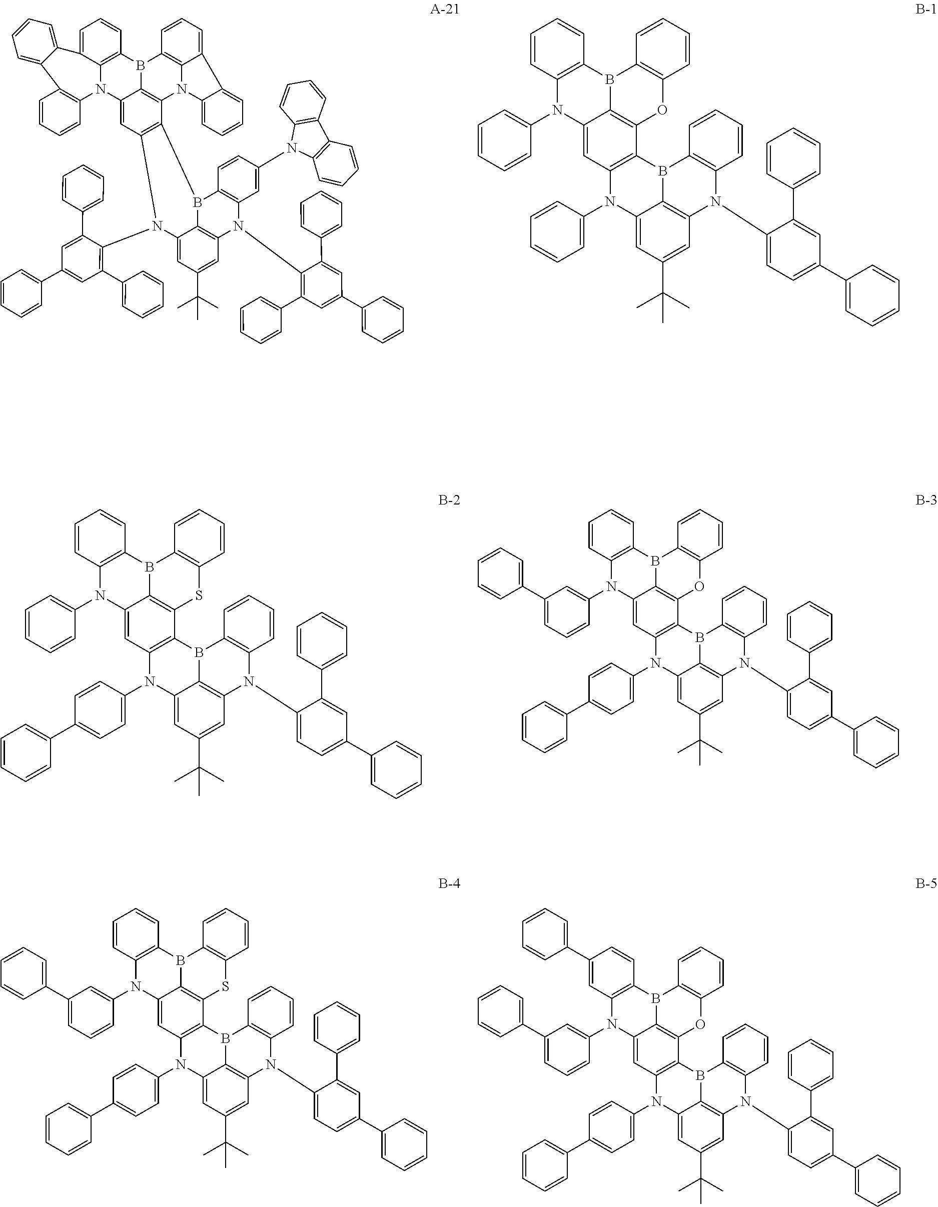

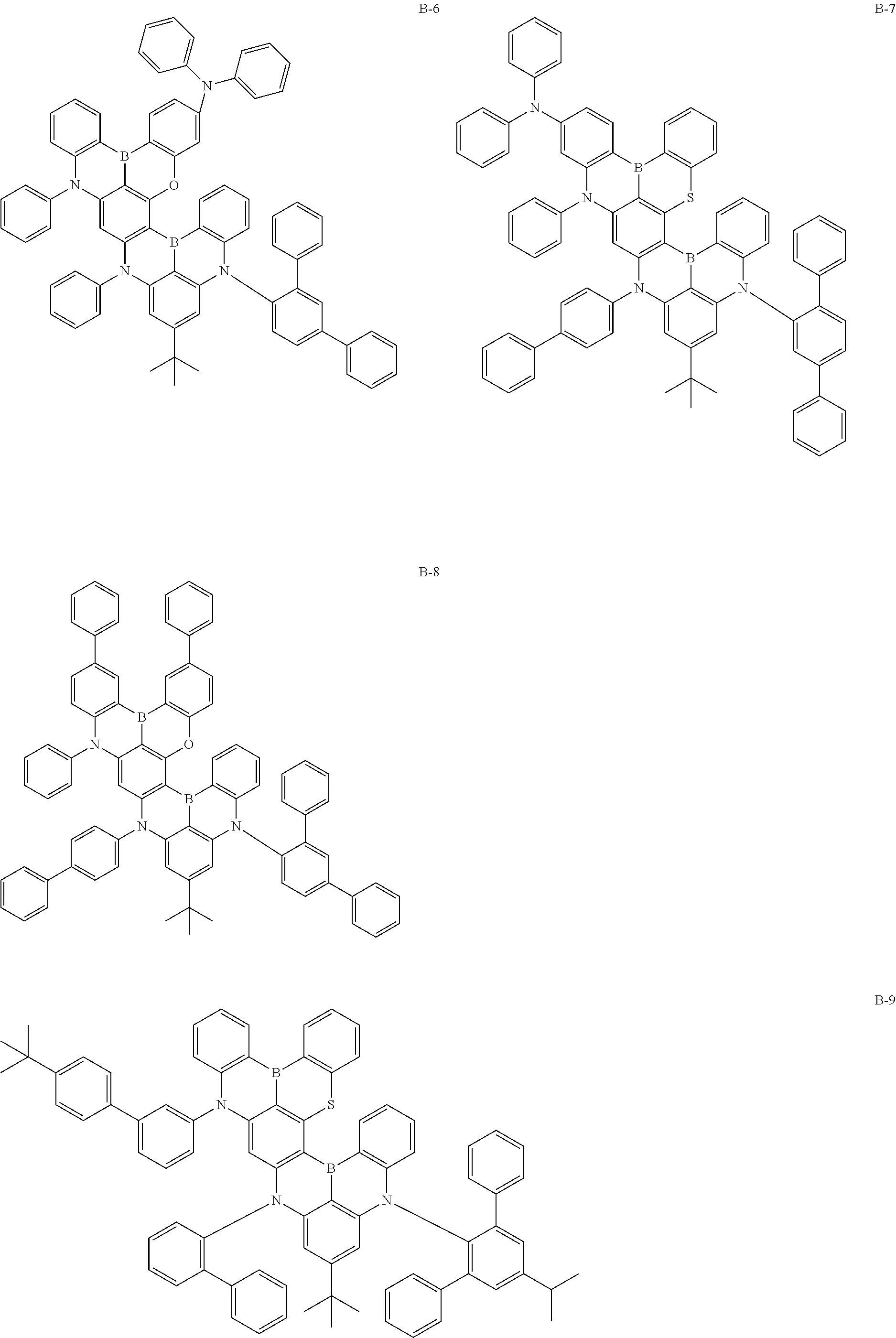

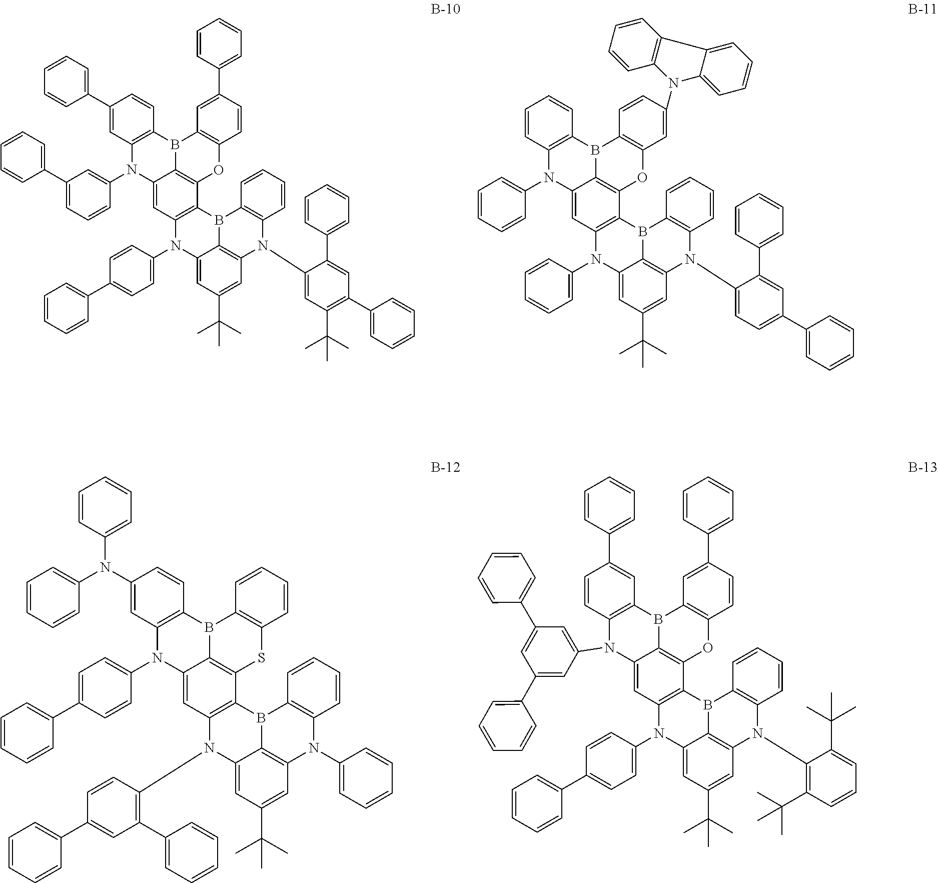

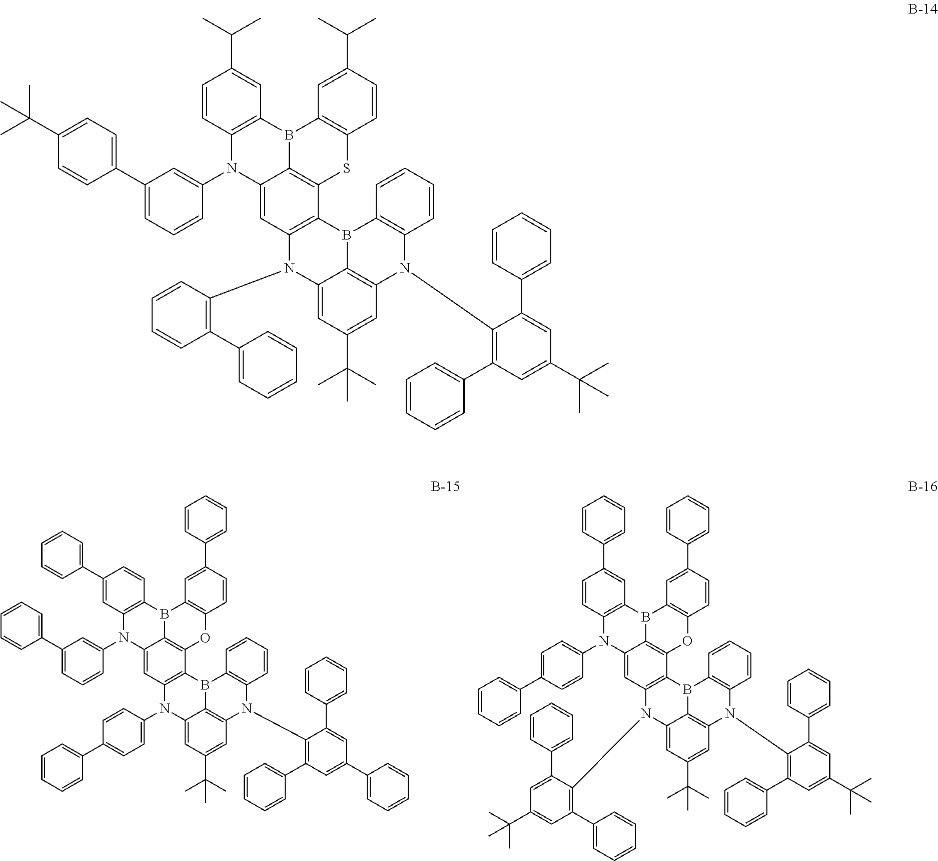

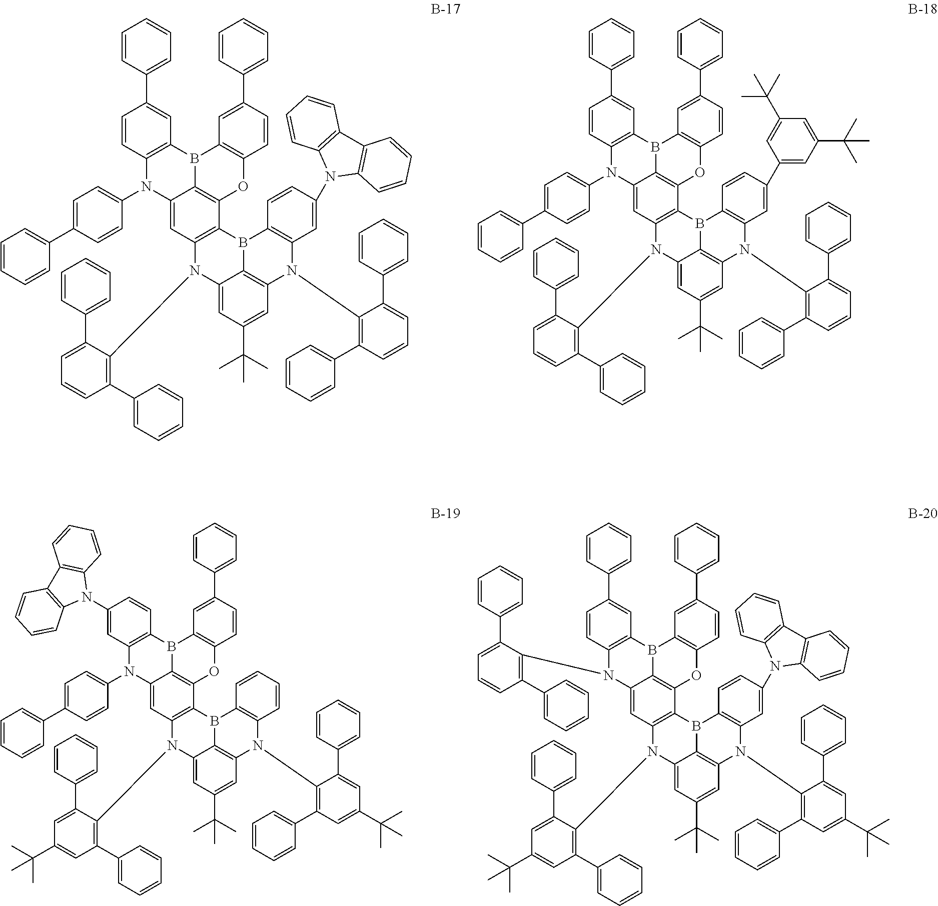

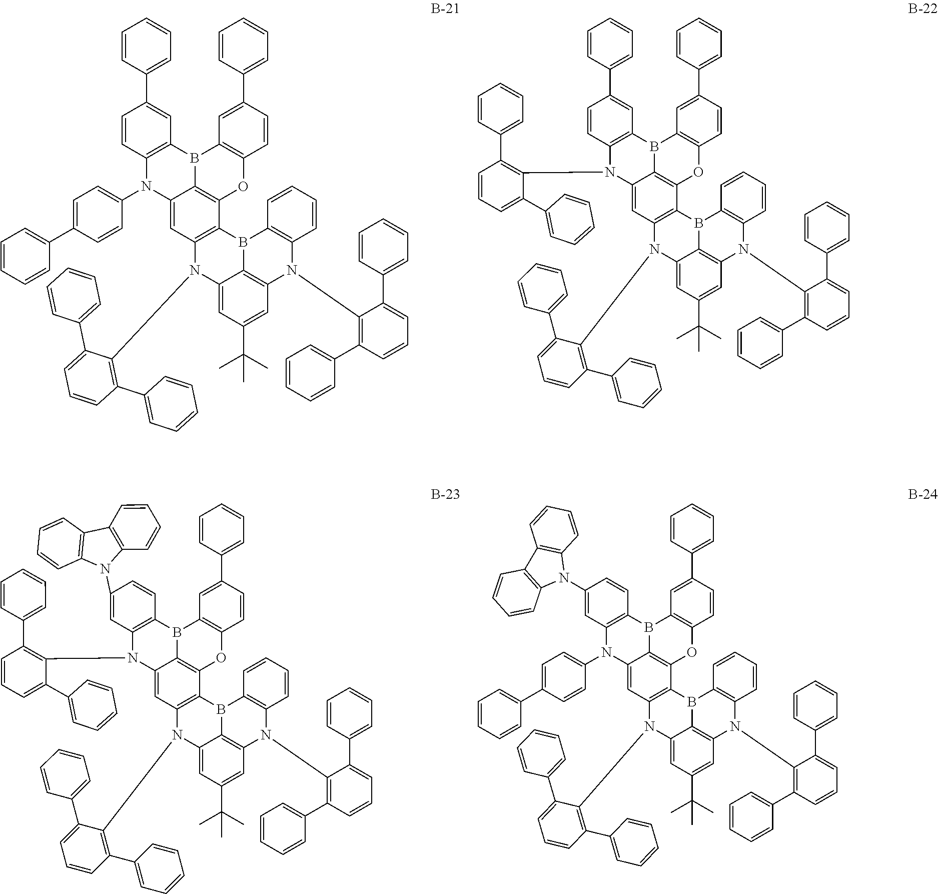

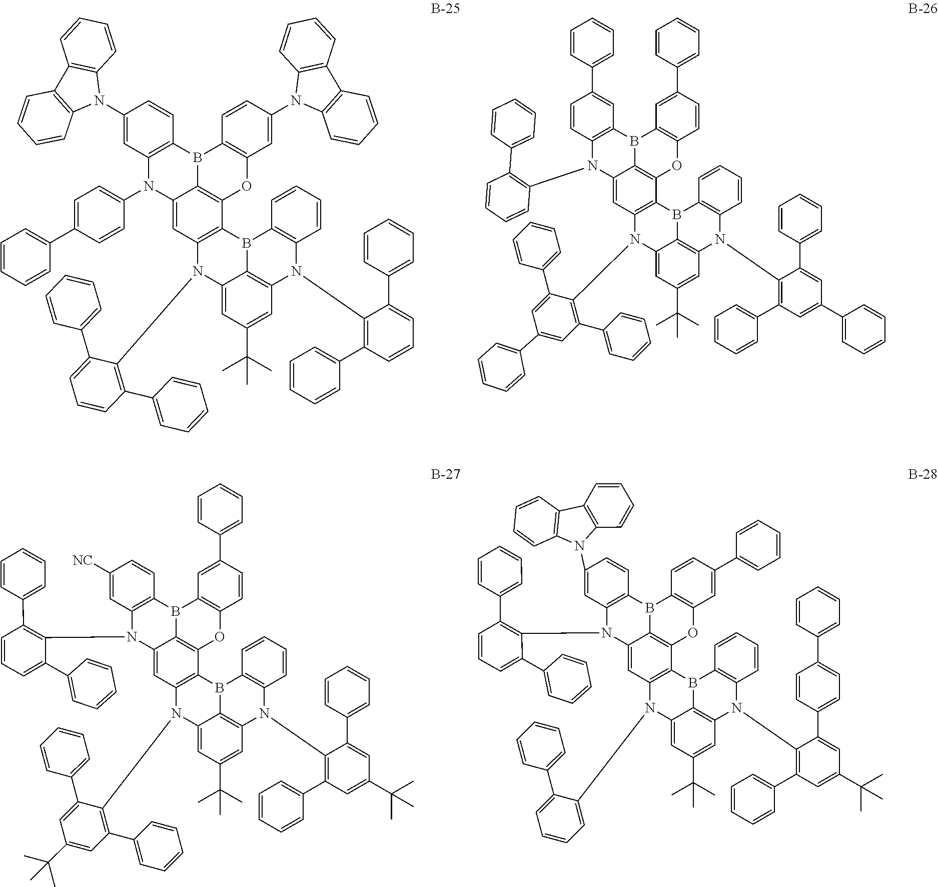

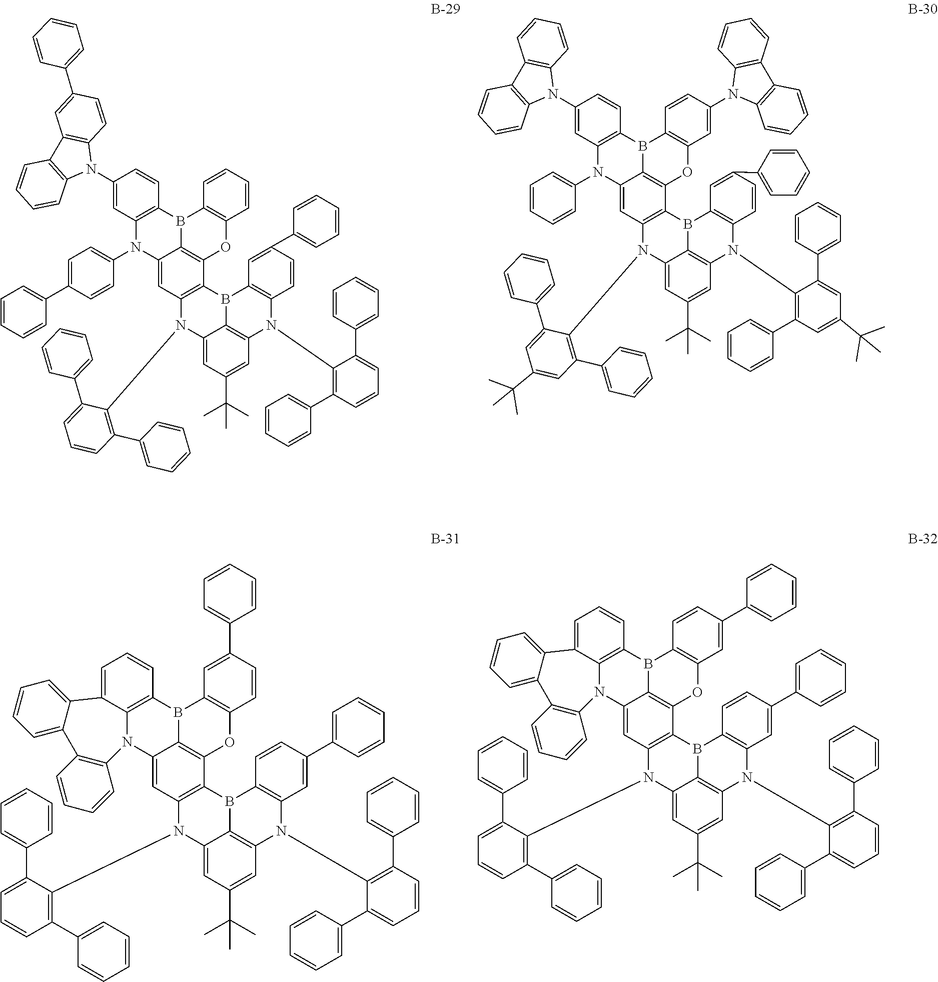

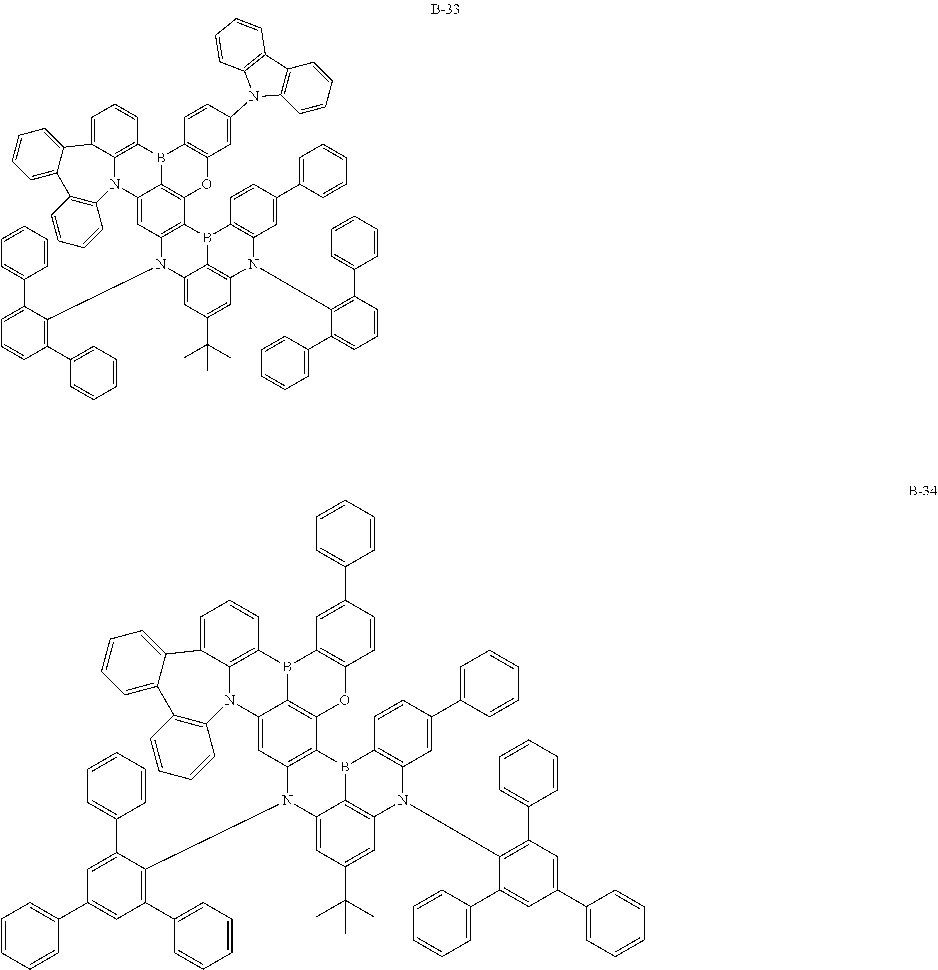 [SMILES: CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-n2c3ccccc3c3ccccc32)ccc1B5c1cccc2c1N4c1ccccc1-c1ccccc1-2 ; CC(C)(C)c1cc2c3c(c1)N(c1c(-c4ccccc4)cc(-c4ccccc4)cc1-c1ccccc1)c1cc4c5c(c1B3c1ccc(-c3ccccc3)cc1N2c1c(-c2ccccc2)cc(-c2ccccc2)cc1-c1ccccc1)Oc1ccc(-c2ccccc2)cc1B5c1cccc2c1N4c1ccccc1-c1ccccc1-2]

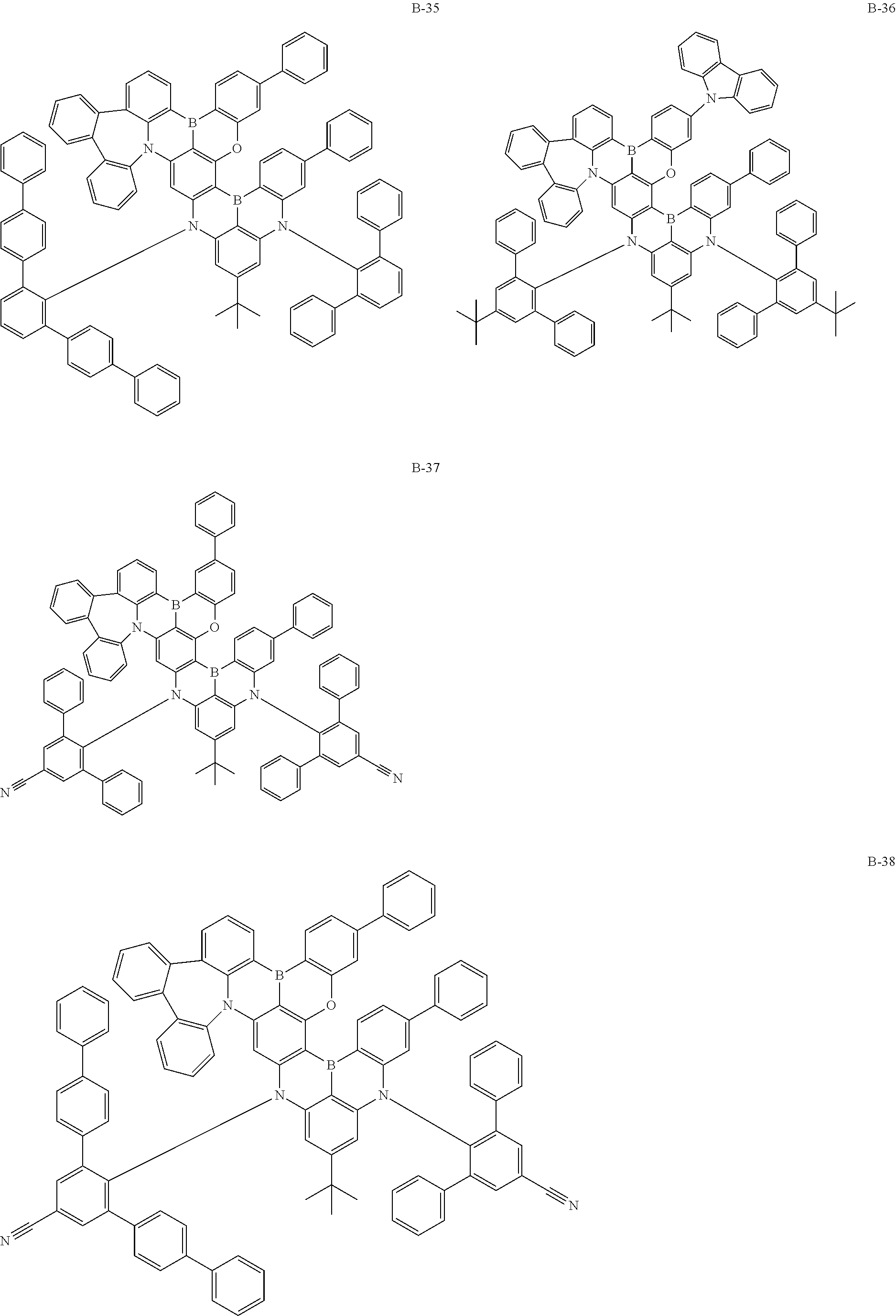

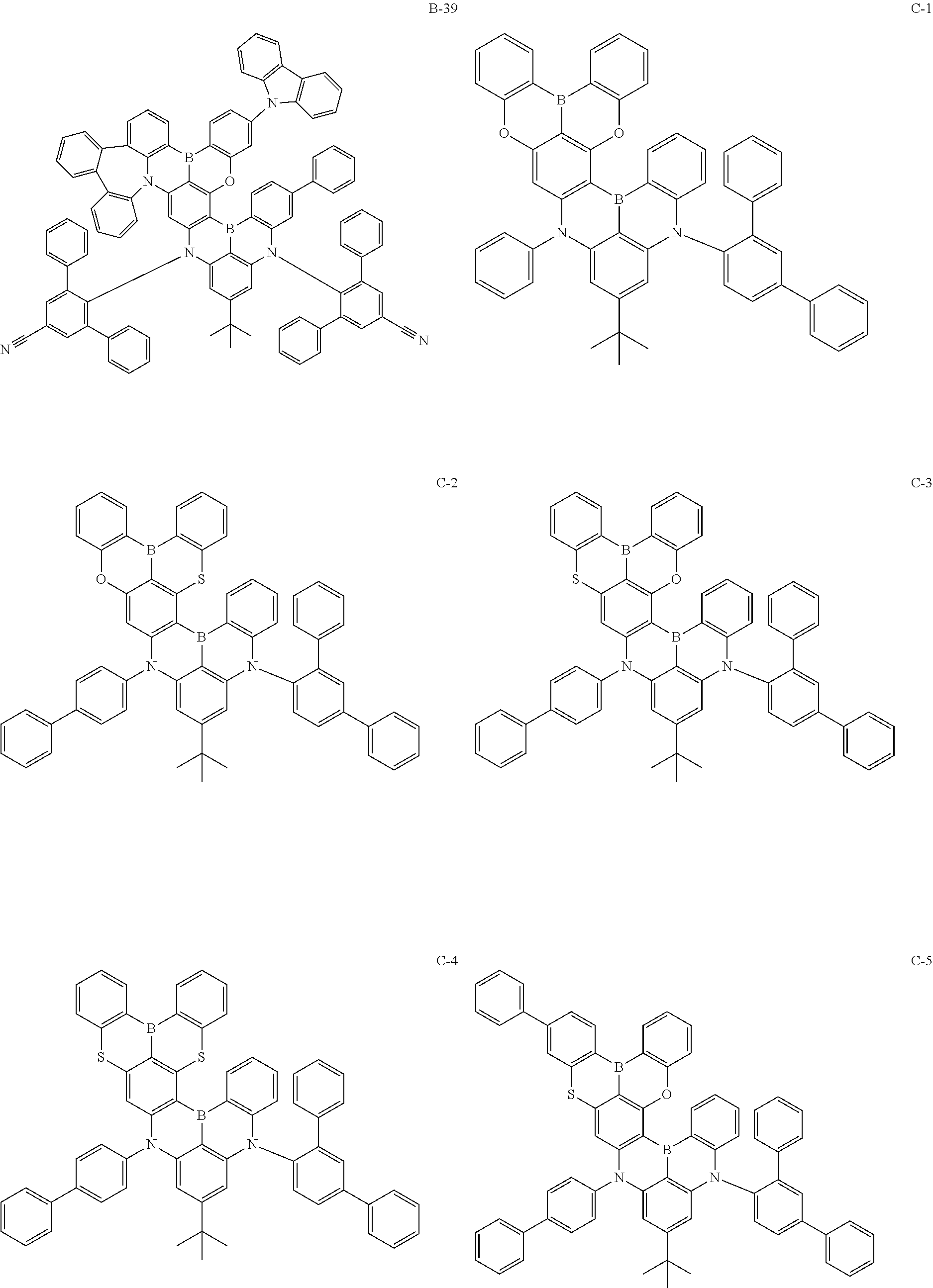

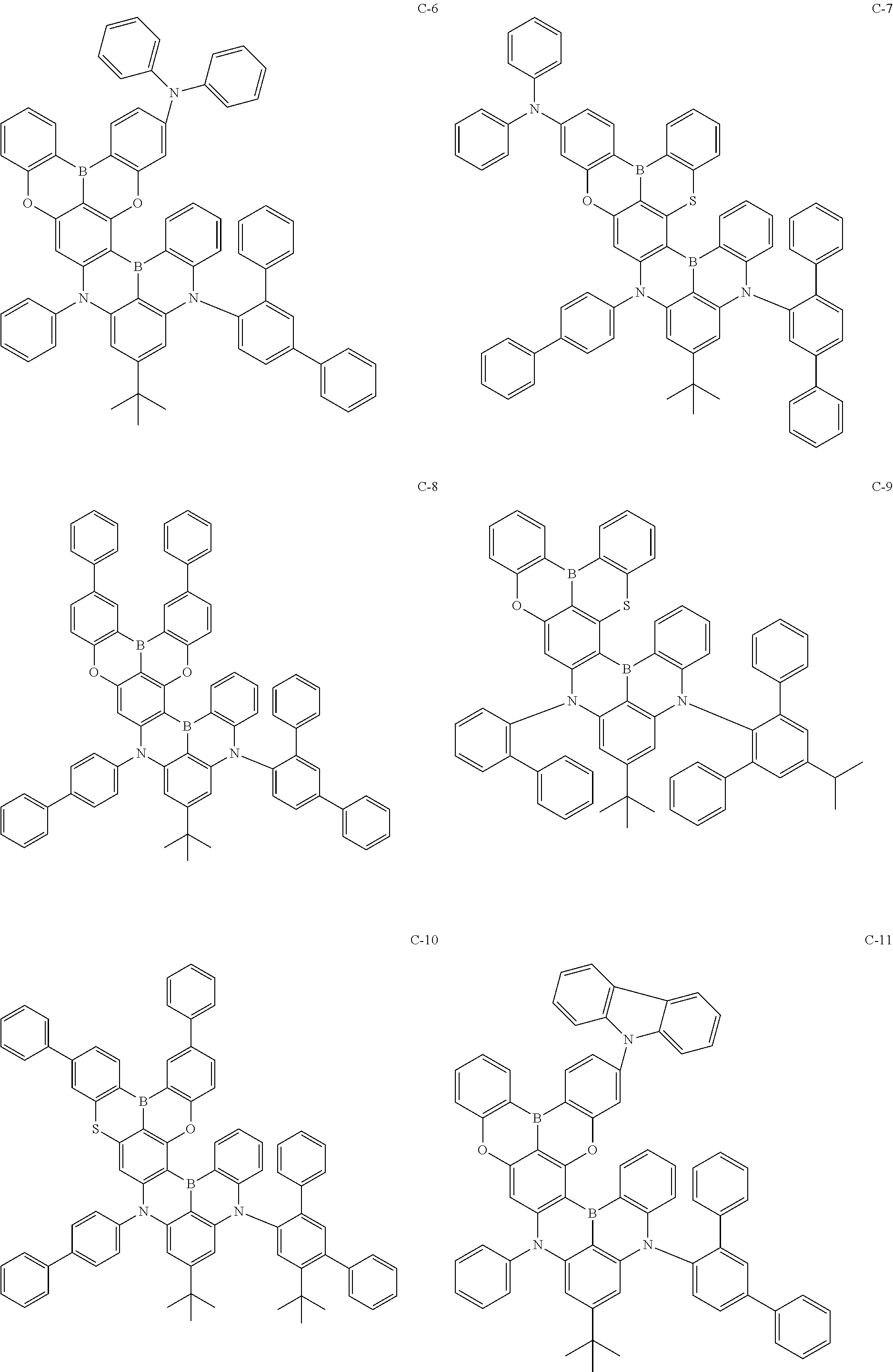

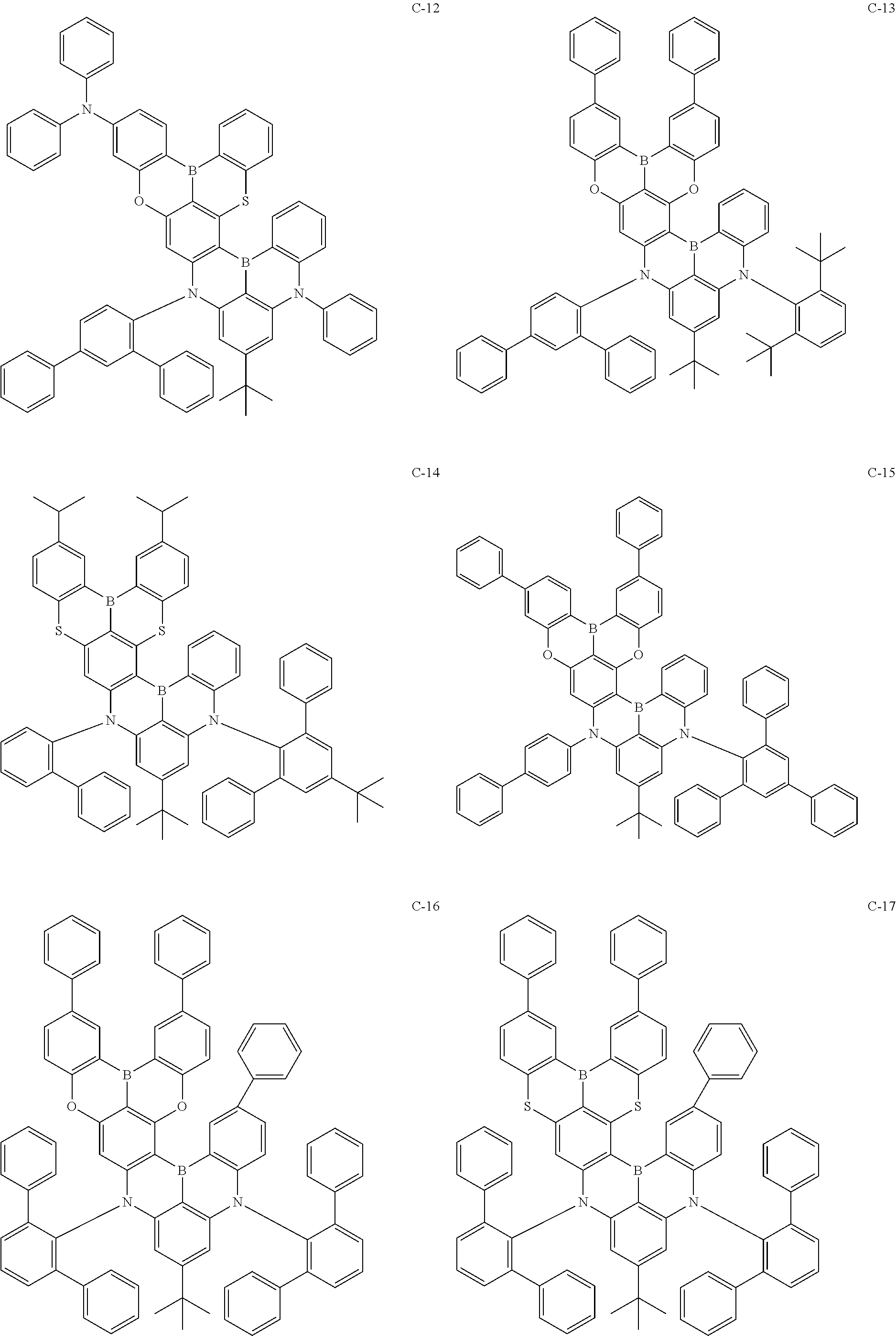

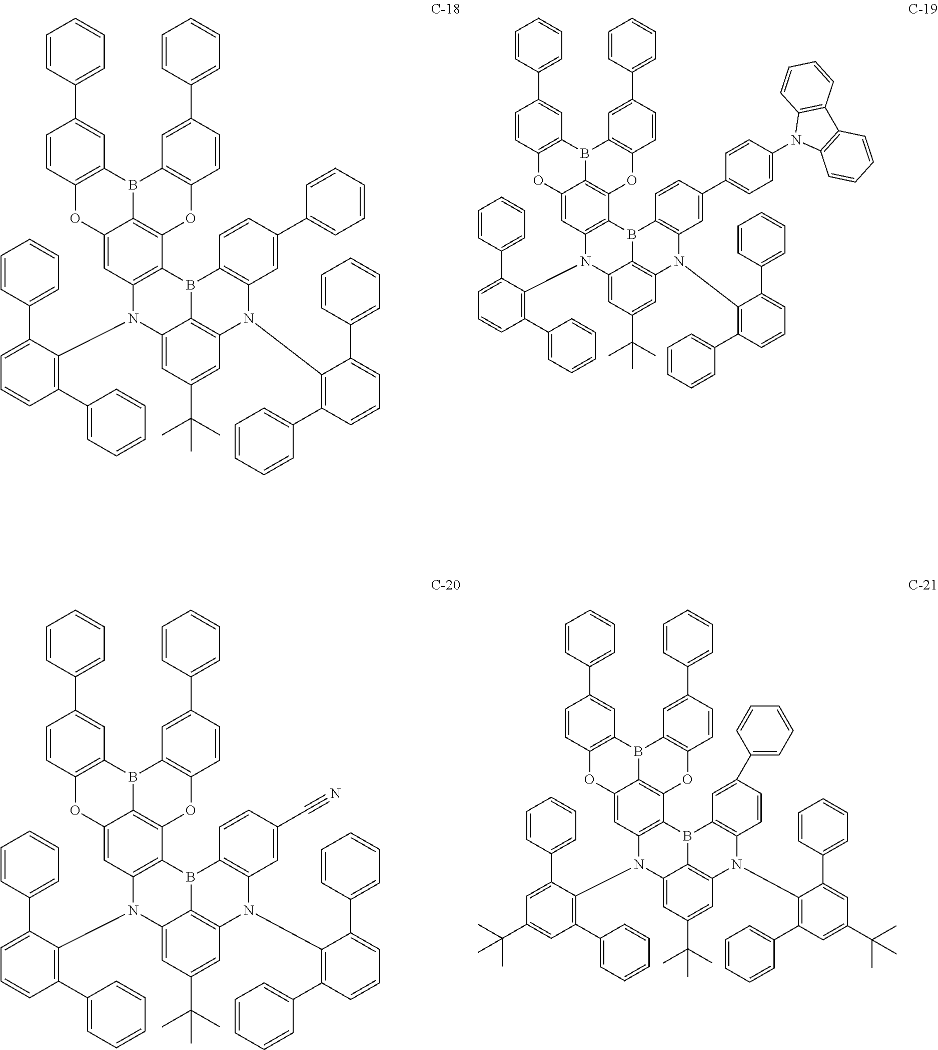

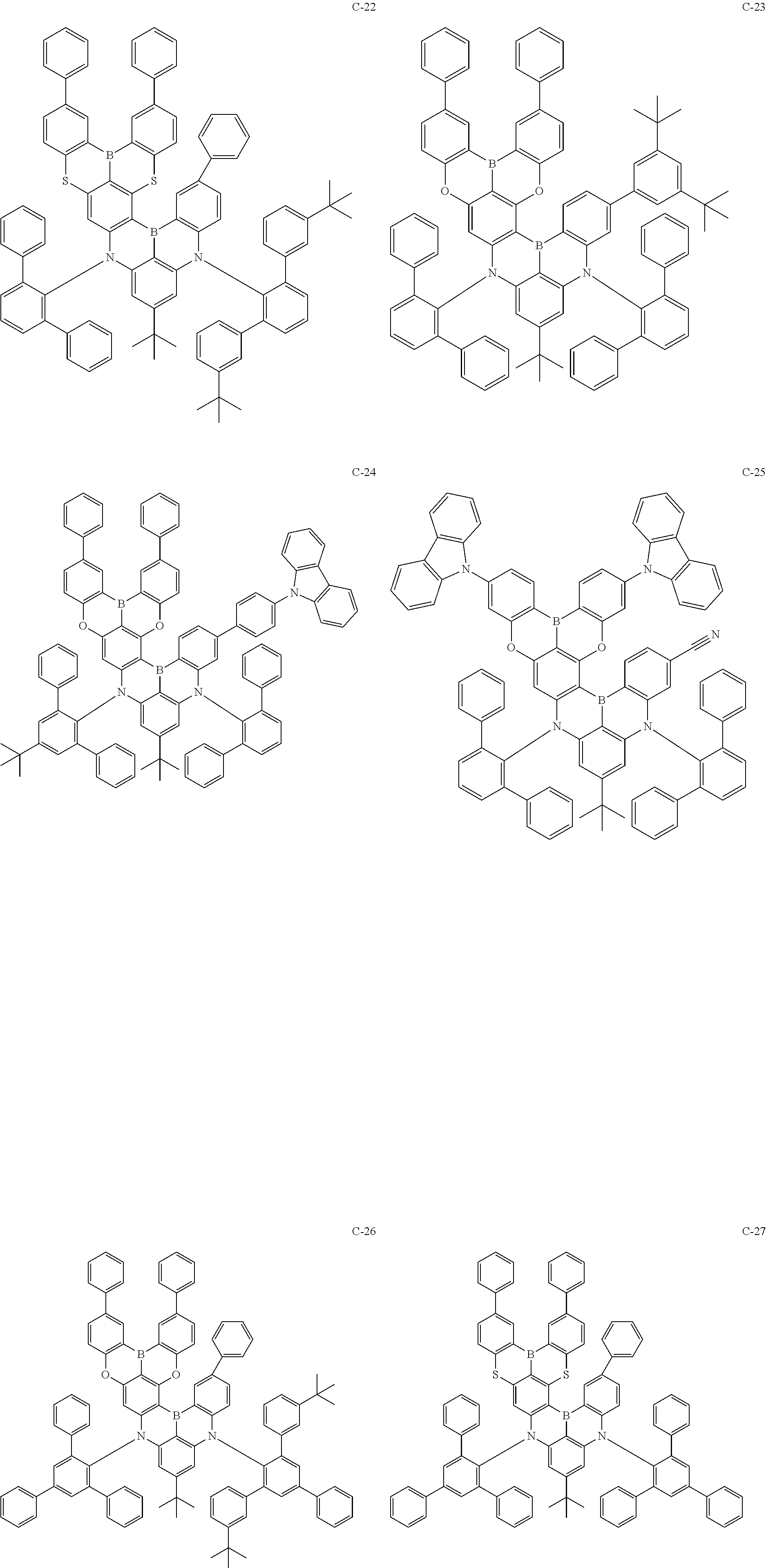

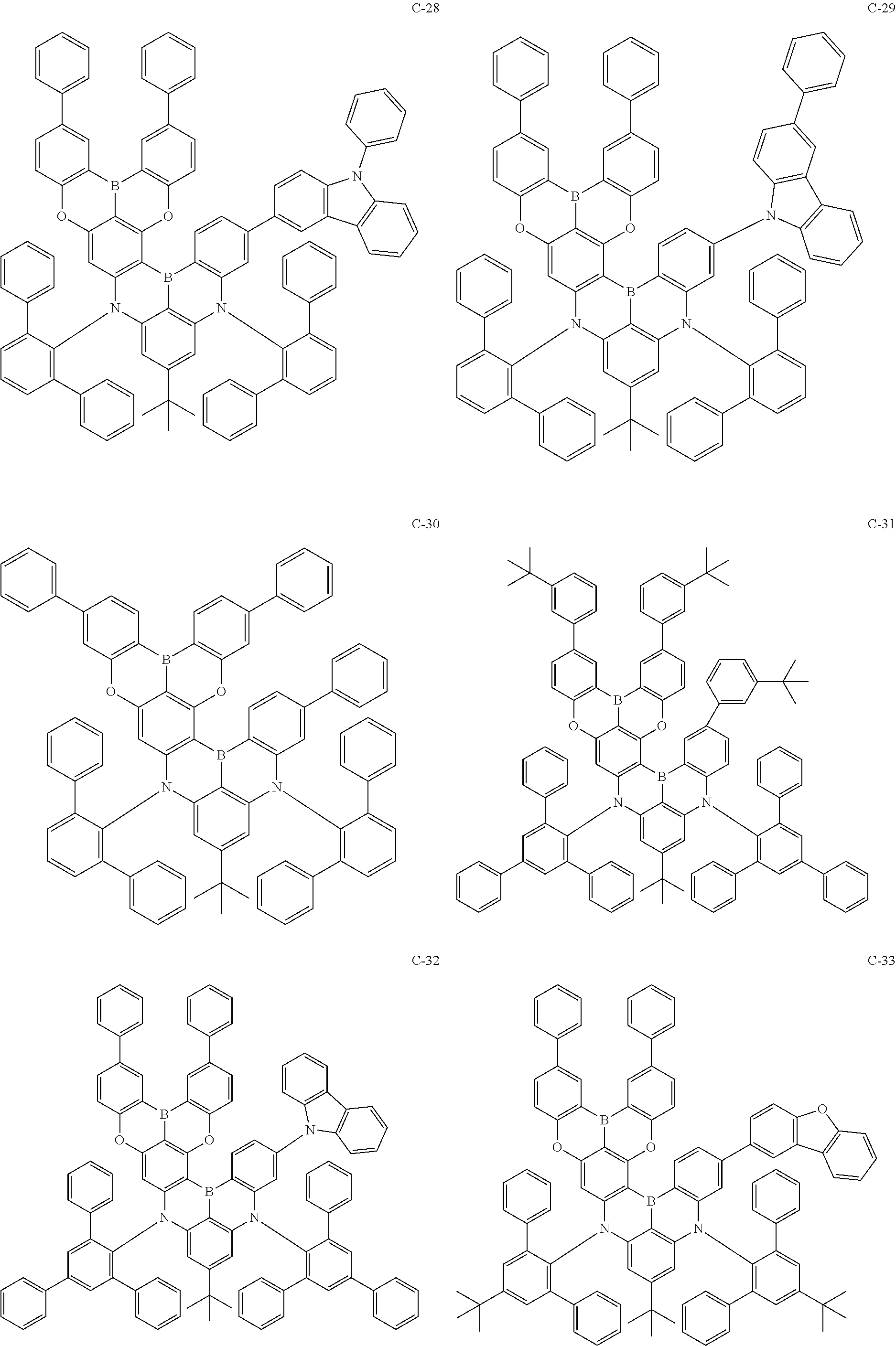

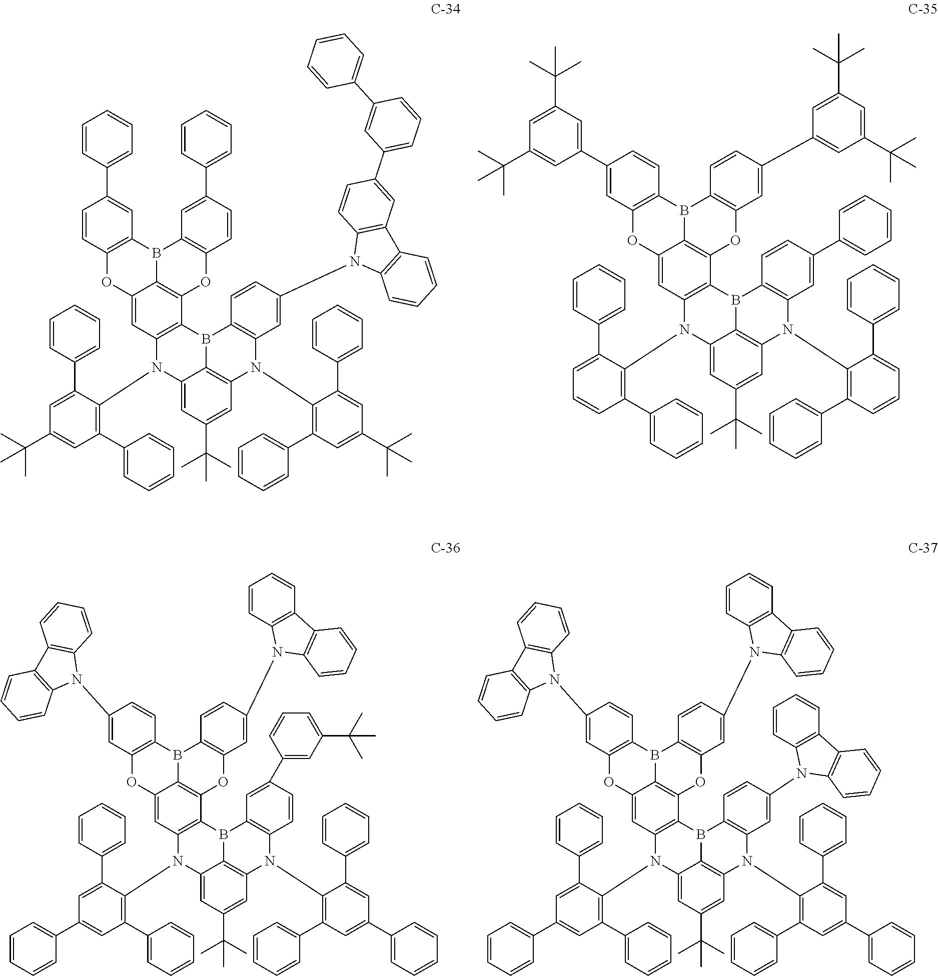

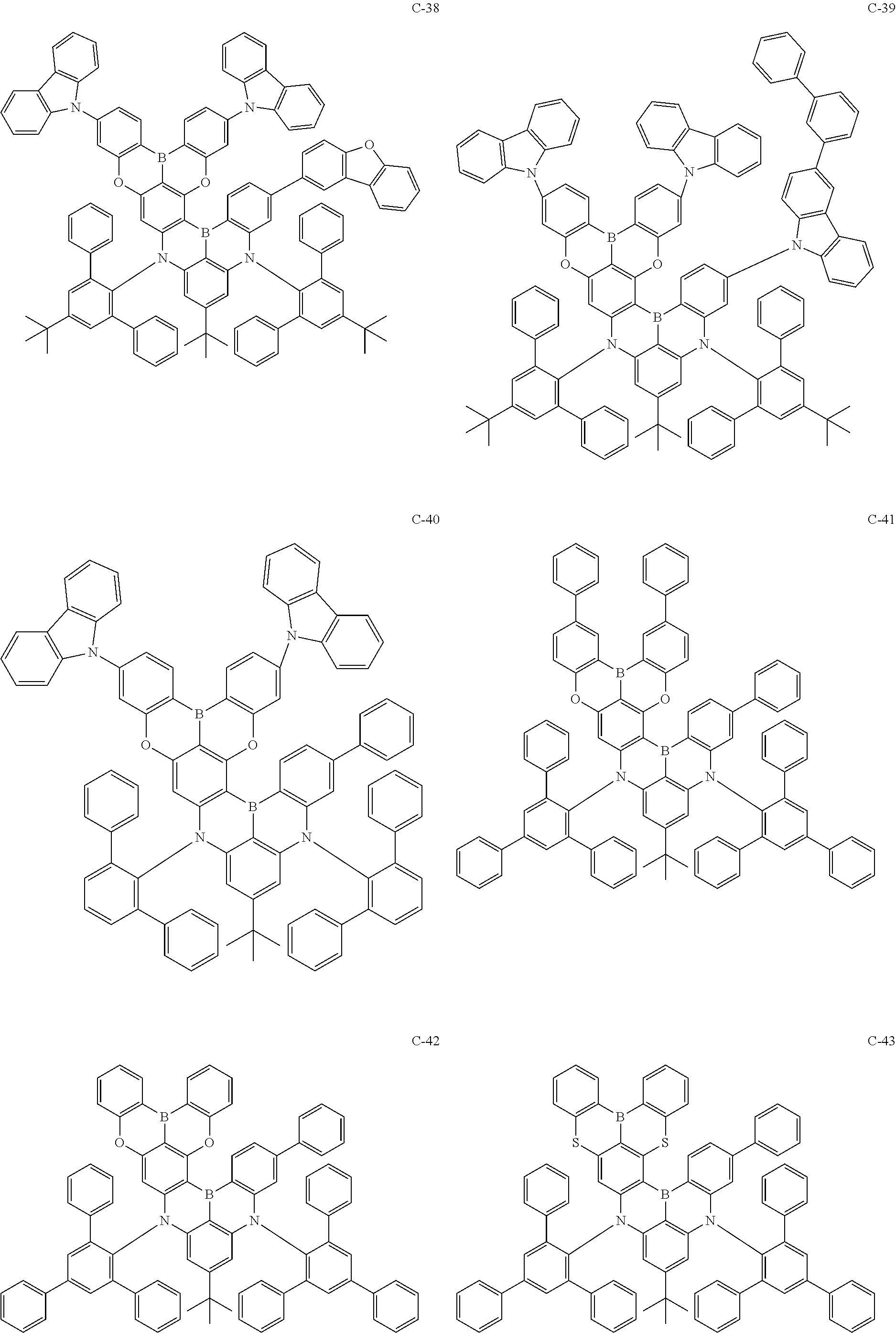

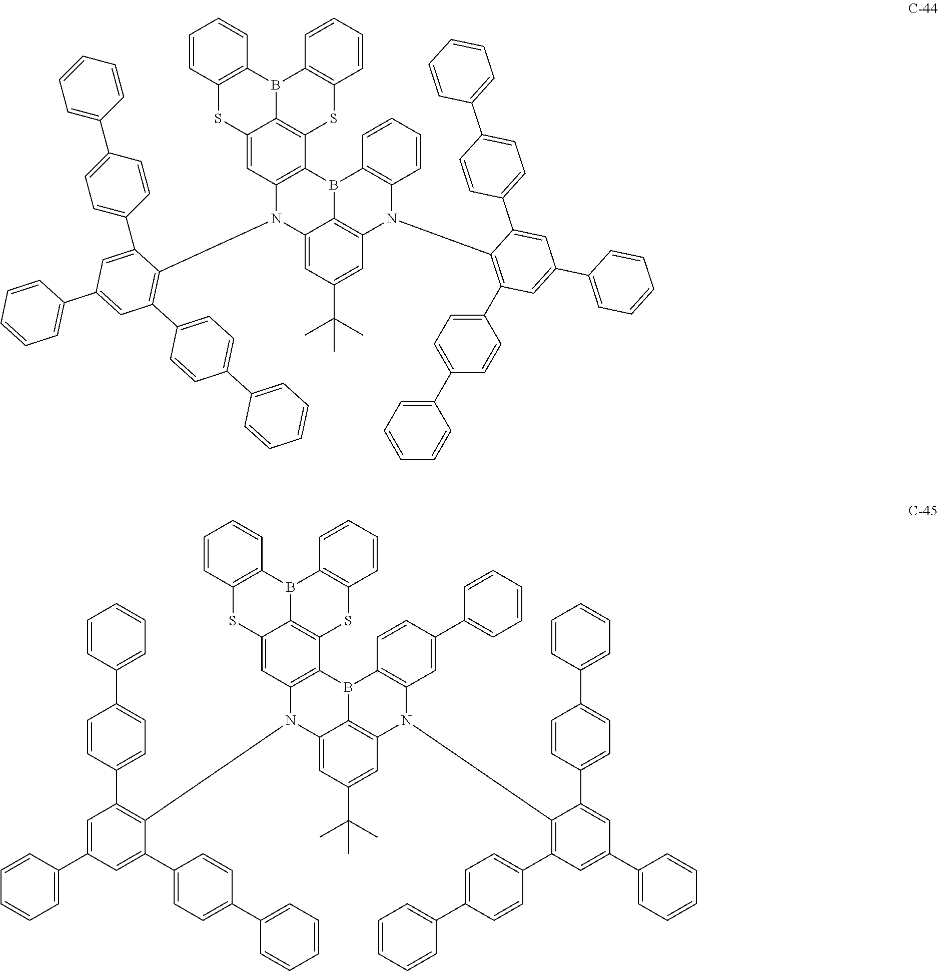 [SMILES: CC(C)(C)c1cc2c3c(c1)N(c1c(-c4ccc(-c5ccccc5)cc4)cc(-c4ccccc4)cc1-c1ccc(-c4ccccc4)cc1)c1cc4c5c(c1B3c1ccccc1N2c1c(-c2ccc(-c3ccccc3)cc2)cc(-c2ccccc2)cc1-c1ccc(-c2ccccc2)cc1)Sc1ccccc1B5c1ccccc1S4 ; CC(C)(C)c1cc2c3c(c1)N(c1c(-c4ccc(-c5ccccc5)cc4)cc(-c4ccccc4)cc1-c1ccc(-c4ccccc4)cc1)c1cc4c5c(c1B3c1ccc(-c3ccccc3)cc1N2c1c(-c2ccc(-c3ccccc3)cc2)cc(-c2ccccc2)cc1-c1ccc(-c2ccccc2)cc1)Sc1ccccc1B5c1ccccc1S4]

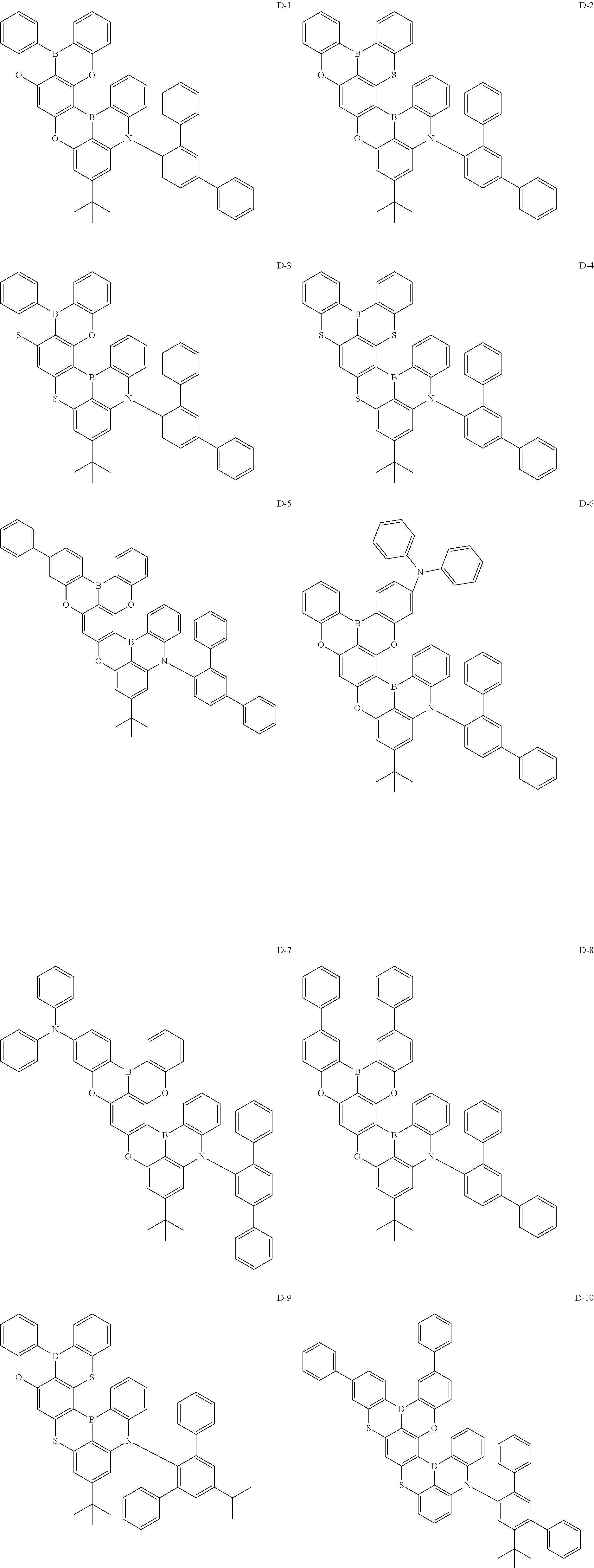

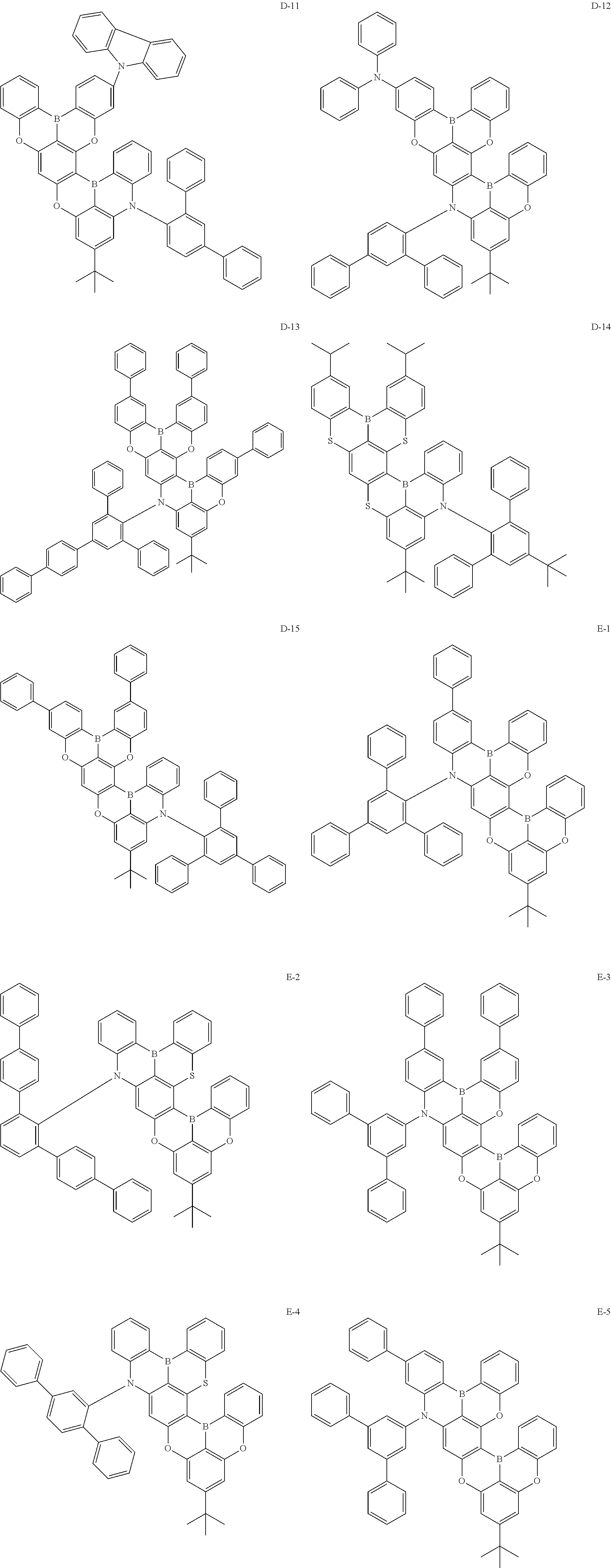

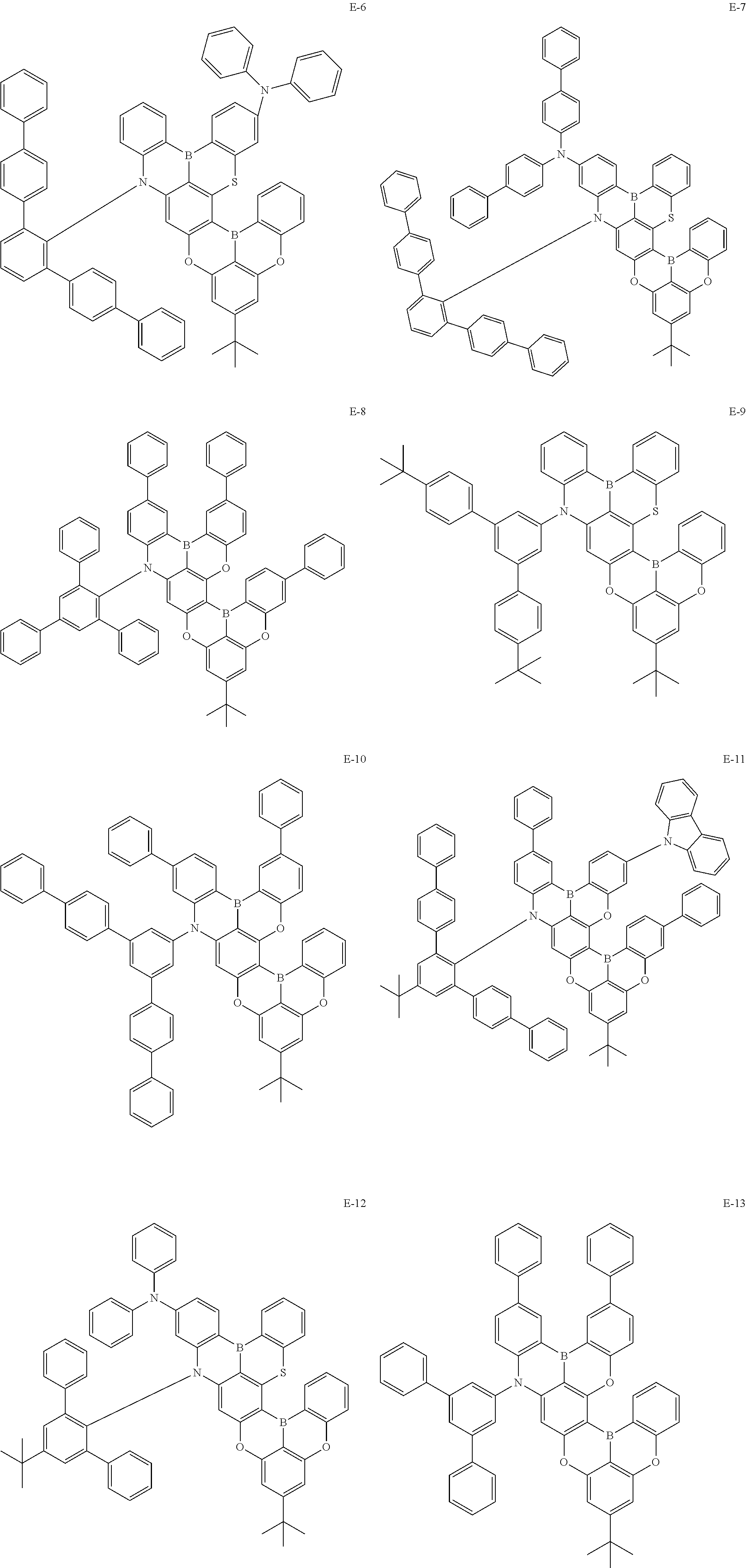

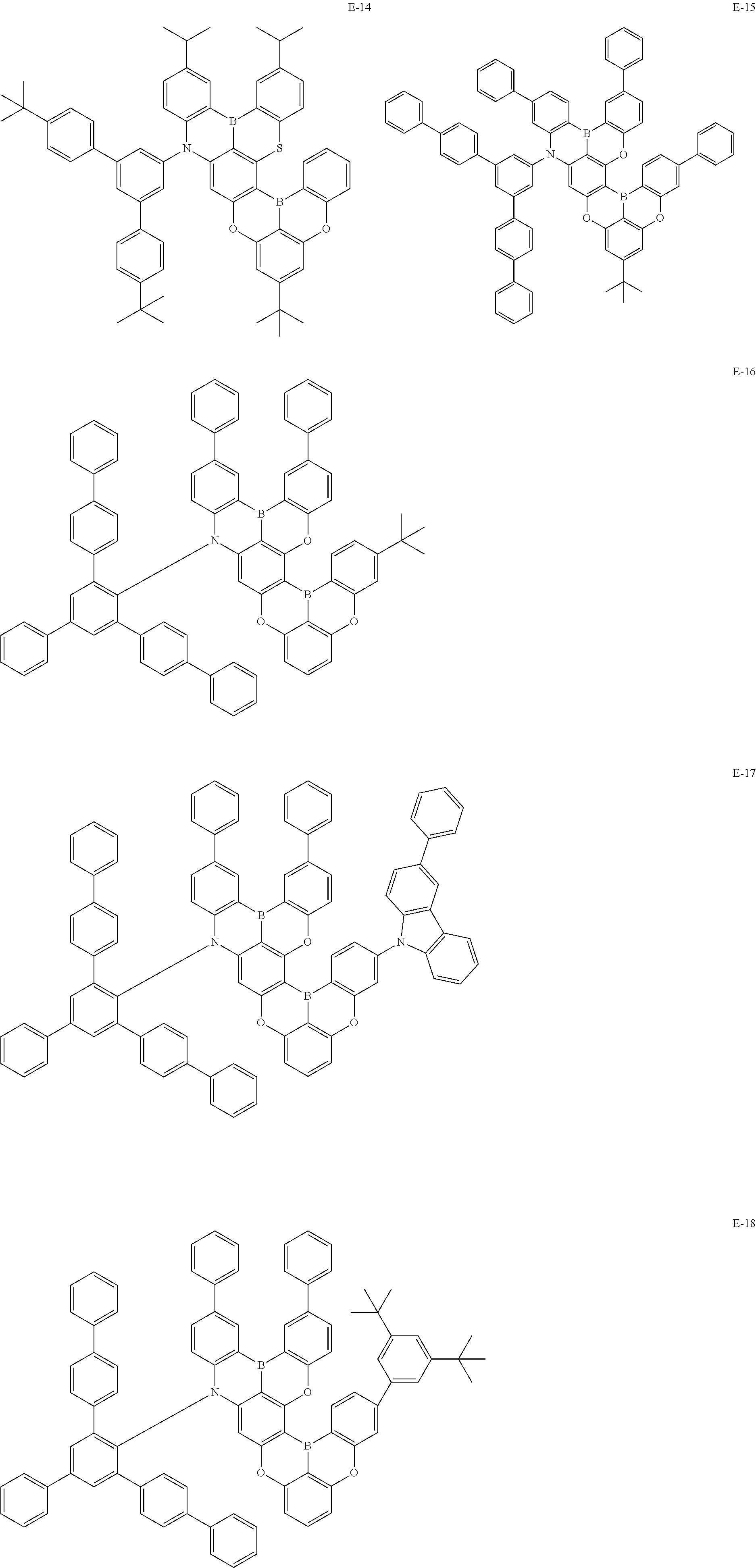

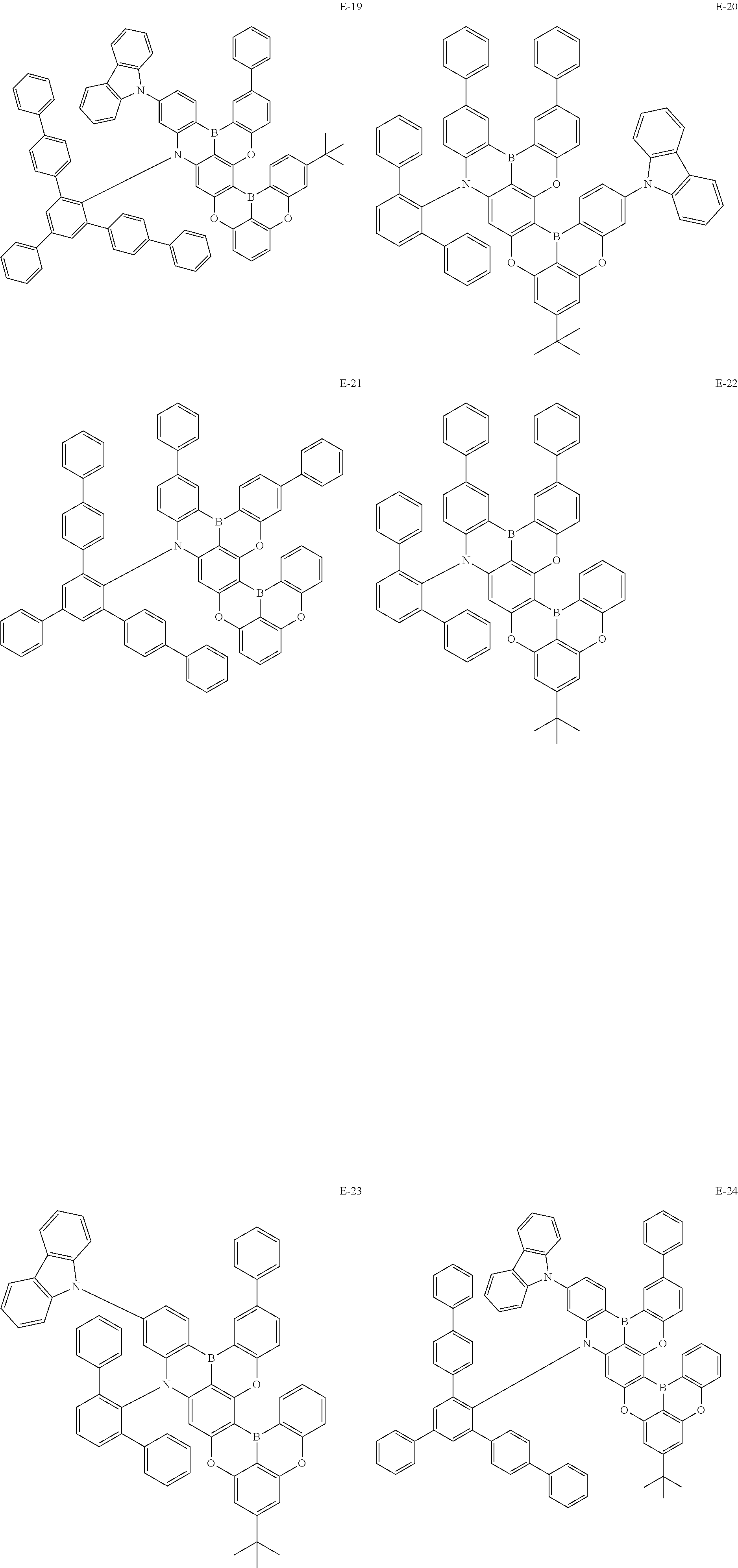

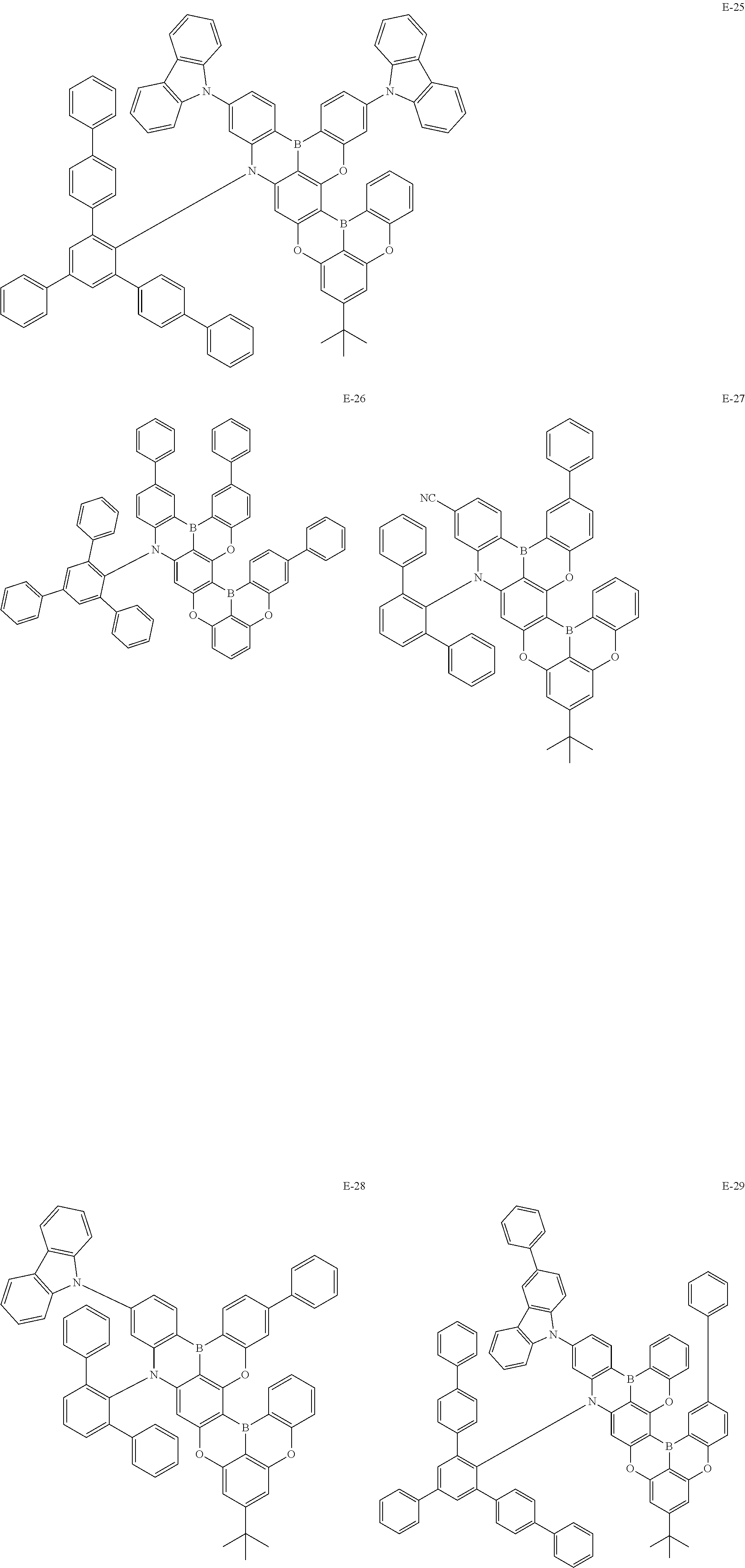

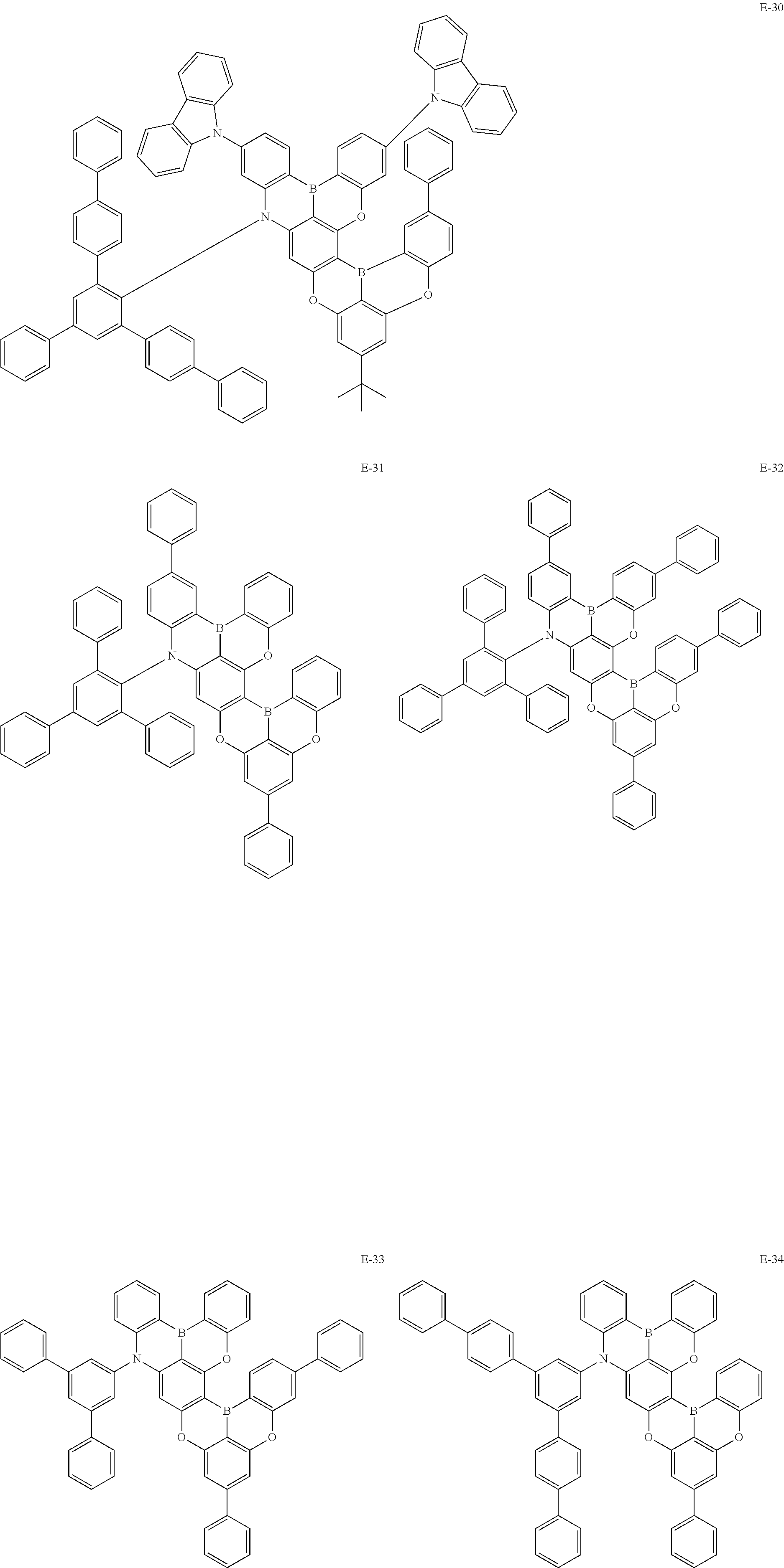

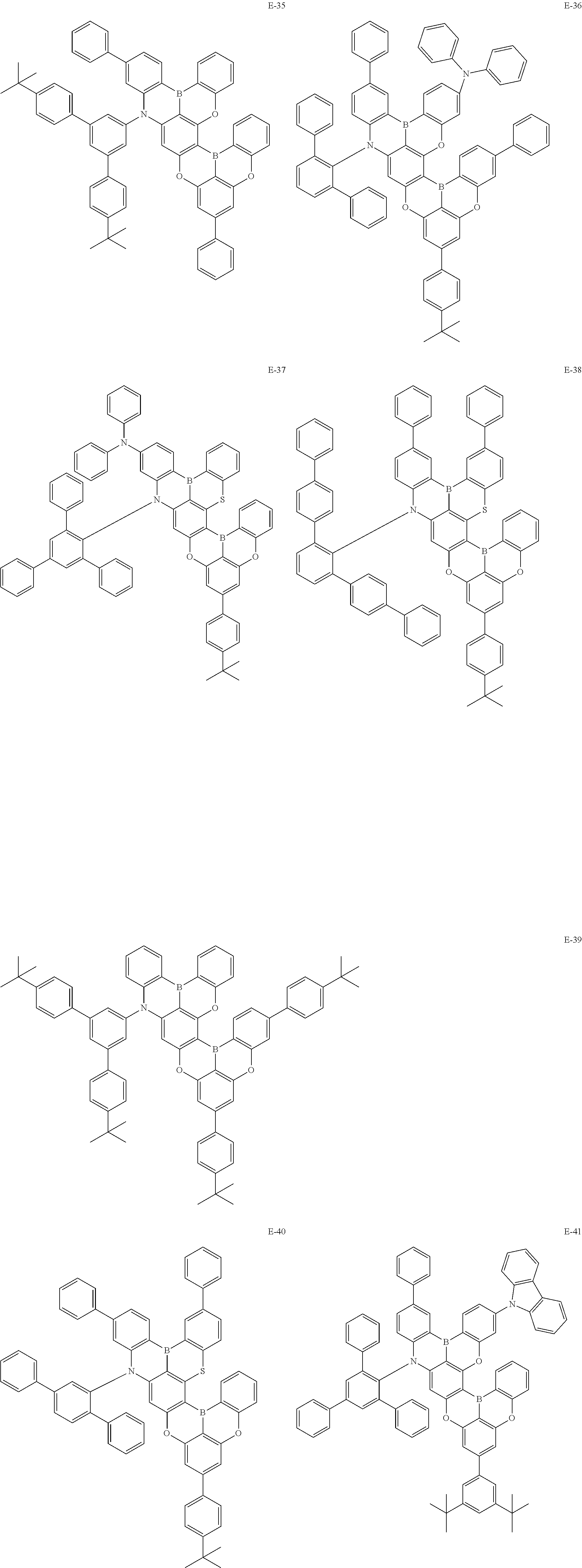

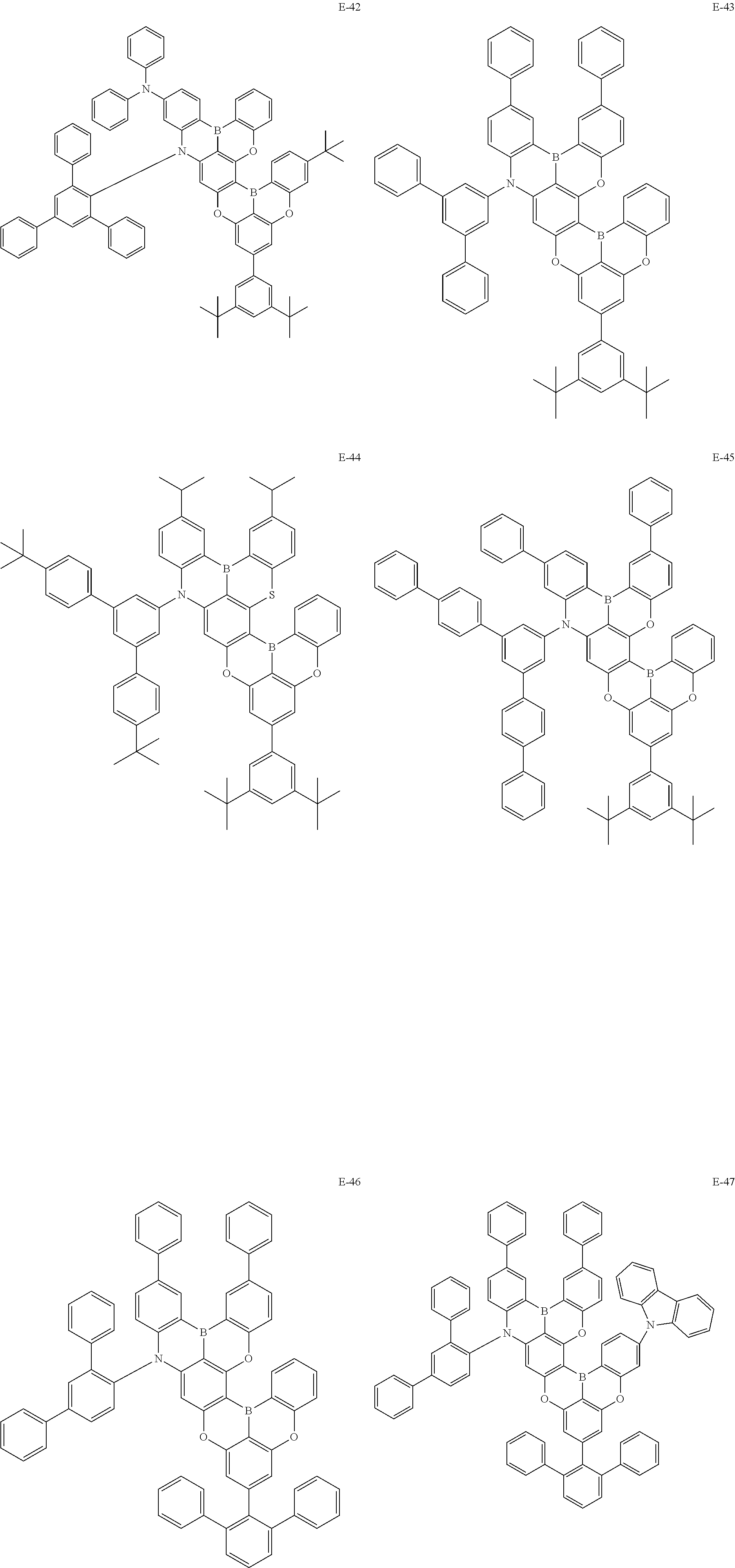

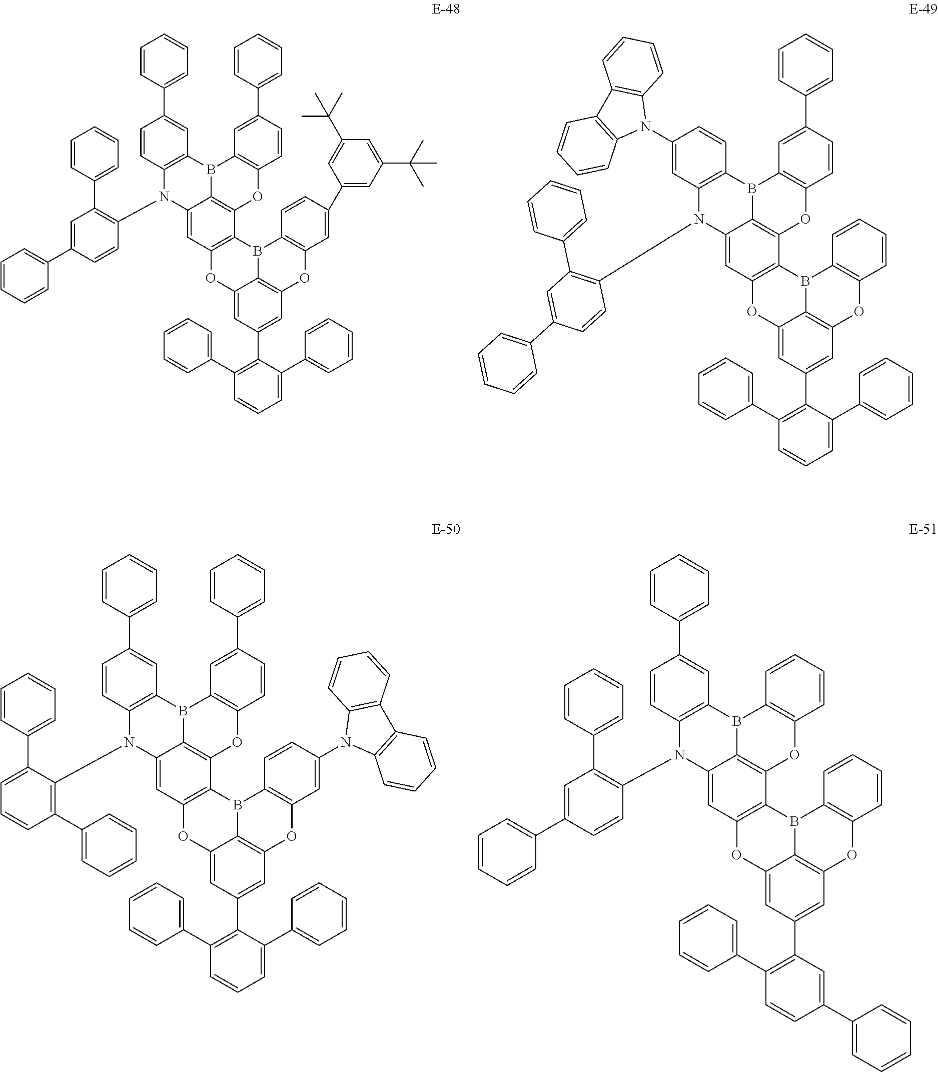

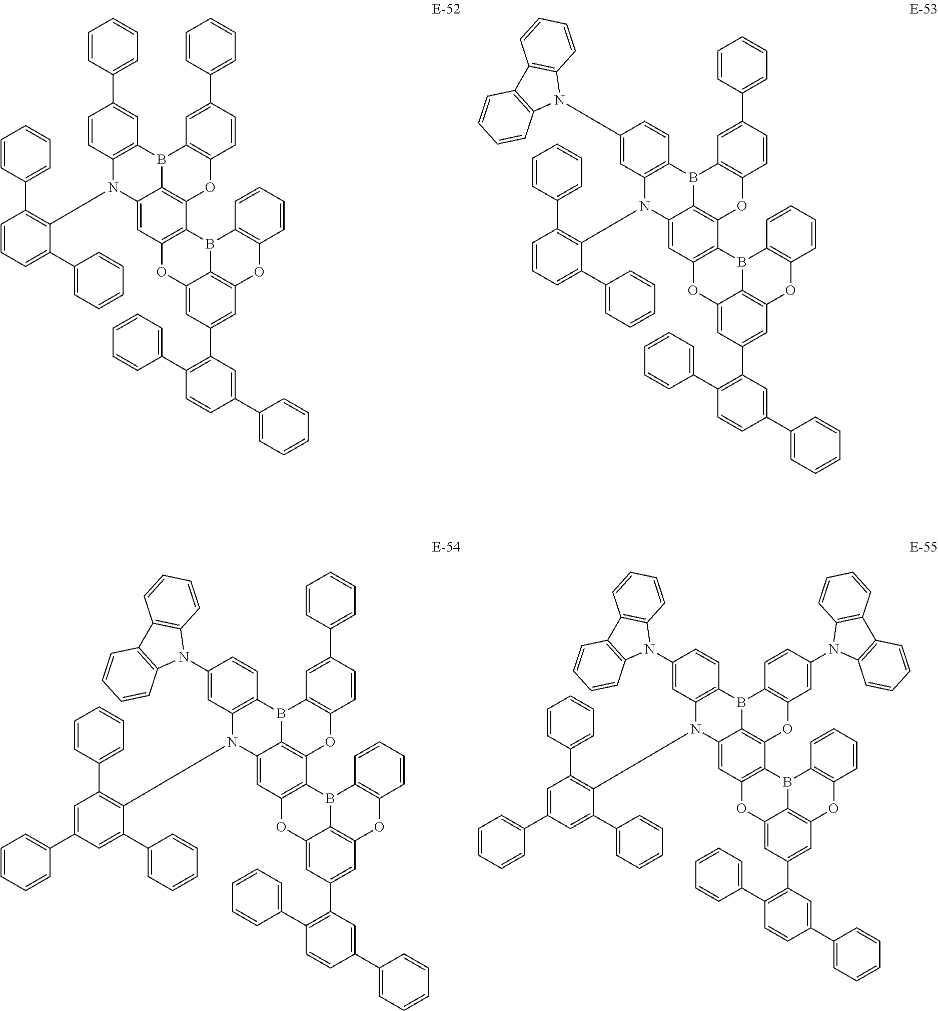

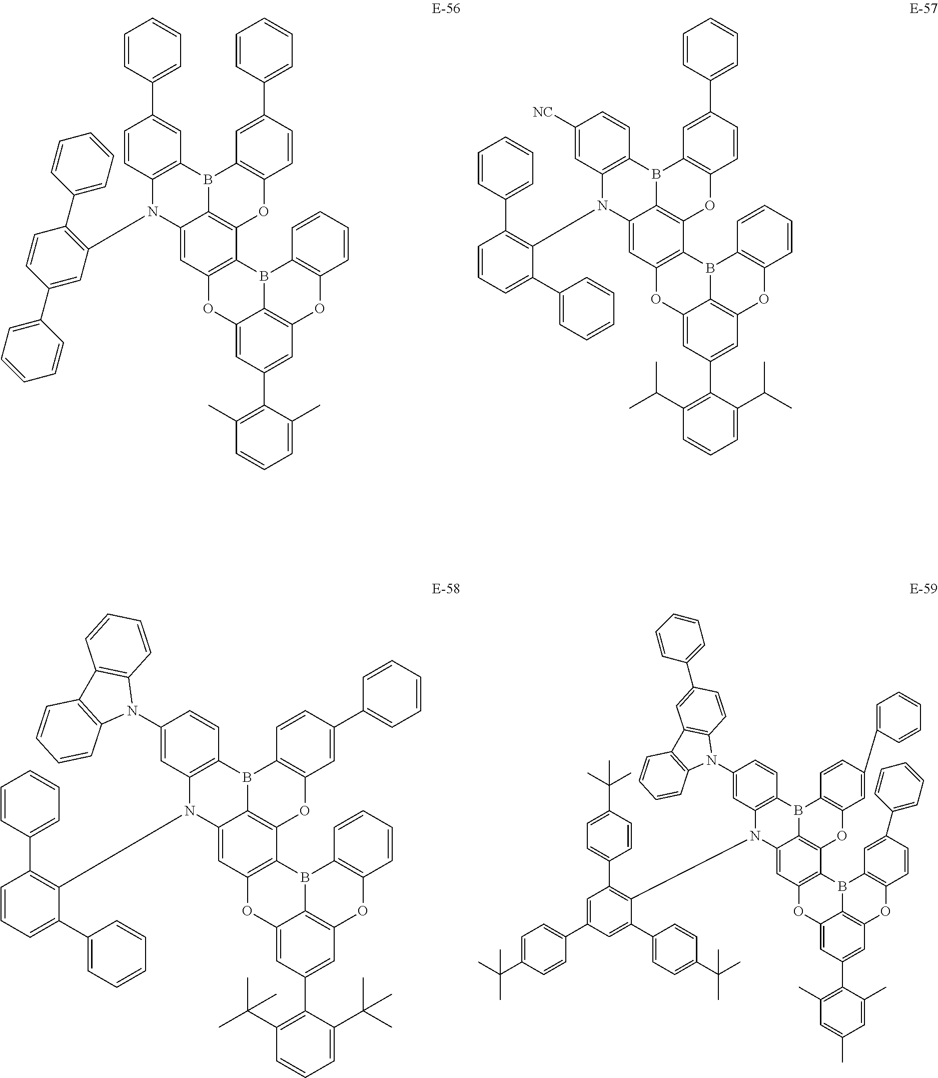

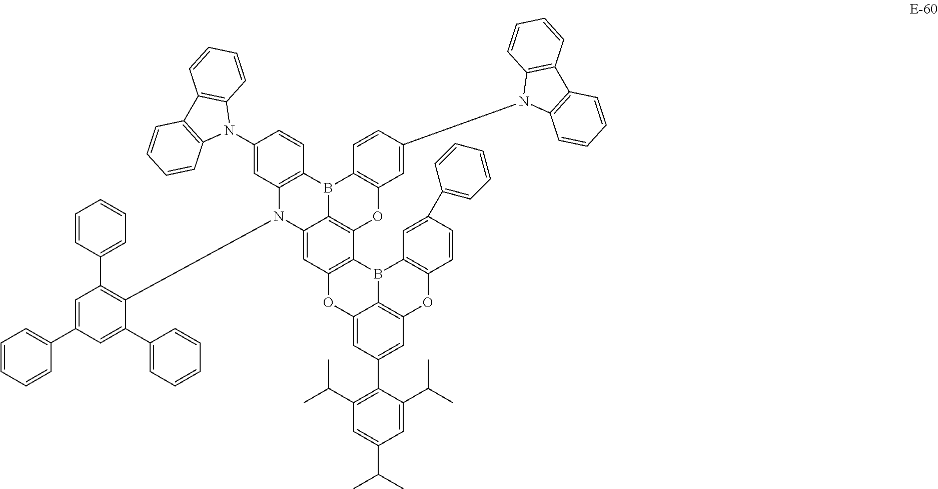 [SMILES: CC(C)c1cc(C(C)C)c(-c2cc3c4c(c2)Oc2cc5c6c(c2B4c2cc(-c4ccccc4)ccc2O3)Oc2cc(-n3c4ccccc4c4ccccc43)ccc2B6c2ccc(-n3c4ccccc4c4ccccc43)cc2N5c2c(-c3ccccc3)cc(-c3ccccc3)cc2-c2ccccc2)c(C(C)C)c1]

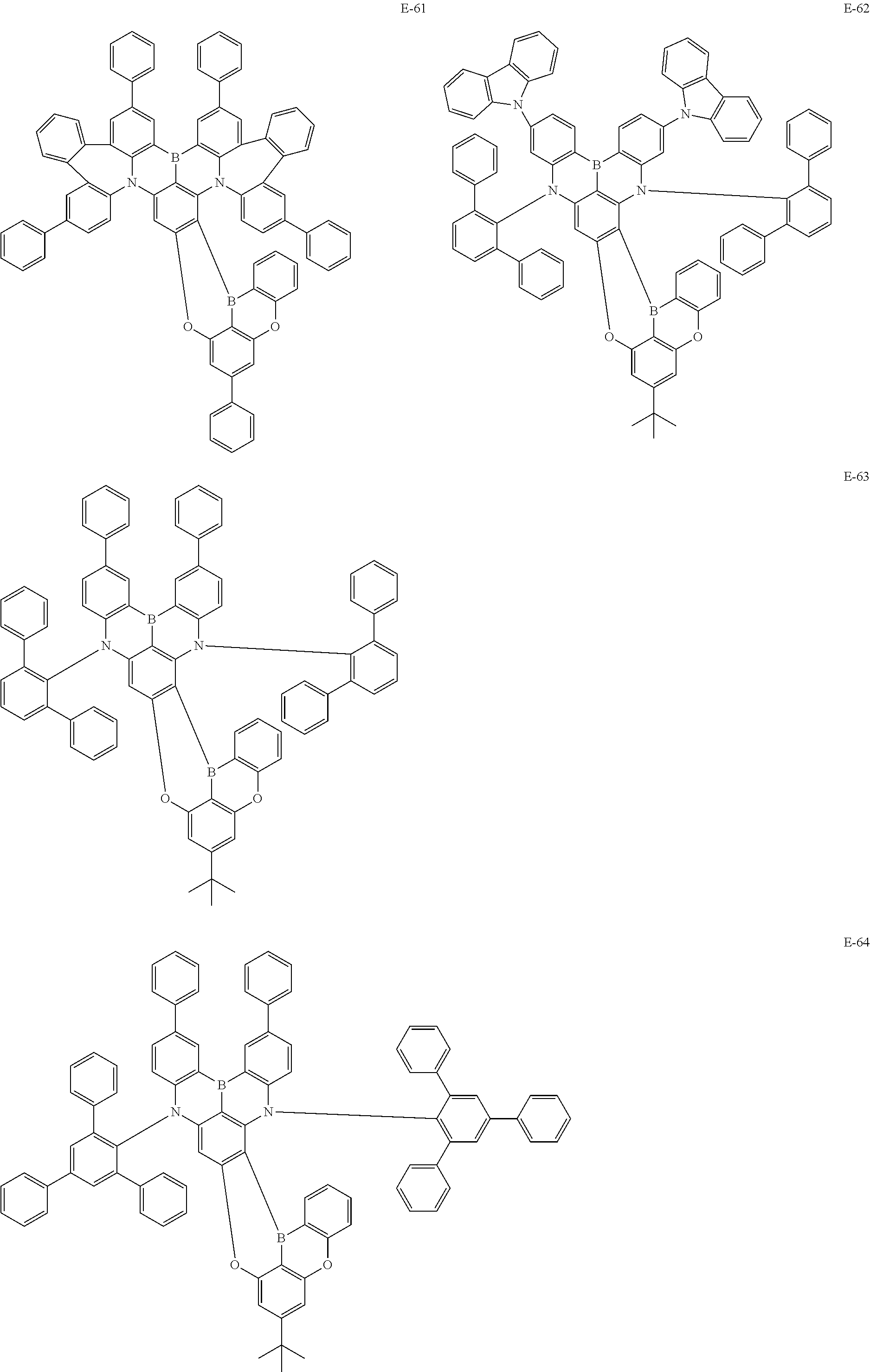

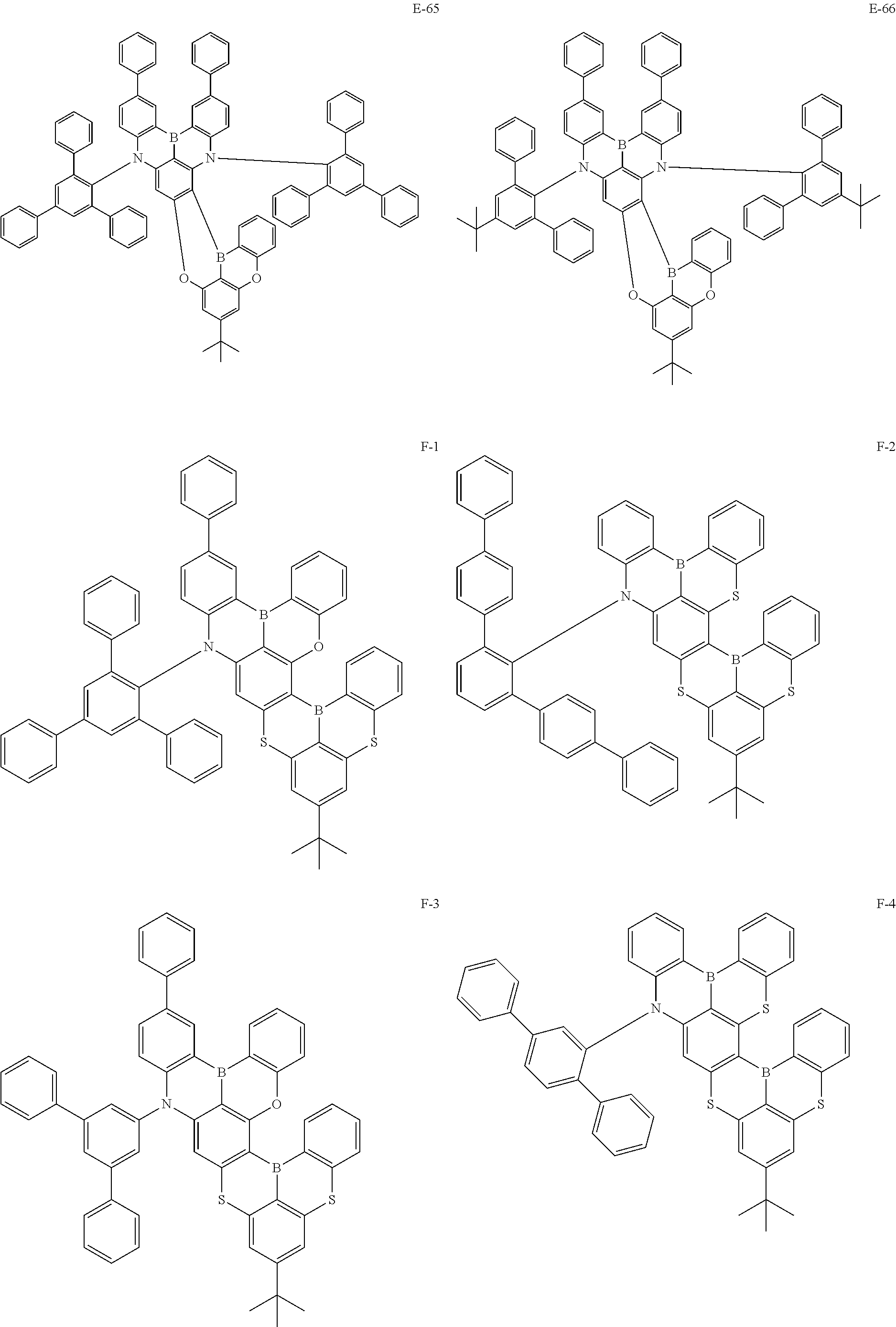

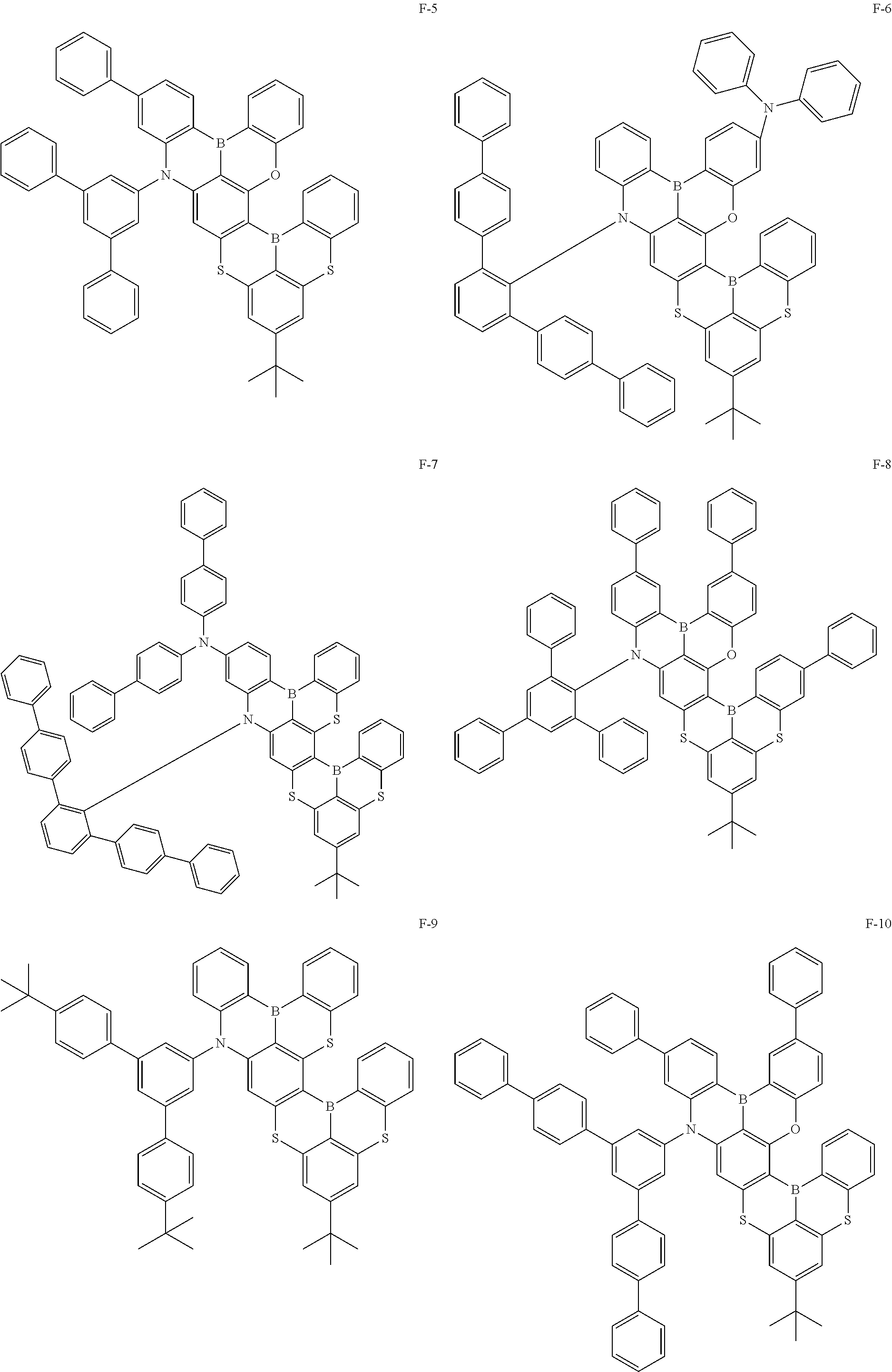

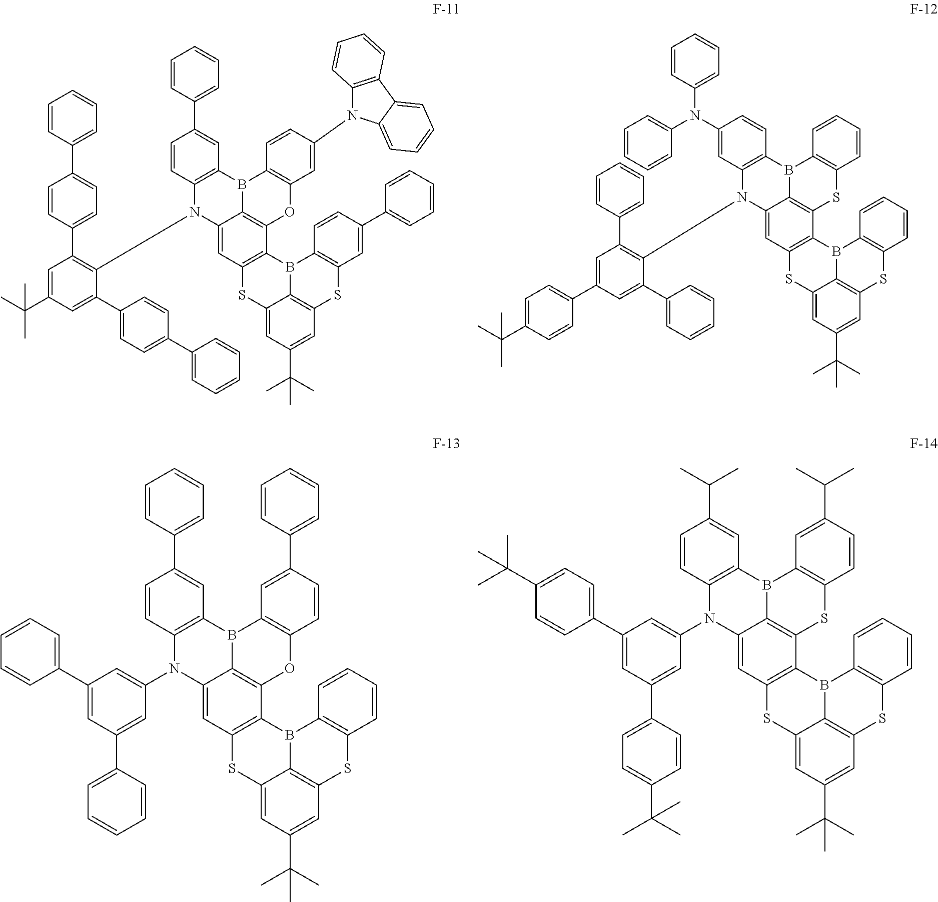

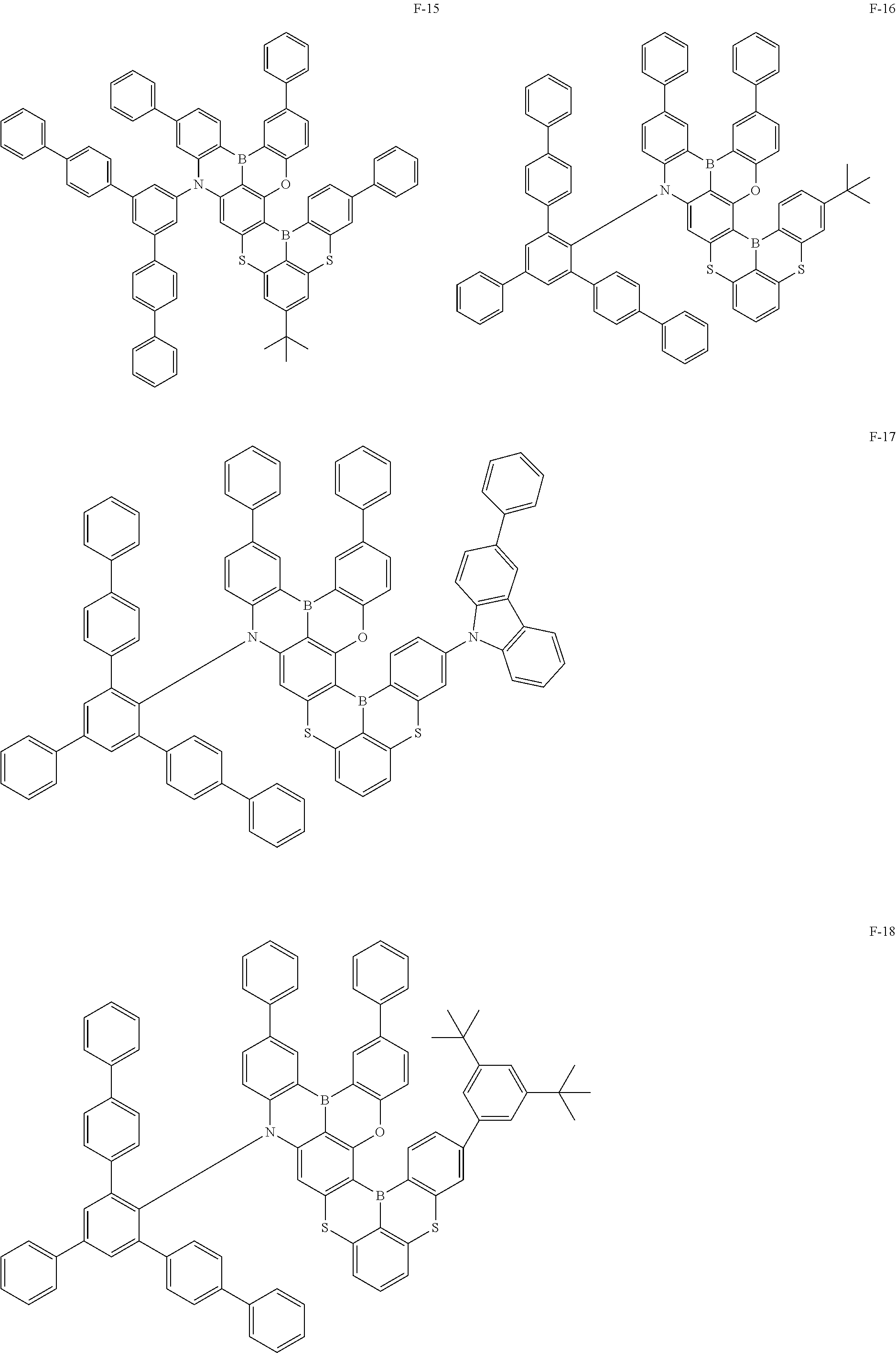

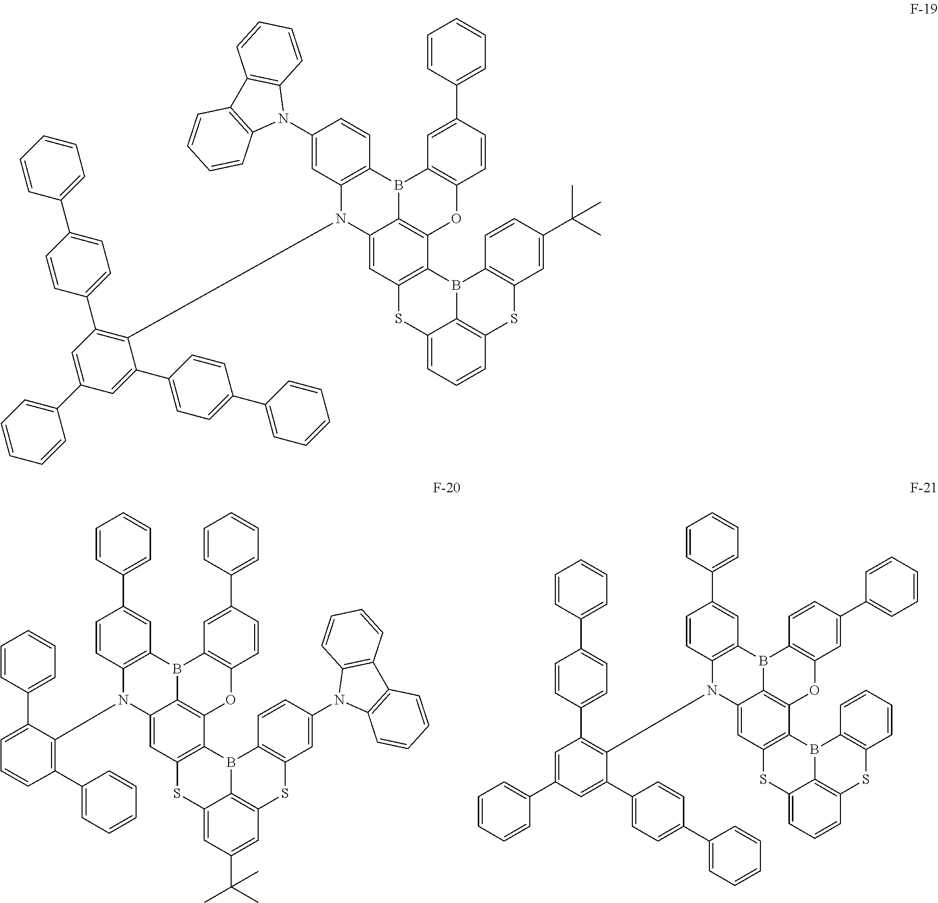 [SMILES: CC(C)(C)c1ccc2c(c1)Sc1cccc3c1B2c1c(cc2c4c1Oc1ccc(-c5ccccc5)cc1B4c1ccc(-n4c5ccccc5c5ccccc54)cc1N2c1c(-c2ccc(-c4ccccc4)cc2)cc(-c2ccccc2)cc1-c1ccc(-c2ccccc2)cc1)S3 ; CC(C)(C)c1cc2c3c(c1)Sc1cc4c5c(c1B3c1ccc(-n3c6ccccc6c6ccccc63)cc1S2)Oc1ccc(-c2ccccc2)cc1B5c1cc(-c2ccccc2)ccc1N4c1c(-c2ccccc2)cccc1-c1ccccc1 ; c1ccc(-c2ccc(-c3cc(-c4ccccc4)cc(-c4ccc(-c5ccccc5)cc4)c3N3c4ccc(-c5ccccc5)cc4B4c5ccc(-c6ccccc6)cc5Oc5c6c(cc3c54)Sc3cccc4c3B6c3ccccc3S4)cc2)cc1]

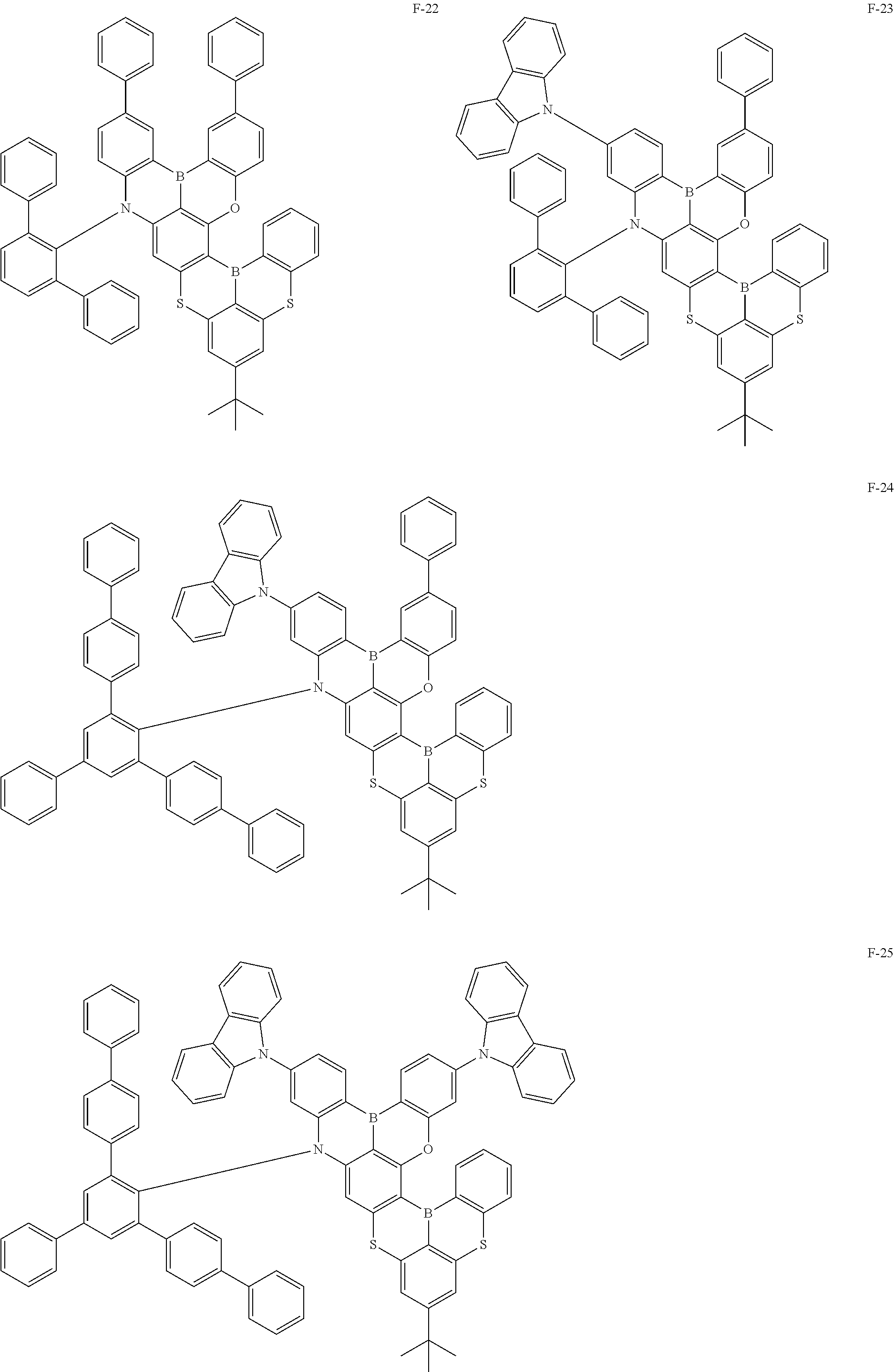

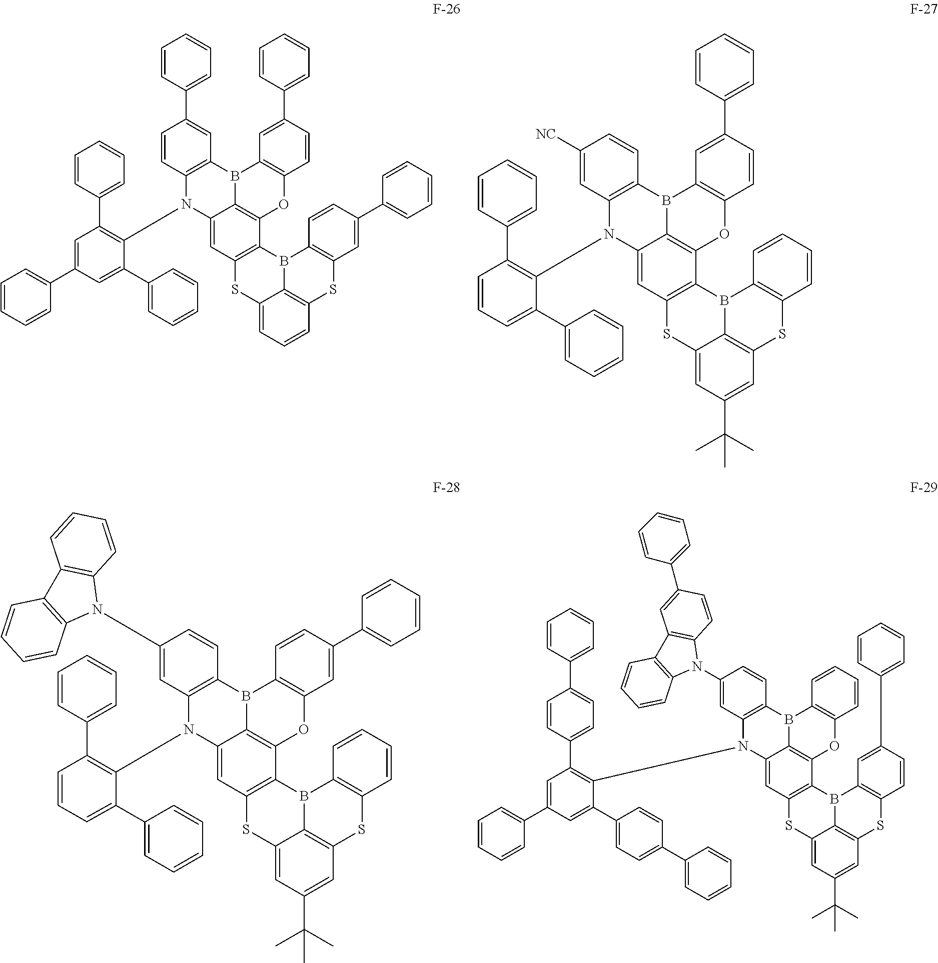

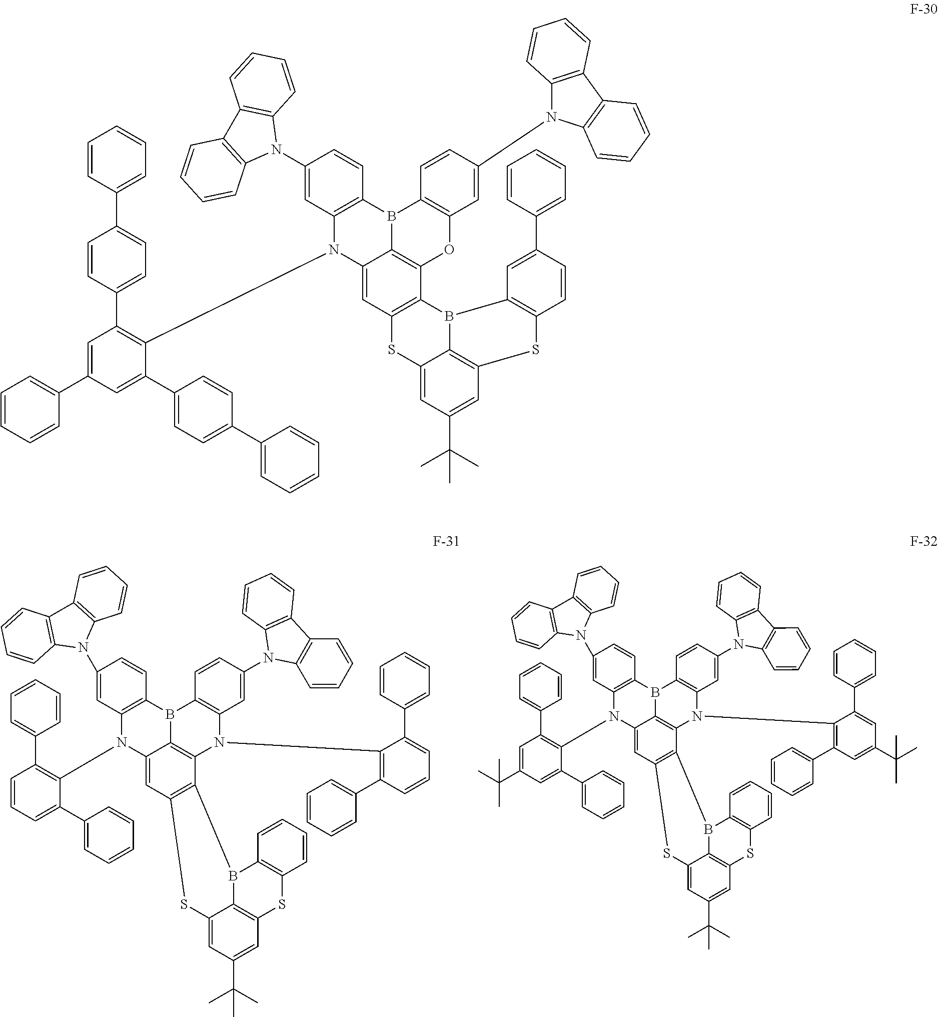

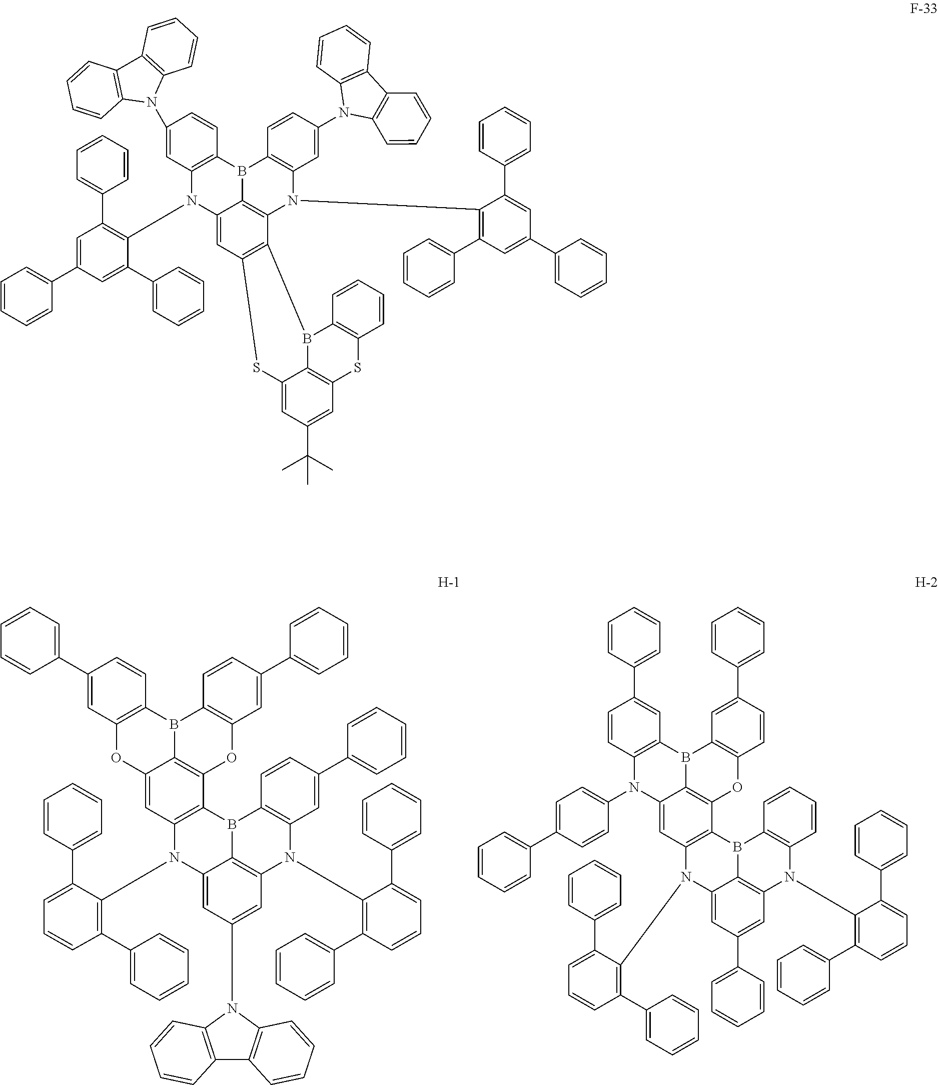

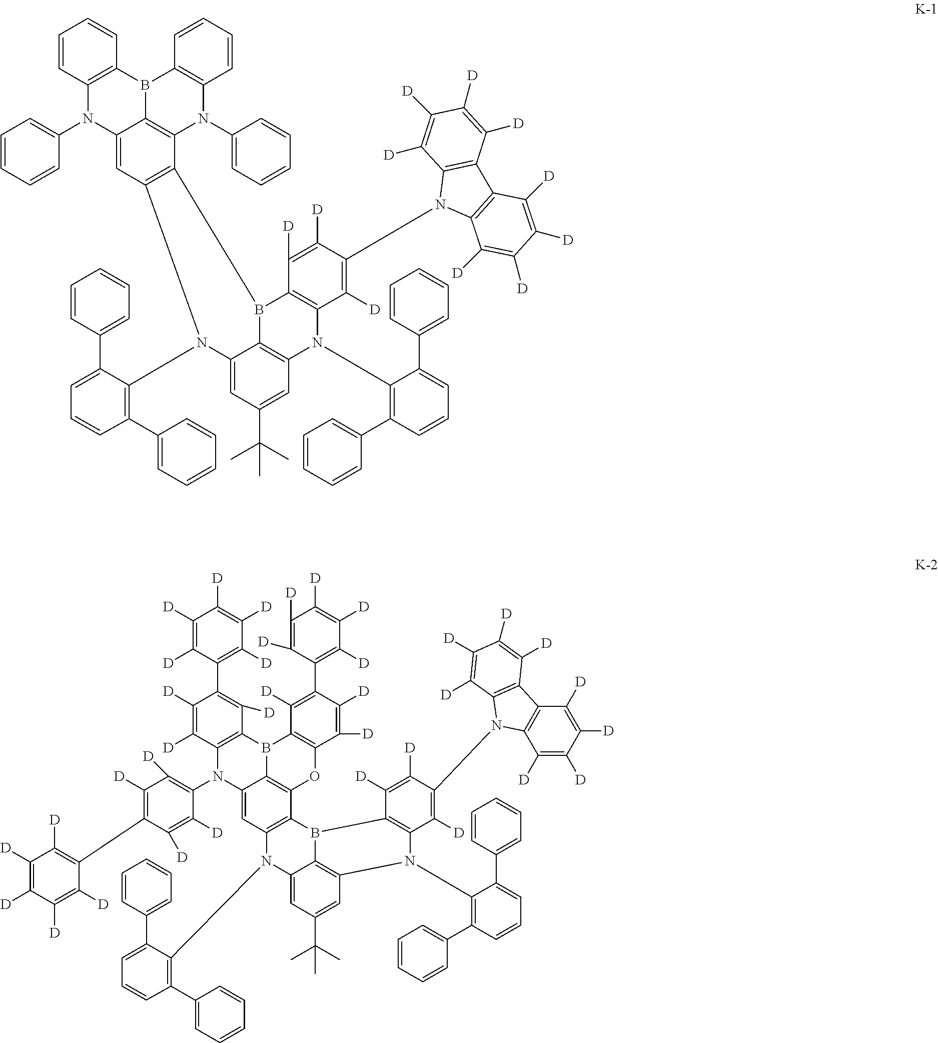

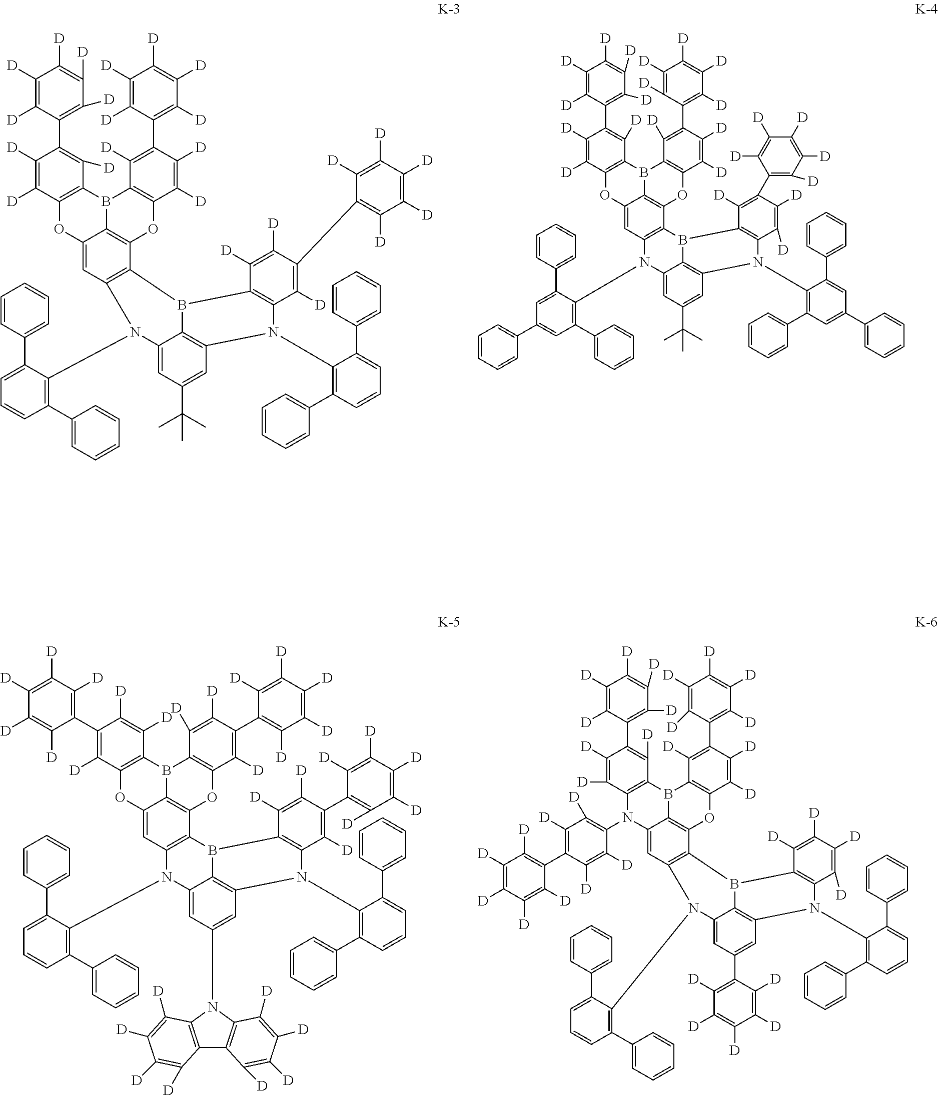

In the light-emitting element ED according to one or more embodiments, the emission layer EML may be a delayed fluorescent emission layer including a host and a dopant. For example, the emission layer EML may emit thermally activated delayed fluorescence (TADF). The polycyclic compound according to one or more embodiments may be a delayed fluorescent dopant. For example, the polycyclic compound according to one or more embodiments may be a thermally activated

delayed fluorescent dopant. The emission layer EML may include the polycyclic compound according to one or more embodiments as a dopant. The polycyclic compound according to one or more embodiments may emit blue light. For example, the polycyclic compound according to one or more embodiments may be a light-emitting material having a light-emitting peak wavelength in a wavelength region of about 430 nm to about 490 nm.

For example, the polycyclic compound according to one or more embodiments may be a light-emitting material having a light-emitting peak wavelength in a wavelength region of about 450 nm to about 470 nm.

In one or more embodiments, the emission layer EML may include the polycyclic compound according to one or more embodiments and may further include at least one selected from among the second to fourth compounds. In one or more embodiments, the emission layer EML may include the second compound represented by Formula HT-1. For example, the second compound may be utilized as a hole transporting host material of the emission layer EML.

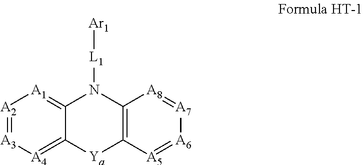

In Formula HT-1, A₁ to A₈ may each independently be N or CR₅₁. For example, all of A₁ to A₈ may be CR₅₁. In one or more embodiments, any one selected from among A₁ to A₈ may be N, and the rest may be CR₅₁.

In Formula HT-1, L₁ may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. For example, L₁ may be a direct linkage (e.g., a single covalent bond), a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage (e.g., a single covalent bond), CR₅₂R₅₃, or SiR₅₄R₅₅. For example, it may refer to that the two benzene rings linked to the nitrogen atom in Formula HT-1 are linked via a direct linkage (e.g., a single covalent bond),

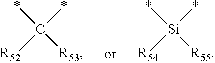

In Formula HT-1, if (e.g., when) Yₐ is a direct linkage (e.g., a single covalent bond), the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

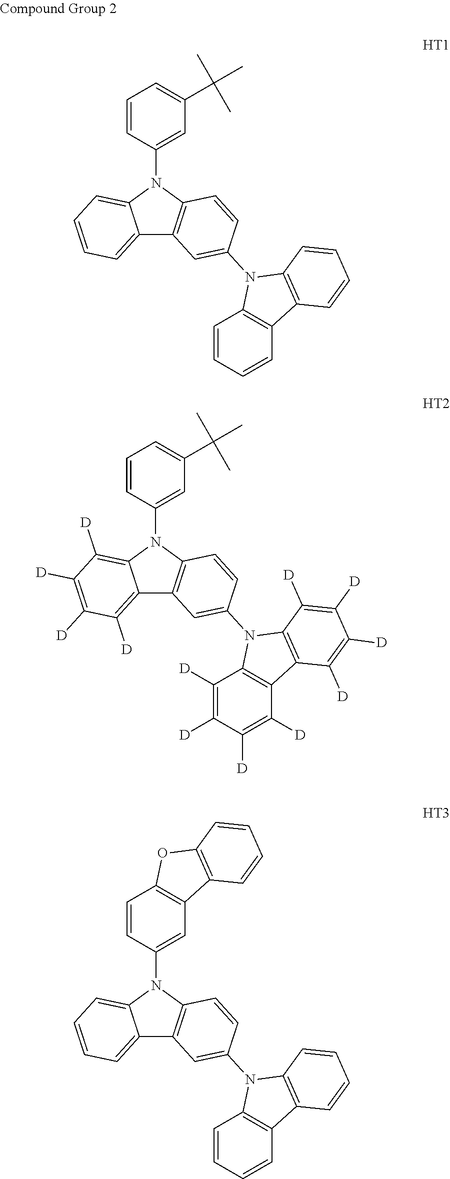 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

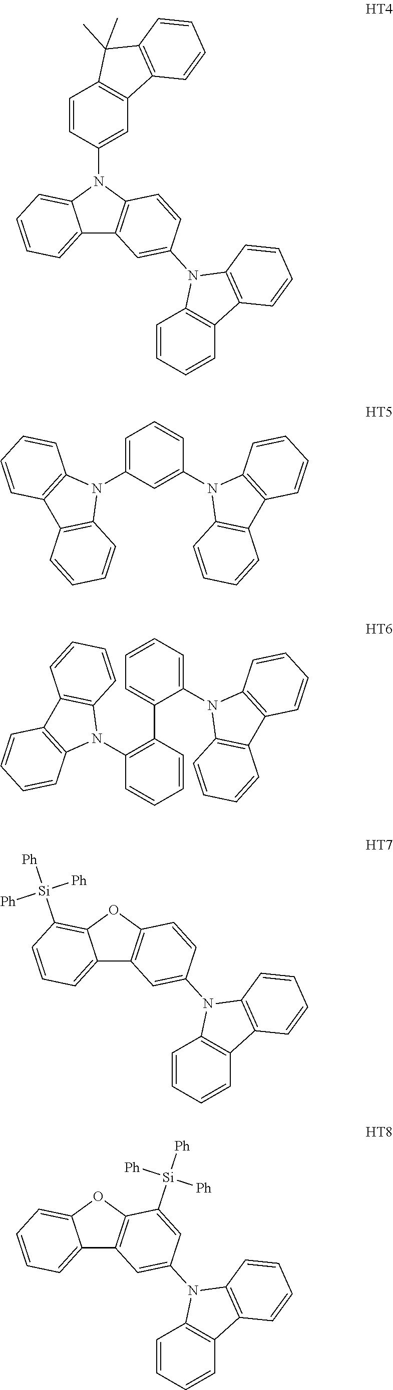 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

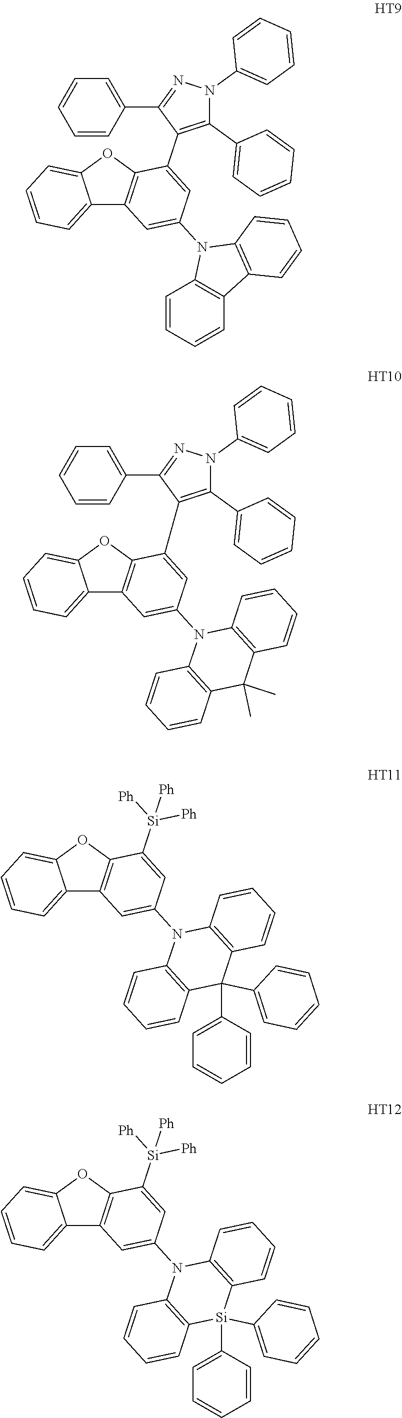 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

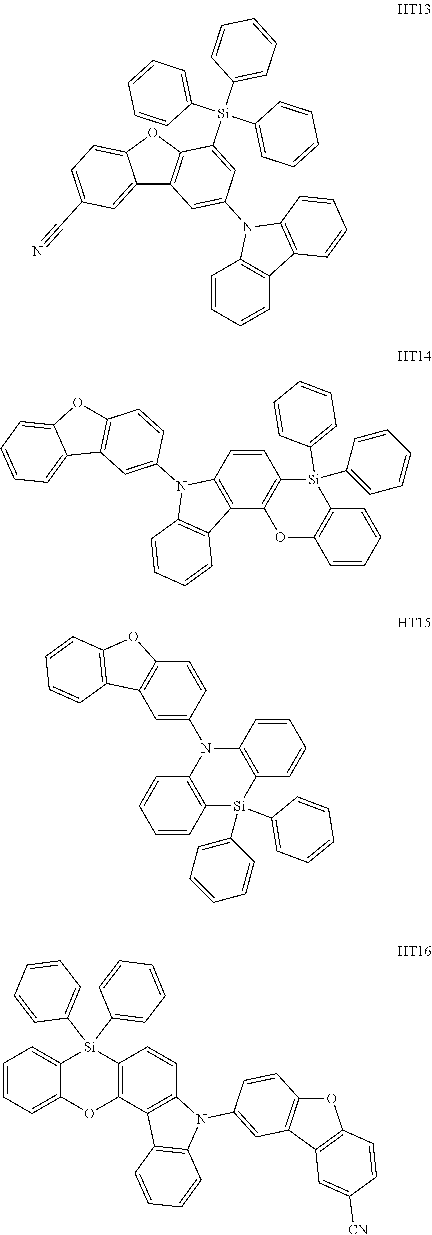 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

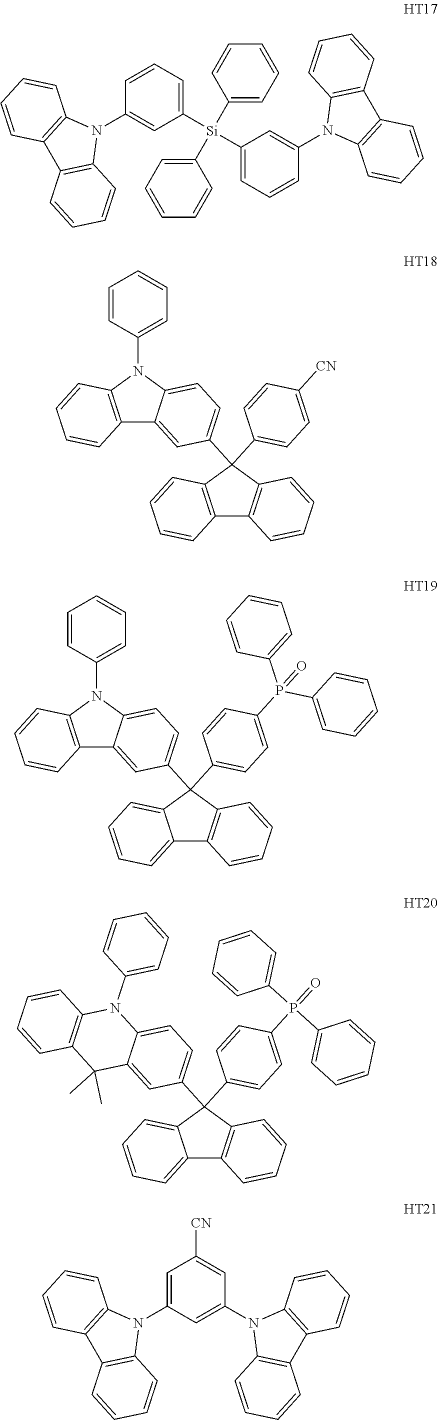 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

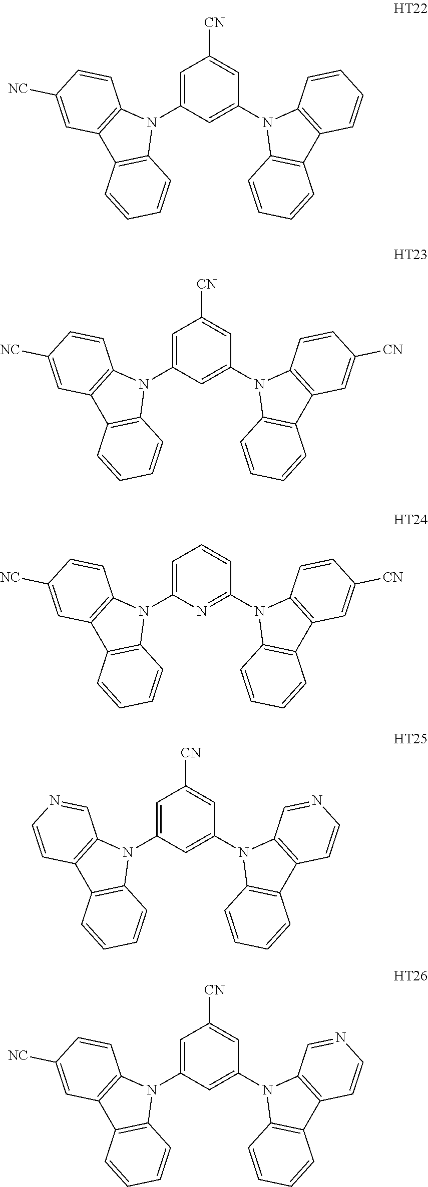 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

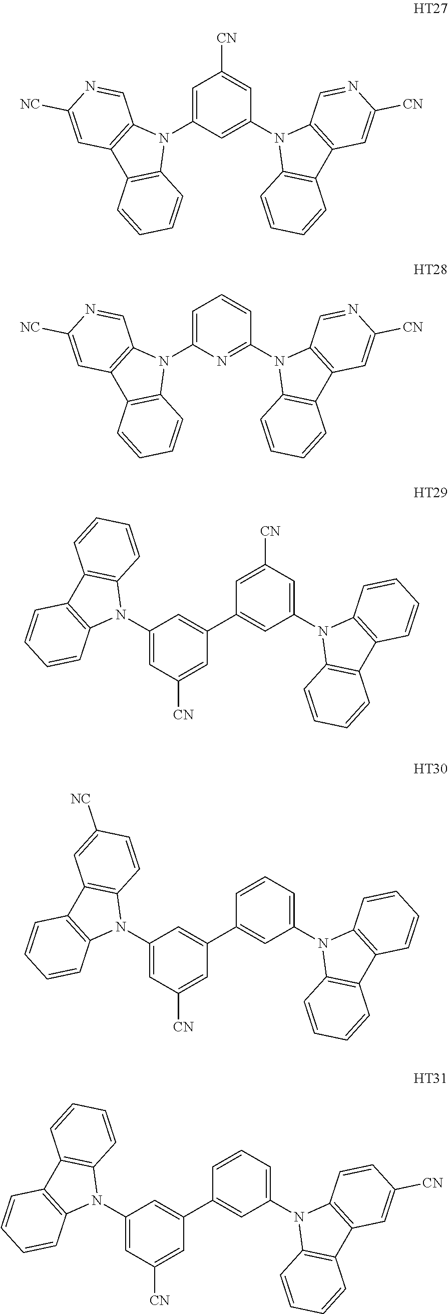 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

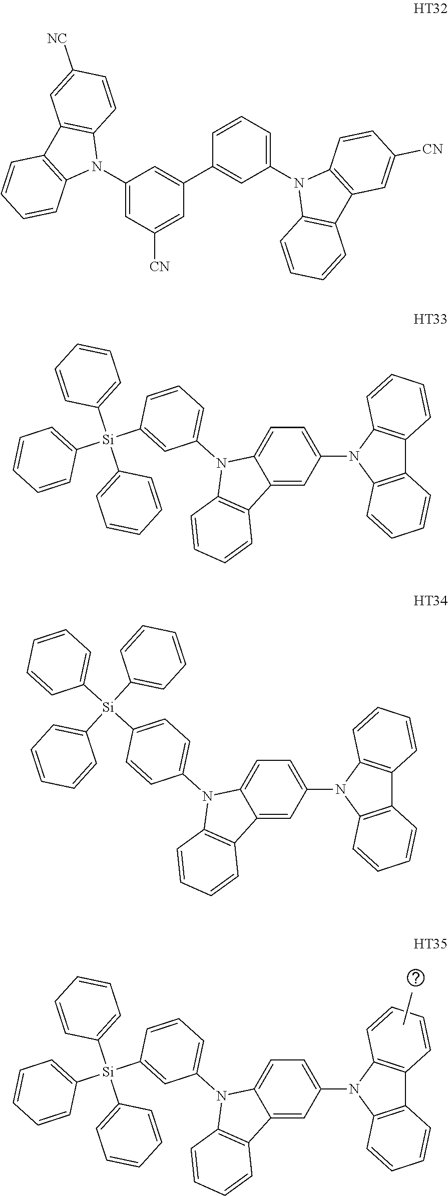

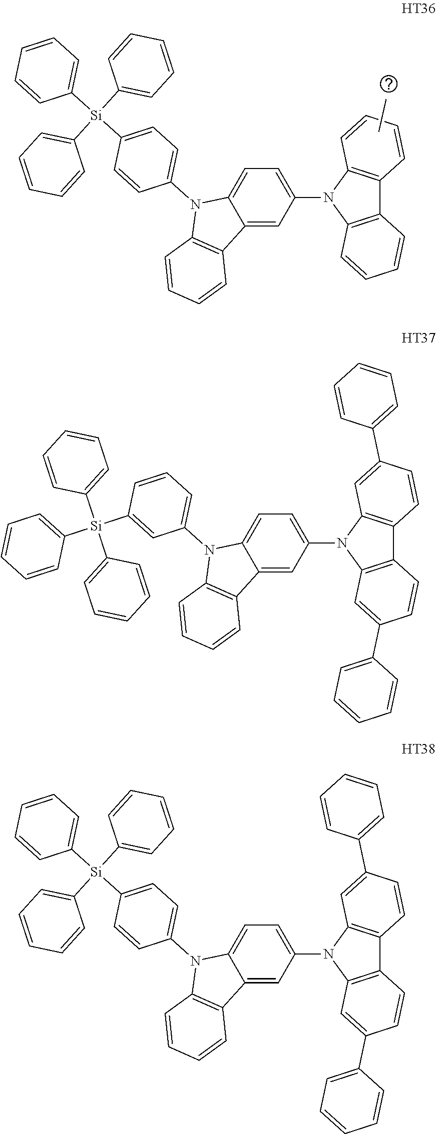

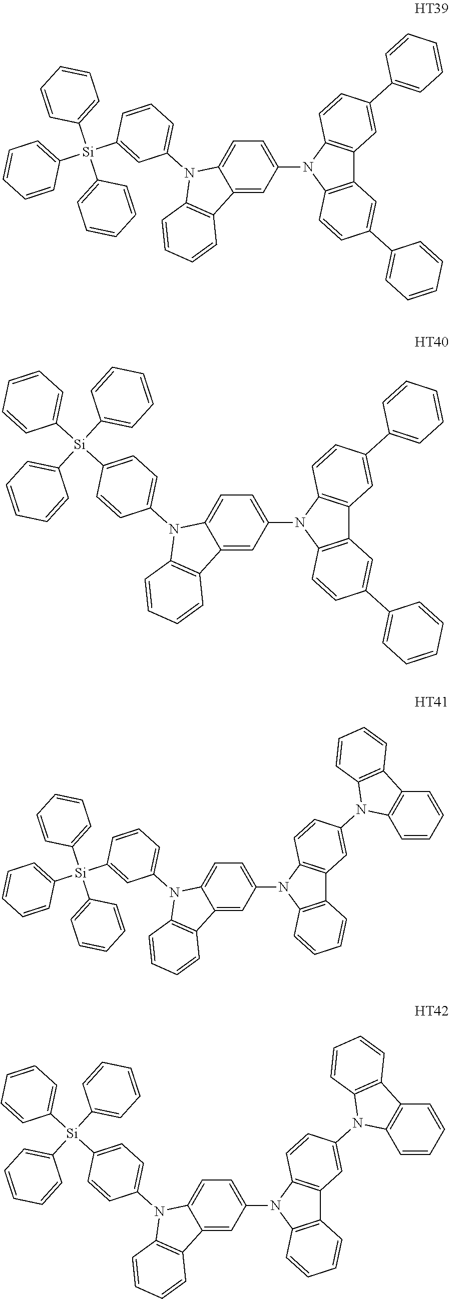 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

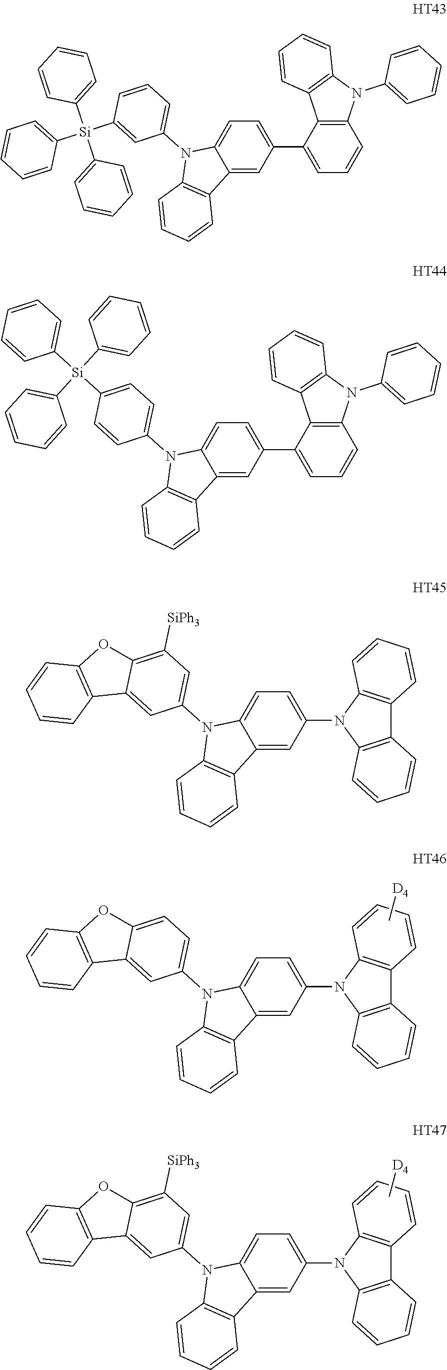

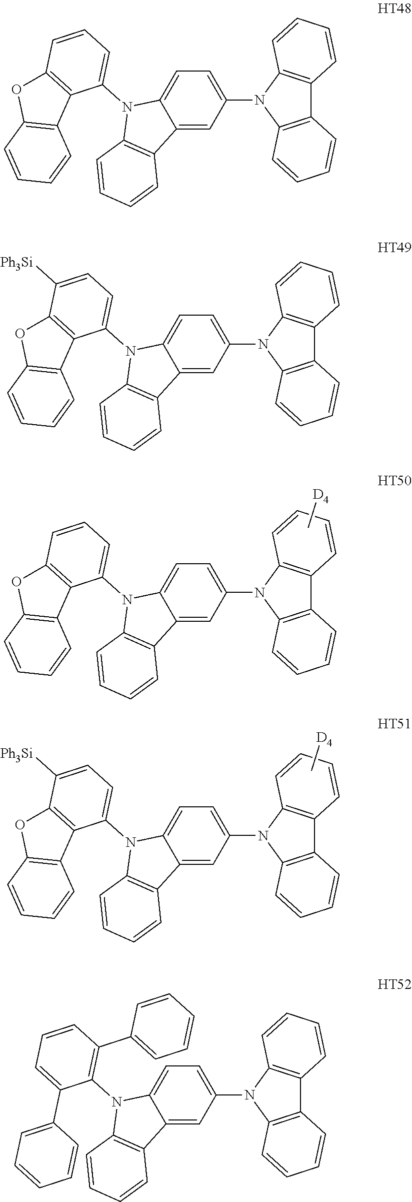

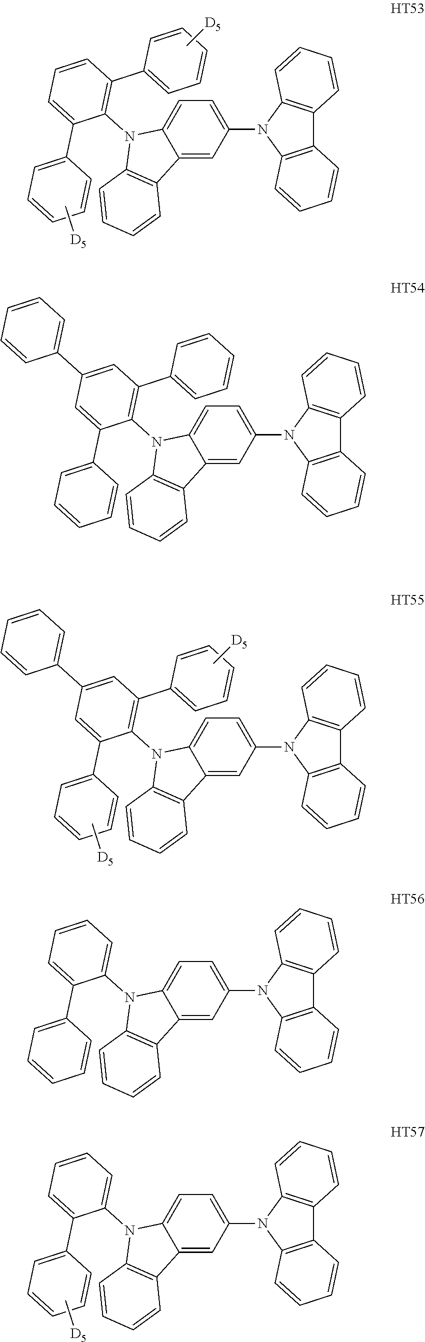

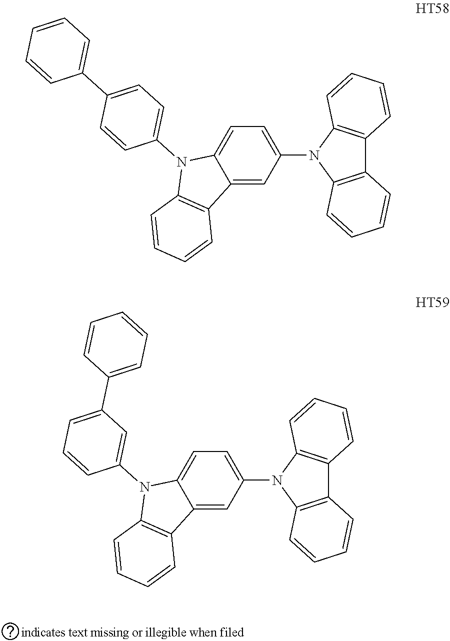 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the compounds presented in Compound Group 2, “D” may refer to a deuterium atom, and “Ph” may refer to a substituted or unsubstituted phenyl group. For example, in the compounds presented in Compound Group 2, “Ph” may refer to an unsubstituted phenyl group.

In one or more embodiments, the emission layer EML may include the third compound represented by Formula ET-1. For example, the third compound may be utilized as an electron transport host material for the emission layer EML.

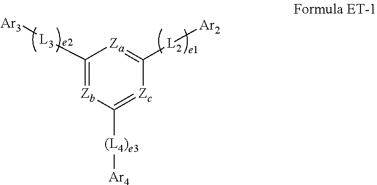

In Formula ET-1, at least one selected from among Zₐ to Z_{c} may be N, and the rest may be CR₅₆. For example, any one selected from among Zₐ to Z_{c} may be N, and the rest may each independently be CR₅₆. In this case, the third compound represented by Formula ET-1 may include a pyridine moiety. In one or more embodiments, two selected from among Zₐ to Z_{c} may be N, and the rest may be CR₅₆. In this case, the third compound represented by Formula ET-1 may include a pyrimidine moiety. In one or more embodiments, Zₐ to Z_{c} may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, e1 to e3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) e1 to e3 are integers of 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be represented by any one selected from among the compounds in Compound Group 3. The light-emitting element ED of one or more embodiments may include any one selected from among the compounds in Compound Group 3.

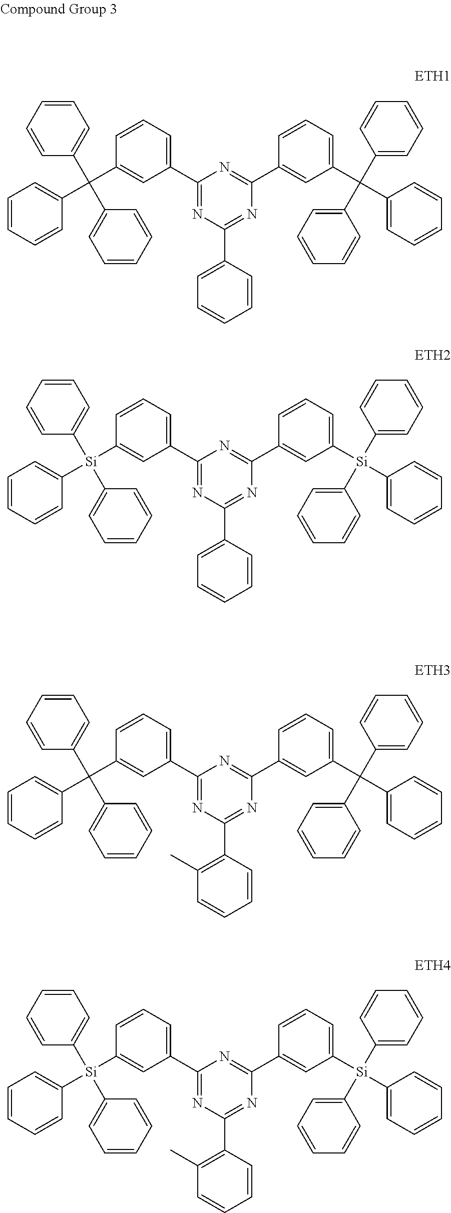 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

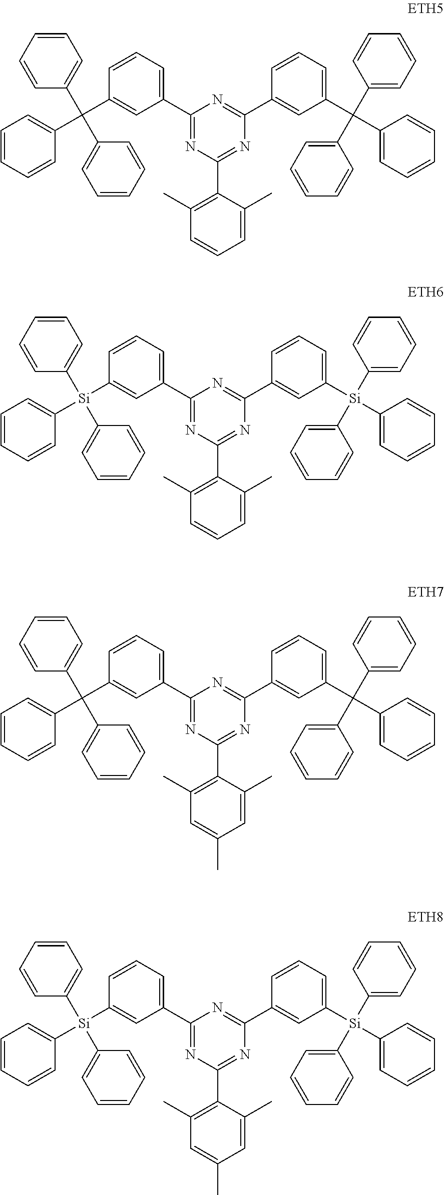 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

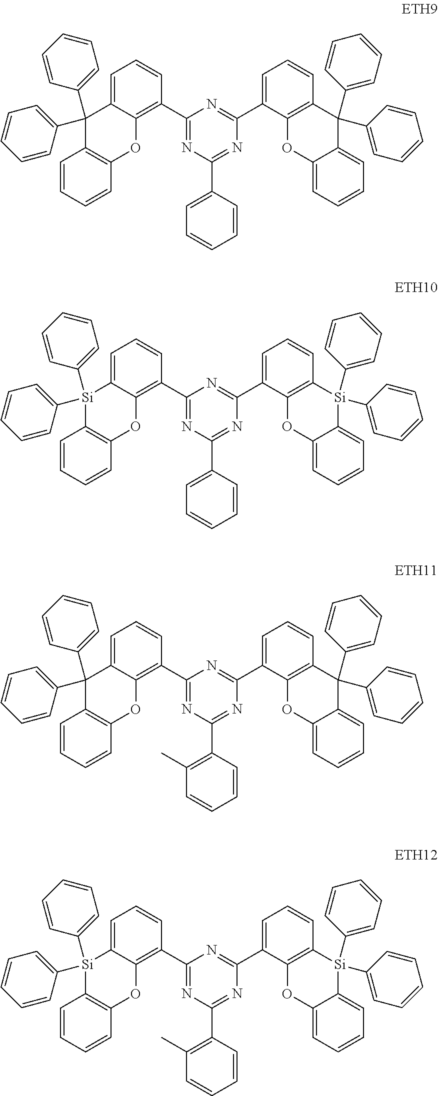 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

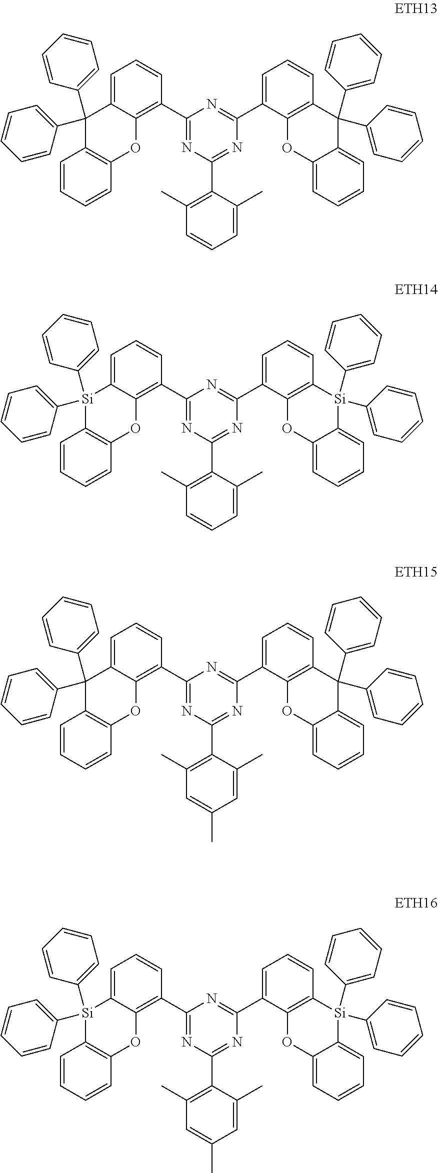 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

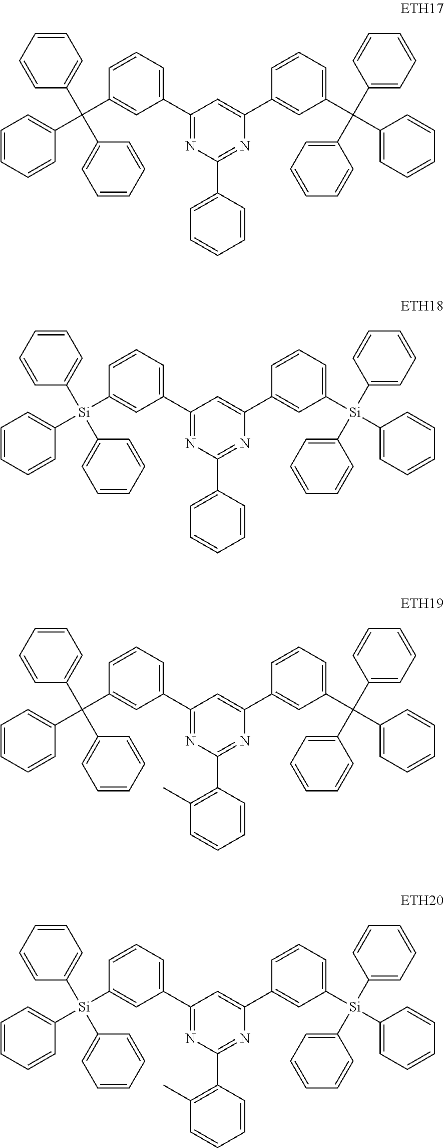 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

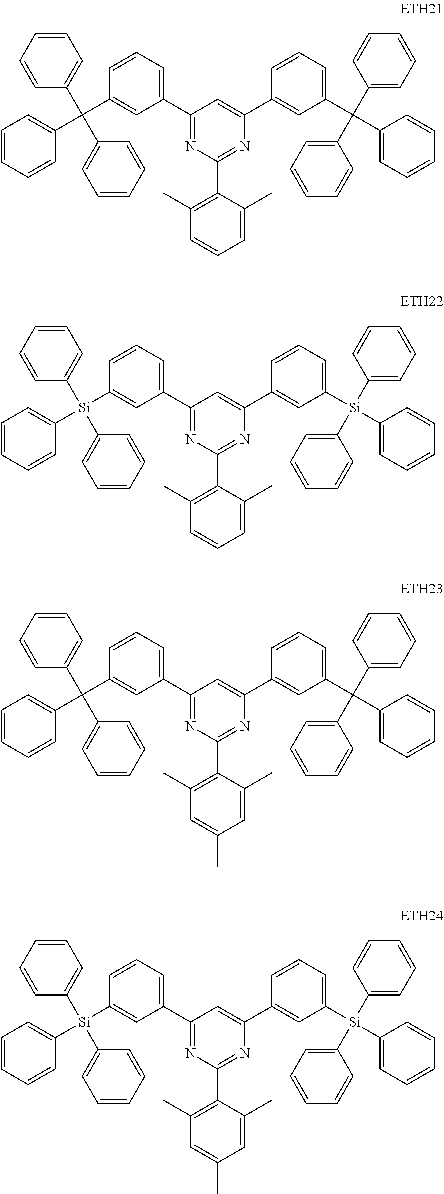 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

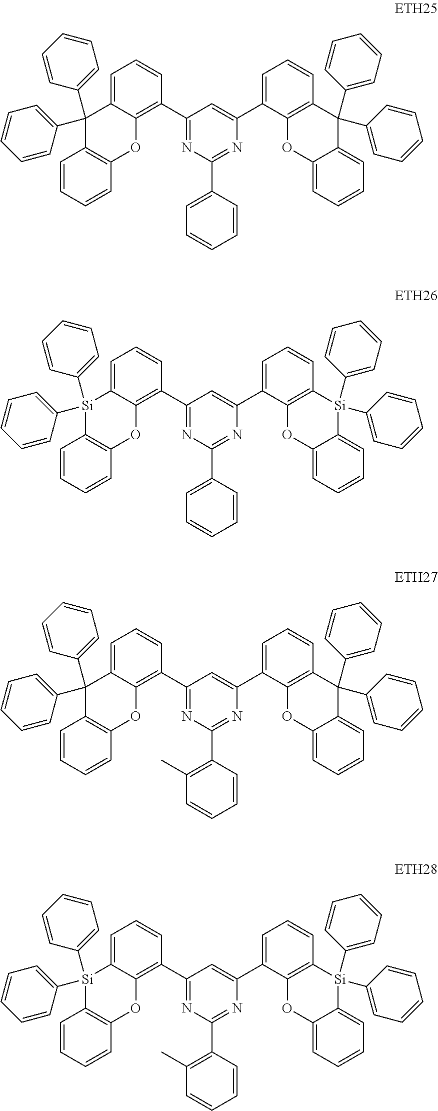 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

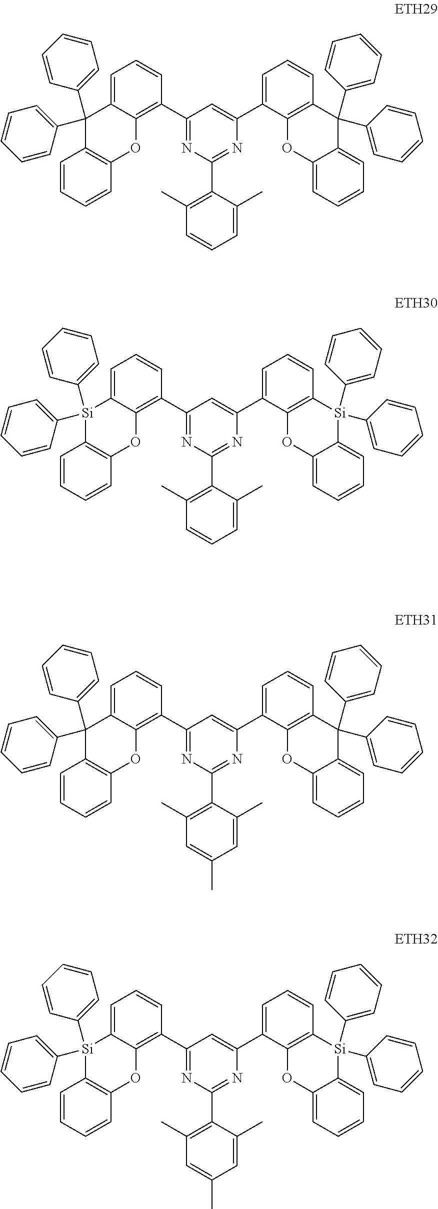 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

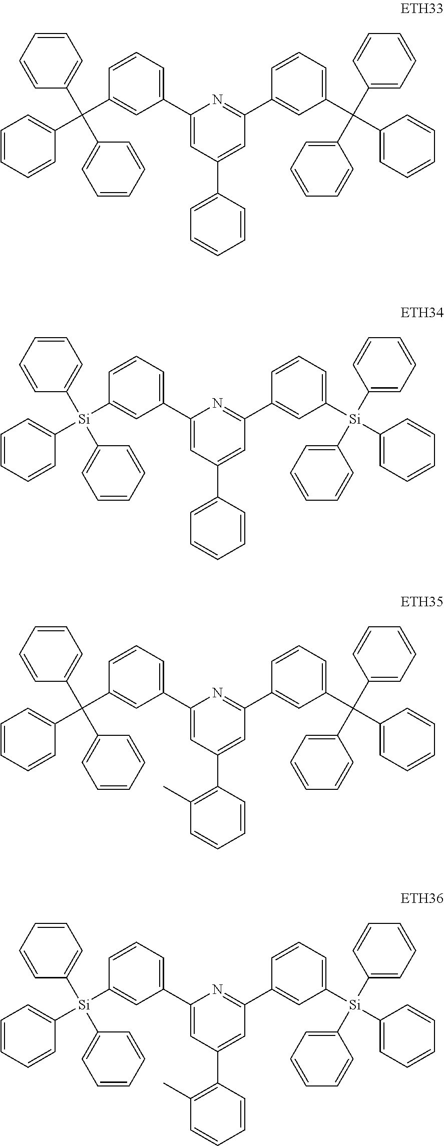 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

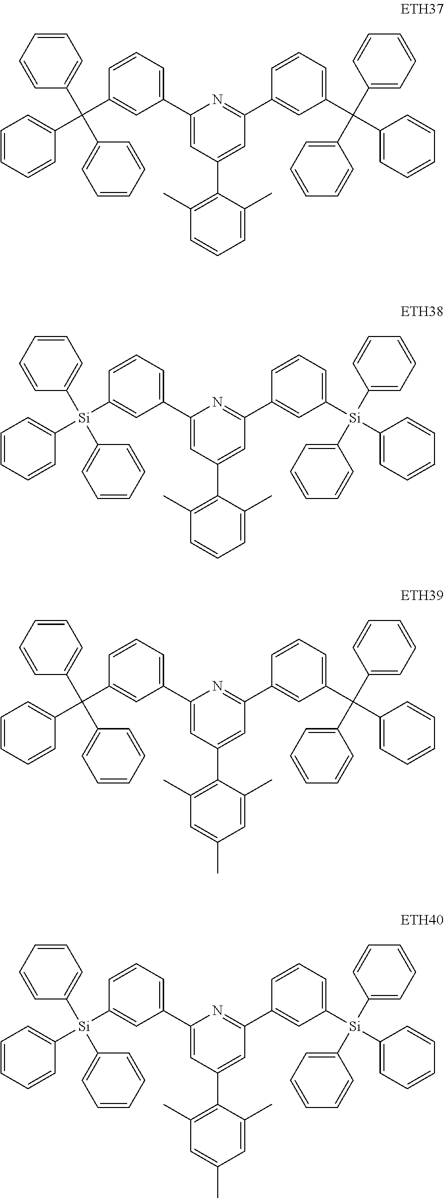 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

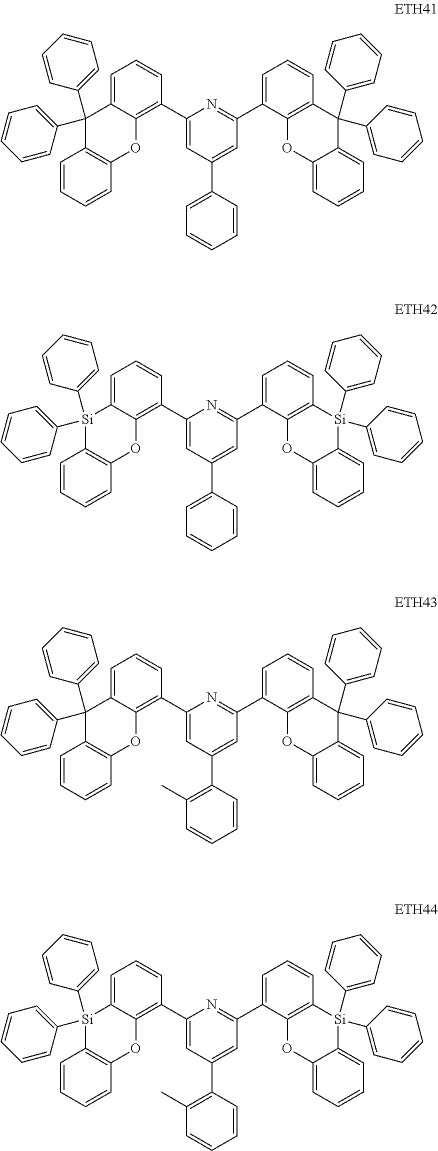 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

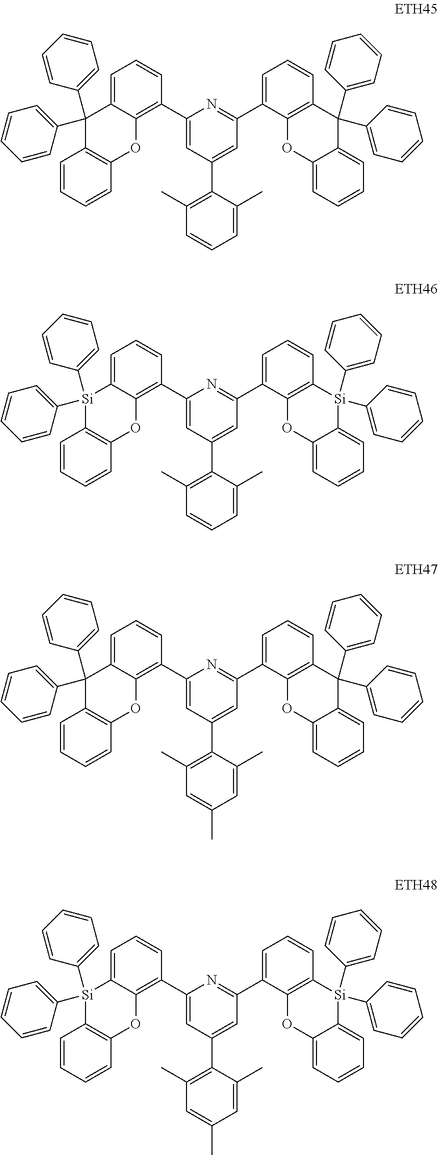 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

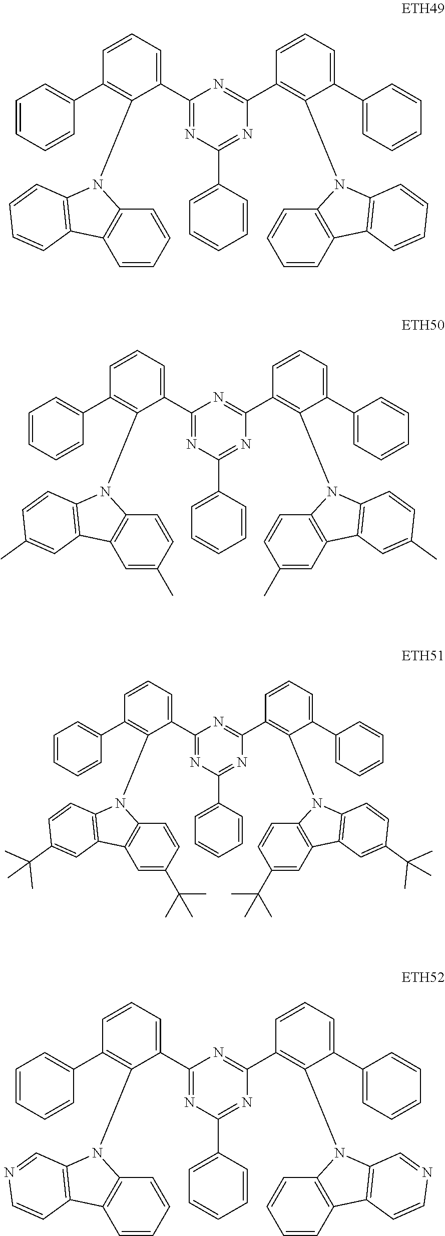

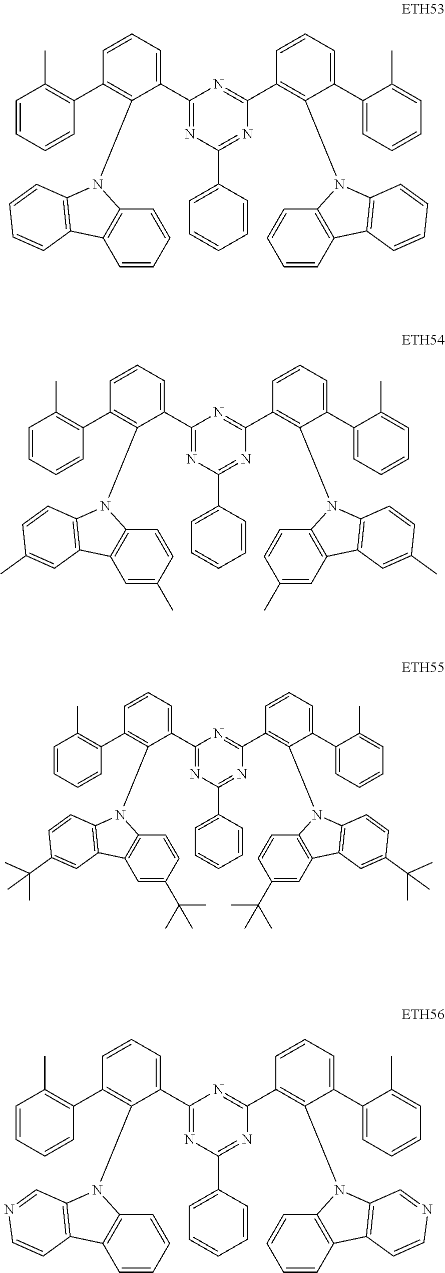

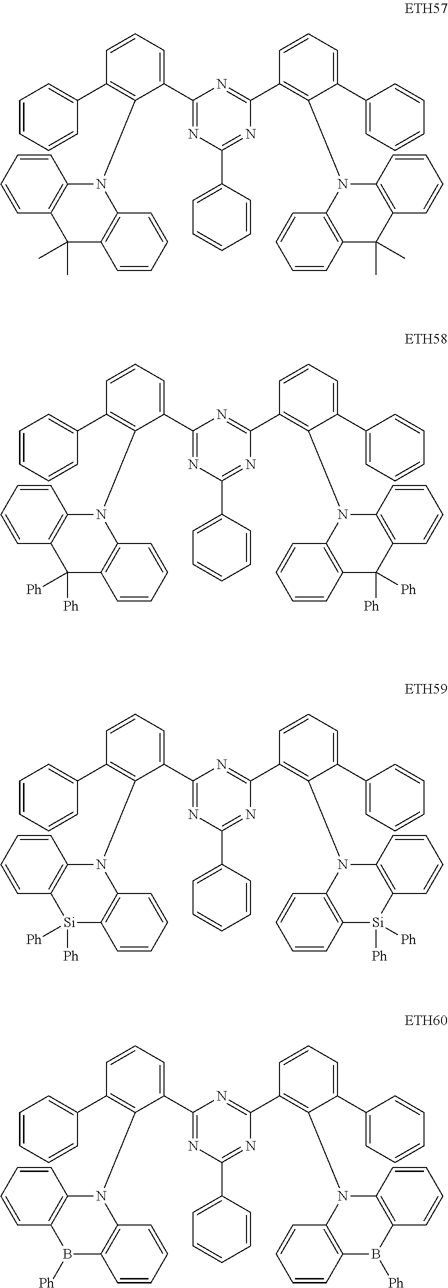

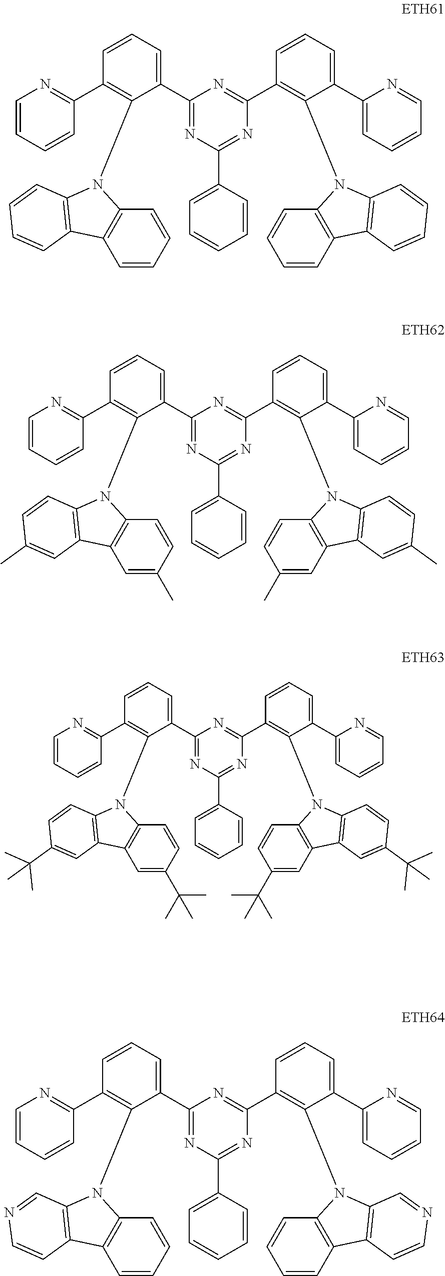

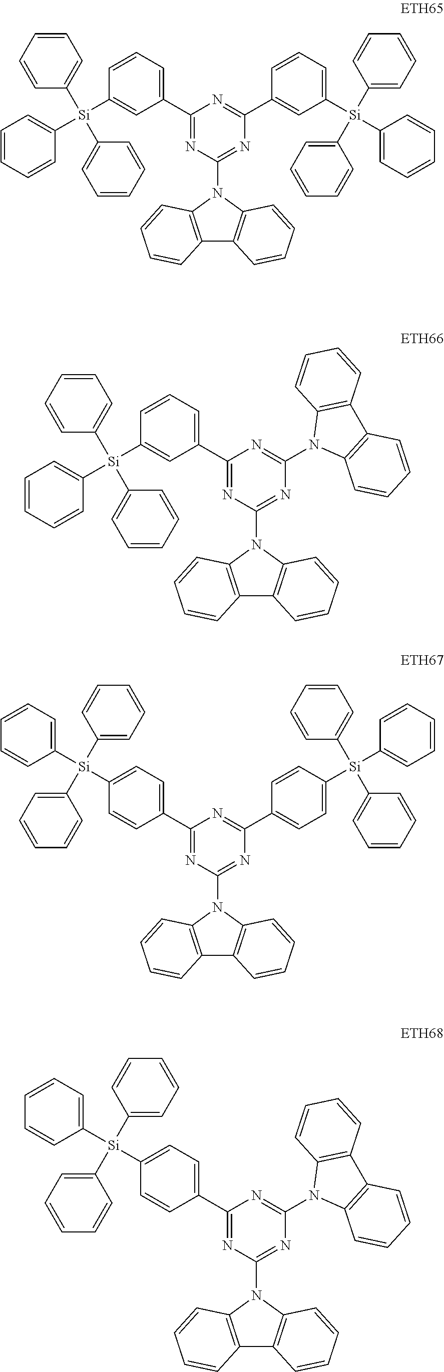 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

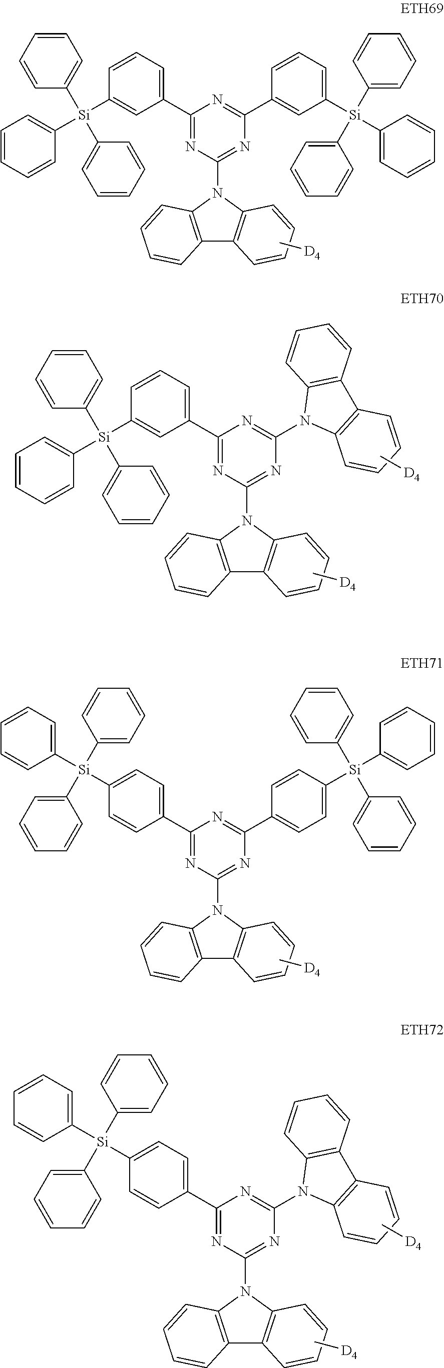

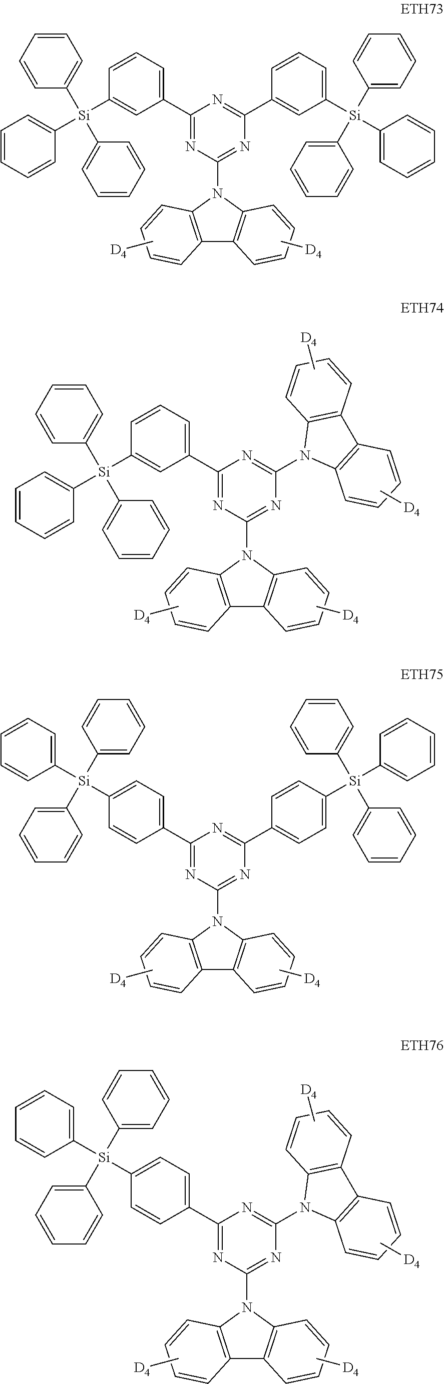

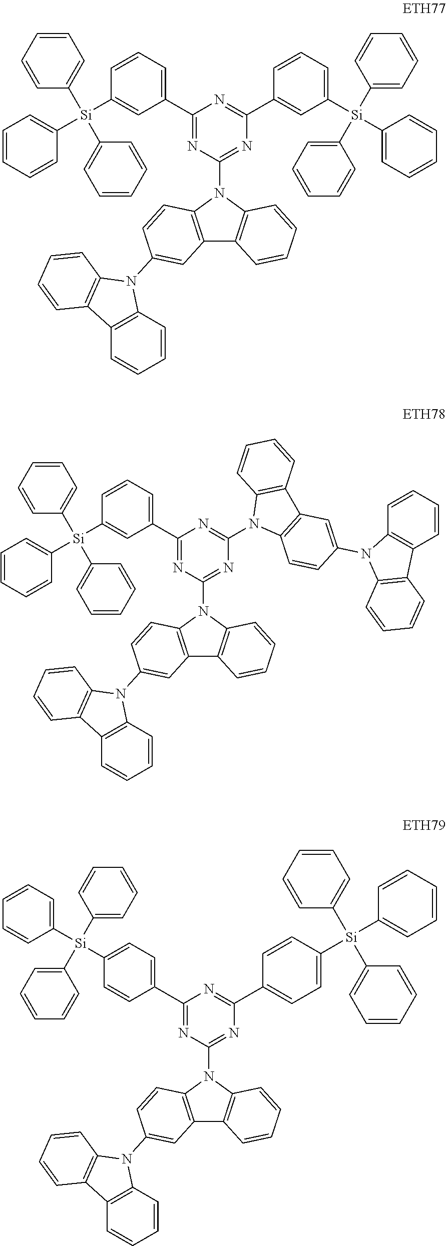 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

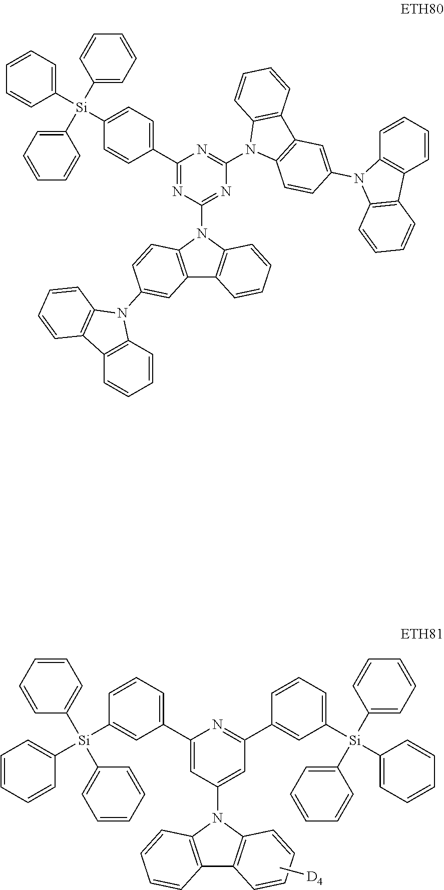

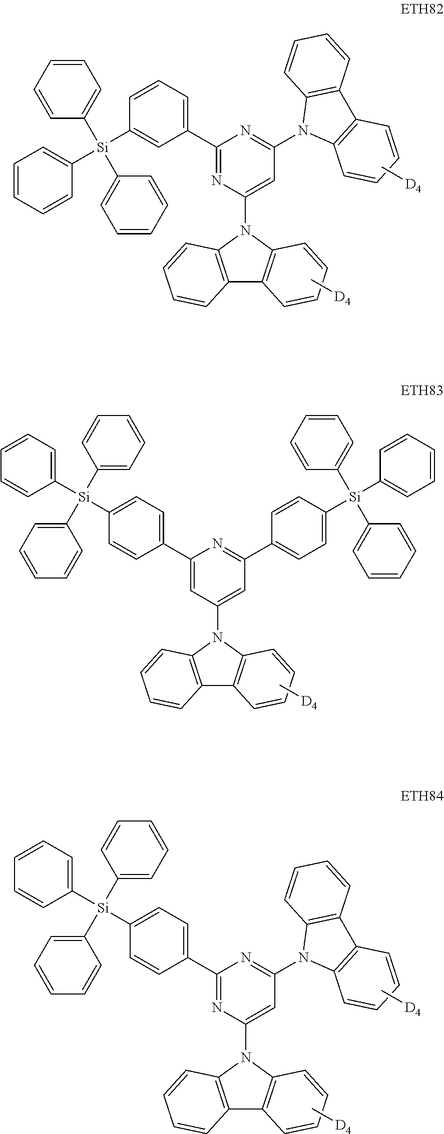

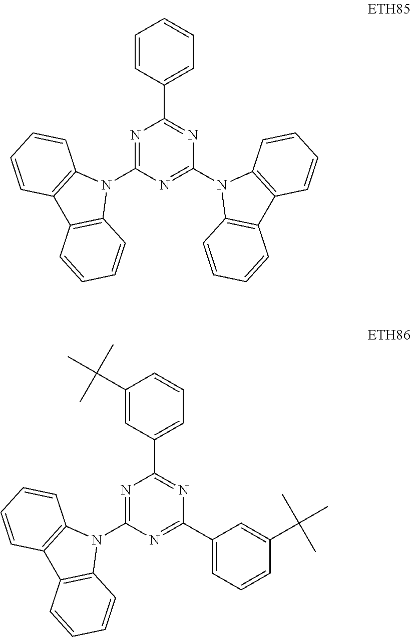 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the compounds presented in Compound Group 3, “D” may refer to a deuterium atom and “Ph” may refer to an unsubstituted phenyl group.

The emission layer EML may include the second compound and the third compound, and the second compound and the third compound may form an exciplex. In the emission layer EML, an exciplex may be formed or provided by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In one or more embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described herein. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light-emitting element ED of one or more embodiments may include, as the fourth compound, a compound represented by Formula D-1:

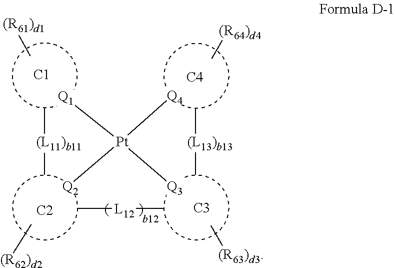

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage (e.g., a single covalent bond),

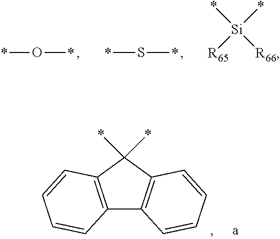

substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” may refer to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₆₁ to R₆₆ may be bonded to an adjacent group to form a ring. R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The case where each of d1 to d4 is 4 and R₆₁'s to R₆₄′ are each hydrogen atoms may be substantially the same as the case where each of d1 to d4 is 0. If (e.g., when) each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

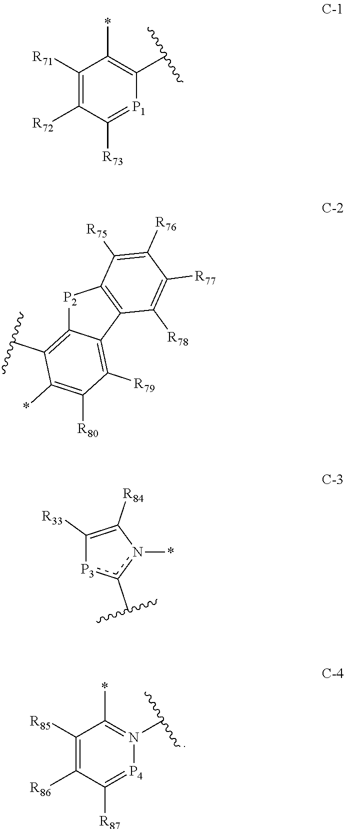

In C-1 to C-4, P₁ may be [symbol] or CR₇₄, P₂ may be [symbol] or NR₈₁, P₃ may be [symbol] or N_{R82}, and P₄ may be [symbol] or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In one or more embodiments, in C-1 to C-4,

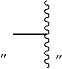

may correspond to a part linked to Pt that is a central metal atom, and “ [symbol] ” may correspond to a part linked to a neighboring cyclic group (C1 to C4) or a linker (L₁₁ to L₁₃).

The emission layer EML of one or more embodiments may include the first compound, which is a fused polycyclic compound, and at least one selected from among the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light-emitting element ED of one or more embodiments may serve as a sensitizer to deliver energy from the host to the first compound that is a light emitting dopant. For example, the fourth compound serving as an auxiliary dopant may accelerate energy delivery to the first compound that is a light emitting dopant, thereby increasing the emission ratio of the first compound. Therefore, the emission layer EML of one or more embodiments may improve or enhance luminous efficiency. In one or more embodiments, if (e.g., when) the energy delivery to the first compound is increased or enhanced, an exciton formed in the emission layer EML may not be accumulated inside the emission layer EML and may emit light rapidly, and thus deterioration of the device may be reduced. Therefore, the service life of the light-emitting element ED of one or more embodiments may increase.

The light-emitting element ED of one or more embodiments may include all of the first compound, the second compound, the third compound, and the fourth compound, and the emission layer EML may include the combination of two host materials and two dopant materials. In the light-emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may represented at least one selected from among the compounds represented by Compound Group 4. The emission layer EML may include at least one selected from among the compounds represented by Compound Group 4 as a sensitizer material.

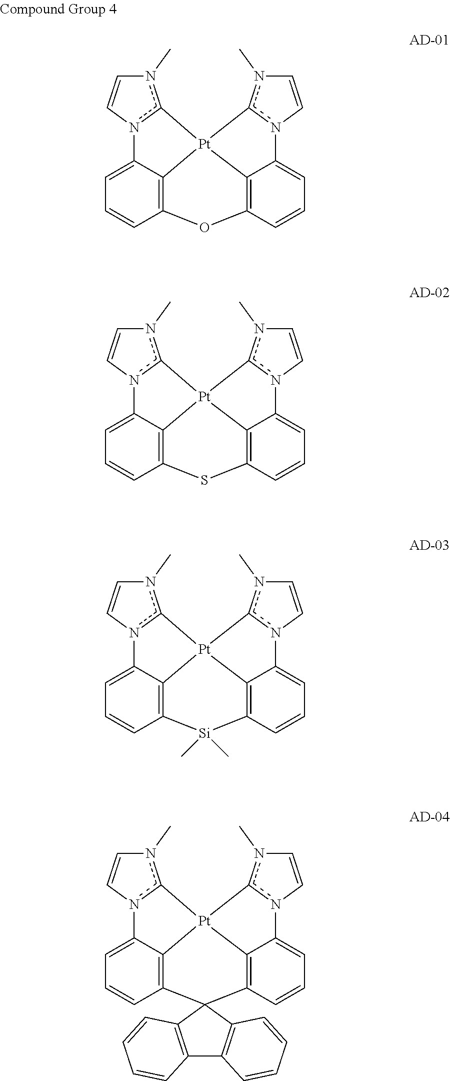

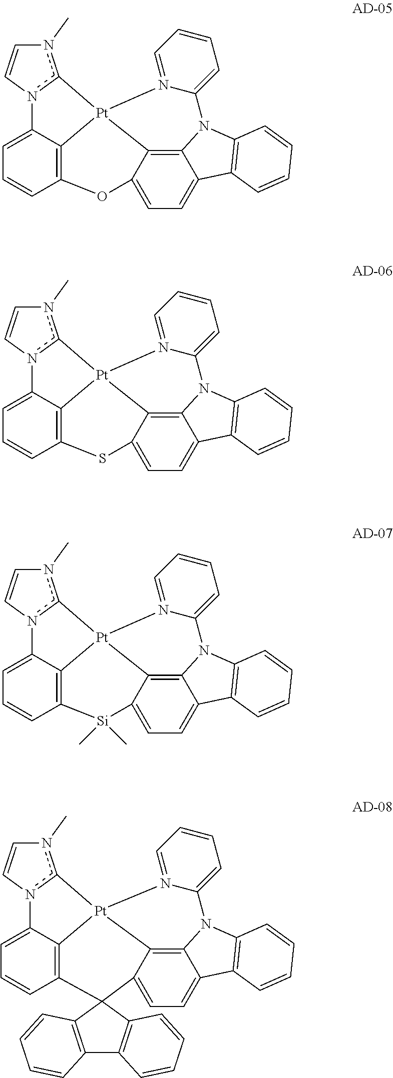

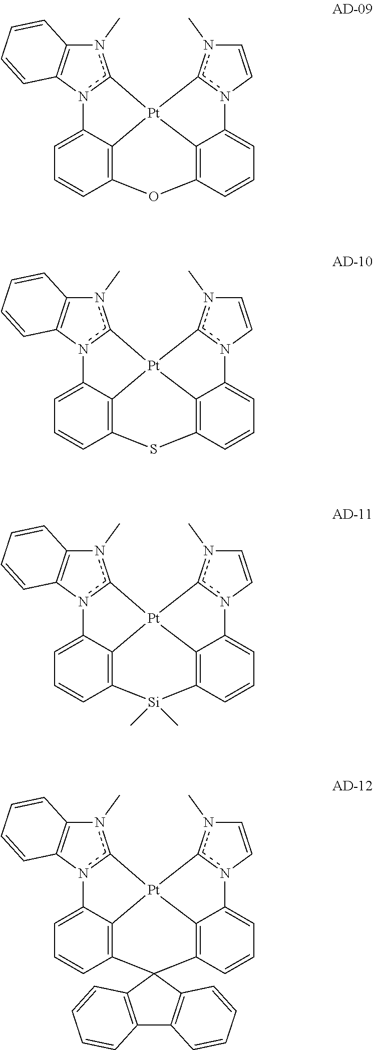

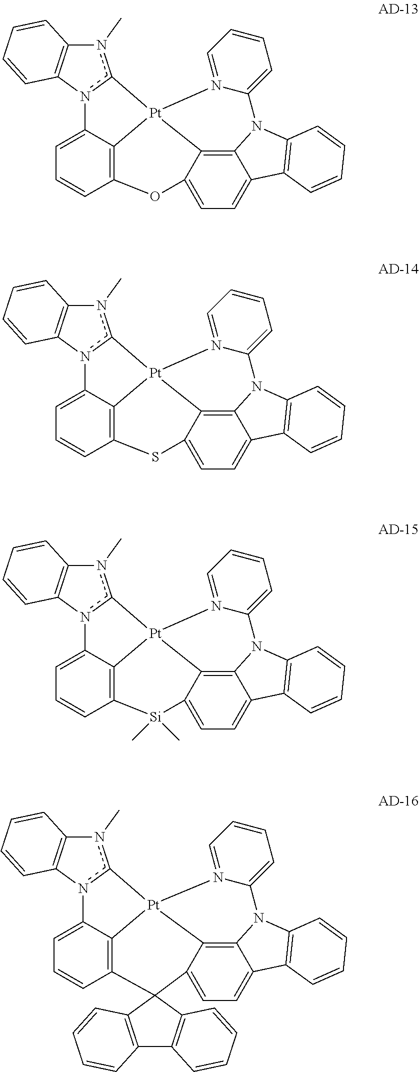

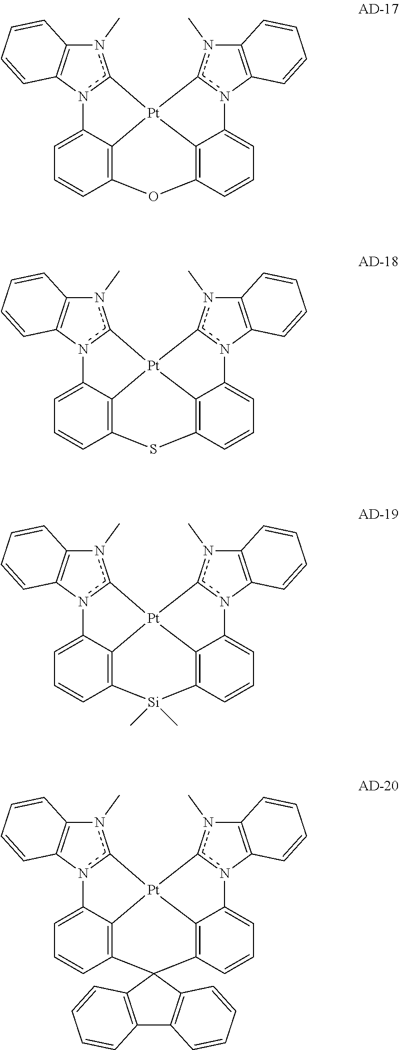

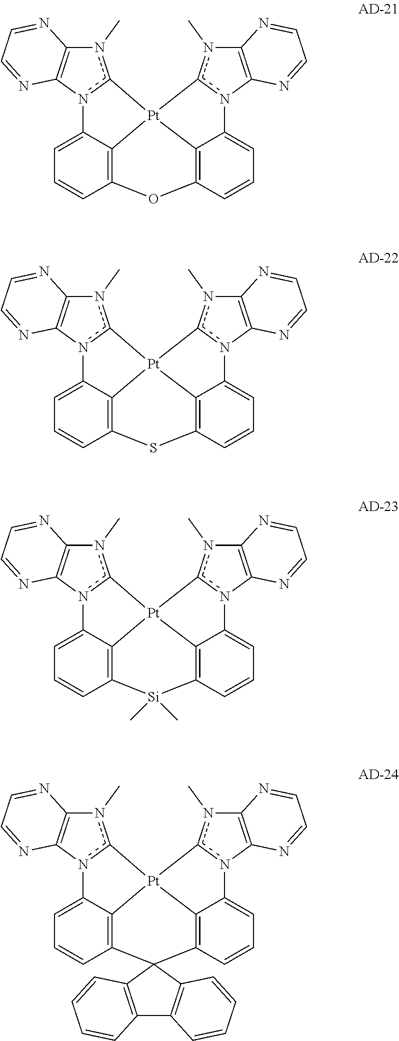

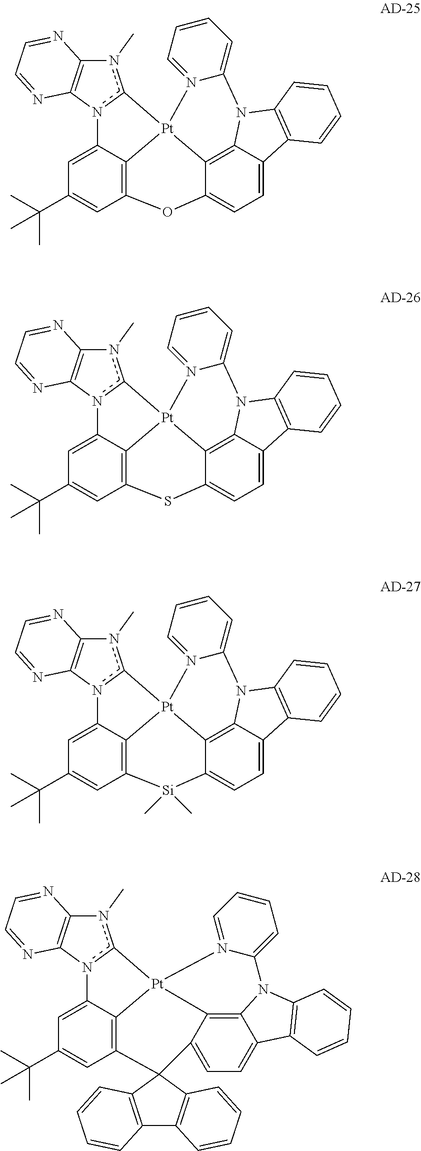

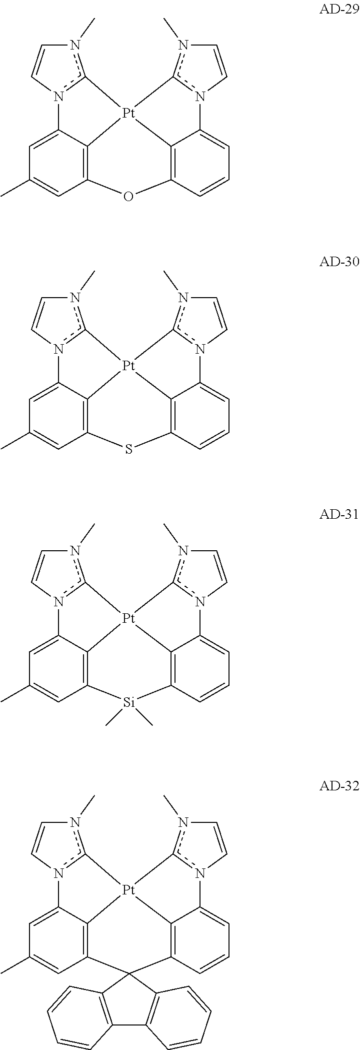

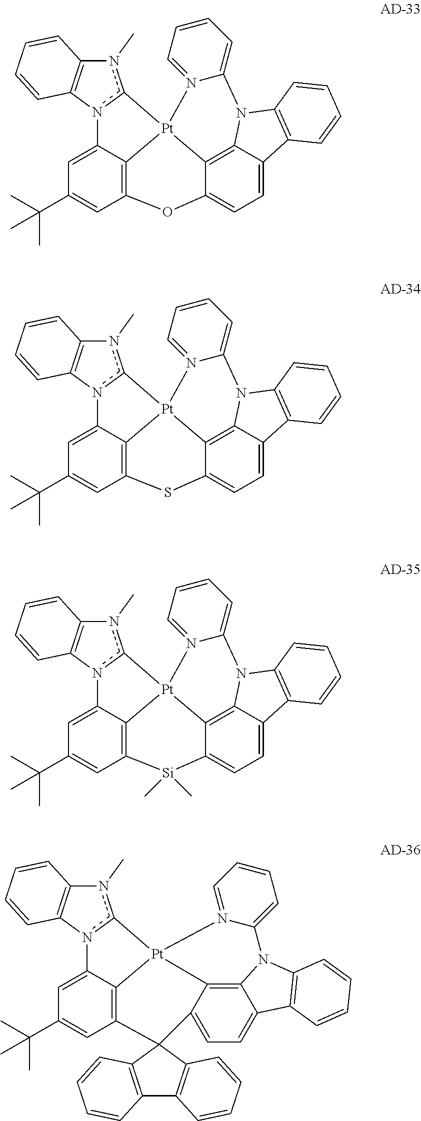

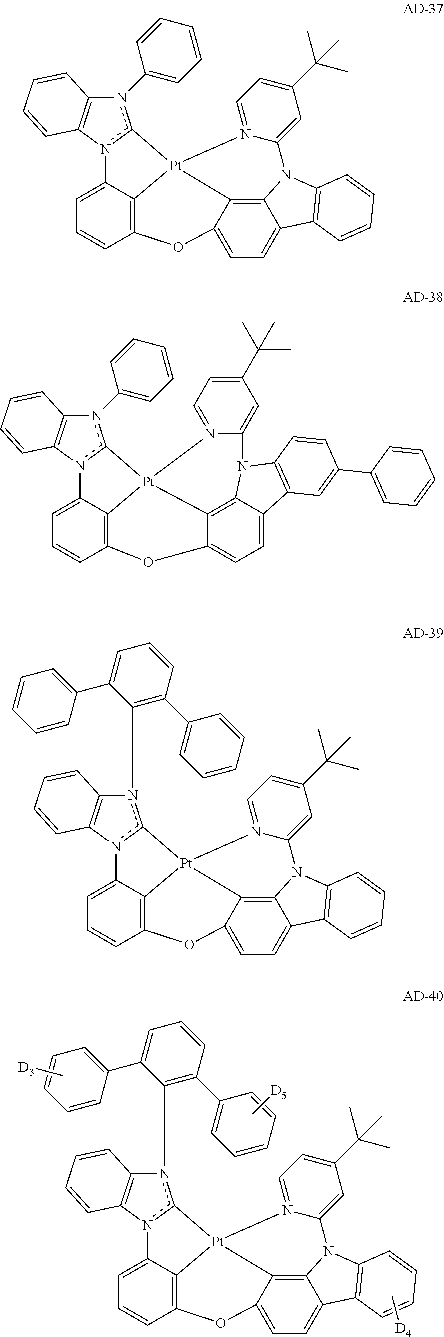

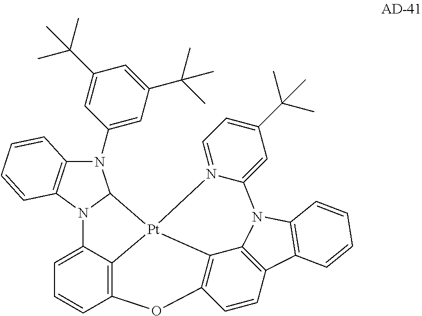

In the compounds presented in Compound Group 4, “D” refers to a deuterium atom.

If (e.g., when) the emission layer EML in the light-emitting element ED of one or more embodiments includes all of the first compound, the second compound, and the third compound, with respect to the total weight (e.g., based on 100 wt %) of the first compound, the second compound, and the third compound, the content (e.g., amount) of the first compound may be about 0.1 wt % to about 5 wt %. However, embodiments of the present disclosure are not limited thereto. If (e.g., when) the content (e.g., amount) of the first compound satisfy the proportion as described in one or more embodiments, the energy transfer from the second compound and the third compound to the first compound may increase or enhance, and thus the luminous efficiency and device service life may increase or enhance.

The contents (e.g., amounts) of the second compound and the third compound in the emission layer EML may be the rest excluding the weight of the first compound. For example, the contents (e.g., amounts) of the second compound and the third compound in the emission layer EML may be about 65 wt % to about 95 wt % with respect to the total weight (e.g., based on 100 wt %) of the first compound, the second compound, and the third compound.

In the total weight (e.g., based on 100 wt %) of the second compound and the third compound, the weight ratio of the second compound and the third compound may be about 3:7 to about 7:3.

If (e.g., when) the contents (e.g., amounts) of the second compound and the third compound satisfy the foregoing ratio, a charge balance characteristic in the emission layer EML may be improved or enhanced, and thus the luminous efficiency and device service life may increase or enhance. If (e.g., when) the contents (e.g., amounts) of the second compound and the third compound deviate from the foregoing ratio range, a charge balance in the emission layer EML may be broken, and thus the luminous efficiency may be reduced and the device may be easily deteriorated.

If (e.g., when) the emission layer EML includes the fourth compound, the content (e.g., amount) of the fourth compound in the emission layer EML may be about 10 wt % to about 30 wt % with respect to the total weight (e.g., based on 100 wt %) of the first compound, the second compound, the third compound, and the fourth compound. However, embodiments of the present disclosure are not limited thereto. If (e.g., when) the content (e.g., amount) of the fourth compound satisfies the foregoing content (e.g., amount), the energy delivery from the host to the first compound which is a light emitting dopant may be increased or enhanced, thereby a luminous ratio may be improved or enhanced, and thus the luminous efficiency of the emission layer EML may be improved or enhanced. If (e.g., when) the first compound, the second compound, the third compound, and the fourth compound included in the emission layer EML satisfy the foregoing content (e.g., amount) ratio range, excellent or suitable luminous efficiency and long service life may be achieved.

The emission layer EML may be provided on the hole transport region HTR. The emission layer EML may have a thickness of, for example, about 100 Å to about 1,000 Å or about 100 Å to about 300 Å. The emission layer EML may have a single layer formed or composed of a single material, a single layer formed or composed of a plurality of different materials, or a multilayer structure having a plurality of layers formed or composed of a plurality of different materials.

In the light-emitting element ED according to one or more embodiments as illustrated in FIG. 5 to FIG. 9, the emission layer EML may include the polycyclic compound according to one or more embodiments as a dopant. In one or more embodiments, in the light-emitting element ED according to one or more embodiments as illustrated in FIG. 5 to FIG. 9, the emission layer EML may include a first compound which is the polycyclic compound according to one or more embodiments and may further include at least one selected from among a second compound represented by Formula 2 and a third compound represented by Formula ET-1. In one or more embodiments, in the light-emitting element ED according to one or more embodiments as illustrated in FIG. 5 to FIG. 9, the emission layer EML may include a first compound which is the polycyclic compound according to one or more embodiments, a second compound represented by Formula HT-1, a third compound represented by Formula ET-1, and a fourth compound represented by Formula D-1.

In the light-emitting element ED of one or more embodiments, the emission layer EML may include an anthracene derivative, a pyrene derivative, a fluoranthene derivative, a chrysene derivative, a dihydrobenzanthracene derivative, and/or a triphenylene derivative. For example, the emission layer EML may include the anthracene derivative and/or the pyrene derivative.

In each light-emitting element ED of one or more embodiments as illustrated in FIGS. 5 to 9, the emission layer EML may further include a host and a dopant, that are generally available or generally used, besides the host and the dopant as described in one or more embodiments, and, for example the emission layer EML may include a compound represented by Formula E-1. The compound represented by Formula E-1 may be utilized as a fluorescent host material.

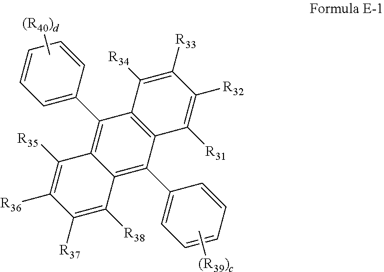

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In one or more embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compound E19:

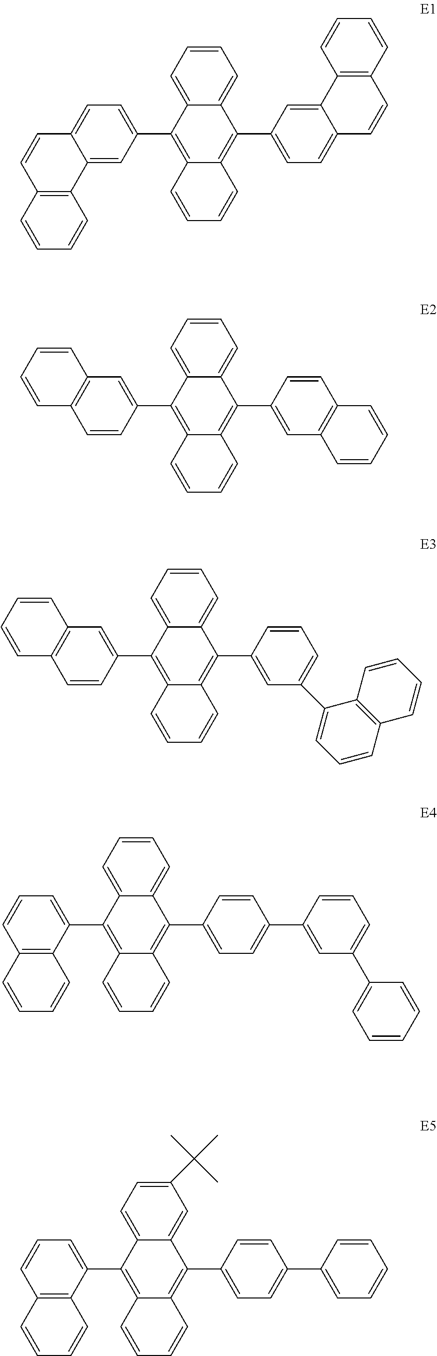

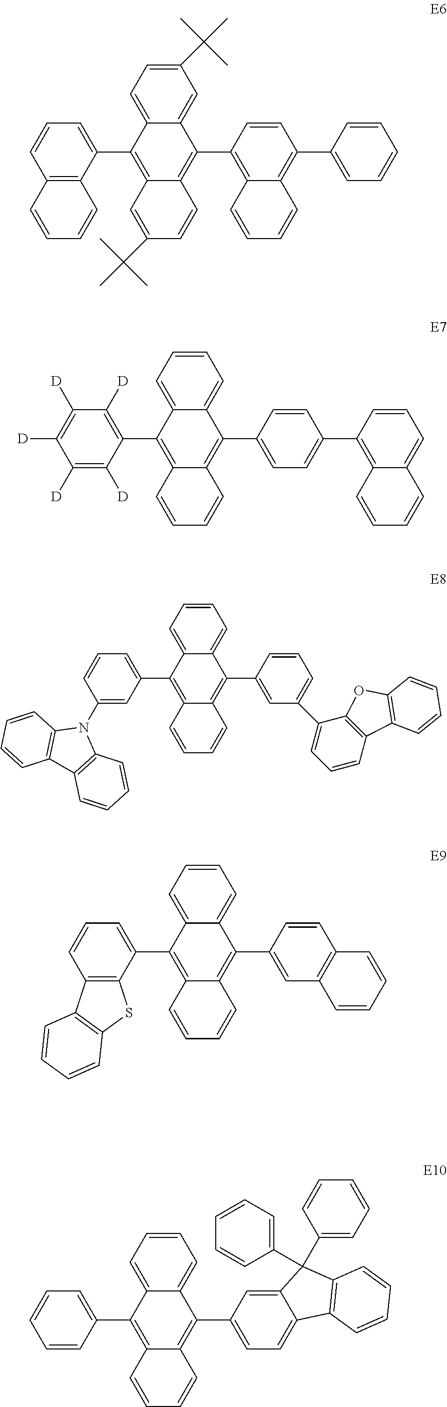

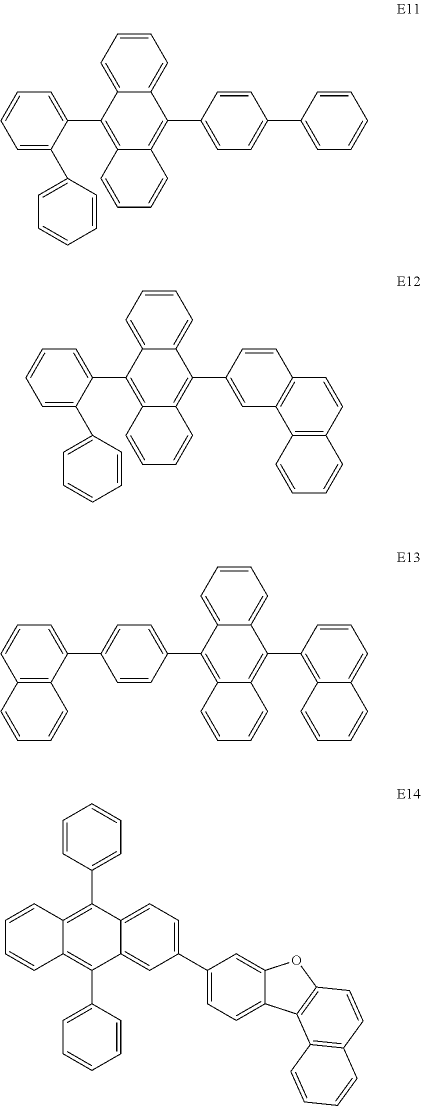

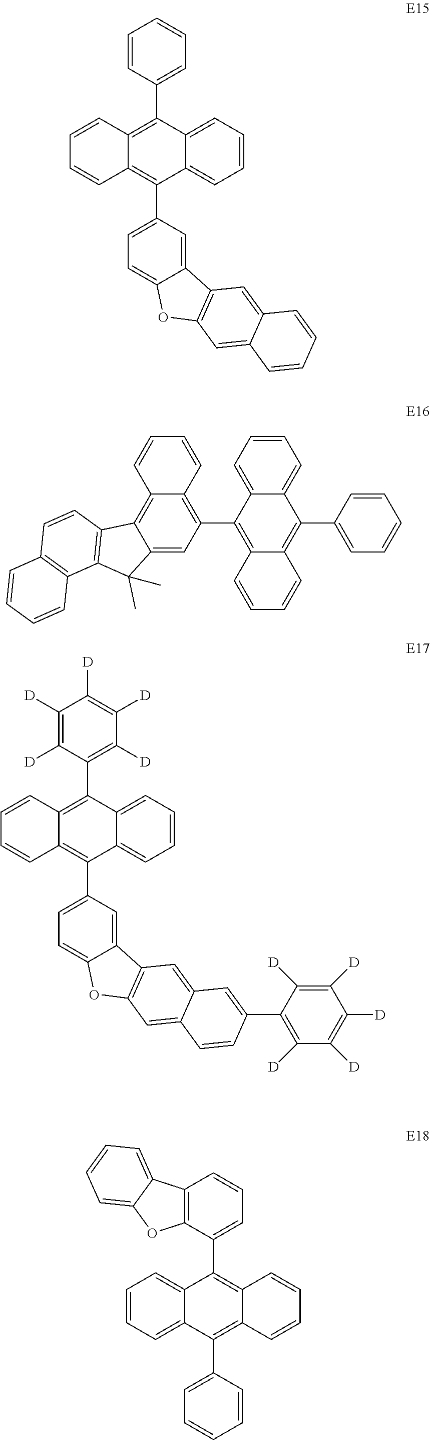

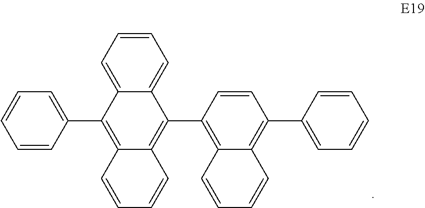 [SMILES: c1ccc(-c2ccc(-c3c4ccccc4c(-c4ccccc4)c4ccccc34)c3ccccc23)cc1]

In one or more embodiments, the emission layer EML may include a compound represented by Formula E-2a or Formula E-2b. The compound represented by Formula E-2a or Formula E-2b may be utilized as a host material for phosphorescent light emitting element.

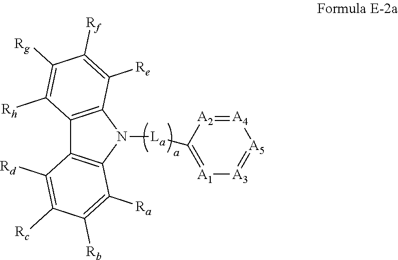

In Formula E-2a, a may be an integer of 0 to 10, and Lₐ may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In one or more embodiments, in Formula E-2a, A₁ to A₅ may each independently be N or CRI. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRI.

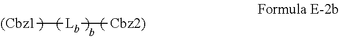

In Formula E-2b, Cbz1 and Cbz2 may each independently be an unsubstituted carbazole group or a carbazole group substituted with an aryl group having 6 to 30 ring-forming carbon atoms. L_{b} may be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or more, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds as listed in Compound Group E-2 are examples, and the compound represented by Formula E-2a or Formula E-2b is not limited to those represented in Compound Group E-2.

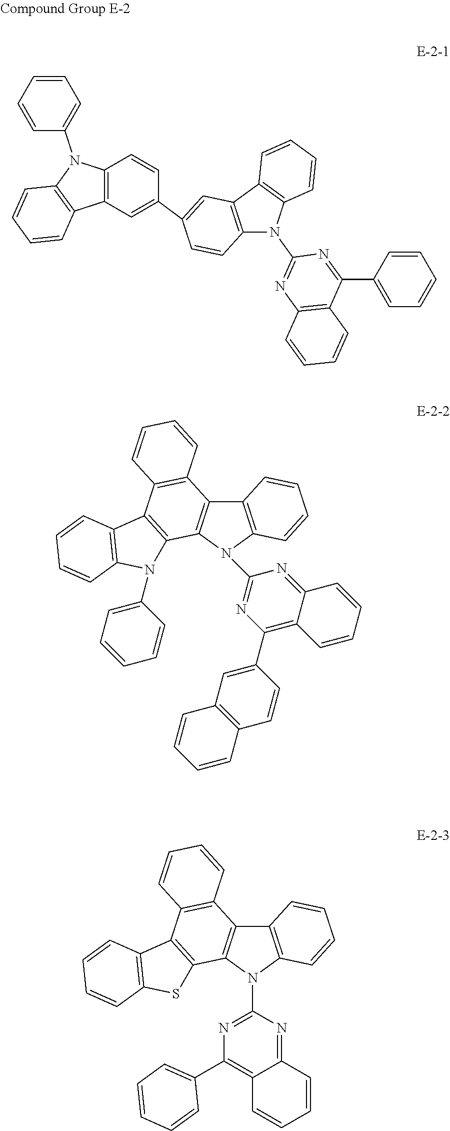 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

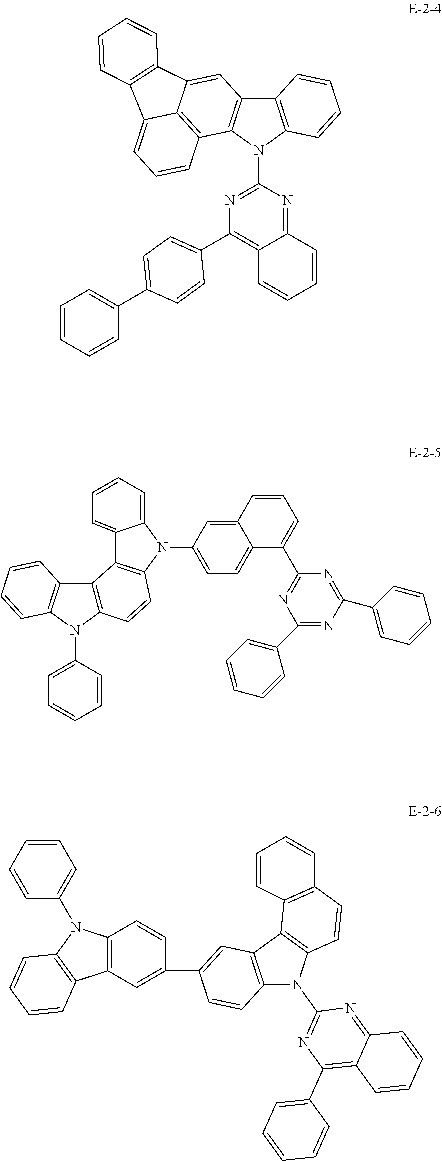 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

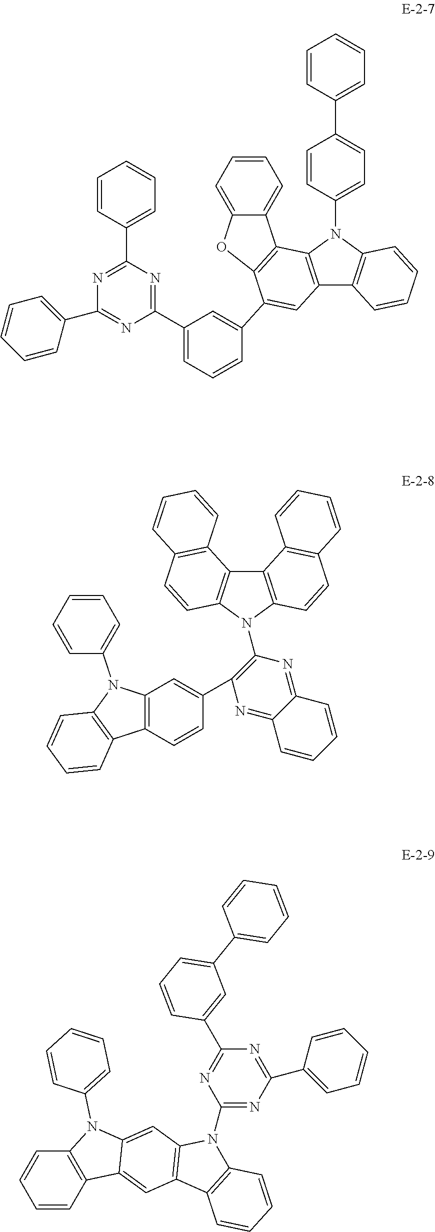 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

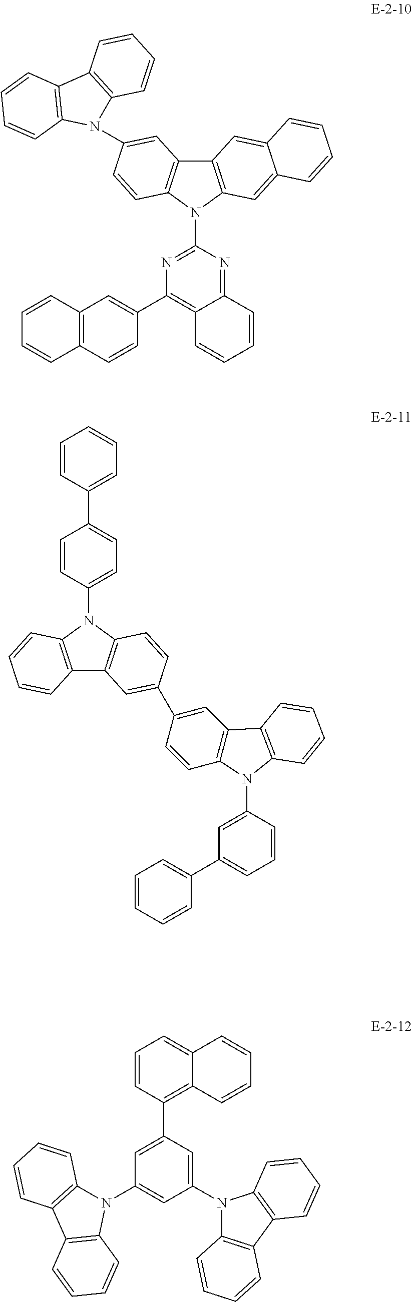 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

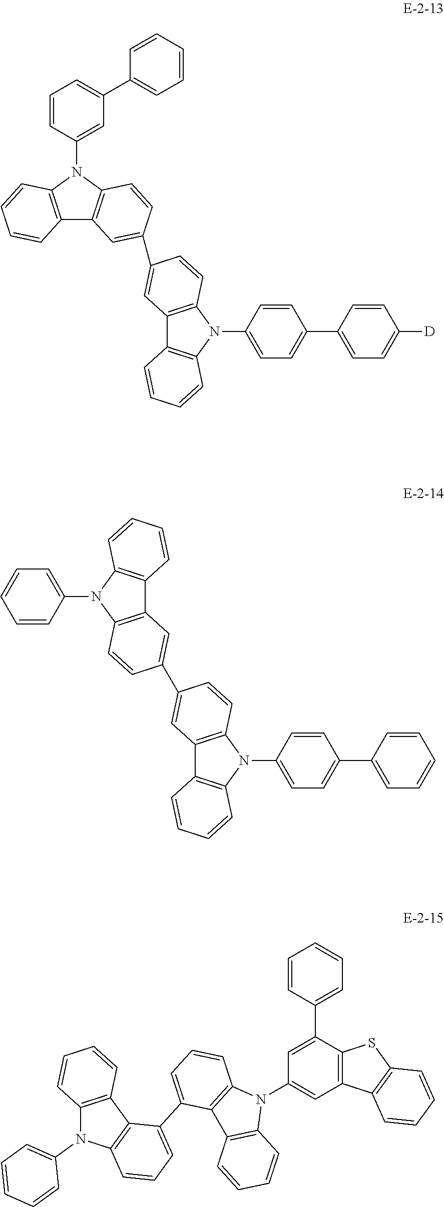 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

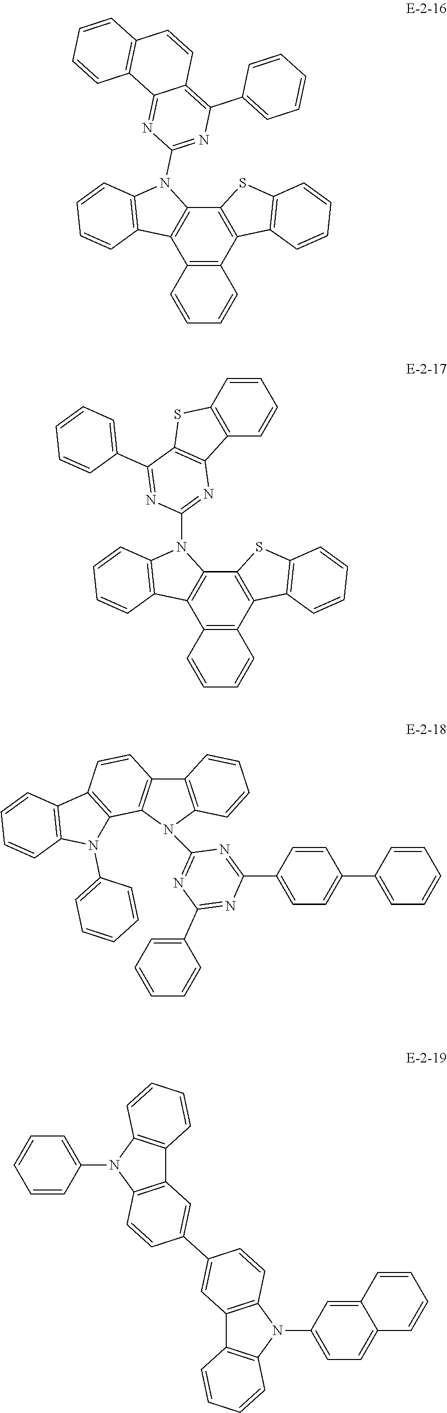 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

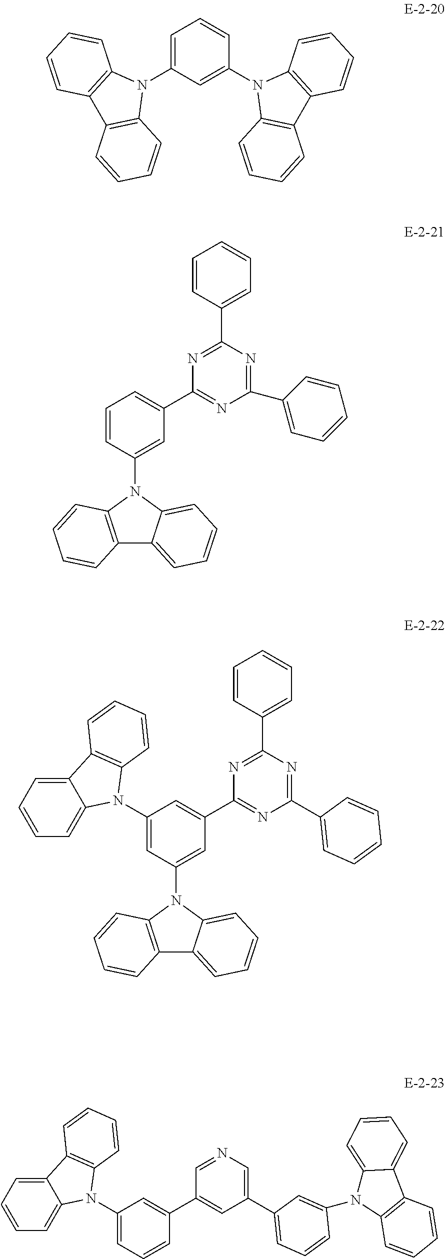 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

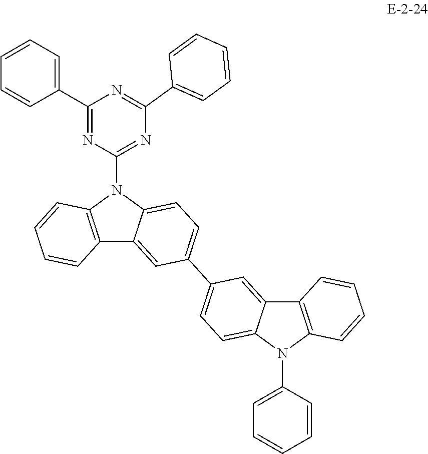 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a. The compound represented by Formula M-a may be utilized as a phosphorescent dopant material.

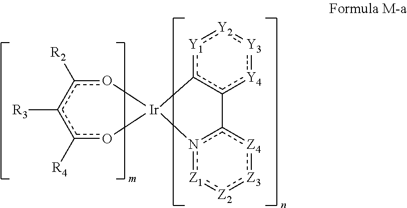

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, if (e.g., when) m is 0, n may be 3, and if (e.g., when) m is 1, n may be 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

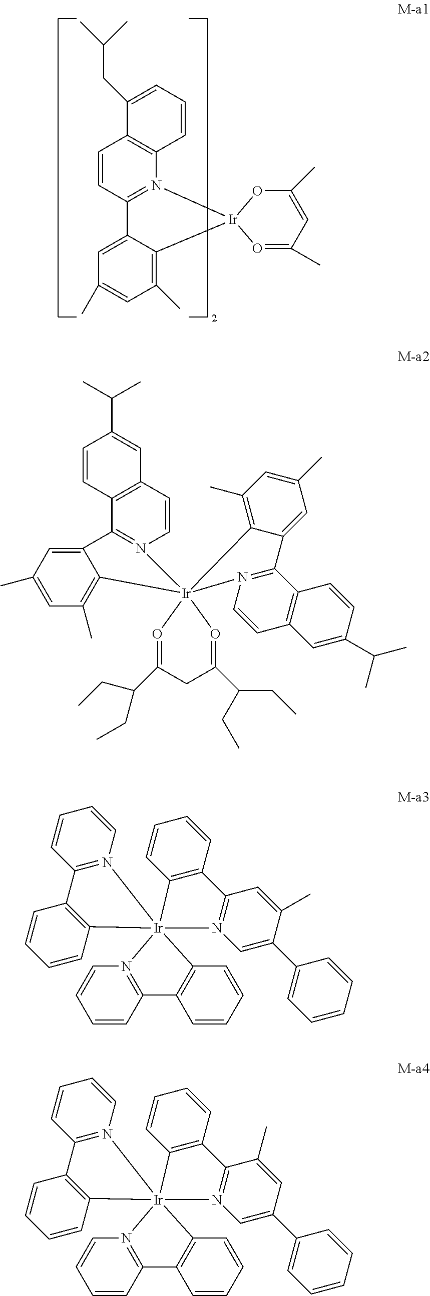

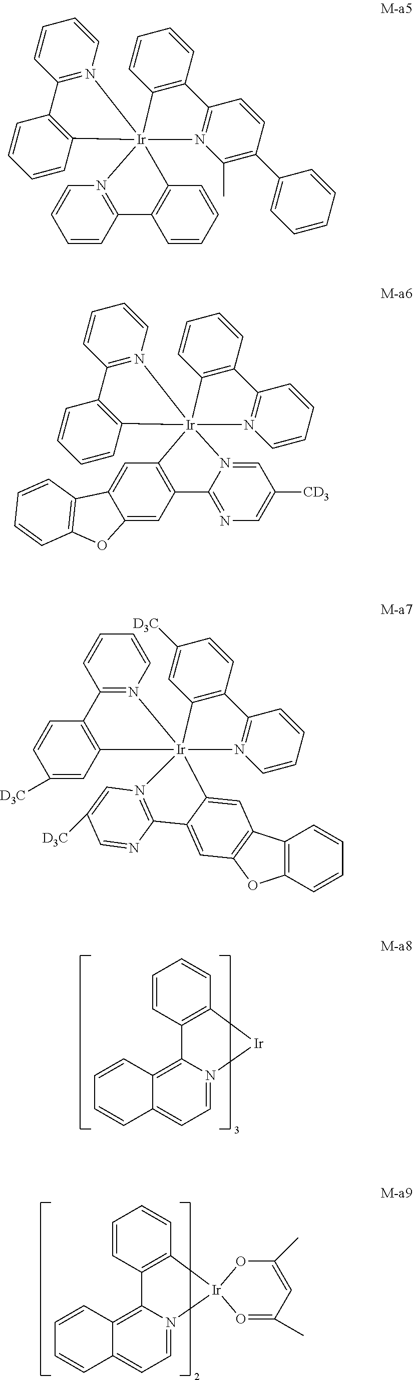

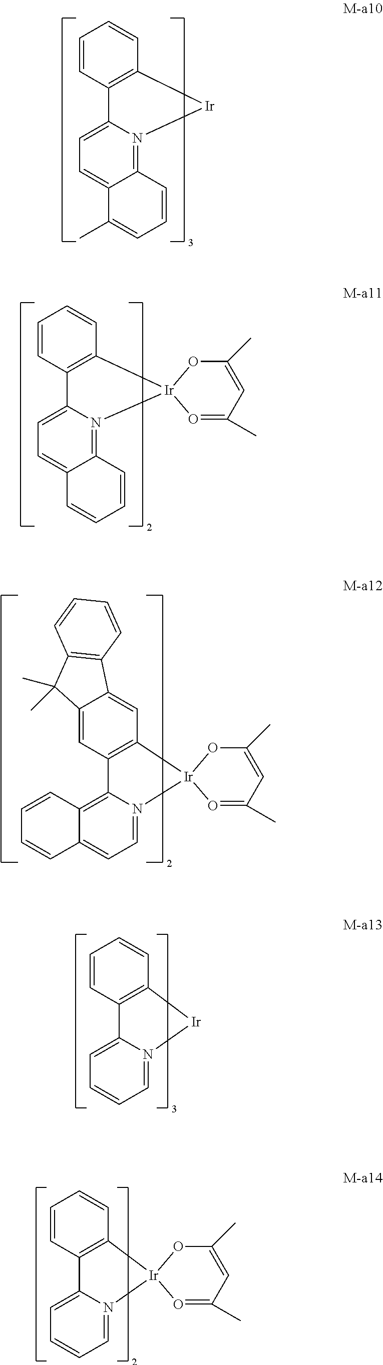

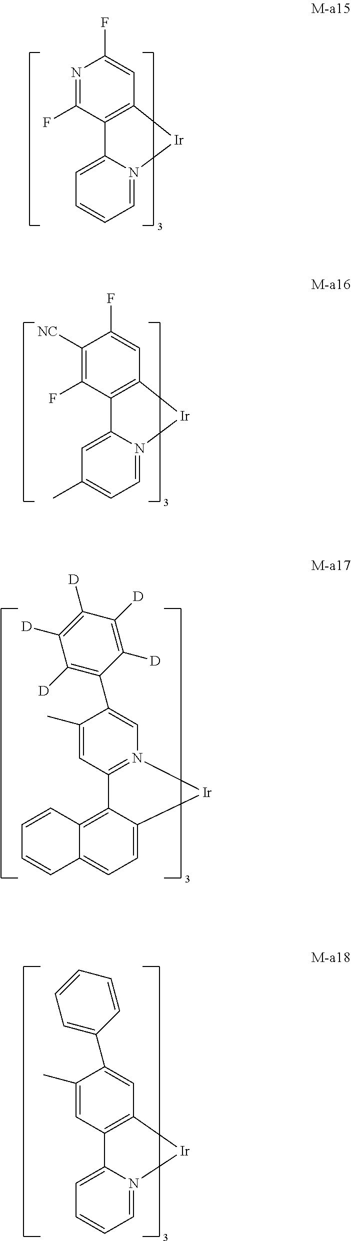

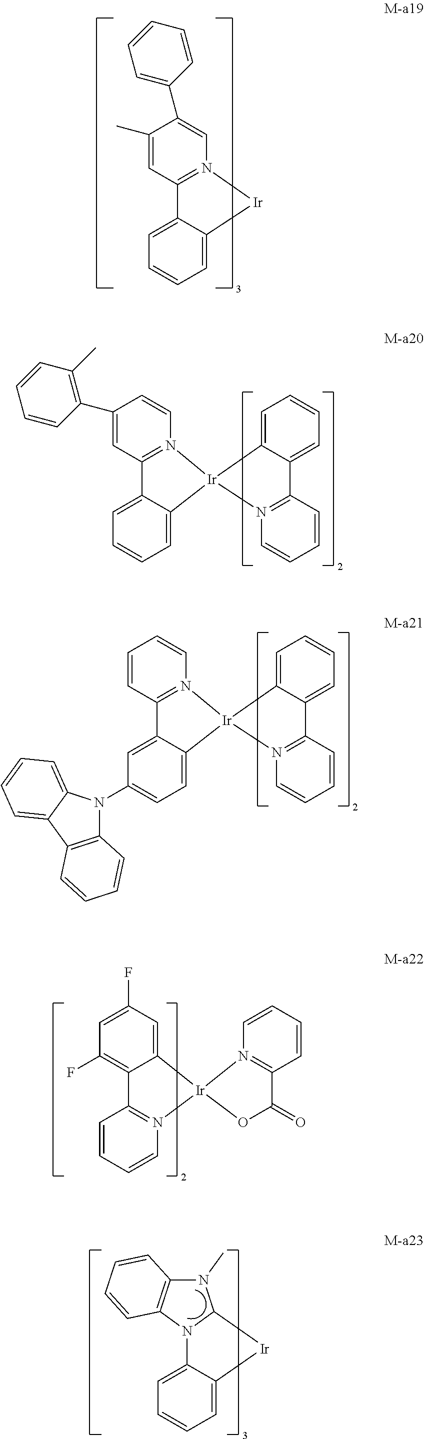

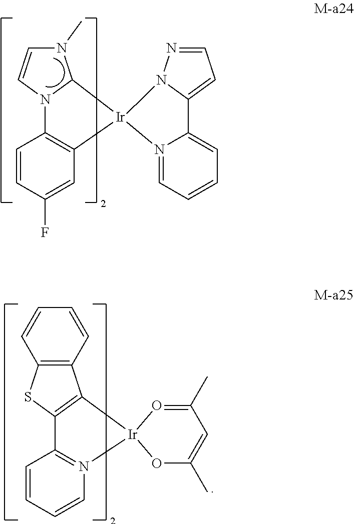

The emission layer EML may include a compound represented by any one selected from among Formula F-a to Formula F-c. The compound represented by Formula F-a to Formula F-c may be utilized as a fluorescence dopant material.

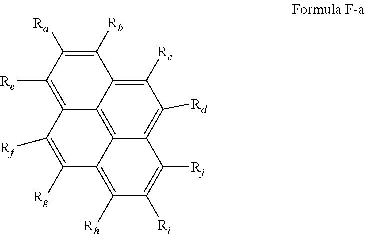

In Formula F-a, two selected from among Rₐ to Rⱼ may each independently be substituted with [symbol] The others, which are not substituted with [symbol] among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In [symbol] , Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

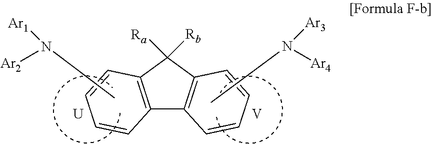

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, if (e.g., when) the number of U or V is 1, one ring may constitute a fused ring at a portion indicated by U or V, and if (e.g., when) the number of U or V is 0, a ring indicated by U or V may not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

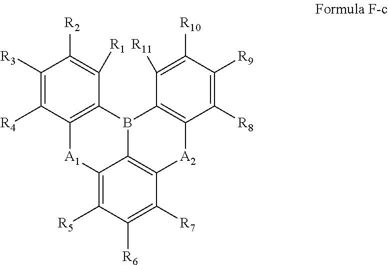

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a fused ring. For example, if (e.g., when) A₁ and A₂ are each independently NRₘ, A₁ may be bonded to R₄ or R₅ to form a ring. In one or more embodiments, A₂ may be bonded to R₇ or R₈ to form a ring.

In one or more embodiments, the emission layer EML may further include, as a dopant material that is generally available or generally used, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a phosphorescence dopant material that is generally available or generally used. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2) (Firpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, embodiments of the present disclosure are not limited thereto.

The emission layer EML may include a quantum dot material. The core of the quantum dot may be selected from a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In one or more embodiments, Group II-VI compound may further include a Group I metal and/or IV element. The Group I-II-VI compound may be selected from the group consisting of CuSnS and/or CuZnS, the Group II-IV-VI compound may be selected from the group consisting of ZnSnS and/or the like. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound, such as In₂S₃ and/or In₂Se₃, a ternary compound, such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound, such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary compound, such as the binary compound, the ternary compound, or the quaternary compound, may be present in a particle with a uniform (e.g., substantially uniform) or non-uniform concentration distribution. For example, the formulae refer to the types or kinds of elements included in the compounds, and the elemental ratio in the compound may be different. For example, AgInGaS₂ may refer to AgInₓGa₁₋ₓS₂ (where x is a real number of 0 to 1).

In one or more embodiments, the quantum dot may have a single structure or a double structure of core-shell in which the concentration of each element included in the quantum dot is uniform (e.g., substantially uniform). For example, the material included in the core may be different from the material included in the shell.

An example of the shell of the quantum dots may include a metal or non-metal oxide, a semiconductor compound, or a combination thereof. For example, the metal or non-metal oxide may be a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound, such as MgAl₂O₄, CoFe₂O₄, NiFe₂O₄, or CoMn₂O₄, but embodiments of the present disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Each element included in a polynary compound, such as the binary compound or the ternary compound, may be present in a particle with a uniform (e.g., substantially uniform) or non-uniform concentration distribution. For example, the formulae refer to the types or kinds of elements included in the compounds, and the elemental ratio in the compound may be different.

The quantum dot may have a full width of half maximum (FWHM) of a light emitting wavelength spectrum of about 45 nm or less, and, for example, about 40 nm or less, and, for example, about 30 nm or less, and color purity or color reproducibility may be improved or enhanced in the foregoing ranges. In one or more embodiments, light emitted through such quantum dot may be emitted in all directions so that (e.g., such that) a wide viewing angle may be improved or enhanced.

In one or more embodiments, although the form of the quantum dot is not limited as long as it is a form that is generally used in the art, and, for example, the quantum dot in the form of spherical (e.g., substantially spherical), pyramidal (e.g., substantially pyramidal), multi-arm (e.g., substantially multi-arm), or cubic (e.g., substantially cubic) nanoparticles, nanotubes, nanowires, nanofibers, nanoplate particles, and/or the like may be utilized.

As the size of the quantum dot is adjusted or the elemental ratio in the quantum dot compound is adjusted, it may be feasible to control the energy band gap, and thus light in one or more suitable wavelength ranges may be obtained in the quantum dot emission layer. Therefore, the quantum dot as described in one or more embodiments (e.g., utilizing different sizes of quantum dots and/or different elemental ratios in the quantum dot compound) may be utilized, and thus the light-emitting element, which emits light in one or more suitable wavelengths, may be implemented. For example, the adjustment of the size of the quantum dot and/or the elemental ratio in the quantum dot compound may be selected to emit red, green, and/or blue light. In one or more embodiments, the quantum dots may be configured or arranged to emit white light by combining one or more suitable colors of light.

In each of the light-emitting elements ED of one or more embodiments as illustrated in FIGS. 5 to 9, the electron transport region ETR may be provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed or composed of a single material, a single layer formed or composed of a plurality of different materials, or a multilayer structure including a plurality of layers formed or composed of a plurality of different materials.

For example, the electron transport region ETR may have a single layer structure of the electron injection layer EIL or the electron transport layer ETL and may have a single layer structure formed or composed of an electron injection material and an electron transport material. In one or more embodiments, the electron transport region ETR may have a single layer structure formed or composed of a plurality of different materials or may have a structure in which an electron transport layer ETL/electron injection layer EIL, a hole blocking layer HBL/electron transport layer ETL/electron injection layer EIL are stacked in order from the emission layer EML, but embodiments of the present disclosure are not limited thereto. The electron transport region ETR may have a thickness, for example, from about 1,000 Å to about 1,500 Å.

The electron transport region ETR may be formed or provided utilizing one or more suitable methods, such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

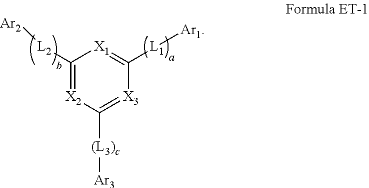

In Formula ET-2, at least one selected from among X₁ to X₃ may be N, and the rest may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage (e.g., a single covalent bond), a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c are each independently an integer of 2 or more, L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq2), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

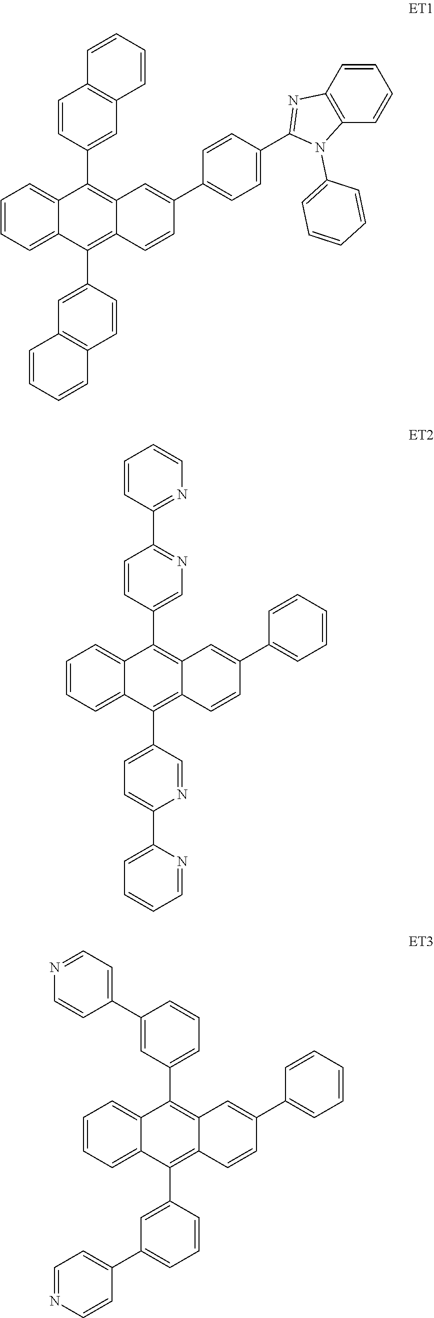 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

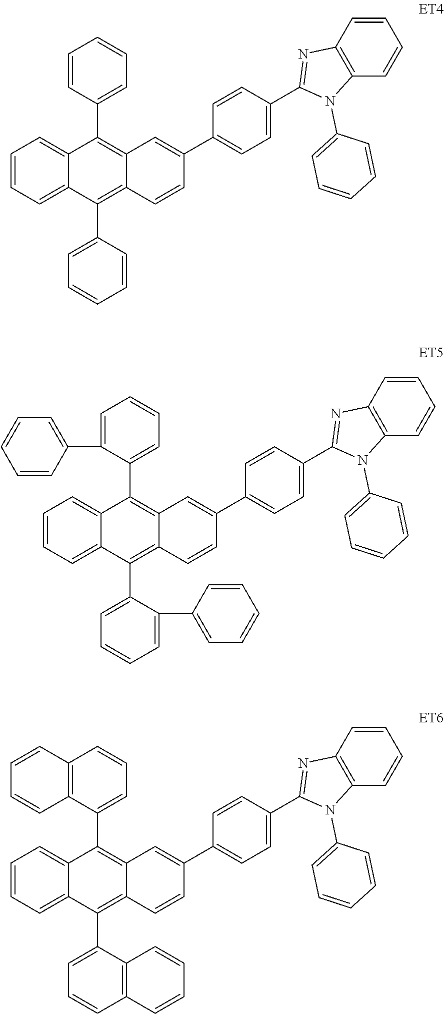 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

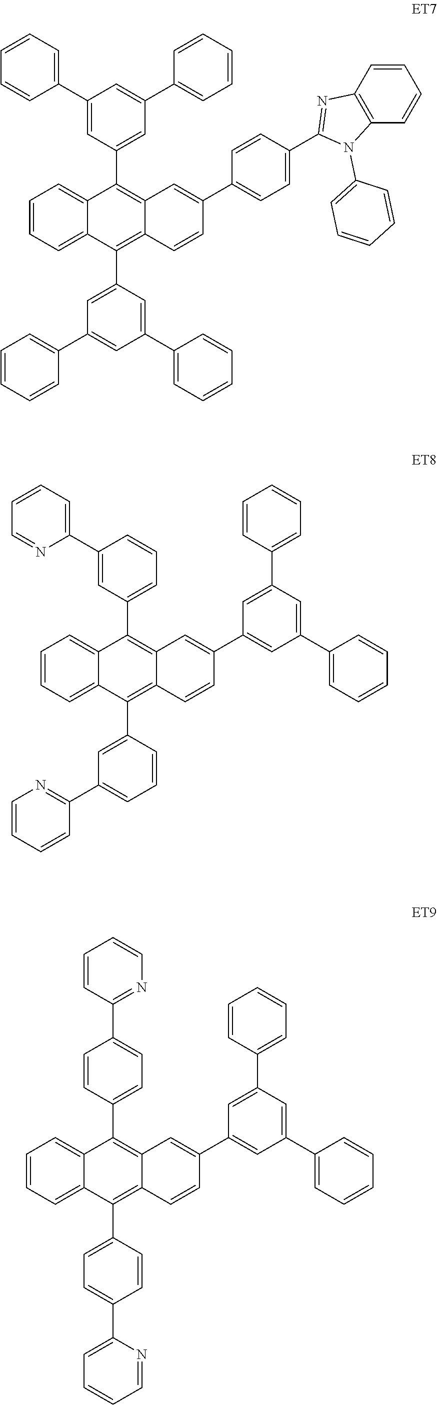 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

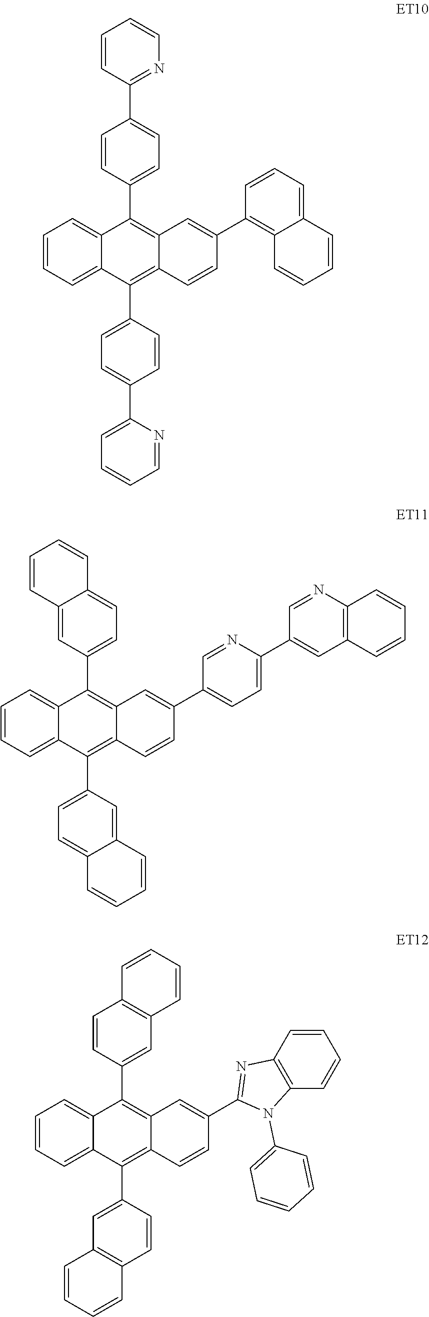 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

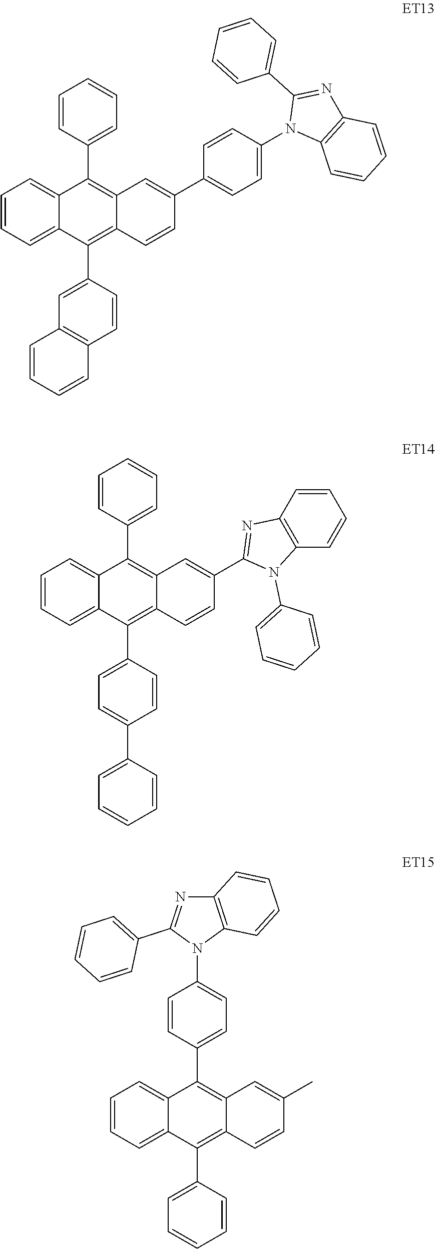 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

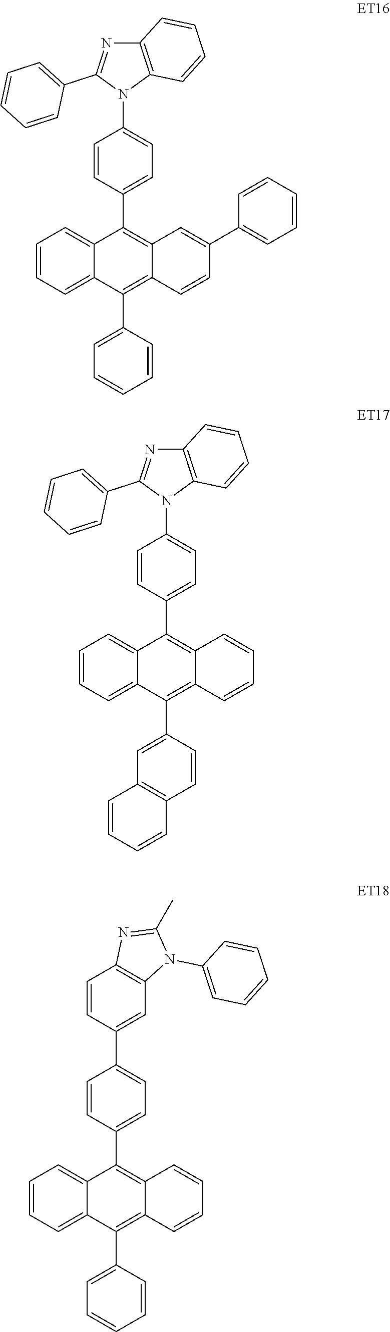 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

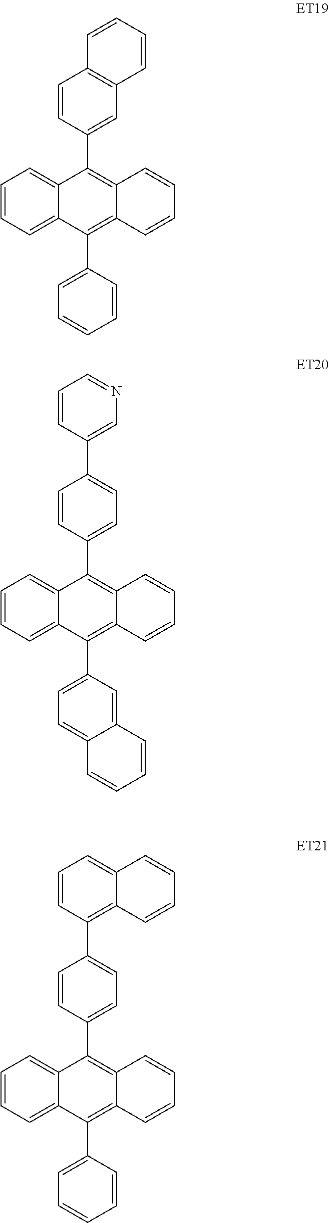

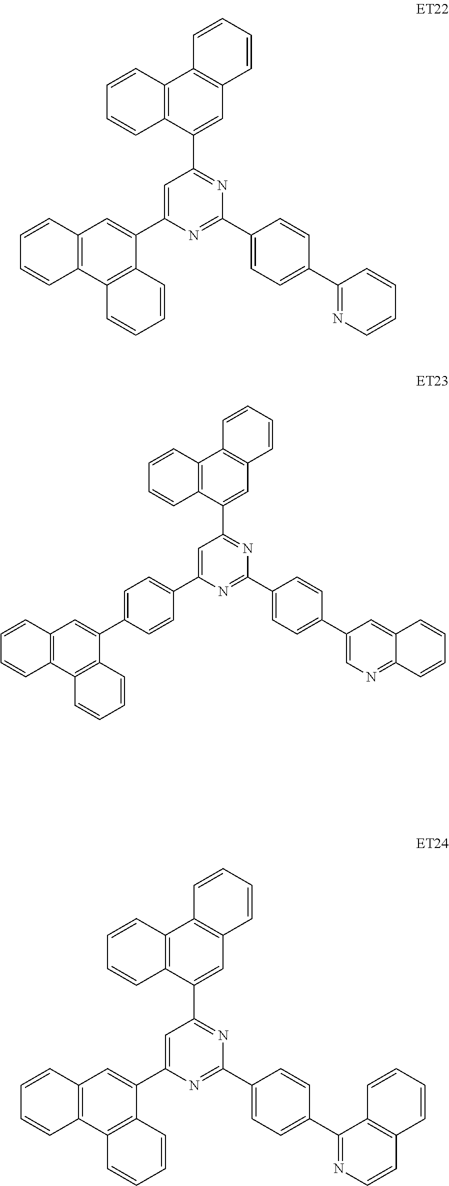 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

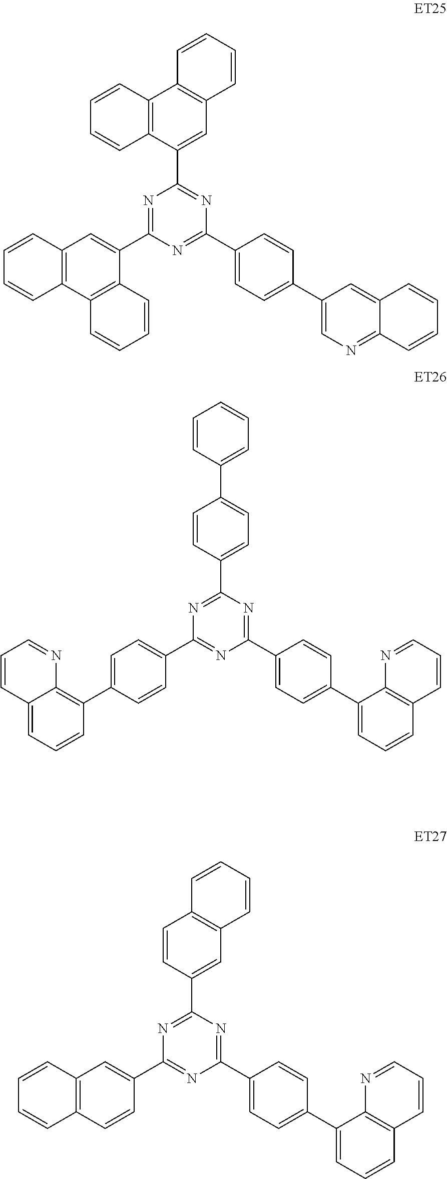 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

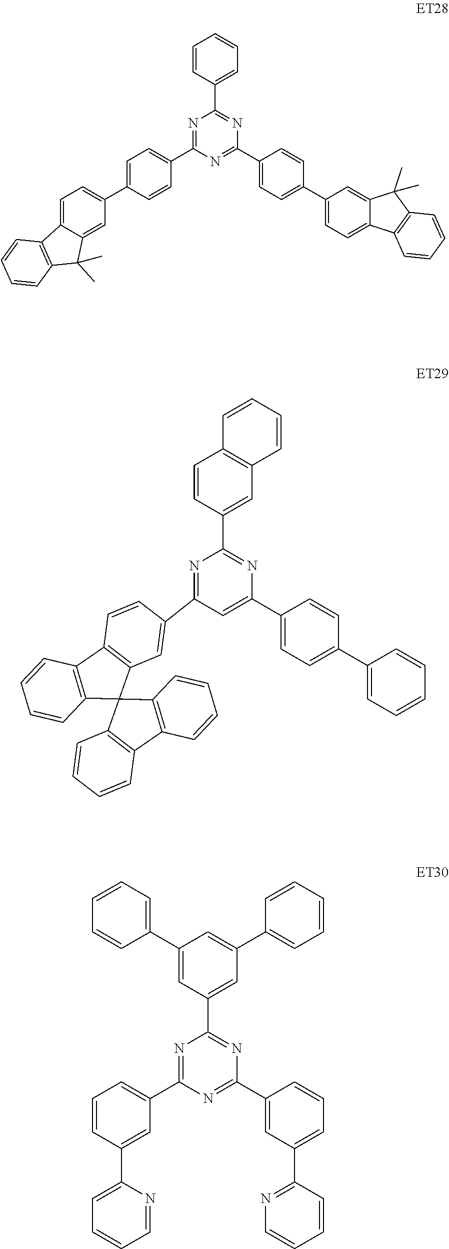 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

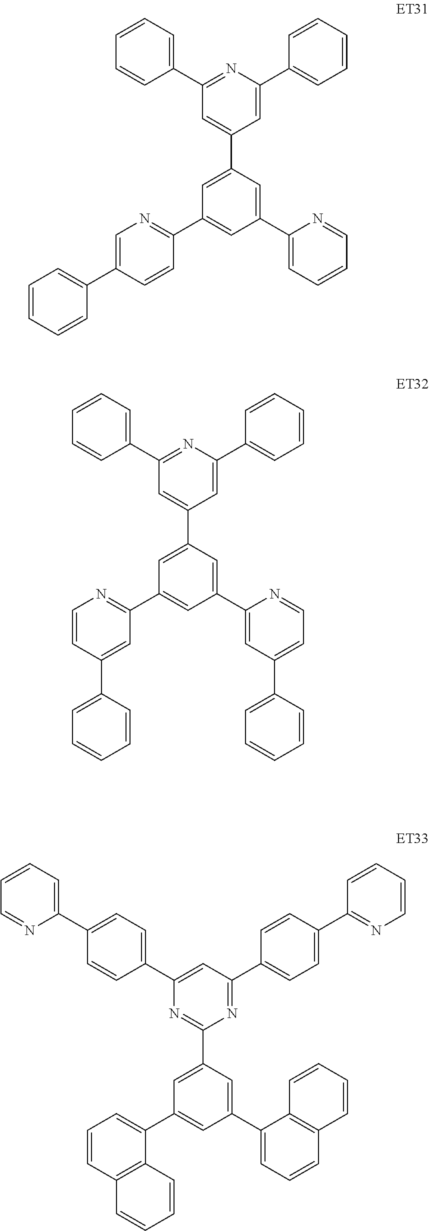 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

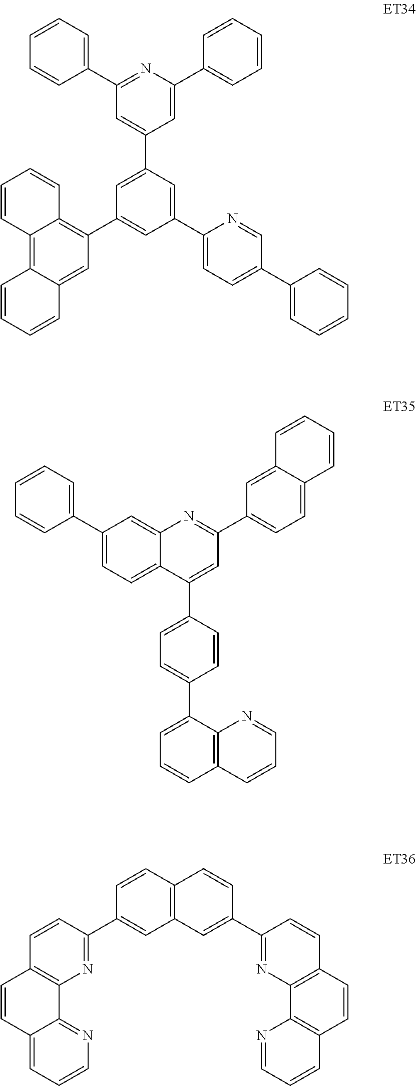 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide, such as LiF, NaCl, CsF, RbCl, RbI, CuI, and/or KI, a lanthanide metal, such as Yb, and a co-deposited material of the metal halide and the lanthanide metal.

For example, the electron transport region ETR may include KI:Yb, RbI:Yb, LiF:Yb, and/or the like, as a co-deposited material. In one or more embodiments, the electron transport region ETR may be formed or provided utilizing a metal oxide, such as Li₂O and/or BaO, 8-hydroxyl-lithium quinolate (Liq), and/or the like, but embodiments of the present disclosure are not limited thereto. The electron transport region ETR may also be formed or composed of a mixture material of an electron transport material and an insulating (e.g., electrically insulating) organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the materials as described in one or more embodiments, but embodiments of the present disclosure are not limited thereto.

The electron transport region ETR may include the compounds of the hole transport region as described in one or more embodiments in at least one of the electron injection layer EIL, the electron transport layer ETL, or the hole blocking layer HBL.

If (e.g., when) the electron transport region ETR includes the electron transport layer ETL, the electron transport layer ETL may have a thickness of about 100 Å to about 1,000 Å, for example, about 150 Å to about 500 Å. If (e.g., when) the thickness of the electron transport layer ETL satisfies the foregoing range, satisfactory or suitable electron transport characteristics may be obtained without a substantial increase in driving voltage. If (e.g., when) the electron transport region ETR includes the electron injection layer EIL, the electron injection layer EIL may have a thickness of about 1 Å to about 100 Å, for example, about 3 Å to about 90 Å. If (e.g., when) the thickness of the electron injection layer EIL satisfies the foregoing range, satisfactory or suitable electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may be formed or composed of a transparent (e.g., substantially transparent) metal oxide, for example, indium tin oxide (ITO), indium zinc oxide (IZO), zinc oxide (e.g., ZnOₓ, wherein 0<x≤2; e.g., ZnO), indium tin zinc oxide (ITZO), and/or the like.

If (e.g., when) the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, and/or MgYb). In one or more embodiments, the second electrode EL2 may have a multilayer structure including a reflective film or a transflective film formed or composed of the materials as described in one or more embodiments, and a transparent (e.g., substantially transparent) conductive (e.g., electrically conductive) film formed or composed of ITO, IZO, ZnO, ITZO, and/or the like. For example, the second electrode EL2 may include the metal materials as described in one or more embodiments, combinations of at least two metal materials of the metal materials as described in one or more embodiments, oxides of the metal materials as described in one or more embodiments, and/or the like.

In one or more embodiments, the second electrode EL2 may be connected with an auxiliary electrode. If (e.g., when) the second electrode EL2 is connected with the auxiliary electrode, the resistance (e.g., electrical resistance) of the second electrode EL2 may be decreased or reduced.

In one or more embodiments, a capping layer CPL may further be disposed or provided on the second electrode EL2 of the light-emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), silicon nitride oxide or silicon oxynitride (e.g., SiOₓN_{y}, wherein 0<x≤2 and 0≤y≤2; e.g., SiON or Si₂N₂O), silicon nitride (e.g., SiNₓ, wherein 0<x≤2; e.g., Si₃N₄), silicon oxide (e.g., SiOₓ, wherein 0<x≤2; e.g., SiO₂), and/or the like.

For example, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, embodiments of the present disclosure are not limited thereto, and the capping layer CPL may include at least one selected from among Compounds P1 to P5:

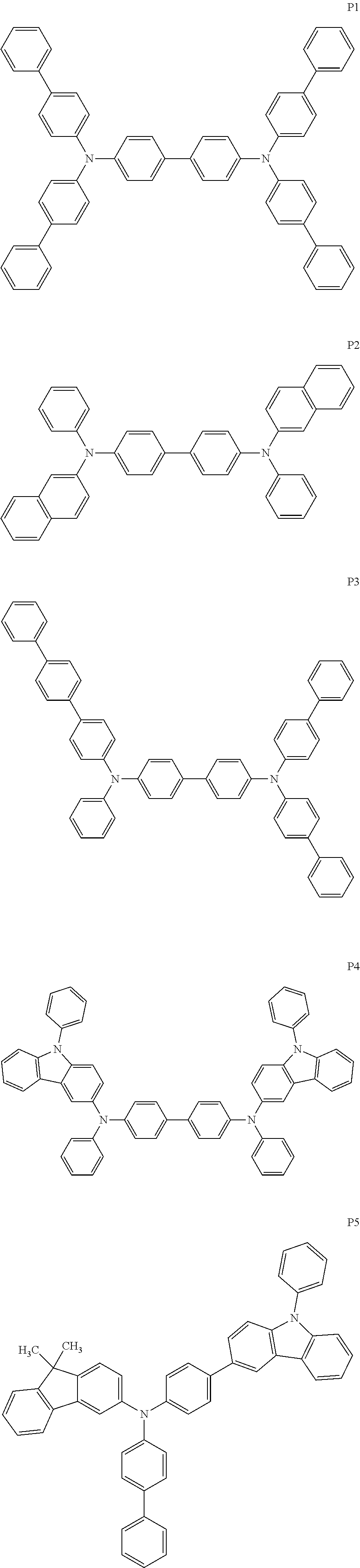 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL may be about 1.6 or more with respect to light in a wavelength range of about 550 nm to about 660 nm.

Each of FIGS. 10 to 13 is a cross-sectional view of a display device according to one or more embodiments of the present disclosure. Hereinafter, in describing the display devices of one or more embodiments in more detail with reference to FIGS. 10 to 13, the duplicated features which have been described in FIGS. 1 to 9 may not be described again, but their differences may be mainly or predominantly described.

Referring to FIG. 10, the display device DD-a according to one or more embodiments may include a display panel DP including a display device layer DP-ED, a light control layer CCL disposed or provided on the display panel DP, and a color filter layer CFL. In one or more embodiments as illustrated in FIG. 7, the display panel DP may include a base layer BS, a circuit layer DP-CL on the base layer BS, and the display device layer DP-ED, and the display device layer DP-ED may include a light-emitting element ED.

The light-emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In one or more embodiments, the structures of the light-emitting elements ED of FIGS. 5 to 9 as described herein may be substantially equally applied to the structure of the light-emitting element ED as illustrated in FIG. 7. The light-emitting element ED as illustrated in FIG. 10 may include the polycyclic compound according to one or more embodiments. Therefore, the light-emitting element ED may exhibit high efficiency and long lifespan characteristics.

Referring to FIG. 10, the emission layer EML may be disposed or provided in an opening OH defined in a pixel defining film PDL. For example, the emission layer EML which is divided by the pixel defining film PDL and provided corresponding to each light emitting regions PXA-R, PXA-G, and PXA-B may emit light in substantially the same wavelength range. In the display device DD-a of one or more embodiments, the emission layer EML may emit blue light. In one or more embodiments, the emission layer EML may be provided as a common layer in the entire light emitting regions PXA-R, PXA-G, and PXA-B.

The light control layer CCL may be disposed or provided on the display panel DP. The light control layer CCL may include a light conversion body. The light conversion body may be a quantum dot, a phosphor, and/or the like. The light conversion body may emit provided light by converting the wavelength thereof. For example, the light control layer CCL may a layer containing the quantum dot or a layer containing the phosphor.

The light control layer CCL may include a plurality of light control parts CCP1, CCP2, and CCP3. The light control parts CCP1, CCP2, and CCP3 may be spaced and/or apart (e.g., spaced apart or separated) from each other.

Referring to FIG. 10, divided patterns BMP may be disposed or provided between the light control parts CCP1, CCP2, and CCP3 which are spaced and/or apart (e.g., spaced apart or separated) from each other, but embodiments of the present disclosure are not limited thereto. FIG. 10 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light-emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. Substantially the same as described herein may be applied with respect to the quantum dots QD1 and QD2.

In one or more embodiments, the light control layer CCL may further include a scatterer (e.g., a light scatterer) SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may be media in which the quantum dots QD1 and QD2 and the scatterer SP are dispersed and may be formed or composed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent (e.g., substantially transparent) resins. In one or more embodiments, the first base resin BR1, the second base resin BR2, and the third base resin BR3 may be substantially the same as or different from each other.

The light control layer CCL may include a barrier layer BFL1. The barrier layer BFL1 may serve to prevent the penetration of moisture and/or oxygen (or reduce a degree or occurrence of the penetration of moisture and/or oxygen) (hereinafter, referred to as ‘moisture/oxygen’). The barrier layer BFL1 may block the light control parts CCP1, CCP2, and CCP3 from being exposed to moisture/oxygen (or reduce a degree to or occurrence of which the light control parts CCP1, CCP2, and CCP3 are exposed to moisture/oxygen). In one or more embodiments, the barrier layer BFL1 may cover the light control parts CCP1, CCP2, and CCP3. In one or more embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed or composed of a single layer or a plurality of layers.

In the display device DD-a of one or more embodiments, the color filter layer CFL may be disposed or provided on the light control layer CCL. For example, the color filter layer CFL may be directly disposed or provided on the light control layer CCL. In this case, the barrier layer BFL2 may not be provided.

The color filter layer CFL may include filters CF1, CF2, and CF3. The color filter layer CFL may include a first filter CF1 configured or arranged to transmit the second color light, a second filter CF2 configured or arranged to transmit the third color light, and a third filter CF3 configured or arranged to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and/or a pigment and/or a dye. The first filter CF1 may include a red pigment and/or dye, the second filter CF2 may include a green pigment and/or dye, and the third filter CF3 may include a blue pigment and/or dye.

Embodiments of the present disclosure are not limited thereto, and the third filter CF3 may not include a pigment and/or a dye. The third filter CF3 may include a polymeric photosensitive resin and may not include a pigment and/or a dye. The third filter CF3 may be transparent (e.g., substantially transparent). The third filter CF3 may be formed or composed of a transparent (e.g., substantially transparent) photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material and/or an inorganic light shielding material containing a black pigment and/or a black dye. The light shielding part may prevent light leakage (or reduce a degree or occurrence of light leakage) and may separate boundaries between the adjacent filters CF1, CF2, and CF3.

The first to third filters CF1, CF2, and CF3 may be disposed or provided corresponding to the red light emitting region PXA-R, the green light emitting region PXA-G, and the blue light emitting region PXA-B, respectively.

A base substrate BL may be disposed or provided on the color filter layer CFL. The base substrate BL may be a member which provides a base surface in which the color filter layer CFL, the light control layer CCL, and/or the like are disposed or provided. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

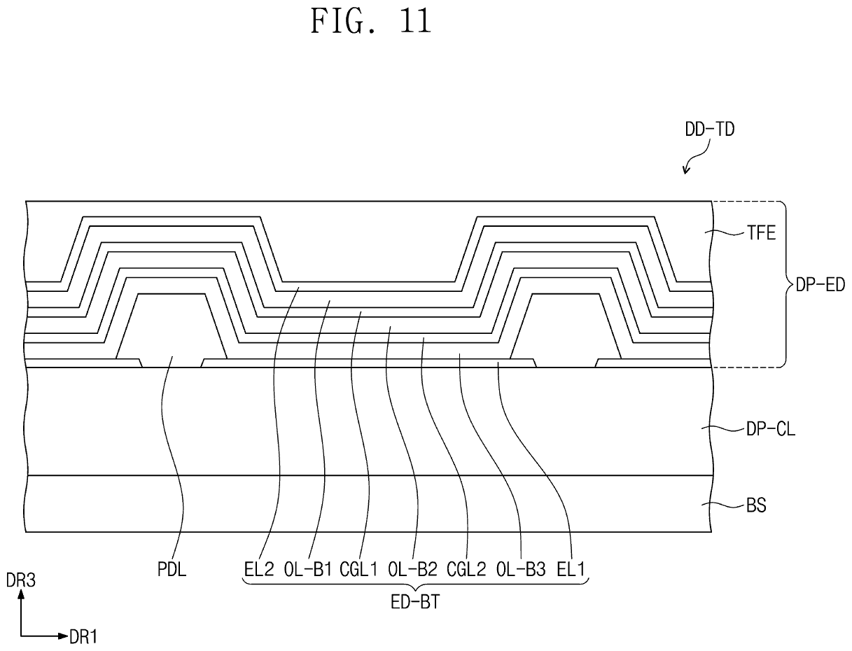

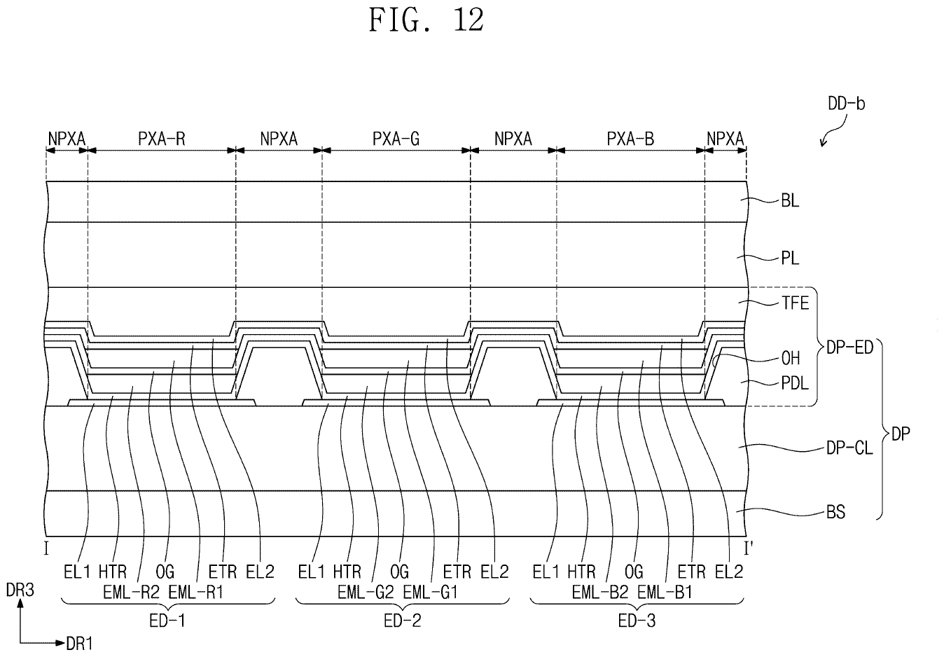

FIG. 11 is a cross-sectional view illustrating a portion of a display device according to one or more embodiments. In the display device DD-TD of one or more embodiments, the light-emitting element ED-BT may include a plurality of light emitting structures OL-B1, OL-B2, and OL-B3. At least one selected from among the plurality of emission structures OL-B1, OL-B2, and OL-B3 may include the polycyclic compound according to one or more embodiments. Therefore, the light-emitting element ED-BT may exhibit high efficiency and long lifespan characteristics.

The light-emitting element ED-BT may include a first electrode EL1 and a second electrode EL2 which are opposite to (e.g., face) each other and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 10) and a hole transport region HTR and an electron transport region ETR disposed or provided with the emission layer EML (FIG. 10) therebetween. For example, the light-emitting element ED-BT included in the display device DD-TD of one or more embodiments may be a light-emitting element having a tandem structure and including a plurality of emission layers.

In one or more embodiments as illustrated in FIG. 11, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light-emitting element ED-BT including the plurality of light emitting structures OL-B1, OL-B2, and OL-B3 which emit light beams having wavelength ranges different from each other may emit white light. Charge generation layers CGL1 and CGL2 may be respectively disposed or provided between two of the neighboring light emitting structures OL-B1, OL-B2, and OL-B3. The charge generation layers CGL1 and CGL2 may include a positive type or kind (p-type or kind) charge generation layer and/or a negative type or kind (n-type or kind) charge generation layer.

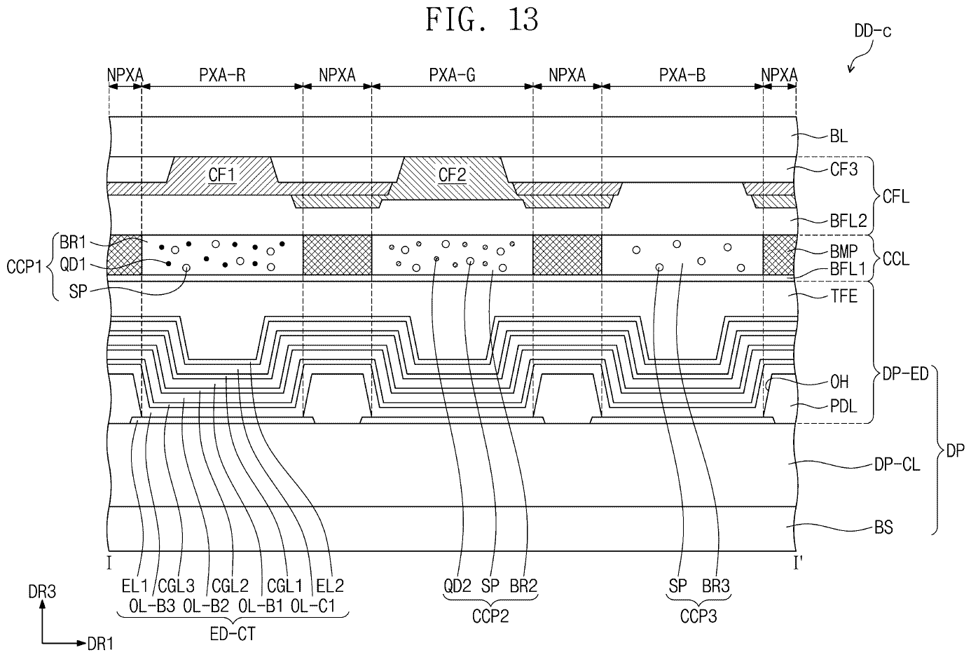

Referring to FIG. 12, the display device DD-b according to one or more embodiments may include light-emitting elements ED-1, ED-2, and ED-3 in which two emission layers are stacked. At least one selected from among the light-emitting elements ED-1, ED-2, and ED-3 may include the polycyclic compound according to one or more embodiments. Therefore, the light-emitting ED-BT may exhibit high efficiency and long lifespan characteristics.

Compared with the display device DD of one or more embodiments as illustrated in FIG. 4, one or more embodiments as illustrated in FIG. 12 may have a difference in that the first to third light-emitting elements ED-1, ED-2, and ED-3 each include two emission layers stacked in the thickness direction. In each of the first to third light-emitting elements ED-1, ED-2, and ED-3, the two emission layers may emit light in substantially the same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. In one or more embodiments, the third light-emitting element ED-3 may include a first blue emission layer EML-B1 and a second blue emission layer EML-B2.

An emission auxiliary part OG may be disposed or provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light-emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed or provided between the emission auxiliary part OG and the electron transport region ETR. The second red emission layer EML-R2, the second green emission layer EML-G2, and the second blue emission layer EML-B2 may be disposed or provided between the hole transport region HTR and the emission auxiliary part OG.

For example, the first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer PL may be disposed or provided on the display device layer DP-ED. The optical auxiliary layer PL may include a polarizing layer. The optical auxiliary layer PL may be disposed or provided on the display panel DP and control reflected light in the display panel DP due to external light. In one or more embodiments, the optical auxiliary layer PL in the display device according to one or more embodiments may not be provided.

FIG. 13 illustrates that a display device DD-c includes four light emitting structures OL-B1, OL-B2, OL-B3, and OL-C1. A light-emitting element ED-CT may include a first electrode EL1 and a second electrode EL2 which are opposite to (e.g., face) each other, and first to fourth light emitting structures OL-B1, OL-B2, OL-B3, and OL-C1 that are sequentially stacked in the thickness direction between the first electrode EL1 and the second electrode EL2. At least one selected from among the first to fourth light-emitting structures OL-B1, OL-B2, OL-B3, and OL-C1 may include the polycyclic compound according to one or more embodiments. Therefore, the light-emitting element ED-BT may exhibit high efficiency and long lifespan characteristics.

Charge generation layers CGL1, CGL2, and CGL3 may be disposed or provided between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments of the present disclosure are not limited thereto, and the first to fourth light emitting structures OL-B1, OL-B2, OL-B3, and OL-C1 may emit light beams in different wavelength regions. The charge generation layers CGL1, CGL2, and CGL3 disposed or provided between adjacent light emitting structures OL-B1, OL-B2, OL-B3, and OL-C1 may include a p-type or kind charge generation layer and/or an n-type or kind charge generation layer.

In one or more embodiments, an electronic apparatus may include a display device including a display panel which includes a plurality of light-emitting elements, and a control unit that controls the display device. The electronic apparatus according to one or more embodiments may be activated in response to an electrical signal. The electronic apparatus may include display devices of one or more embodiments. For example, the electronic apparatus may include not only large-sized electronic apparatuses, such as a television set, a monitor, or an outdoor billboard, but also include small- and medium-sized electronic apparatuses, such as a personal computer, a laptop computer, a personal digital terminal, a display device for a vehicle, a game console, a smart phone, a tablet, a smart watch, or a camera. In one or more embodiments, these are merely presented as examples, without departing from the spirit and scope of the present disclosure, the display device according to one or more embodiments may be applied to another electronic apparatus.

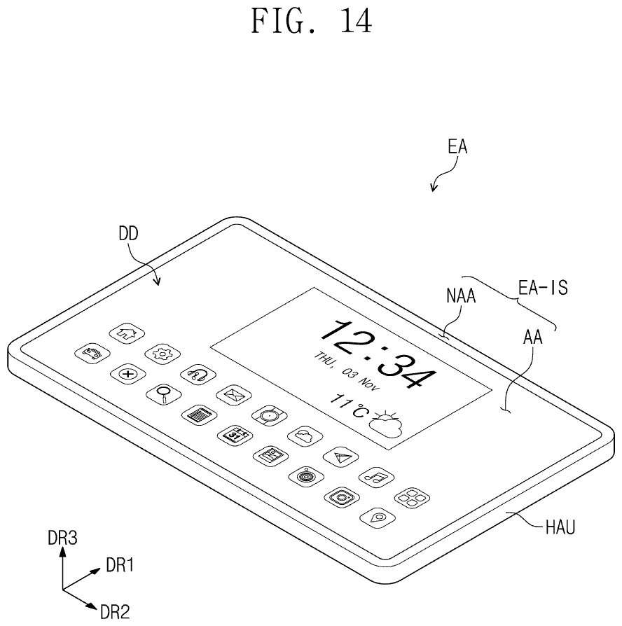

FIG. 14 illustrates a tablet terminal as an example of the electronic apparatus EA. The tablet terminal may be configured or arranged by disposing electronic modules mounted on a main board, a camera module, a power module, and/or the like in a bracket/housing HAU and/or the like together with a display device DM.

In one or more embodiments, the electronic apparatus EA including a display device DD which is equipped with a flat (e.g., substantially flat) display surface is illustrated, but embodiments of the present disclosure are not limited thereto. The electronic apparatus EA may also include a curved display surface or a three-dimensional display surface. For example, the three-dimensional display surface may include a plurality of display regions which indicate different directions and may also include a bent display surface. The electronic apparatus EA according to one or more embodiments of the present disclosure may be a flexible electronic apparatus. The flexible electronic apparatus may be a foldable electronic apparatus that may be folded.

As illustrated in FIG. 14, a display surface EA-IS may include an active region AA which displays a video and a bezel region NAA which is adjacent to the active region AA. The bezel region NAA may be a region where a video is not displayed. FIG. 13 illustrates icon images as an example of a video. The active region AA may be referred to as a display region of a display device DM, and the bezel region BAA may be referred to as a non-display region of the display device DM.

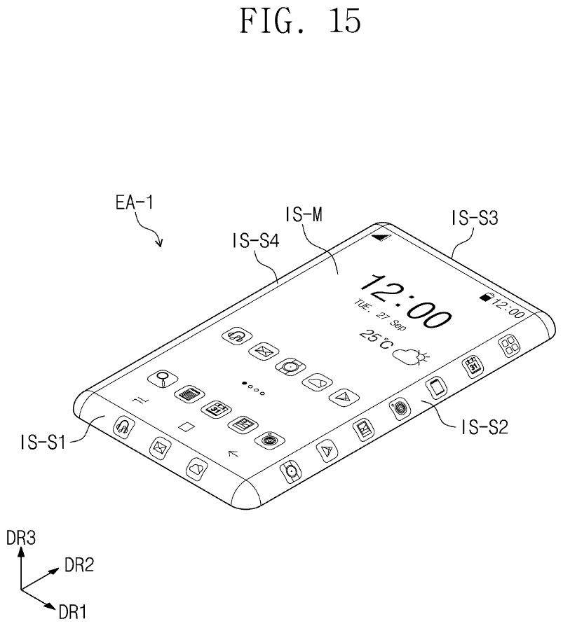

An electronic apparatus EA-1 as illustrated in FIG. 15 may include the display device according to one or more embodiments as described in more detail with reference to FIG. 3, FIG. 4, FIG. 10 to FIG. 13, and/or the like.

FIG. 15 illustrates a portable terminal as an example of an electronic apparatus EA-1 according to one or more embodiments. Referring to FIG. 15, the electronic apparatus EA-1 according to one or more embodiments may include a plurality of display surfaces. The electronic apparatus EA-1 according to one or more embodiments may include display surfaces IS-M, IS-S1, IS-S2, IS-S3, and IS-S4 which have main or predominant display directions which are different from each other.

For example, in one or more embodiments, the electronic apparatus EA-1 may be a three-dimensional display device including a top display surface IS-M and a plurality of side display surfaces IS-S1, IS-S2, IS-S3, and IS-S4. Each of the plurality of side display surfaces IS-S1, IS-S2, IS-S3, and IS-S4 may extend from one side of the top display surface IS-M. In one or more embodiments, the electronic apparatus EA-1 may include a main or predominant display surface providing an image mainly or predominantly in one direction and a plurality of sub display surfaces each providing an image in a different direction from the one direction. In the electronic apparatus EA according to one or more embodiments as illustrated in FIG. 14, the main display surface may be the top display surface IS-M, and the sub display surfaces may be the side display surfaces IS-S1, IS-S2, IS-S3, and IS-S4.

The side display surfaces IS-S1, IS-S2, IS-S3, and IS-S4 may each have a display surface which is not parallel to the top display surface IS-M. In one or more embodiments, the plurality of side display surfaces IS-S1, IS-S2, IS-S3, and IS-S4 may each be a display region that is bent and extended from one side of the top display surface IS-M, and, for example, the plurality of side display surfaces IS-S1, IS-S2, IS-S3, and IS-S4 may each be a bent display region.

The electronic apparatus EA as illustrated in FIG. 15 may include the display device according to one or more embodiments as described in more detail with reference to FIG. 3, FIG. 4, FIG. 10 to FIG. 13, and/or the like.

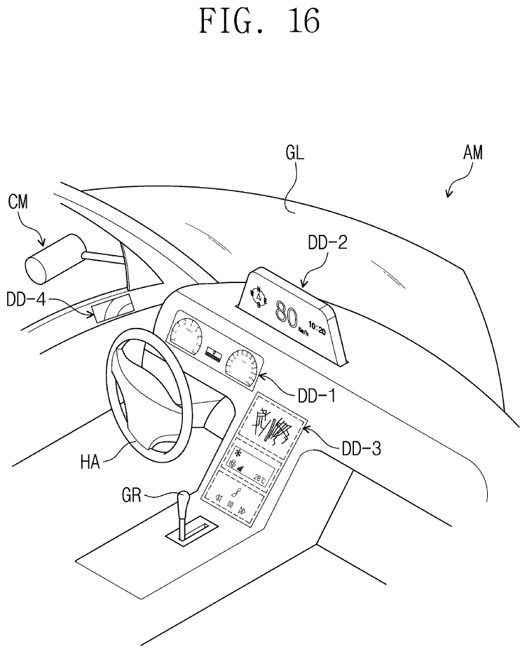

FIG. 16 is a view illustrating a vehicle AM in which first to fourth display devices DD-1, DD-2, DD-3, and DD-4 are disposed or provided. At least one selected from among the first to fourth display devices DD-1, DD-2, DD-3, and DD-4 may include substantially the same configuration or arrangement as the display devices DD, DD-TD, DD-a, DD-b, and DD-c as described in more detail with reference to FIGS. 3, and 4, and 8 to 13.

FIG. 16 illustrates a vehicle AM, but this is an example, and the first to fourth display devices DD-1, DD-2, DD-3, and DD-4 may be disposed or provided in another transportation means, such as bicycles, motorcycles, trains, ships, and airplanes. In one or more embodiments, at least one selected from among the first to fourth display devices DD-1, DD-2, DD-3, and DD-4 including substantially the same configuration or arrangement as the display devices DD, DD-TD, DD-a, DD-b, and DD-c of one or more embodiments may be employed in a personal computer, a laptop computer, a personal digital terminal, a game console, a portable electronic apparatus, a television, a monitor, an outdoor billboard, and/or the like. In one or more embodiments, these are merely provided as examples, and thus may be employed in other electronic apparatuses unless departing from the scope of the present disclosure.

At least one selected from among the first to fourth display devices DD-1, DD-2, DD-3, and DD-4 may include the light-emitting element ED of one or more embodiments as described in more detail with reference to FIGS. 5 to 9. At least one selected from among the first to fourth display devices DD-1, DD-2, DD-3, and DD-4 may include the polycyclic compound according to one or more embodiments. Therefore, the first to fourth display devices DD-1, DD-2, DD-3, and DD-4 each including the polycyclic compound according to one or more embodiments may have improved or enhanced display efficiency and display lifespan.

Referring to FIG. 16, the vehicle AM may include a steering wheel HA and a gear GR to drive the vehicle AM. In one or more embodiments, the vehicle AM may include a front window GL disposed or provided so as to be opposite to (e.g., face) the driver.

The first display device DD-1 may be disposed or provided in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (for example, revolutions per minute (RPM)), an image which indicates a fuel state, and/or the like. A first scale and a second scale may be indicated as a digital image.

The second display device DD-2 may be disposed or provided in a second region being opposite to (e.g., facing) the driver's seat and overlapping the front window GL. The driver's seat may be a seat in which the steering wheel HA is disposed or provided. For example, the second display device DD-2 may be a head up display (HUD) which displays second information of the vehicle AM. The second display device DD-2 may be optically transparent (e.g., substantially transparent). The second information may include digital numbers which indicate a driving speed and may further include information, such as the current time. In one or more embodiments, the second information of the second display device DD-2 may be projected to the front window GL to be displayed.

The third display device DD-3 may be disposed or provided in a third region adjacent to the gear GR. For example, the third display device DD-3 may be disposed or provided between the driver's seat and the passenger seat and may be a center information display (CID) for a vehicle AM to display third information. The passenger seat may be a seat spaced and/or apart (e.g., spaced apart or separated) from the driver's seat with the gear GR disposed or provided therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR and may be disposed or provided in a fourth region adjacent to the side of the vehicle AM. For example, the fourth display device DD-4 may be a digital side-view mirror which displays fourth information. The fourth display device DD-4 may display an image outside the vehicle AM taken by a camera module CM disposed or provided outside the vehicle AM. The fourth information may include an image outside the vehicle AM.

The first to fourth information as described in one or more embodiments may be examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include substantially the same information as one another.

Hereinafter, with reference to Examples and Comparative Examples, the polycyclic compound according to one or more embodiments of the present disclosure and the light-emitting element according to one or more embodiments will be described in more detail. However, these embodiments are examples, and embodiments of the present disclosure are not limited thereto.

### EXAMPLES

### 1. Synthesis of Polycyclic Compound

A synthetic method of the polycyclic compounds according to one embodiment will be described in more detail by exemplifying the synthetic methods of Compounds B-17, C-18, C-26, H-1, and H-2. Also, the synthetic methods of the polycyclic compounds described hereinafter are examples, and the synthetic method of the compound according to one or more embodiments of the present disclosure is not limited to the embodiments.

### 1) Synthesis of Intermediate a

Intermediate a may be synthesized by, for example, methods in Reaction Scheme A.

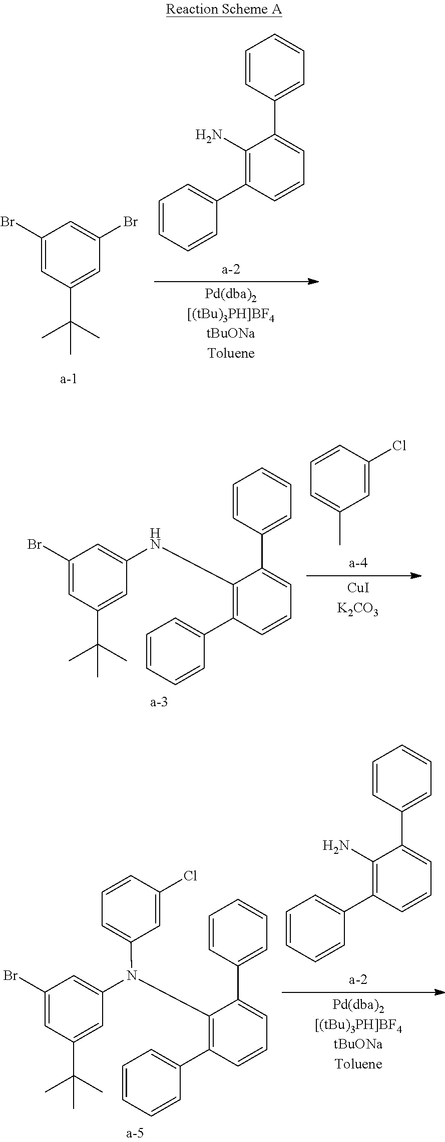

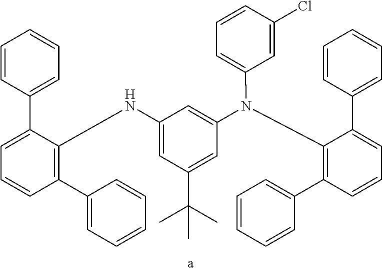 [SMILES: CC(C)(C)c1cc(Nc2c(-c3ccccc3)cccc2-c2ccccc2)cc(N(c2cccc(Cl)c2)c2c(-c3ccccc3)cccc2-c2ccccc2)c1]

Intermediate a-1 (300 mmol), Intermediate a-2 (150 mmol), tBuONa (600 mmol), Pd(dba)₂ (15 mmol), and [(tBu)₃PH]BF₄ (30 mmol) were put into a three-necked flask, the flask was purged with argon (Ar), then toluene of about 1000 mL was added, and then the resultant mixture was stirred at about 60° C. for about 8 hours. Water was added to the reaction vessel, and an organic layer was extracted using toluene, and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 131 mmol (yield of about 87%). The obtained purified product was identified to have a molecular weight of 456 g/mol through fast atom bombardment mass spectrometry (FABMS) measurement, and thus obtaining Intermediate a-3 was confirmed.

Thereafter, Intermediate a-3 (131 mmol), Intermediate a-4 (1290 mmol), K₂CO₃ (645 mmol), and CuI (141 mmol) were put into a three-necked flask, the flask was purged with argon, and then the resultant mixture was stirred at about 210° C. for about 24 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 112 mmol (yield of about 85%). The obtained purified product was identified to have a molecular weight of 567 g/mol through FABMS measurement, and thus obtaining Intermediate a-5 was confirmed.

Next, Intermediate a-5 (112 mmol), Intermediate a-2 (120 mmol), tBuONa (336 mmol), Pd(dba)₂ (11 mmol), and [(tBu)₃PH]BF₄ (22 mmol) were put into a three-necked flask, the flask was purged with argon, toluene of 1000 mL was added and then the mixture was stirred at about 100° C. for about 2 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 131 mmol (yield of about 87%). The obtained purified product was identified to have a molecular weight of 731 g/mol through FABMS measurement, and thus obtaining Intermediate a was confirmed.

### 2) Synthesis of Intermediate b

Intermediate b may be synthesized by, for example, methods in Reaction Scheme B.

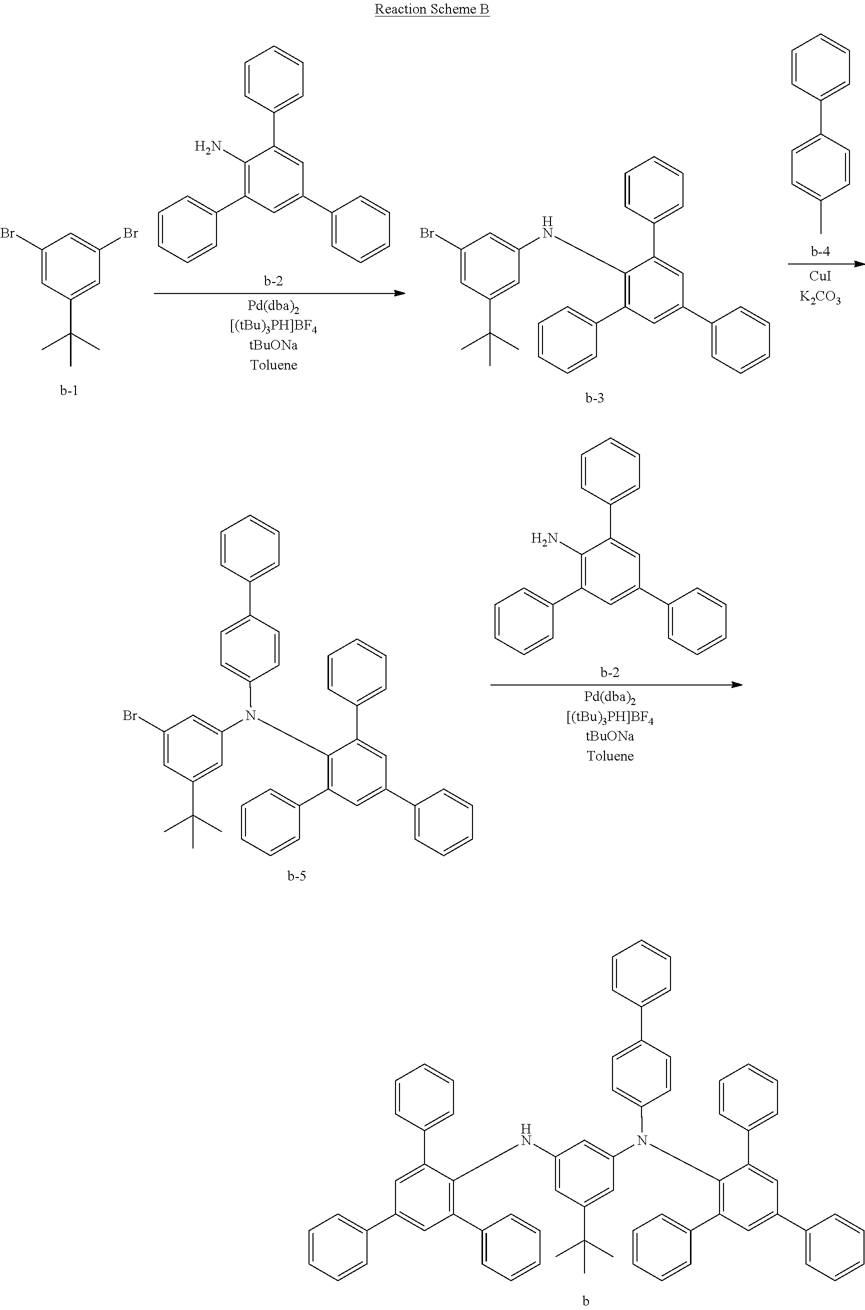

Intermediate b-1 (300 mmol), Intermediate b-2 (150 mmol), tBuONa (600 mmol), Pd(dba)₂ (15 mmol), and [(tBu)₃PH]BF₄ (30 mmol) were put into a three-necked flask, the flask was purged with argon, then toluene of about 1000 mL was added, and then the resultant mixture was stirred at about 70° C. for about 5 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 104 mmol (yield of about 69%). The obtained purified product was identified to have a molecular weight of 532 g/mol through FABMS measurement, and thus obtaining Intermediate b-3 was confirmed.

Next, Intermediate b-3 (104 mmol), Intermediate b-4 (1040 mmol), K₂CO₃ (520 mmol), and CuI (104 mmol) were put into a three-necked flask, the flask was purged with argon, and then the resultant mixture was stirred at about 210° C. for about 54 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 98 mmol (yield of about 94%). The obtained purified product was identified to have a molecular weight of 685 g/mol, through FABMS measurement, and thus obtaining Intermediate b-5 was confirmed.

Thereafter, Intermediate b-5 (98 mmol), Intermediate b-2 (104 mmol), tBuONa (300 mmol), Pd(dba)₂ (10 mmol), and [(tBu)₃PH]BF₄ (20 mmol) were put into a three-necked flask, the flask was purged with argon, then toluene of about 800 mL was added and the resultant mixture was stirred at about 100° C. for about 3 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 90 mmol (yield of about 92%). The obtained purified product was identified to have a molecular weight of 925 g/mol through FABMS measurement, and thus obtaining Intermediate b was confirmed.

### 3) Synthesis of Intermediate c

Intermediate c may be synthesized by, for example, methods in Reaction Scheme C.

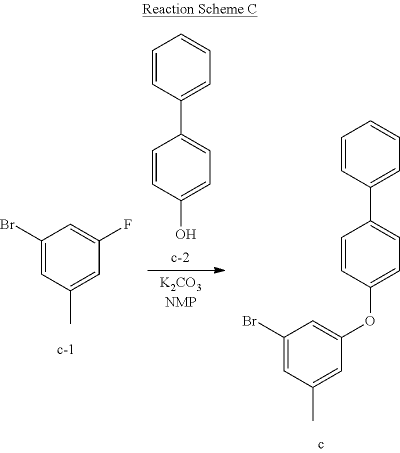

Intermediate c-1 (200 mmol), Intermediate c-2 (220 mmol), and K₂CO₃ (600 mmol) were put into a three-necked flask, the flask was purged with argon, then 1-methyl-2-pyrrolidinone (NMP) of 200 mL was added, and then the resultant mixture was stirred at about 150° C. for about 24 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 154 mmol (yield of about 77%). The obtained purified product was identified to have a molecular weight of 390 g/mol through FABMS measurement, and thus obtaining Intermediate c was confirmed.

### 4) Synthesis of Intermediate d

Intermediate d may be synthesized by, for example, methods in Reaction Scheme D.

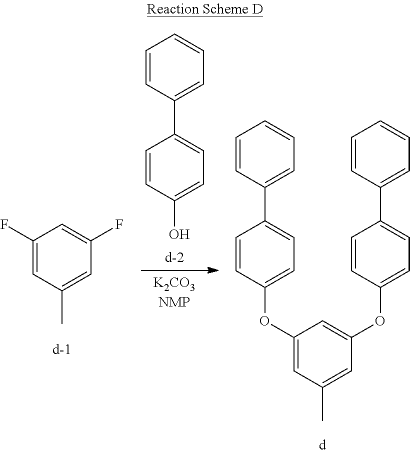

Intermediate d-1 (200 mmol), Intermediate d-2 (440 mmol), and K₂CO₃ (600 mmol) were put into a three-necked flask, the flask was purged with argon, then NMP of 200 mL was added, and then the mixture was stirred at about 150° C. for about 32 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 125 mmol (yield of about 63%). The obtained purified product was identified to have a molecular weight of 540 g/mol, through FABMS measurement, and thus obtaining Intermediate d was confirmed.

### 5) Synthesis of Compound B-17

Compound B-17 according to one embodiment may be synthesized by, for example, methods in Reaction Scheme 1.

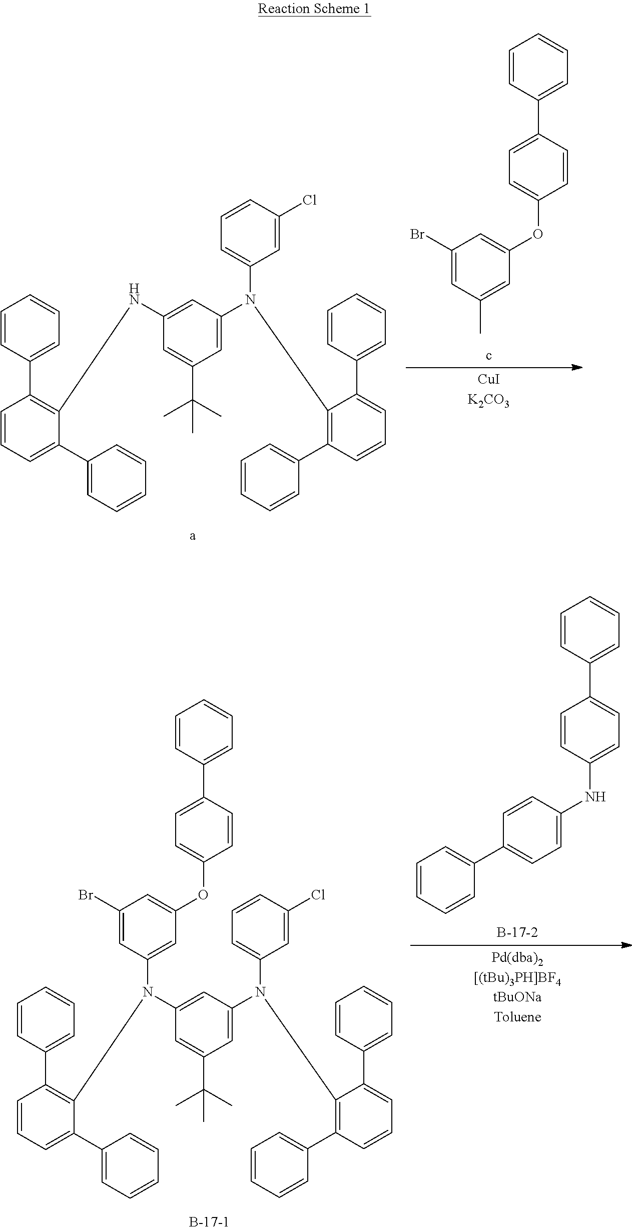 [SMILES: CC(C)(C)c1cc(Nc2c(-c3ccccc3)cccc2-c2ccccc2)cc(N(c2cccc(Cl)c2)c2c(-c3ccccc3)cccc2-c2ccccc2)c1 ; Cc1cc(Br)cc(Oc2ccc(-c3ccccc3)cc2)c1 ; CC(C)(C)c1cc(N(c2cccc(Cl)c2)c2c(-c3ccccc3)cccc2-c2ccccc2)cc(N(c2cc(Br)cc(Oc3ccc(-c4ccccc4)cc3)c2)c2c(-c3ccccc3)cccc2-c2ccccc2)c1 ; c1ccc(-c2ccc(Nc3ccc(-c4ccccc4)cc3)cc2)cc1]

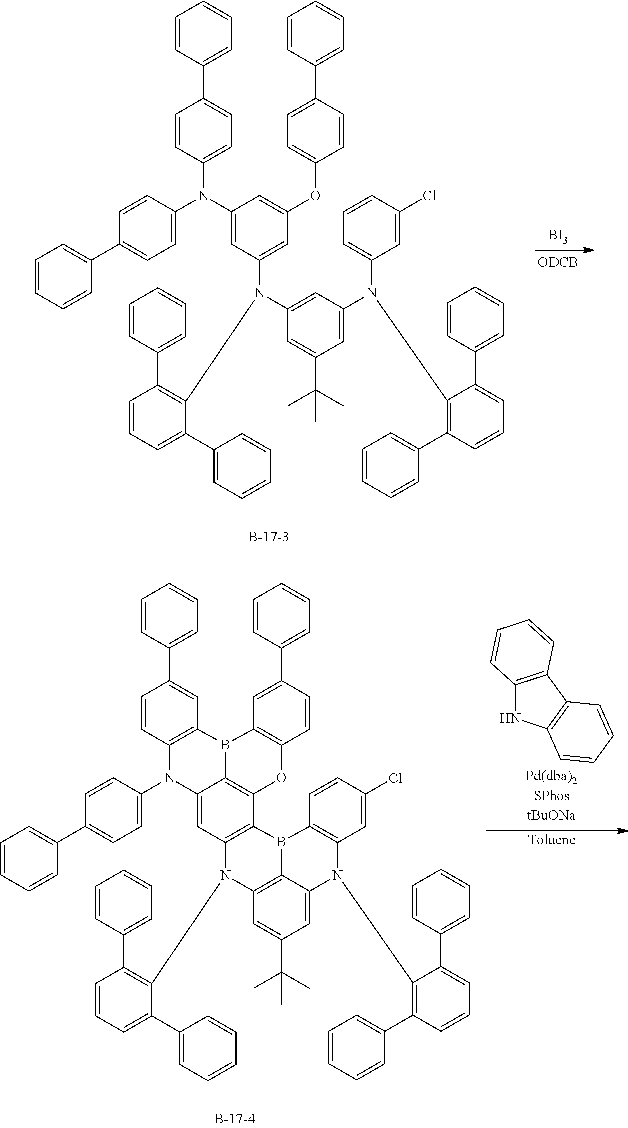

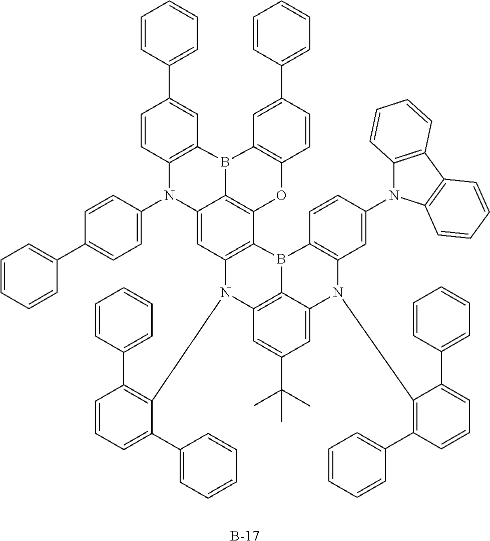

Intermediate a (131 mmol), Intermediate c (1310 mmol), K₂CO₃ (655 mmol), and CuI (131 mmol) were put into a three-necked flask, the flask was purged with argon, and then the resultant mixture was stirred at about 200° C. for about 55 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 116 mmol (yield of about 89%). The obtained purified product was identified to have a molecular weight of 1055 g/mol, through FABMS measurement, and thus obtaining Intermediate B-17-1 was confirmed.

Thereafter, Intermediate B-17-1 (116 mmol), Intermediate B-17-2 (120 mmol), tBuONa (348 mmol), Pd(dba)₂ (12 mmol), and [(tBu)₃PH]BF₄ (24 mmol) were put into a three-necked flask, the flask was purged with argon, then toluene of 600 mL was added and then the resultant mixture was stirred at about 80° C. for about 8 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 101 mmol (yield of about 87%). The obtained purified product was identified to have a molecular weight of 1295 g/mol, through FABMS measurement, and thus obtaining Intermediate B-17-3 was confirmed.

Next, Intermediate B-17-3 (101 mmol) was put into a three-necked flask, the flask was purged with argon, then the Intermediate B-17-3 was dissolved by adding ortho-dichlorobenzene (ODCB) of 50 mL, then boron triiodide (BI₃) (404 mmol) was added, and the resultant mixture was stirred at about 140° C. for about 3 hours. The reaction mixture was washed and dispersed using a large amount of acetonitrile, and then the solid was collected by filtration. The obtained crude product was purified through silica gel column chromatography (a mixed solvent of hexane/toluene) and recrystallization (a mixed solvent of ethanol/toluene) to obtain yellow solids of about 56 mmol (yield of about 55%). The obtained purified product was identified to have a molecular weight of 1311 g/mol through FABMS measurement, and thus obtaining Intermediate B-17-4 was confirmed.

Thereafter, Intermediate B-17-4 (56 mmol), carbazole (112 mmol), Pd(dba)₂ (6 mmol), SPhos (12 mmol), and tBuONa (168 mmol) were put into a three-necked flask, the flask was purged with argon, then toluene of 50 mL was added and then the resultant mixture was stirred at about 110° C. for about 8 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 43 mmol (yield of about 77%). The obtained purified product was identified to have a molecular weight of 1441 g/mol through FABMS measurement, and thus obtaining Compound B-17 was confirmed.

### 6) Synthesis of Compound C-18

Compound C-18 according to one embodiment may be synthesized by, for example, methods in Reaction Scheme 2.

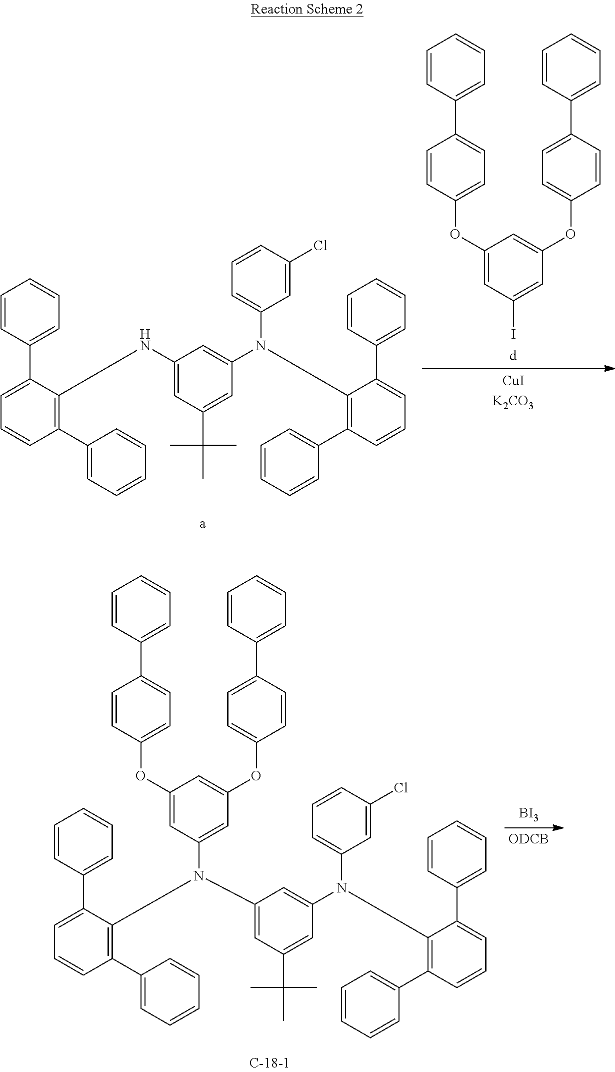

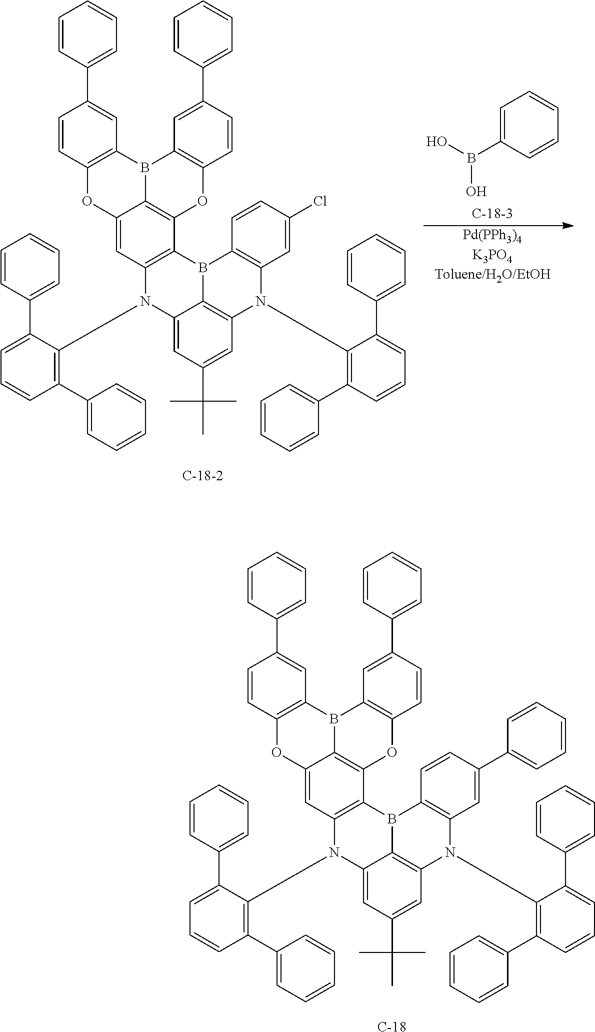

Intermediate a (131 mmol), Intermediate d (1310 mmol), K₂CO₃ (655 mmol), and CuI (131 mmol) were put into a three-necked flask, the flask was purged with argon, and then the resultant mixture was stirred at about 200° C. for about 25 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 95 mmol (yield of about 72%). The obtained purified product was identified to have a molecular weight of 1144 g/mol through FABMS measurement, and thus obtaining Intermediate C-18-1 was confirmed.

Next, Intermediate C-18-1 (95 mmol) was put into a three-necked flask, the flask was purged with argon, then the obtained was dissolved by adding ODCB of 30 mL, then BI₃ (380 mmol) was added, and the resultant mixture was stirred at about 140° C. for about 1 hour. The reaction mixture was washed and dispersed using a large amount of acetonitrile, and then the solid was collected by filtration. The obtained crude product was purified through silica gel column chromatography (a mixed solvent of hexane/toluene) and recrystallization (a mixed solvent of ethanol/toluene) to obtain yellow solids of about 59 mmol (yield of about 62%). The obtained purified product was identified to have a molecular weight of 1159 g/mol through FABMS measurement, and thus obtaining Intermediate C-18-2 was confirmed.

Thereafter, Intermediate C-18-2 (59 mmol), Intermediate C-18-3 (1310 mmol), K₃PO₄ (1310 mmol), and Pd(PPh₃)₄ (6 mmol) were put into a three-necked flask, the flask was purged with argon, then the resultant mixture was dissolved in toluene 400 mL, H₂O 50 mL, and EtOH 25 mL and then was stirred at about 110° C. for about 2 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain yellow solids of about 49 mmol (yield of about 83%). The obtained purified product was identified to have a molecular weight of 1201 g/mol through FABMS measurement, and thus obtaining Compound C-18 was confirmed.

### 7) Synthesis of Compound C-26

Compound C-26 according to one embodiment may be synthesized by, for example, methods in Reaction Scheme 3.

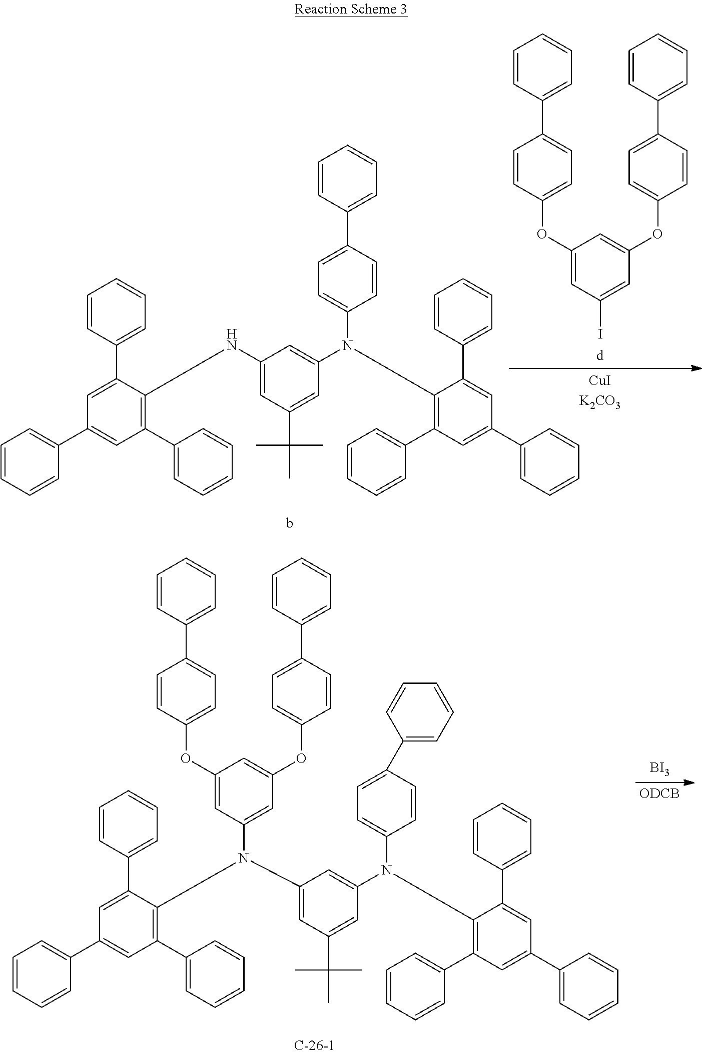 [SMILES: CC(C)(C)c1cc(Nc2c(-c3ccccc3)cc(-c3ccccc3)cc2-c2ccccc2)cc(N(c2ccc(-c3ccccc3)cc2)c2c(-c3ccccc3)cc(-c3ccccc3)cc2-c2ccccc2)c1 ; Ic1cc(Oc2ccc(-c3ccccc3)cc2)cc(Oc2ccc(-c3ccccc3)cc2)c1 ; CC(C)(C)c1cc(N(c2ccc(-c3ccccc3)cc2)c2c(-c3ccccc3)cc(-c3ccccc3)cc2-c2ccccc2)cc(N(c2cc(Oc3ccc(-c4ccccc4)cc3)cc(Oc3ccc(-c4ccccc4)cc3)c2)c2c(-c3ccccc3)cc(-c3ccccc3)cc2-c2ccccc2)c1 ; "ODCB" ; "BI3"]

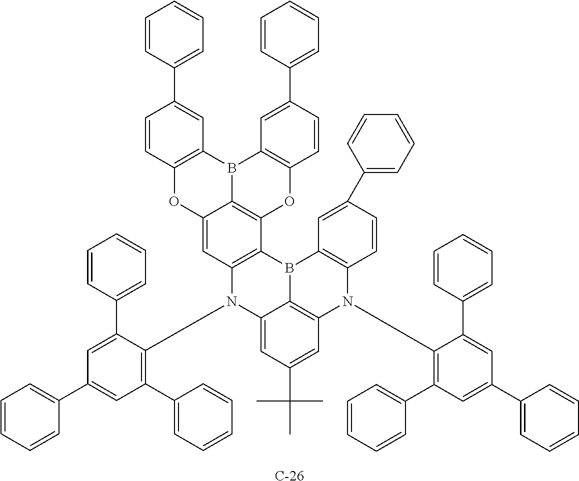

Intermediate b (90 mmol), Intermediate d (900 mmol), K₂CO₃ (450 mmol), and CuI (90 mmol) were put into a three-necked flask, the flask was purged with argon, and then the resultant mixture was stirred at about 200° C. for about 24 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 75 mmol (yield of about 83%). The obtained purified product was identified to have a molecular weight of 1338 g/mol through FABMS measurement, and thus obtaining Intermediate C-26-1 was confirmed.

Thereafter, Intermediate C-26-1 was put into a three-necked flask, the flask was purged with argon, then the obtained was dissolved by adding ODCB of 30 mL, then BI₃ (380 mmol) was added, and the resultant mixture was stirred at about 140° C. for about 2 hours. The reaction mixture was washed and dispersed using a large amount of acetonitrile, and then the solid was collected by filtration. The obtained crude product was purified through silica gel column chromatography (a mixed solvent of hexane/toluene) and recrystallization (a mixed solvent of ethanol/toluene) to obtain yellow solids of about 25 mmol (yield of about 33%). The obtained purified product was identified to have a molecular weight of 1353 g/mol through FABMS measurement, and thus obtaining Intermediate C-26 was confirmed.

### 8) Synthesis of Compound H-1

Compound H-1 according to one embodiment may be synthesized by, for example, methods in Reaction Scheme 4.

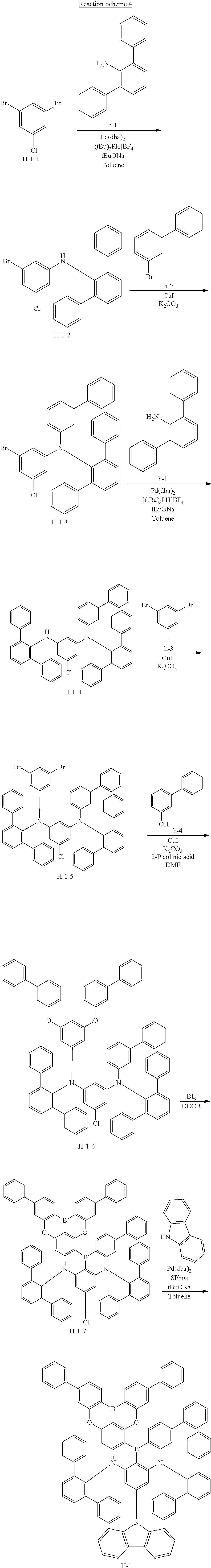

Intermediate H-1-1 (300 mmol), Intermediate h-1 (150 mmol), tBuONa (600 mmol), Pd(dba)₂ (15 mmol), and (tBu)₃PH]BF₄ (30 mmol) were put into a three-necked flask, the flask was purged with argon, toluene of 1000 mL was added and then the mixture was stirred at about 60° C. for about 12 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 120 mmol (yield of about 40%). The obtained purified product of the white solids was identified to have a molecular weight of 435 g/mol through FABMS measurement and thus obtaining Intermediate H-1-2 was confirmed.

Subsequently, Intermediate H-1-2 (120 mmol), Intermediate h-2 (1200 mmol), K₂CO₃ (1200 mmol), and CuI (120 mmol) were put into a three-necked flask, the flask was purged with argon (Ar), then the mixture was stirred at about 210° C. for about 65 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 105 mmol (yield of about 88%). The obtained purified product was identified to have a molecular weight of 587 g/mol through FABMS measurement, and thus obtaining Intermediate H-1-3 was confirmed.

Intermediate H-1-3 (105 mmol), Intermediate h-1 (120 mmol), tBuONa (240 mmol), Pd(dba)₂ (10 mmol), and [(tBu)₃PH]BF₄ (22 mmol) were put into a three-necked flask, the flask was purged with argon (Ar), toluene of 300 mL was added and then the resultant mixture was stirred at about 90° C. for about 6 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 94 mmol (yield of about 89%). The obtained purified product of the white solids was identified to have a molecular weight of 751 g/mol through FABMS measurement, and thus obtaining Intermediate H-1-4 was confirmed.

Subsequently, Intermediate H-1-4 (94 mmol), Intermediate h-3 (940 mmol), K₂CO₃ (940 mmol), and CuI (94 mmol) were put into a three-necked flask, the flask was purged with argon (Ar), then the resultant mixture was stirred at about 210° C. for about 24 hours. Water was added to the reaction vessel, an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 74 mmol (yield of about 79%). The obtained purified product of the white solids was identified to have a molecular weight of 985 g/mol through FABMS measurement, and thus obtaining Intermediate H-1-5 was confirmed.

Intermediate H-1-5 (74 mmol), Intermediate h-4 (222 mmol), K₂CO₃ (222 mmol), CuI (74 mmol), and dimethylformamide (DMF, 300 mL) were put into a three-necked flask, the flask was purged with Ar, then the resultant mixture was stirred at about 160° C. for about 54 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 54 mmol (yield of about 73%). The obtained purified product of the white solids was identified to have a molecular weight of 1164 g/mol through FABMS measurement and thus obtaining Intermediate H-1-6 was confirmed.

Intermediate H-1-6 (54 mmol) was put into a three-necked flask, the flask was purged with argon (Ar), then the obtained was dissolved by adding ODCB of 50 mL, then BI₃ (216 mmol) was added, and the resultant mixture was stirred at about 140° C. for about 3 hours. The reaction mixture was washed and dispersed using a large amount of acetonitrile, and then the solid was collected by filtration. The obtained crude product was purified through silica gel column chromatography (a mixed solvent of hexane/toluene) and recrystallization (a mixed solvent of ethanol/toluene) to obtain yellow solids of about 38 mmol (yield of about 70%). The obtained purified product of the yellow solids was identified to have a molecular weight of 1179 g/mol through FABMS measurement, and thus obtaining Intermediate H-1-7 was confirmed.

Intermediate H-1-7 (38 mmol), carbazole (57 mmol), Pd(dba)₂ (6 mmol), SPhos (12 mmol), and tBuONa (168 mmol) were put into a three-necked flask, the flask was purged with argon (Ar), then toluene of 50 mL was added and then the resultant mixture was stirred at about 110° C. for about 8 hours. Water was added to the reaction vessel, an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain yellow solids of about 30 mmol (yield of about 78%). The obtained purified product of the yellow solids was identified to have a molecular weight of 1310 g/mol through FABMS measurement, and thus obtaining Compound H-1 was confirmed.

### 9) Synthesis of Compound H-2

Compound H-2 according to one embodiment may be synthesized by, for example, methods in Reaction Scheme 5.

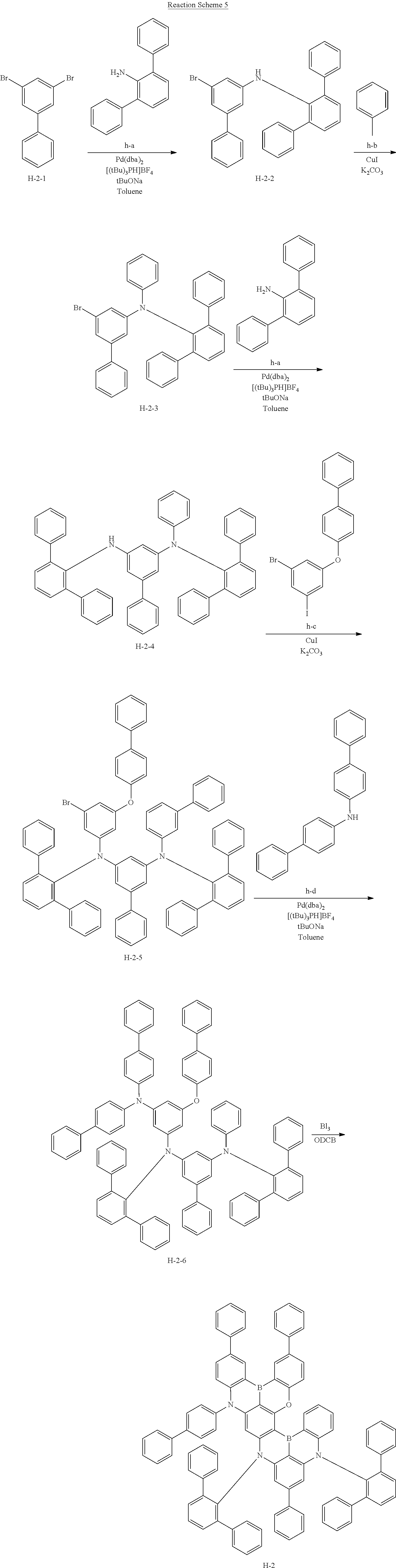

Intermediate H-2-1 (300 mmol), Intermediate h-a (150 mmol), tBuONa (600 mmol), Pd(dba)₂ (15 mmol), and [(tBu)₃PH]BF₄ (30 mmol) were put into a three-necked flask, the flask was purged with argon (Ar), then toluene of 1000 mL was added and then the resultant mixture was stirred at about 60° C. for about 24 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 160 mmol (yield of about 53%). The obtained purified product of the white solids was identified to have a molecular weight of 477 g/mol through FABMS measurement, and thus obtaining Compound H-2-2 was confirmed.

Subsequently, Intermediate H-2-2 (160 mmol), Intermediate h-b (1600 mmol), K₂CO₃ (1600 mmol), and CuI (160 mmol) were put into a three-necked flask, the flask was purged with argon (Ar), and then the resultant mixture was stirred at about 210° C. for about 24 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 151 mmol (yield of about 94%). The obtained purified product of the white solids was identified to have a molecular weight of 553 g/mol through FABMS measurement, and thus obtaining Intermediate H-2-3 was confirmed.

Intermediate H-2-3 (300 mmol), (151 mmol), Intermediate h-a (200 mmol), tBuONa (300 mmol), Pd(dba)₂ (10 mmol), and [(tBu)₃PH]BF₄ (22 mmol) were put into a three-necked flask, the flask was purged with argon (Ar), then toluene of 300 mL was added and then the resultant mixture was stirred at about 90° C. for about 9 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 130 mmol (yield of about 86%). The obtained purified product of the white solids was identified to have a molecular weight of 717 g/mol through FABMS measurement, and thus obtaining Compound H-2-4 was confirmed.

Subsequently, Intermediate H-2-4 (130 mmol), Intermediate h-c (1300 mmol), K₂CO₃ (1300 mmol), and CuI (130 mmol) were put into a three-necked flask, the flask was purged with argon (Ar), and then the mixture was stirred at about 210° C. for about 30 hours. Water was added to the reaction vessel, and an organic layer was extracted using toluene and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 111 mmol (yield of about 85%). The obtained purified product of the white solids was identified to have a molecular weight of 1116 g/mol through FABMS measurement, and thus obtaining Compound H-2-5 was confirmed.

Intermediate H-2-5 (111 mmol), Intermediate h-d (200 mmol), tBuONa (600 mmol), Pd(dba)₂ (15 mmol), and [(tBu)₃PH]BF₄ (30 mmol) were put into a three-necked flask, the flask was purged with argon (Ar), then toluene of 200 mL was added and then the resultant mixture was stirred at about 90° C. for about 24 hours. Water was added to the reaction vessel, and an organic layer was extracted using toluene, and then was dried over magnesium sulfate to remove a solvent by evaporation. The obtained crude product was purified through silica gel column chromatography (a mixed solvent of hexane/toluene) and recrystallization (a mixed solvent of ethanol/toluene) to obtain white solids of about 105 mmol (yield of about 95%). The obtained purified product of the white solids was identified to have a molecular weight of 1281 g/mol through FABMS measurement, and thus obtaining Compound H-2-6 was confirmed.

Intermediate H-2-6 (105 mmol) was put into a three-necked flask, the flask was purged with argon (Ar), then the obtained was dissolved by adding ODCB of 50 mL, then BI₃ (420 mmol) was added, and the resultant mixture was stirred at about 140° C. for about 2 hours. The reaction mixture was washed and dispersed using a large amount of acetonitrile, and then the solid was collected by filtration. The obtained crude product was purified through silica gel column chromatography (a mixed solvent of hexane/toluene) and recrystallization (a mixed solvent of ethanol/toluene) to obtain yellow solids of about 55 mmol (yield of about 52%). The obtained purified product of yellow solids was identified to have a molecular weight of 1296 g/mol through FABMS measurement, and thus obtaining Compound H-2 was confirmed.

### 2. Evaluation of Fluorescence Light-Emitting Characteristics of Compound

The fluorescence light-emitting characteristics of the polycyclic compounds according to Examples and Comparative Example Compounds were evaluated and the evaluated results are listed in Table 1. For evaluating light-emitting characteristics, a fluorescence light-emitting spectrum of a 20 wt % doped film which is generated by deposition onto quartz glass using PPF as a matrix was measured using a JASCO V-670 spectrometer. A fluorescent quantum yield was measured using a JASCOILF-835 integrating sphere system.

Compounds used in evaluation of fluorescence light-emitting characteristics

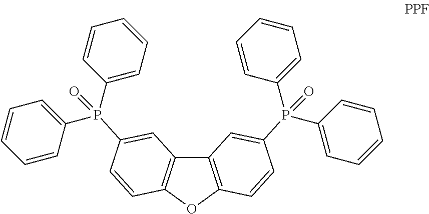 [SMILES: O=P(c1ccccc1)(c1ccccc1)c1ccc2oc3ccc(P(=O)(c4ccccc4)c4ccccc4)cc3c2c1]

### Example Compounds

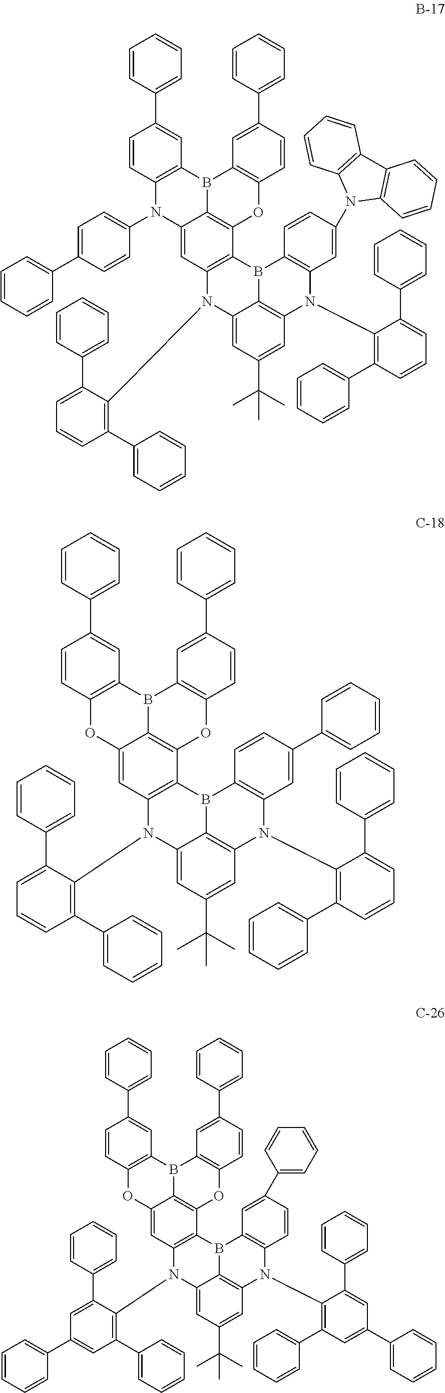

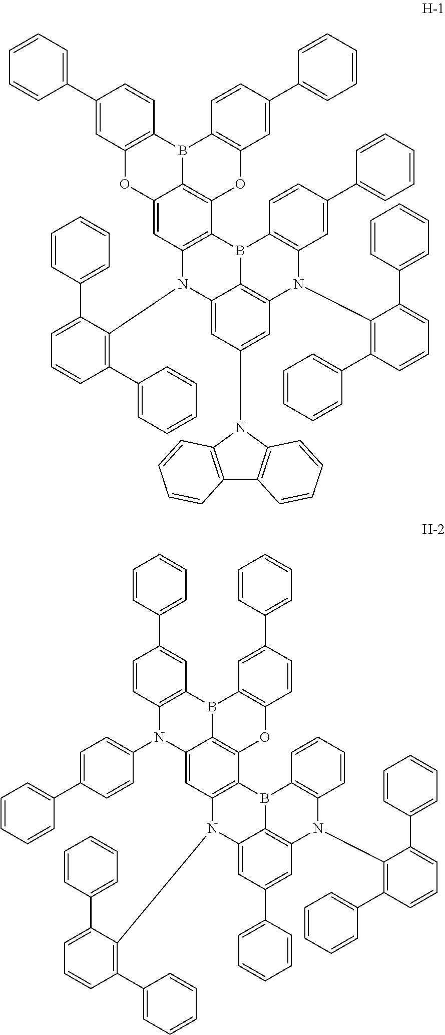 [SMILES: c1ccc(-c2ccc3c(c2)Oc2cc4c(c5c2B3c2ccc(-c3ccccc3)cc2O5)B2c3ccc(-c5ccccc5)cc3N(c3c(-c5ccccc5)cccc3-c3ccccc3)c3cc(-n5c6ccccc6c6ccccc65)cc(c32)N4c2c(-c3ccccc3)cccc2-c2ccccc2)cc1 ; c1ccc(-c2ccc(N3c4ccc(-c5ccccc5)cc4B4c5cc(-c6ccccc6)ccc5Oc5c4c3cc3c5B4c5ccccc5N(c5c(-c6ccccc6)cccc5-c5ccccc5)c5cc(-c6ccccc6)cc(c54)N3c3c(-c4ccccc4)cccc3-c3ccccc3)cc2)cc1]

### Comparative Example Compounds

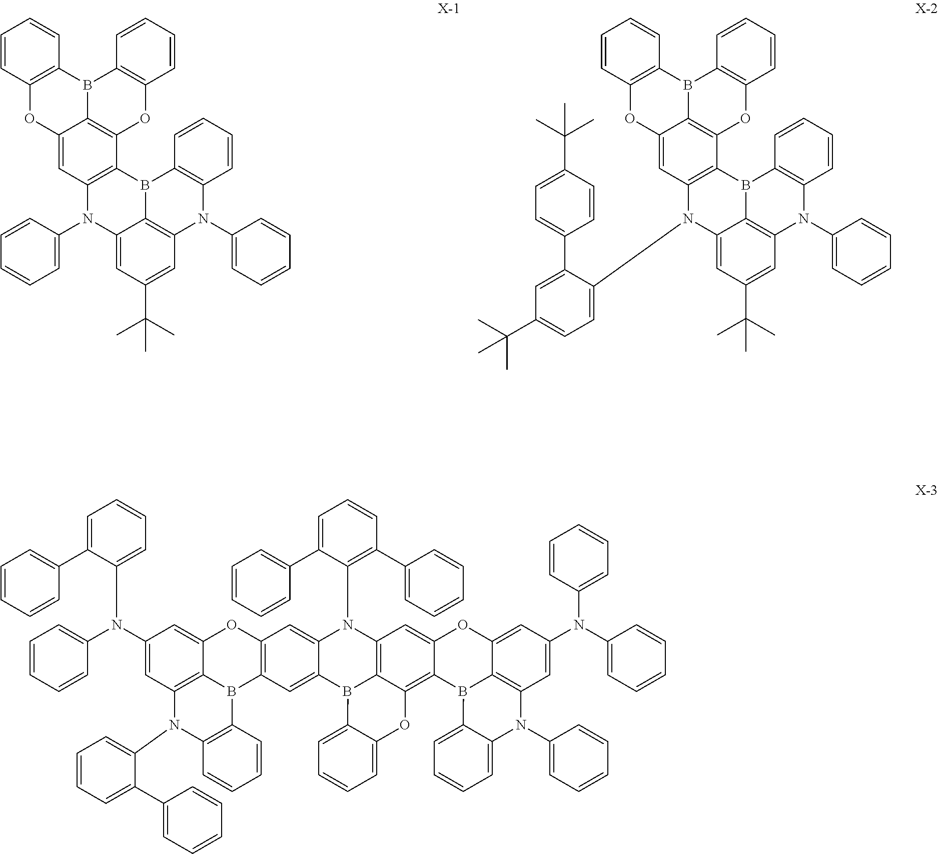 [SMILES: CC(C)(C)c1cc2c3c(c1)N(c1ccccc1)c1cc4c5c(c1B3c1ccccc1N2c1ccccc1)Oc1ccccc1B5c1ccccc1O4 ; CC(C)(C)c1ccc(-c2cc(C(C)(C)C)ccc2N2c3cc(C(C)(C)C)cc4c3B(c3ccccc3N4c3ccccc3)c3c2cc2c4c3Oc3ccccc3B4c3ccccc3O2)cc1 ; c1ccc(-c2ccccc2N(c2ccccc2)c2cc3c4c(c2)N(c2ccccc2-c2ccccc2)c2ccccc2B4c2cc4c(cc2O3)N(c2c(-c3ccccc3)cccc2-c2ccccc2)c2cc3c(c5c2B4c2ccccc2O5)B2c4ccccc4N(c4ccccc4)c4cc(N(c5ccccc5)c5ccccc5)cc(c42)O3)cc1]

TABLE 1

| Compound | λmax/nm | Fluorescence quantum yield/% |
|---|---|---|
| Example Compound B-17 | 458 | 80 |
| Example Compound C-18 | 460 | 80 |
| Example Compound C-26 | 460 | 83 |
| Example Compound H-1 | 455 | 85 |
| Example Compound H-2 | 457 | 81 |
| Comparative Example | 455 | 75 |
| Compound X-1 | | |
| Comparative Example | 454 | 78 |
| Compound X-2 | | |
| Comparative Example | 466 | 79 |
| Compound X-3 | | |

Referring to the results in Table 1, it is confirmed that because each of Example Compound B-17, Example Compound C-18, Example Compound C-26, Example Compound H-1, and Example Compound H-2 emits light in a wavelength region of about 450 nm to about 470 nm and a fluorescence quantum yield thereof is measured as a value of about 80% or higher, Example Compound B-17, Example Compound C-18, Example Compound C-26, Example Compound H-1, and Example Compound H-2 are suitable for use as a light-emitting material. Also, it is confirmed that each Comparative Example Compound emits light in a wavelength region of about 450 nm to about 470 nm and exhibits a fluorescence quantum yield in a similar level to Example Compounds.

### 3. Manufacture and Evaluation of Light-Emitting Element

Polycyclic compounds according to Examples or Comparative Example Compounds were manufactured by the following method. Light-emitting elements according to Example 1 to Example 5 were manufactured respectively using Compounds B-17, C-18, C-26, H-1 and H-2, which are the polycyclic compounds according to one or more embodiments, as a dopant material for an emission layer. Light-emitting elements according to Comparative Example 1 to Comparative Example 3 were manufactured respectively using Comparative Example Compound X-1 to Comparative Example Compound X-3 as a dopant material for the emission layer.

### (1) Manufacture of Light-Emitting Element

A first electrode having a thickness of about 1500 Å was formed or composed of an ITO, then was subjected to cleansing using ultrapure water and was subjected to UV ozone treatment for about 10 minutes. Thereafter, a hole injection layer having a thickness of about 100 Å was formed on the first electrode with dipyrazino[2,3-f: 2′,3′-h]quinoxaline-2,3,6,7,10,11-hexacarbonitrile (HAT-CN), and a hole transport layer having a thickness of about 400 Å was formed on the hole injection layer with α-NPD.

An electron blocking layer having a thickness of about 50 Å was formed on the hole transport layer with 3,3′-di(9H-carbazol-9-yl)-1,1′-biphenyl (mCBP), and an emission layer in which Example Compound or Comparative Example Compound, and mCBP were mixed at a ratio of about 20:80, was formed. In this case, the emission layer was formed to a thickness of about 200 Å. An electron transport layer having a thickness of about 300 Å was formed with 2,2′,2″-(1,3,5-benzinetriyl)-tris(1-phenyl-1-H-benzimidazole) (TPBi) on the emission layer, and an electron injection layer having a thickness of about 5 Å was formed with Liq on the electron transport layer. Subsequently, a second electrode having a thickness of about 1000 Å was formed with aluminum (Al) on the electron injection layer. Each layer was formed in a vacuum atmosphere by a deposition method.

Compounds used for the manufacture of the light-emitting elements according to Examples and Comparative Examples are disclosed herein. Each material is a material that is generally available, and the commercially available product was purified via sublimation and utilized for the manufacture of the element.

The compounds used for the manufacture of the light-emitting elements are as follows.

### Common Materials Used for the Manufacture of the Light-Emitting Elements

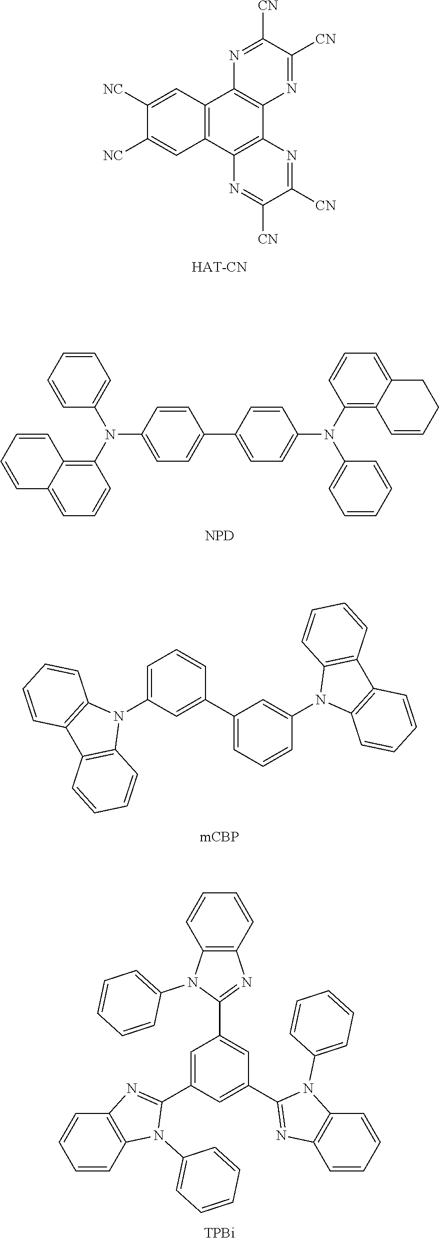

### (2) Evaluation of Characteristics of Light-Emitting Element

Characteristics of the light-emitting elements according to Example 1 to Example 5 and Comparative Example 1 to Comparative Example 3 were evaluated, and the results are listed in Table 2. For evaluation of the light-emitting element, a voltage and a current density were measured using a source meter (Keithley Instrument, Inc., 2400 series), and luminance and external quantum efficiency were measured using an external quantum efficiency measurement system C9920-12 made by Hamamatsu Photonics K,K. In Table 2, LT₅₀ is expressed as a relative value with respect to a half lifespan of Comparative Example 1 of 100%.

TABLE 2

| Element | | | | |
|---|---|---|---|---|
| manufacturing | | λmax | EQEₘₐₓ | LT₅₀ |
| example | Dopant | nm | % | % |
| Example 1 | Example Compound B-17 | 459 | 23 | 354 |
| Example 2 | Example Compound C-18 | 461 | 22 | 433 |
| Example 3 | Example Compound C-26 | 461 | 21 | 424 |
| Example 4 | Example Compound H-1 | 457 | 23 | 410 |
| Example 5 | Example Compound H-2 | 459 | 21 | 380 |
| Comparative | Comparative Example | 458 | 16 | 100 |
| Example 1 | Compound X1 | | | |
| Comparative | Comparative Example | 457 | 19 | 156 |
| Example 2 | Compound X2 | | | |
| Comparative | Comparative Example | 468 | 20 | 330 |
| Example 3 | Compound X3 | | | |

Referring to the results in Table 2, the light-emitting elements according to Examples exhibited similar light-emitting wavelength characteristics as the light-emitting elements according to Comparative Examples which include Comparative Example Compounds, each having a similar core structure as Example Compounds. Also, it can be confirmed that the light-emitting elements according to Examples using polycyclic compounds according to one or more embodiments as a light-emitting material have excellent or suitable efficiency, and, for example, have significantly or substantially improved or enhanced characteristics in element lifespan, compared to the light-emitting elements according to Comparative Examples. For example, it is seen that because the light-emitting elements according to Examples each include the polycyclic compound according to one or more embodiments having improved or enhanced material stability in the emission layer, the polycyclic compound has decreased deterioration in the emission layer, and thus luminous efficiency of the emission layer and lifespan characteristics of the element are improved or enhanced.

From the results in Table 2, it can be confirmed that because the first substituent is connected to at least one nitrogen atom of the core in the polycyclic compound according to one or more embodiments and at least two first sub substituents are additionally connected, resonance stability is improved or enhanced, molecular planarity is alleviated, and a boron atom of the core is sterically protected, and thus it can be confirmed that long lifespan characteristics is exhibited if (e.g., when) the polycyclic compound according to one or more embodiments is utilized as a light-emitting material.

In Example Compounds used in the light-emitting elements according to Example 1 to Example 5, compared to Comparative Example Compounds, the first substituent which is a phenyl group is connected to at least one nitrogen atom included in the core, two or three phenyl groups are additionally connected to the first substituent, and thus a steric protection effect for the core may increase or enhance. Therefore, the light-emitting elements according to Example 1 to Example 5 each have increased or enhanced efficiency as well as increased element stability.

On the contrary, because only one unsubstituted phenyl group is connected to each of nitrogen atoms of the core in Comparative Example Compound X-1 utilized in the light-emitting element according to Comparative Example 1, molecular distortion occurs due to steric hindrance, and thus resonance stability of the core deteriorates, and element lifespan is shortened.

In Comparative Example Compound X-3 utilized in the light-emitting element according to Comparative Example 3, because three boron atoms are introduced in the core, overall planarity of the molecule increases, and thus concentration quenching is more likely to occur. Therefore, the light-emitting element according to Comparative Example 3 exhibited slightly deteriorated luminous efficiency and lifespan characteristics compared to the light-emitting elements according to Examples.

In the light-emitting element according to one or more embodiments, the emission layer may include the polycyclic compound according to one or more embodiments. The polycyclic compound according to one or more embodiments may include, as a core structure, a fused ring with nine rings including four hetero atoms and two boron atoms as a ring-forming atom, and the core of the fused ring with nine rings may include at least one nitrogen atom as a hetero atom to which a first substituent and a plurality of first sub substituent are connected. Therefore, the polycyclic compound according to one or more embodiments may have a structure in which the fused ring core with nine rings is protected, and molecular planarity thereof is alleviated. Therefore, in the polycyclic compound according to one or more embodiments, because a multi-resonance core region where light-emitting-related transition occurs is protected, intermolecular interaction that may cause other side reactions other than light-emitting may be suppressed or reduced, and thus material stability may increase or enhance. Also, the light-emitting element including the polycyclic compound according to one or more embodiments in the emission layer may exhibit high efficiency and long lifespan characteristics.

The light-emitting element according to one or more embodiments may include the polycyclic compound according to one or more embodiments in the emission layer, and thus high efficiency and long lifespan characteristics may be exhibited.

The polycyclic compound according to one or more embodiments may contribute to improvements or enhancements in luminous efficiency and long lifespan.

The electronic apparatus according to one or more embodiments may exhibit excellent or suitable display quality.

Hereinbefore, certain embodiments of the present disclosure have been described and illustrated, however, it should be apparent to a person having ordinary skill in the art that the present disclosure is not limited to the embodiments as described, and may be suitably modified and transformed without departing from the spirit and scope of the present disclosure. In one or more embodiments, the modified or transformed embodiments as such may not be understood separately from the technical ideas and aspects of one or more embodiments of the present disclosure, and the modified embodiments may be within the scope of the appended claims and equivalents thereof of the present disclosure.

What is claimed is:

1. An electronic apparatus comprising:
a display panel comprising a plurality of light-emitting elements,
wherein at least one selected from among the plurality of light-emitting elements comprises a first electrode, a second electrode being opposite to the first electrode, and an emission layer provided between the first electrode and the second electrode and comprising a polycyclic compound represented by Formula 1: 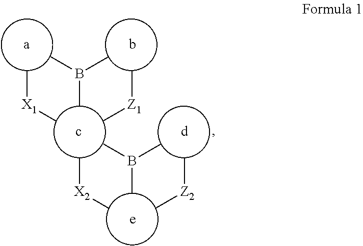
wherein, in Formula 1,
ring a, ring b, ring c, ring d, and ring e are each independently a substituted or unsubstituted aromatic hydrocarbon ring having 6 to 30 ring-forming carbon atoms, or a substituted or unsubstituted heterocycle which comprises a hetero atom other than a boron atom as a ring-forming atom and has 2 to 30 ring-forming carbon atoms, or bonded to an adjacent group to form a ring,
X₁, X₂, Z₁, and Z₂ are each independently O, S, NRₐ, or NR_{b}, and at least one of X₁, X₂, Z₁, or Z₂ is NR_{b},
Rₐ is a substituted or unsubstituted aryl group having 6 to 30 ring-forming carbon atoms or is bonded to an adjacent group to form a ring, and
R_{b} is represented by Formula 2: 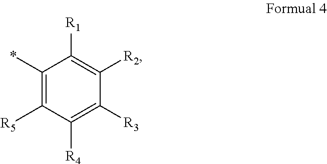
wherein, in Formula 2,
R₁ to R₅ are each independently a hydrogen atom, a deuterium atom, a halogen atom, a cyano group, a nitro group, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, or represented by Formula 3, [symbol]
is a portion connected to Formula 1, and
at least two selected from among R₁ to R₅ are represented by Formula 3: 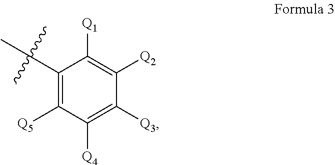
wherein, in Formula 3,
Q₁ to Q₅ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and 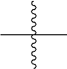
is a portion connected to Formula 2.

2. The electronic apparatus as claimed in claim 1, comprising a display device,
the display device comprising the display panel and displaying a video,
wherein the display device further comprises a first emission region, a second emission region, and a third emission region, each arranged to emit light in a different wavelength region and distinguished from each other on a plane, and
the first emission region, the second emission region, and the third emission region are each a region arranged to emit light generated in each of the plurality of light-emitting elements.

3. The electronic apparatus as claimed in claim 2, wherein the plurality of light-emitting elements each comprises a first light-emitting element arranged to correspond to the first emission region, a second light-emitting element arranged to correspond to the second emission region, and a third light-emitting element arranged to correspond to the third emission region.

4. The electronic apparatus as claimed in claim 2, wherein the display device comprises a plurality of display surfaces each having a different main display direction for the video.

5. The electronic apparatus as claimed in claim 1, comprising a plurality of display devices independently controlled and each displaying a video,
wherein at least one selected from among the plurality of display devices comprises the display panel.

6. The electronic apparatus as claimed in claim 1, further comprising at least one selected from among a processor, a memory, and a power module.

7. The electronic apparatus as claimed in claim 1,
the electronic apparatus is a television, a monitor, an outdoor billboard, a personal computer, a laptop computer, a personal digital assistant, a vehicular apparatus, a game console, a smartphone, a tablet terminal, a smart watch, or a camera.

8. A light-emitting element comprising:
a first electrode;
a second electrode being opposite to the first electrode; and
an emission layer provided between the first electrode and the second electrode and comprising a first compound represented by Formula 1: 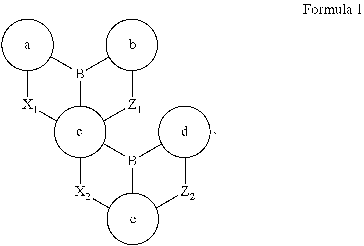
wherein, in Formula 1,
ring a, ring b, ring c, ring d, and ring e are each independently a substituted or unsubstituted aromatic hydrocarbon ring having 6 to 30 ring-forming carbon atoms or a substituted or unsubstituted heterocycle which comprises a hetero atom other than a boron atom as a ring-forming atom and has 2 to 30 ring-forming carbon atoms, or bonded to an adjacent group to form a ring,
X₁, X₂, Z₁, and Z₂ are each independently O, S, NRₐ, or NR_{b}, and at least one of X₁, X₂, Z₁, or Z₂ is NR_{b},
Rₐ is a substituted or unsubstituted aryl group having 6 to 30 ring-forming carbon atoms or is bonded to an adjacent group to form a ring, and
R_{b} is represented by Formula 2: 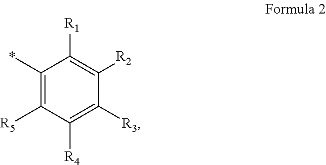
wherein, in Formula 2,
R₁ to R₅ are each independently a hydrogen atom, a deuterium atom, a halogen atom, a cyano group, a nitro group, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, or represented by Formula 3, [symbol]
is a portion connected to Formula 1, and
at least two selected from among R₁ to R₅ are represented by Formula 3: 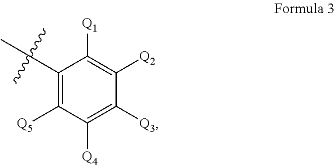
wherein, in Formula 3,
Q₁ to Q₅ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and 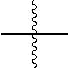
is a portion connected to Formula 2.

9. The light-emitting element as claimed in claim 8, wherein Formula 2 is represented by Formula 2-1: 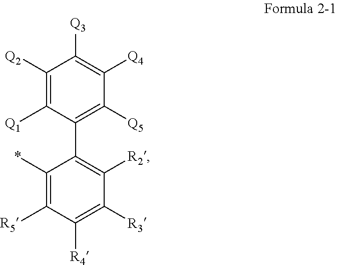
wherein, in Formula 2-1,
one or two selected from among R₂′, R₃′, R₄′, and R₅′ are represented by Formula 3, and the rest are each independently a hydrogen atom, a deuterium atom, or a substituted or unsubstituted alkyl group having 1 to 20 carbon atoms, and
Q₁ to Q₅ are the same as defined in Formula 3.

10. The light-emitting element as claimed in claim 8,
wherein at least one selected from among X₁, X₂, and Z₂ is NR_{b}, and
Z₁ and the rest among X₁, X₂, and Z₂ that are not NR_{b} are each independently O, S, or NRₐ.

11. The light-emitting element as claimed in claim 8, wherein the first compound represented by Formula 1 is represented by Formula 4: 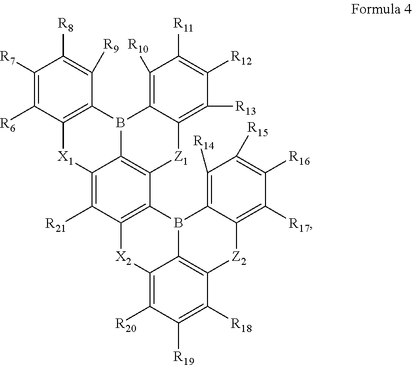
wherein, in Formula 4,
R₆ to R₂₁ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and
X₁, X₂, Z₁, and Z₂ are the same as defined in Formula 1.

12. The light-emitting element as claimed in claim 11,
wherein the first compound represented by Formula 4 is represented by any one selected from among Formula 5-1 to Formula 5-3: 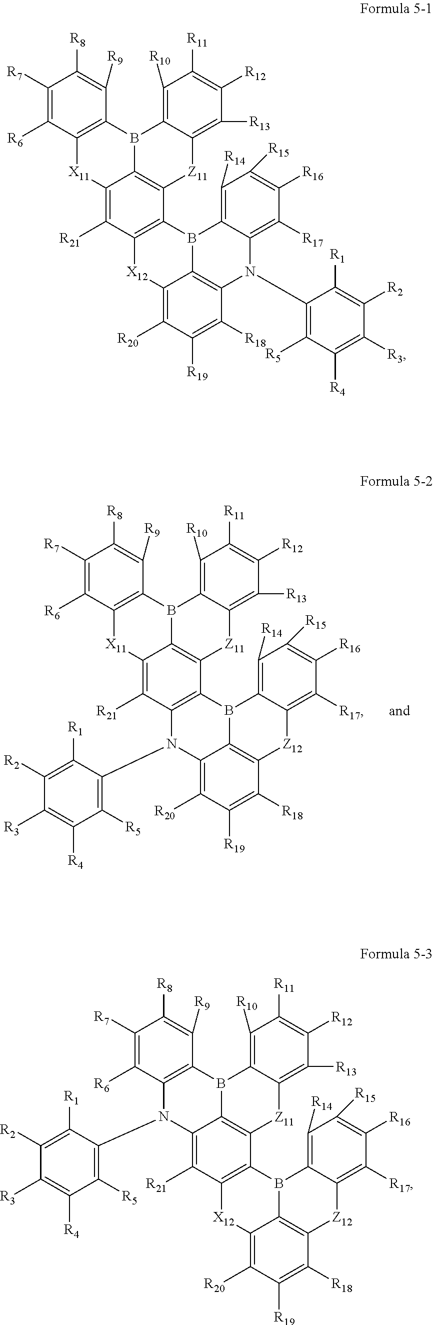
wherein, in Formula 5-1 to Formula 5-3,
X₁₁, X₁₂, and Z₁₂ are each independently O, S, NRₐ, or NR_{b},
Z₁ is O, S, or NRₐ,
Rₐ and R_{b} are the same as defined in Formula 1,
R₁ to R₅ are the same as defined in Formula 2, and
R₆ to R₂₁ are the same as defined in Formula 4.

13. The light-emitting element as claimed in claim 11, wherein the first compound represented by Formula 4 is represented by any one selected from among Formula 6-1 to Formula 6-6: 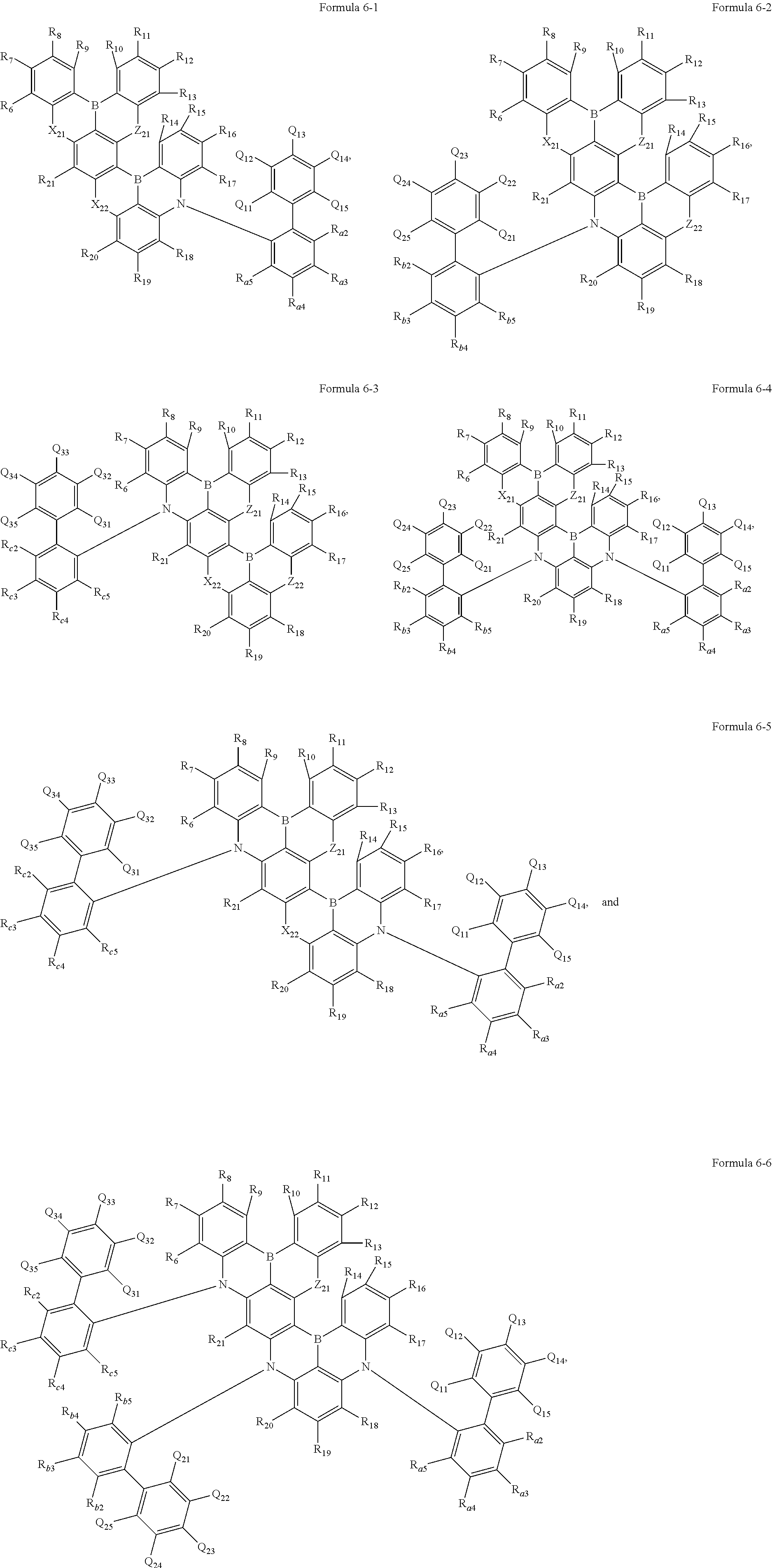
wherein, in Formula 6-1 to Formula 6-6,
X₂₁, X₂₂, Z₂₁, and Z₂₂ are each independently O, S, or NRₐ,
at least one selected from among Rₐ₂ to Rₐ₅, at least one selected from among R_{b2} to R_{b5}, and at least one selected from among R_{c2} to R_{c5} are each independently represented by Formula 3,
the rest among Rₐ₂ to Rₐ₅, R_{b2} to R_{b5}, and R_{c2} to R_{c5} that are not represented by Formula 3 are each independently a hydrogen atom, a deuterium atom, a substituted or unsubstituted alkyl group having 1 to 20 carbon atoms, or a substituted or unsubstituted aryl group having 6 to 30 ring-forming carbon atoms,
Q₁₁ to Q₁₅, Q₂₁ to Q₂₅, and Q₃₁ to Q₃₅ are each independently a hydrogen atom, a deuterium atom, a substituted or unsubstituted t-butyl group, a substituted or unsubstituted phenyl group, or bonded to an adjacent group to form a ring,
Rₐ is the same as defined in Formula 1, and
R₆ to R₂₁ are the same as defined in Formula 4.

14. The light-emitting element as claimed in claim 11, wherein R₆ to R₂₁ are each independently a hydrogen atom, a deuterium atom, a cyano group, a substituted or unsubstituted diphenylamine group, a substituted or unsubstituted propyl group, a substituted or unsubstituted t-butyl group, a substituted or unsubstituted phenyl group, a substituted or unsubstituted terphenyl group, a substituted or unsubstituted carbazole group, or a substituted or unsubstituted dibenzofuran group.

15. The light-emitting element as claimed in claim 8, wherein at least one selected from among hydrogen atoms in the first compound represented by Formula 1 is substituted with a deuterium atom.

16. The light-emitting element as claimed in claim 8, wherein the emission layer emits blue light.

17. The light-emitting element as claimed in claim 8, wherein the emission layer further comprises at least one selected from among a second compound represented by Formula HT-1, a third compound represented by Formula ET-1, and a fourth compound represented by Formula D-1: 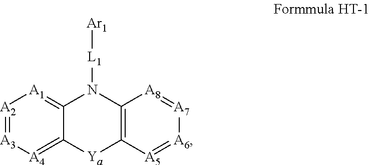
wherein, in Formula HT-1,
A₁ to A₅ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring: 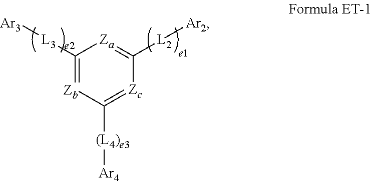
wherein, in Formula ET-1,
at least one selected from among Zₐ to Z_{c} is N, and the rest are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
e1 to e3 are each independently an integer of 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms: 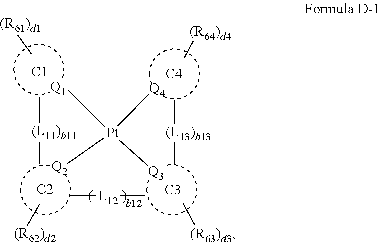
wherein, in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 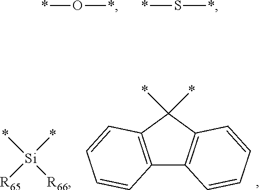
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring, and
d1 to d4 are each independently an integer of 0 to 4.

18. A polycyclic compound represented by Formula 1: 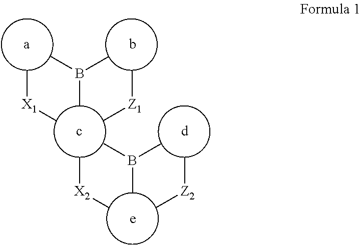
wherein in Formula 1,
ring a, ring b, ring c, ring d, and ring e are each independently a substituted or unsubstituted aromatic hydrocarbon ring having 6 to 30 ring-forming carbon atoms or a substituted or unsubstituted heterocycle which comprises a hetero atom other than a boron atom as a ring-forming atom and has 2 to 30 ring-forming carbon atoms, or bonded to an adjacent group to form a ring,
X₁, X₂, Z₁, and Z₂ are each independently O, S, NRₐ, or NR_{b}, and at least one of X₁, X₂, Z₁, or Z₂ is NR_{b},
Rₐ is a substituted or unsubstituted aryl group having 6 to 30 ring-forming carbon atoms or is bonded to an adjacent group to form a ring, and
R_{b} is represented by Formula 2: 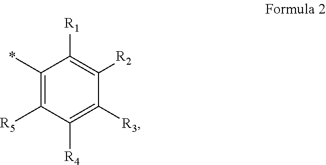
wherein, in Formula 2,
R₁ to R₅ are each independently a hydrogen atom, a deuterium atom, a halogen atom, a cyano group, a nitro group, a substituted or unsubstituted amine group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, or represented by Formula 3, [symbol]
is a portion connected to Formula 1, and
at least two selected from among R₁ to R₅ are represented by Formula 3: 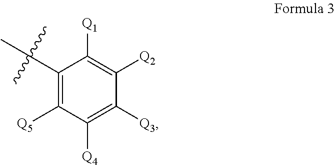
wherein, in Formula 3,
Q₁ to Q₅ are each independently a hydrogen atom, a deuterium atom, a halogen atom, a cyano group, a nitro group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring, and 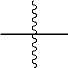
is a portion connected to Formula 2.

19. The polycyclic compound as claimed in claim 18, wherein Formula 2 is represented by Formula 2-1: 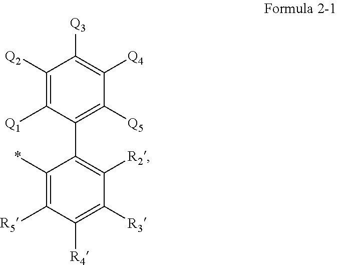
wherein, in Formula 2-1,
one or two selected from among R₂′, R₃′, R₄′, and R₅′ are represented by Formula 3, and the rest are each independently a hydrogen atom, a deuterium atom, or a substituted or unsubstituted alkyl group having 1 to 20 carbon atoms, and
Q₁ to Q₅ are the same as defined in Formula 3.

20. The polycyclic compound as claimed in claim 18, wherein Formula 1 is represented by Formula 4: 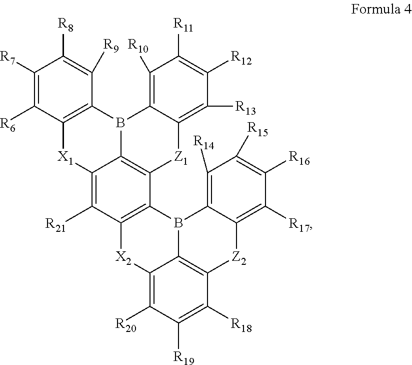
wherein, in Formula 4,
R₆ to R₂₁ are each independently a hydrogen atom, a deuterium atom, a cyano group, a substituted or unsubstituted amine group, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
X₁, X₂, Z₁, and Z₂ are the same as defined in Formula 1.
